(19) United States
(12) Patent Application Publication
(10) Pub. No.: US 2023/0276689 A1
(43) Pub. Date: Aug. 31, 2023

(54) LIGHT EMITTING DEVICE AND FUSED POLYCYCLIC COMPOUND FOR LIGHT EMITTING DEVICE

(71) Applicant: Samsung Display Co., Ltd., Yongin-si (KR)

(72) Inventors: MINJUNG JUNG, Namhae-gun (KR); TAEIL KIM, Hwaseong-si (KR); SERAN KIM, Suwon-si (KR); JUNHA PARK, Gwacheon-si (KR); JANG YEOL BAEK, Yongin-si (KR); MinJae SUNG, Hwaseong-si, (KR)

(21) Appl. No.: 18/057,124

(22) Filed: Nov. 18, 2022

(30) Foreign Application Priority Data
Feb. 25, 2022 (KR) 10-2022-0025158

(51) Int. Cl. H01L 51/00; C07F 5/02; C09K 11/06

(52) U.S. Cl. CPC H01L 51/008; H01L 51/0094; H01L 51/0087; C07F 5/027; C09K 11/06; H01L 51/5028

(57) ABSTRACT

Provided is a light emitting device including a first electrode, a second electrode facing the first electrode, and an emission layer between the first electrode and the second electrode, wherein the emission layer includes a first compound represented by Formula 1 below:

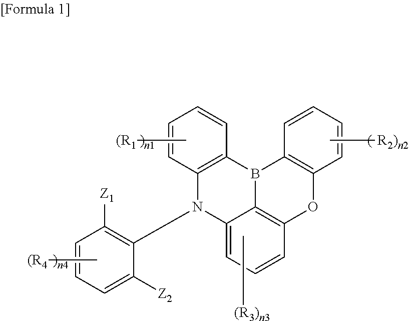

### CROSS-REFERENCE TO RELATED APPLICATION

This application claims priority to and the benefit of Korean Patent Application No. 10-2022-0025158, filed on Feb. 25, 2022, the entire contents of which are hereby incorporated by reference.

### BACKGROUND

### 1. Field

Embodiments of the present disclosure herein relate to a light emitting device and a fused polycyclic compound for the light emitting device.

### Description of the Related Art

Recently, the development of an organic electroluminescence display apparatus as an image display apparatus is being actively conducted. Unlike liquid crystal display apparatuses and the like, the organic electroluminescence display apparatus is a so-called self-luminescent display apparatus in which holes and electrons injected from a first electrode and a second electrode recombine in an emission layer, and thus, a luminescent material including an organic compound in the emission layer emits light to implement a display.

In the application of an organic electroluminescence device to a display apparatus, there is a demand for an organic electroluminescence device having a low driving voltage, high luminous efficiency, and a long service life, and the development on materials, for an organic electroluminescence device, capable of stably attaining such characteristics is being continuously researched.

Recently, in order to accomplish an organic electroluminescence device having high efficiency, techniques of phosphorescence emission which uses energy in a triplet state or delayed fluorescence emission which uses the generating phenomenon of singlet excitons by the collision of triplet excitons (triplet-triplet annihilation, TTA) are being developed, and development of a material for thermally activated delayed fluorescence (TADF) using delayed fluorescence phenomenon is being conducted.

### SUMMARY

Embodiments of the present disclosure provide a light emitting device in which luminous efficiency and a device service life are improved.

Embodiments of the present disclosure also provide a fused polycyclic compound capable of improving luminous efficiency and a device service life of a light emitting device.

An embodiment of the present disclosure provides a light emitting device including a first electrode, a second electrode facing the first electrode, and an emission layer between the first electrode and the second electrode, wherein the emission layer includes a first compound represented by Formula 1 below:

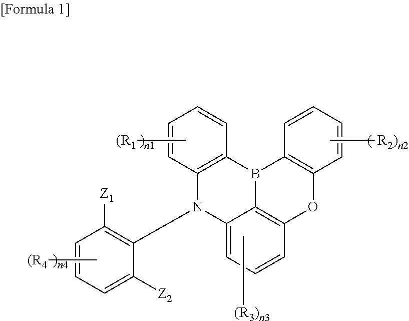

In Formula 1 above, R₁ to R₄ are each independently a hydrogen atom, a deuterium atom, a halogen atom, a cyano group, a nitro group, a substituted or unsubstituted oxy group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring, Z₁ and Z₂ are each independently a substituted or unsubstituted aryl group having 6 to 30 ring-forming carbon atoms, or a substituted or unsubstituted heteroaryl group having 2 to 30 ring-forming carbon atoms, n1 and n2 are each independently an integer of 0 to 4, and n3 and n4 are each independently an integer of 0 to 3.

In an embodiment, the first compound represented by Formula 1 above may be represented by Formula 2 below:

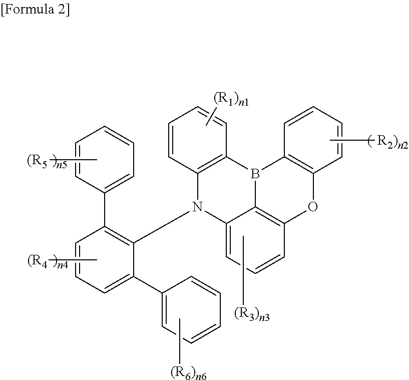

In Formula 2 above, R₅ and R₆ are each independently a hydrogen atom, a deuterium atom, a halogen atom, a cyano group, a nitro group, a substituted or unsubstituted oxy group, a substituted or unsubstituted thio group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring, and n5 and n6 are each independently an integer of 0 to 5.

In Formula 2 above, the same as defined with respect to Formula 1 above may be applied to R₁ to R₄, and n1 to n4.

In an embodiment, the first compound represented by Formula 1 above may be represented by any one selected from among Formula 3-1 to Formula 3-3 below:

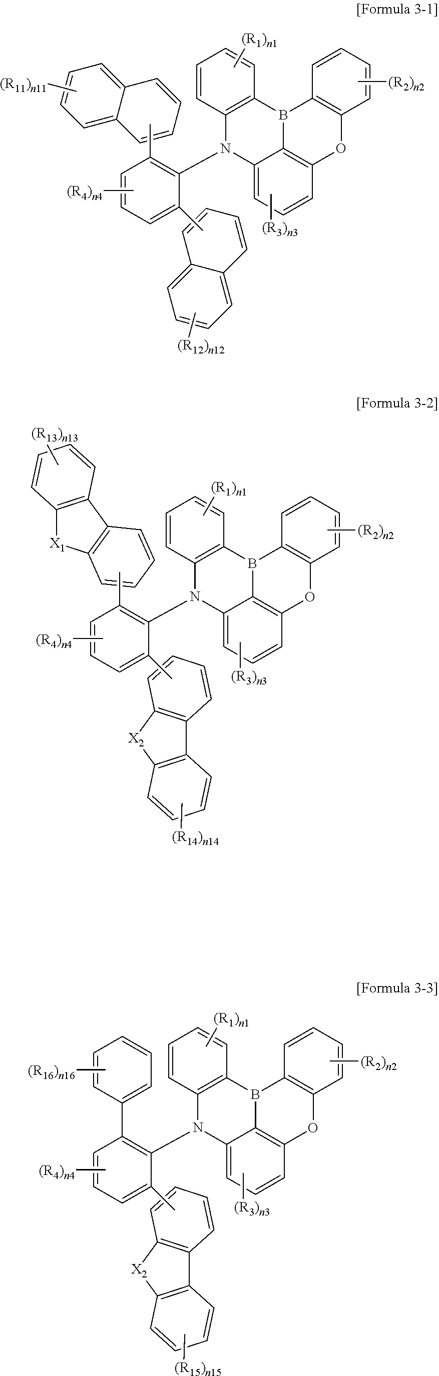

In Formula 3-1 to Formula 3-3 above, X₁ to X₃ are each independently NR₁₇, O, or S, R₁₁ to R₁₇ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, n11 to n15 are each independently an integer of 0 to 7, and n16 is an integer of 0 to 5.

In Formula 3-1 to Formula 3-3 above, the same as defined with respect to Formula 1 above may be applied to R₁ to R₄, and n1 to n4.

In an embodiment, the first compound represented by Formula 1 above may be represented by Formula 4 below:

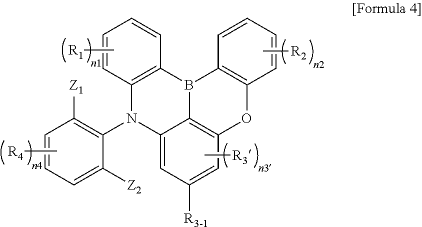

In Formula 4 above, R₃₋₁ is a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, R₃′ is a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and n3′ is an integer of 0 to 2.

In Formula 4 above, the same as defined with respect to Formula 1 above may be applied to R₁, R₂, R₄, n1, n2, n4, Z₁, and Z₂.

In an embodiment, R₃₋₁ above may be a deuterium atom or a substituted or unsubstituted alkyl group having 1 to 10 carbon atoms, or may be represented by any one selected from among Formula 5-1 to Formula 5-4 below:

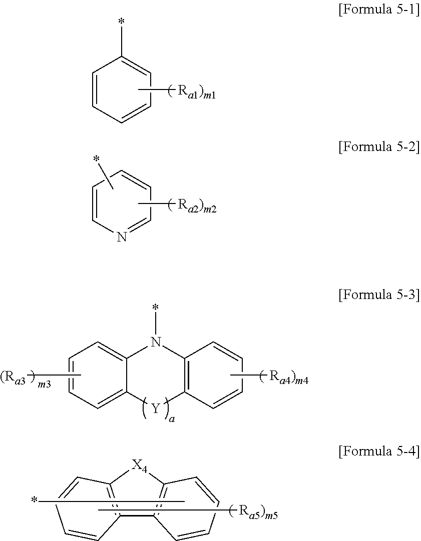

In Formula 5-1 to Formula 5-4 above, X₄ is NRₐ₆, O, S, or Se, Rₐ₁ to Rₐ₆ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, a is 0 or 1, when a is 1, Y is a direct linkage, m1, m3, and m4 are each independently an integer of 0 to 5, m2 is an integer of 0 to 4, m5 is an integer of 0 to 7, the sum of a and m3 is 5 or less, and the sum of a and m4 is 5 or less.

In an embodiment, the first compound represented by Formula 1 above may be represented by any one selected from among Formula 6-1 to Formula 6-4 below:

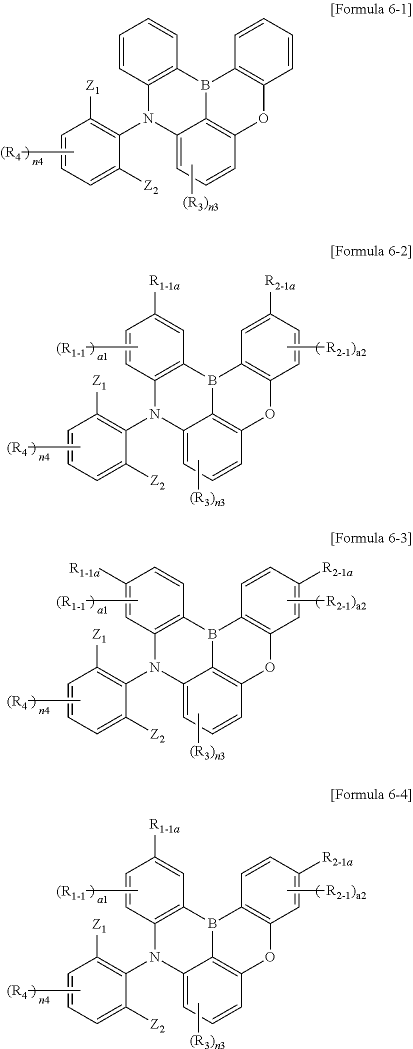

In Formula 6-1 to Formula 6-4 above, R₁₋₁ to R₂₋₁ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, R₁₋₁ₐ and R₂₋₁ₐ are each independently a substituted or unsubstituted amine group, a substituted or unsubstituted phenyl group, a substituted or unsubstituted dibenzofuran group, or a substituted or unsubstituted carbazole group, and a1 and a2 are each independently an integer of 0 to 3.

In Formula 6-1 to Formula 6-4 above, the same as defined with respect to Formula 1 above may be applied to R₃, R₄, n3, n4, Z₁, and Z₂.

In an embodiment, the first compound represented by Formula 1 above may be represented by any one selected from among Formula 7-1 to Formula 7-5 below:

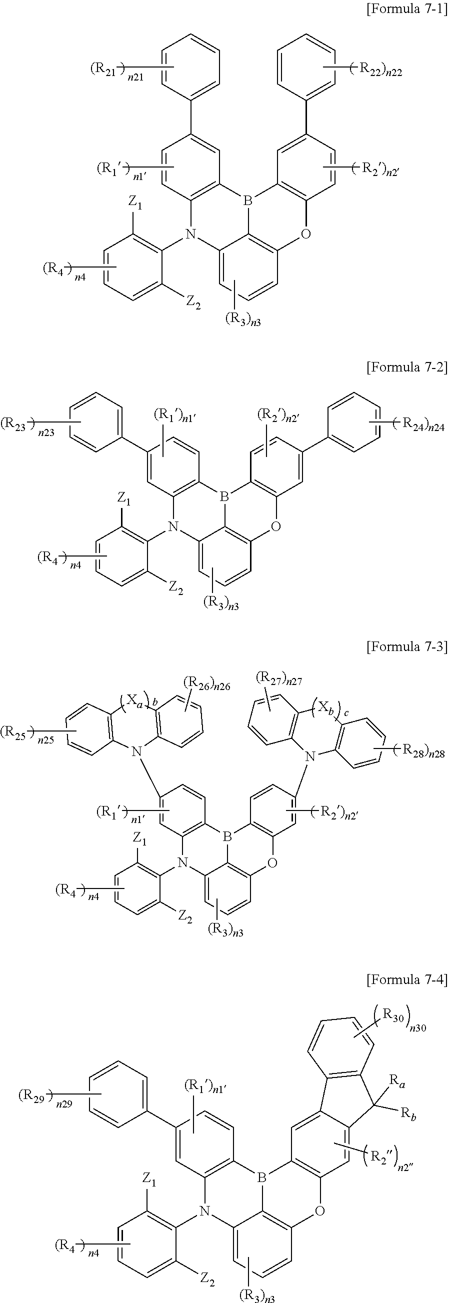

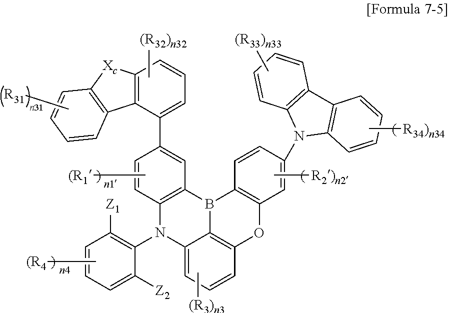

In Formula 7-1 to Formula 7-5 above, Xₐ to X_{c} are each independently a direct linkage, O, NR₃₅, CR₃₆R₃₇, S, or Se, R₂₁ to R₃₇ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, Rₐ and R_{b} are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring, R₁′, R₂′, and R₂″ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, n1′ and n2′ are each independently an integer of 0 to 3, n2″ is an integer of 0 to 2, b and c are each independently 0 or 1, n21 to n29 are each independently an integer of 0 to 5, n30, n31, n33, and n34 are each independently an integer of 0 to 4, n32 is an integer of 0 to 3, the sum of b and n25 is 5 or less, the sum of b and n26 is 5 or less, the sum of c and n27 is 5 or less, and the sum of c and n28 is 5 or less.

In Formula 7-1 to Formula 7-5 above, the same as defined with respect to Formula 1 above may be applied to R₃, R₄, n3, n4, Z₁, and Z₂.

In an embodiment, Z₁ and Z₂ above may be each independently represented by any one selected from among Formula 8-1 to Formula 8-4 below:

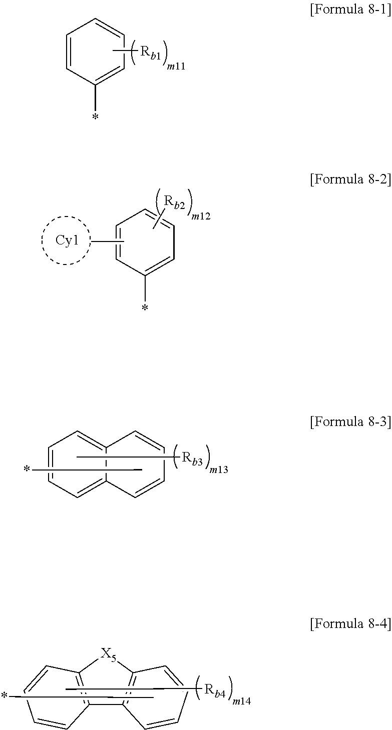

In Formula 8-1 to Formula 8-4 above, Cy1 is a substituted or unsubstituted cycloalkyl group having 3 to 10 carbon atoms, X₅ is NR_{b5}, O, or S, R_{b1} to R_{b5} are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, m11 is an integer of 0 to 5, m12 is an integer of 0 to 4, and m13 and m14 are each independently an integer of 0 to 7.

In an embodiment, the emission layer may further include a second compound represented by Formula H-1 below:

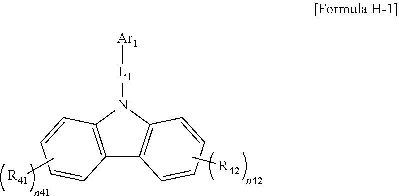

In Formula H-1 above, L₁ is a direct linkage, a substituted or unsubstituted arylene group having 6 to 30 ring-forming carbon atoms, or a substituted or unsubstituted heteroarylene group having 2 to 30 ring-forming carbon atoms, Ar₁ is a substituted or unsubstituted aryl group having 6 to 30 ring-forming carbon atoms, or a substituted or unsubstituted heteroaryl group having 2 to 30 ring-forming carbon atoms, R₄₁ and R₄₂ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring, and n41 and n42 are each independently an integer of 0 to 4.

In an embodiment, the emission layer may further include a third compound represented by Formula H-2 below:

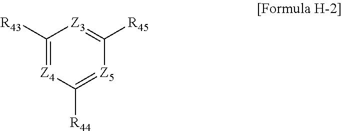

In Formula H-2 above, Z₃ to Z₅ are each independently N or CR₄₆, at least any one selected from among Z₃ to Z₅ is N, and R₄₃ to R₄₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring.

In an embodiment, the emission layer may further include a fourth compound represented by Formula D-1 below:

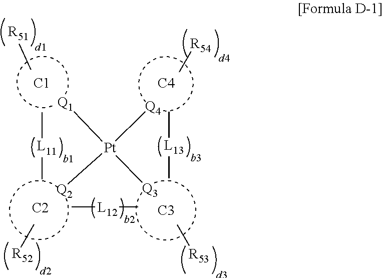

In Formula D-1 above, Q₁ to Q₄ are each independently C or N, C1 to C4 are each independently a substituted or unsubstituted hydrocarbon ring having 5 to 30 ring-forming carbon atoms, or a substituted or unsubstituted heterocycle having 2 to 30 ring-forming carbon atoms, L₁₁ to L₁₃ are each independently a direct linkage,

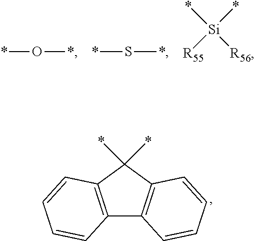

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, b1 to b3 are each independently 0 or 1, R₅₁ to R₅₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring, and d1 to d4 are each independently an integer of 0 to 4.

In an embodiment of the present disclosure, a fused polycyclic compound is represented by Formula 1 above.

### BRIEF DESCRIPTION OF THE DRAWINGS

The accompanying drawings are included to provide a further understanding of the subject matter of the present disclosure, and are incorporated in and constitute a part of this specification. The drawings illustrate example embodiments of the present disclosure and, together with the description, serve to explain principles of the present disclosure. In the drawings:

FIG. 1 is a plan view of a display apparatus according to an embodiment of the present disclosure;

FIG. 2 is a cross-sectional view of a display apparatus according to an embodiment of the present disclosure;

FIG. 3 is a cross-sectional view schematically illustrating a light emitting device according to an embodiment of the present disclosure;

FIG. 4 is a cross-sectional view schematically illustrating a light emitting device according to an embodiment of the present disclosure;

FIG. 5 is a cross-sectional view schematically illustrating a light emitting device according to an embodiment of the present disclosure;

FIG. 6 is a cross-sectional view schematically illustrating a light emitting device according to an embodiment of the present disclosure;

Each of FIGS. 7 and 8 is a cross-sectional view of a display apparatus according to an embodiment of the present disclosure;

FIG. 9 is a cross-sectional view illustrating a display apparatus according to an embodiment of the present disclosure; and

FIG. 10 is a cross-sectional view illustrating a display apparatus according to an embodiment of the present disclosure.

### DETAILED DESCRIPTION

The subject matter of the present disclosure may be modified in many alternate forms, and thus, example embodiments will be illustrated in the drawings and described in this text in more detail. It should be understood, however, that it is not intended to limit the present disclosure to the particular forms disclosed, but rather, is intended to cover all modifications, equivalents, and alternatives falling within the spirit and scope of the present disclosure.

When explaining each of the drawings, like reference numerals are used for referring to like elements. In the accompanying drawings, the dimensions of each structure may be exaggeratingly illustrated for clarity of the present disclosure. It will be understood that, although the terms “first”, “second”, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the singular forms, “a,” “an,” and “the” are intended to include the plural forms as well, unless the context clearly indicates otherwise.

In the present application, it will be understood that the terms “include,” “have” or the like specify the presence of features, numbers, steps, operations, components, parts, or combinations thereof disclosed in the specification, but do not exclude the possibility of presence or addition of one or more other features, numbers, steps, operations, components, parts, or combinations thereof.

In the present application, when a part such as a layer, a film, a region, or a plate is referred to as being “on” or “above” another part, it can be directly on the other part, or an intervening part may also be present. On the contrary, when a part such as a layer, a film, a region, or a plate is referred to as being “under” or “below” another part, it can be directly under the other part, or an intervening part may also be present. In addition, it will be understood that when a part is referred to as being “on” another part, it can be above the other part, or under the other part as well.

In the present specification, the term “substituted or unsubstituted” may mean substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group. In addition, each of the substituents described above may be substituted or unsubstituted. For example, a biphenyl group may be interpreted as an aryl group or a phenyl group substituted with a phenyl group.

In the present specification, the phrase “bonded to an adjacent group to form a ring” may indicate that one is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. In addition, the rings formed by being bonded to each other may be connected to another ring to form a spiro structure.

In the present specification, the term “adjacent group” may mean a substituent substituted for an atom which is directly linked to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In addition, two methyl groups in 4,5-dimethylphenanthrene may be interpreted as “adjacent groups” to each other.

In the present specification, examples of the halogen atom may include a fluorine atom, a chlorine atom, a bromine atom, or an iodine atom.

In the present specification, the alkyl group may be a linear, branched, or cyclic type (e.g., a linear alkyl group, a branched alkyl group, or a cyclic alkyl group). The number of carbons in the alkyl group is 1 to 50, 1 to 30, 1 to 20, 1 to 10, or 1 to 6. Examples of the alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments of the present disclosure are not limited thereto.

In the present specification, a cycloalkyl group may mean a cyclic alkyl group. The number of carbons in the cycloalkyl group is 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments of the present disclosure are not limited thereto.

In the present specification, the alkenyl group means a hydrocarbon group including one or more carbon double bonds in the middle of or at the terminal of an alkyl group having two or more carbon atoms. The alkenyl group may be a linear chain or a branched chain. The carbon number is not specifically limited, but is 2 to 30, 2 to 20, or 2 to 10. Examples of the alkenyl group include a vinyl group, a 1-butenyl group, a 1-pentenyl group, a 1,3-butadienyl aryl group, a styrenyl group, a styrylvinyl group, etc., without limitation.

In the present specification, an aryl group means any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments of the present disclosure are not limited thereto.

In the present specification, the fluorenyl group may be substituted, and two substituents may be bonded to each other to form a spiro structure. Examples of cases where the fluorenyl group is substituted are as follows. However, embodiments of the present disclosure are not limited thereto.

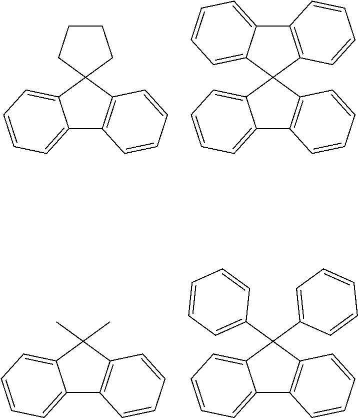

In the present specification, the heteroaryl group may include at least one of B, O, N, P, Si, or S as a heteroatom. When the heteroaryl group contains two or more heteroatoms, the two or more heteroatoms may be the same as or different from each other. The heteroaryl group may be a monocyclic heterocyclic group or polycyclic heterocyclic group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments of the present disclosure are not limited thereto.

In the present specification, the above description of the aryl group may be applied to an arylene group except that the arylene group is a divalent group. The above description of the heteroaryl group may be applied to a heteroarylene group except that the heteroarylene group is a divalent group.

In the description, the silyl group includes an alkylsilyl group and an arylsilyl group. Examples of the silyl group may include trimethylsilyl, triethylsilyl, t-butyldimethylsilyl, vinyldimethylsilyl, propyldimethylsilyl, triphenylsilyl, diphenylsilyl, phenylsilyl, etc. However, embodiments of the present disclosure are not limited thereto.

In the present specification, a thio group may include an alkylthio group and an arylthio group. The thio group may mean that a sulfur atom is bonded to the alkyl group or the aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments of the present disclosure are not limited thereto.

In the present specification, an oxy group may mean that an oxygen atom is bonded to the alkyl group or the aryl group as defined above. The oxy group may include an alkoxy group and an aryl oxy group. The alkoxy group may be a linear chain, a branched chain, or a ring chain. The number of carbon atoms in the alkoxy group is not specifically limited, but may be, for example, 1 to 20 or 1 to 10. Examples of the oxy group include methoxy, ethoxy, n-propoxy, isopropoxy, butoxy, pentyloxy, hexyloxy, octyloxy, nonyloxy, decyloxy, benzyloxy, etc., but embodiments of the present disclosure are not limited thereto.

The boron group herein may mean that a boron atom is bonded to the alkyl group or the aryl group as defined above. The boron group includes an alkyl boron group and an aryl boron group. Examples of the boron group may include a dimethylboron group, a trimethylboron group, a t-butyldimethylboron group, a diphenylboron group, a phenylboron group, etc., but embodiments of the present disclosure are not limited thereto.

In the present specification, the number of carbon atoms in an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, a triphenylamine group, etc., but embodiments of the present disclosure are not limited thereto.

In the present specification, a direct linkage may mean a single bond.

As used herein, “ [symbol] ” means a position to be connected.

Hereinafter, embodiments of the present disclosure will be described with reference to the accompanying drawings.

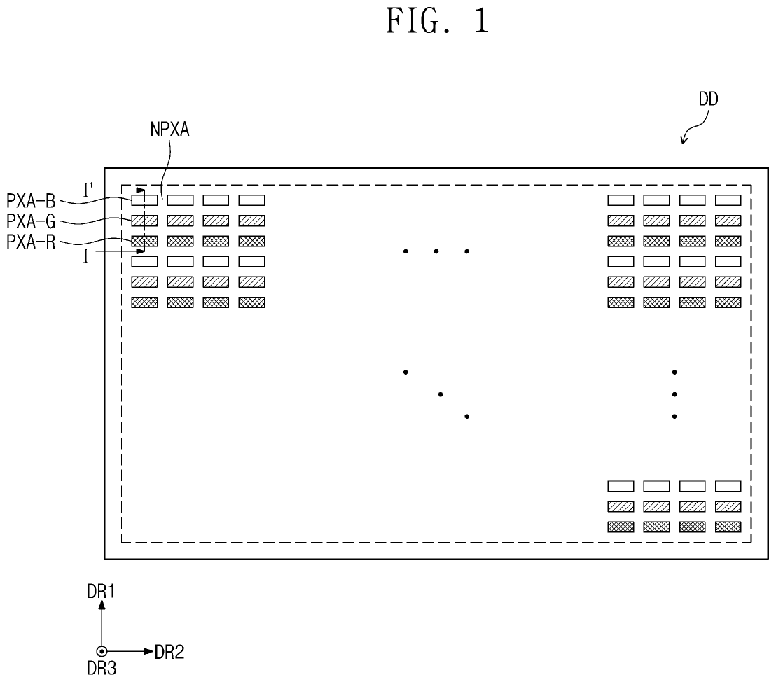

FIG. 1 is a plan view illustrating an embodiment of a display apparatus DD.

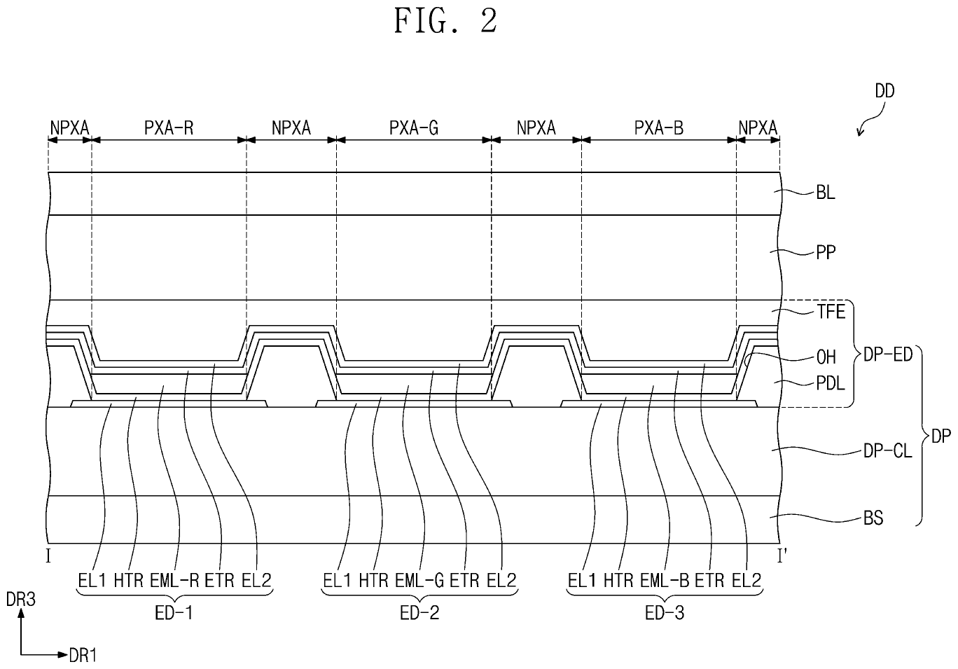

FIG. 2 is a cross-sectional view of the display apparatus DD of the embodiment. FIG. 2 is a cross-sectional view illustrating a part taken along line I-I′ of FIG. 1.

The display apparatus DD may include a display panel DP and an optical layer PP on the display panel DP. The display panel DP includes light emitting devices ED-1, ED-2, and ED-3. The display apparatus DD may include a plurality of light emitting devices ED-1, ED-2, and ED-3. The optical layer PP may be on the display panel DP to control reflected light in the display panel DP due to external light. The optical layer PP may include, for example, a polarization layer or a color filter layer. Unlike the configuration illustrated in the drawing, the optical layer PP may be omitted from the display apparatus DD of an embodiment.

A base substrate BL may be on the optical layer PP. The base substrate BL may be a member which provides a base surface on which the optical layer PP is located. The base substrate BL may be a glass substrate, a metal substrate, a plastic substrate, etc. However, embodiments of the present disclosure are not limited thereto, and the base substrate BL may be an inorganic layer, an organic layer, or a composite material layer. In addition, unlike the configuration illustrated, in an embodiment, the base substrate BL may be omitted.

The display apparatus DD according to an embodiment may further include a filling layer. The filling layer may be between a display device layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and the display device layer DP-ED. The display device layer DP-ED may include a pixel defining film PDL, the light emitting devices ED-1, ED-2, and ED-3 between portions of the pixel defining film PDL, and an encapsulation layer TFE on the light emitting devices ED-1, ED-2, and ED-3.

The base layer BS may be a member which provides a base surface on which the display device layer DP-ED is located. The base layer BS may be a glass substrate, a metal substrate, a plastic substrate, etc. However, the embodiment is not limited thereto, and the base layer BS may be an inorganic layer, an organic layer, or a composite material layer.

In an embodiment, the circuit layer DP-CL is on the base layer BS, and the circuit layer DP-CL may include a plurality of transistors. Each of the transistors may include a control electrode, an input electrode, and an output electrode. For example, the circuit layer DP-CL may include a switching transistor and a driving transistor for driving the light emitting devices ED-1, ED-2, and ED-3 of the display device layer DP-ED.

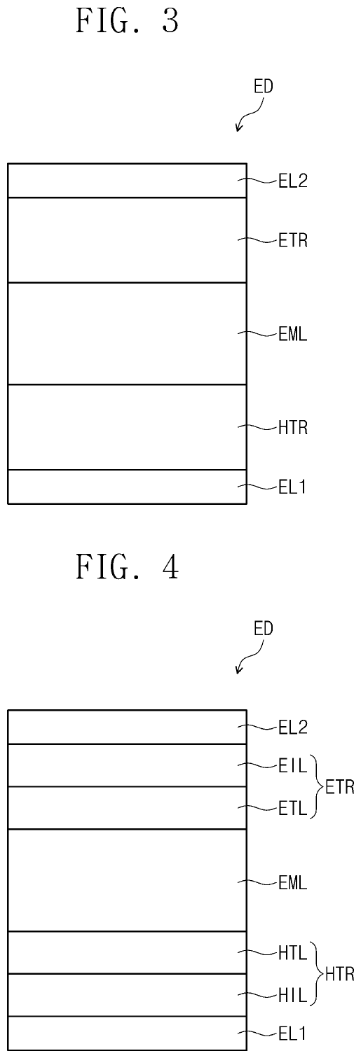

Each of the light emitting devices ED-1, ED-2, and ED-3 may have a structure of a light emitting device ED of an embodiment according to FIGS. 3 to 6, which will be further described herein below. Each of the light emitting devices ED-1, ED-2 and ED-3 may include a first electrode EL1, a hole transport region HTR, emission layers EML-R, EML-G and EML-B, an electron transport region ETR, and a second electrode EL2.

FIG. 2 illustrates an embodiment in which the emission layers EML-R, EML-G, and EML-B of the light emitting devices ED-1, ED-2, and ED-3 are in openings OH defined in the pixel defining film PDL, and the hole transport region HTR, the electron transport region ETR, and the second electrode EL2 are provided as a common layer in the entire light emitting devices ED-1, ED-2, and ED-3. However, embodiments of the present disclosure are not limited thereto, and unlike the configuration illustrated in FIG. 2, the hole transport region HTR and the electron transport region ETR in an embodiment may be provided by being patterned inside the openings OH defined in the pixel defining film PDL. For example, the hole transport region HTR, the emission layers EML-R, EML-G, and EML-B, and the electron transport region ETR of the light emitting devices ED-1, ED-2, and ED-3 in an embodiment may be provided by being patterned in an inkjet printing method.

The encapsulation layer TFE may cover the light emitting devices ED-1, ED-2, and ED-3. The encapsulation layer TFE may seal the display device layer DP-ED. The encapsulation layer TFE may be a thin film encapsulation layer. The encapsulation layer TFE may be formed by laminating one layer or a plurality of layers. The encapsulation layer TFE includes at least one insulation layer. The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film protects the display device layer DP-ED from moisture/oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, and/or the like, but embodiments of the present disclosure are not particularly limited thereto. The encapsulation-organic film may include an acrylic-based compound, an epoxy-based compound, and/or the like. The encapsulation-organic film may include a photopolymerizable organic material, but embodiments of the present disclosure are not particularly limited thereto.

The encapsulation layer TFE may be on the second electrode EL2 and may fill the opening OH.

Referring to FIGS. 1 and 2, the display apparatus DD may include a non-light emitting region NPXA and light emitting regions PXA-R, PXA-G, and PXA-B. The light emitting regions PXA-R, PXA-G, and PXA-B may be regions in which light generated by the respective light emitting devices ED-1, ED-2 and ED-3 is emitted. The light emitting regions PXA-R, PXA-G, and PXA-B may be spaced apart from each other on a plane.

Each of the light emitting regions PXA-R, PXA-G, and PXA-B may be a region divided by the pixel defining film PDL. The non-light emitting regions NPXA may be regions between the adjacent light emitting regions PXA-R, PXA-G, and PXA-B, which correspond to portions of the pixel defining film PDL. In the present specification, the light emitting regions PXA-R, PXA-G, and PXA-B may respectively correspond to pixels. The pixel defining film PDL may divide the light emitting devices ED-1, ED-2, and ED-3. The emission layers EML-R, EML-G, and EML-B of the light emitting devices ED-1, ED-2, and ED-3 may be in openings OH defined in the pixel defining film PDL and separated from (e.g., spaced apart from) each other.

The light emitting regions PXA-R, PXA-G, and PXA-B may be divided into a plurality of groups according to the color of light generated from the light emitting devices ED-1, ED-2, and ED-3. In the display apparatus DD of an embodiment shown in FIGS. 1 and 2, three light emitting regions PXA-R, PXA-G, and PXA-B which emit red light, green light, and blue light, respectively are illustrated as examples. For example, the display apparatus DD of an embodiment may include the red light emitting region PXA-R, the green light emitting region PXA-G, and the blue light emitting region PXA-B that are separated from (e.g., spaced apart from) each other.

In the display apparatus DD according to an embodiment, the plurality of light emitting devices ED-1, ED-2, and ED-3 may emit light beams having wavelengths different from each other. For example, in an embodiment, the display apparatus DD may include a first light emitting device ED-1 that emits red light, a second light emitting device ED-2 that emits green light, and a third light emitting device ED-3 that emits blue light. In some embodiments, the red light emitting region PXA-R, the green light emitting region PXA-G, and the blue light emitting region PXA-B of the display apparatus DD may correspond to the first light emitting device ED-1, the second light emitting device ED-2, and the third light emitting device ED-3, respectively.

However, embodiments of the present disclosure are not limited thereto, and the first to third light emitting devices ED-1, ED-2, and ED-3 may emit light beams in the same wavelength range or at least one light emitting device may emit a light beam in a wavelength range different from the others. For example, the first to third light emitting devices ED-1, ED-2, and ED-3 may all emit blue light.

The light emitting regions PXA-R, PXA-G, and PXA-B in the display apparatus DD according to an embodiment may be arranged in a stripe form. Referring to FIG. 1, the plurality of red light emitting regions PXA-R, the plurality of green light emitting regions PXA-G, and the plurality of blue light emitting regions PXA-B each may be arranged along a second directional axis DR2. In addition, the red light emitting region PXA-R, the green light emitting region PXA-G, and the blue light emitting region PXA-B may be alternately arranged in this order along a first directional axis DR1.

FIGS. 1 and 2 illustrate that all the light emitting regions PXA-R, PXA-G, and PXA-B have a similar area, but embodiments of the present disclosure are not limited thereto. Thus, the light emitting regions PXA-R, PXA-G, and PXA-B may have different areas from each other according to the wavelength range of the emitted light. In this case, the areas of the light emitting regions PXA-R, PXA-G, and PXA-B may mean areas when viewed on a plane defined by the first directional axis DR1 and the second directional axis DR2.

An arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations according to the characteristics of display quality required in the display apparatus DD. For example, the arrangement form of the light emitting regions PXA-R, PXA-G, and PXA-B may be a PENTILE™ arrangement form (e.g., an RGBG matrix, RGBG structure, or RGBG matrix structure) or a Diamond Pixel™ arrangement form. PENTILE® is a duly registered trademark of Samsung Display Co., Ltd.

In addition, the areas of the light emitting regions PXA-R, PXA-G, and PXA-B may be different from each other. For example, in an embodiment, the area of the green light emitting region PXA-G may be smaller than that of the blue light emitting region PXA-B, but embodiments of the present disclosure are not limited thereto.

Hereinafter, FIGS. 3 to 6 are cross-sectional views schematically illustrating light emitting devices according to embodiments. Each of the light emitting devices ED according to embodiments may include a first electrode EL1, a hole transport region HTR, an emission layer EML, an electron transport region ETR, and a second electrode EL2 that are sequentially stacked.

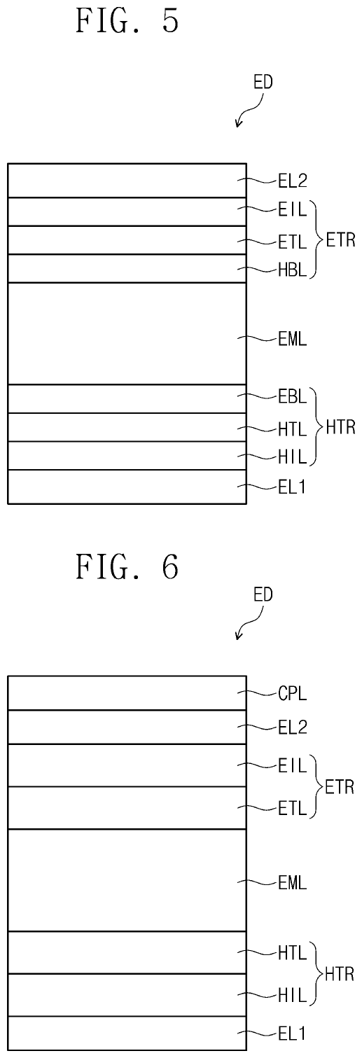

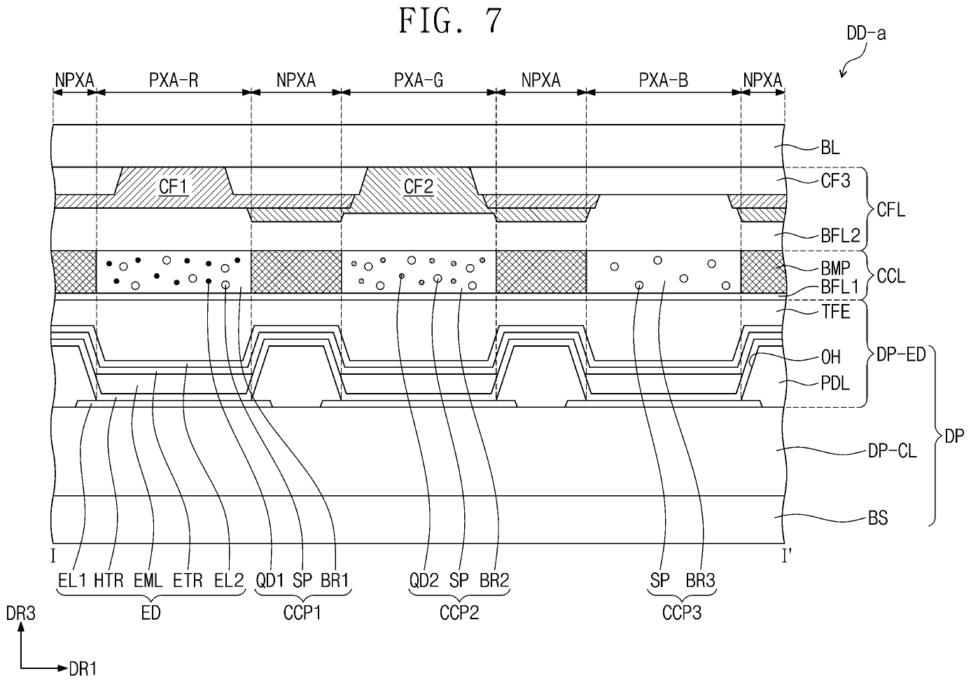

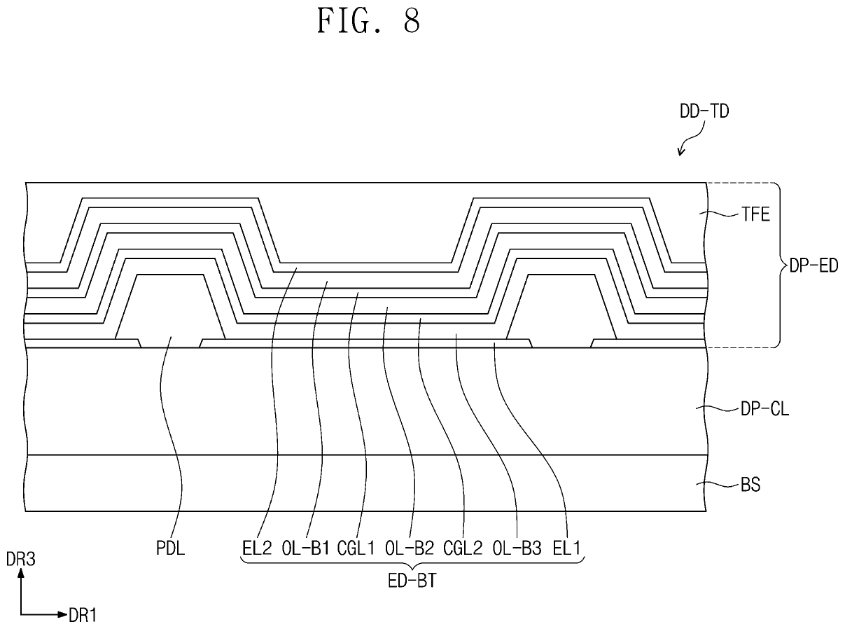

Compared with FIG. 3, FIG. 4 illustrates a cross-sectional view of a light emitting device ED of an embodiment, in which a hole transport region HTR includes a hole injection layer HIL and a hole transport layer HTL, and an electron transport region ETR includes an electron injection layer EIL and an electron transport layer ETL. In addition, compared with FIG. 3, FIG. 5 illustrates a cross-sectional view of a light emitting device ED of an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. Compared with FIG. 4, FIG. 6 illustrates a cross-sectional view of a light emitting device ED of an embodiment including a capping layer CPL on a second electrode EL2.

The first electrode EL1 has conductivity (e.g., electrical conductivity). The first electrode EL1 may be formed of a metal material, a metal alloy, and/or a conductive compound (e.g., an electrically conductive compound). The first electrode EL1 may be an anode or a cathode. However, embodiments of the present disclosure are not limited thereto. In addition, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from among these, a mixture of two or more selected from among these, and/or an oxide thereof.

If the first electrode EL1 is the transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound or mixture thereof (e.g., a mixture of Ag and Mg). In some embodiments, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but embodiments of the present disclosure are not limited thereto. In addition, embodiments of the present disclosure are not limited thereto, and the first electrode EL1 may include the above-described metal materials, combinations of at least two metal materials of the above-described metal materials, oxides of the above-described metal materials, or the like. The thickness of the first electrode EL1 may be from about 700 Å to about 10,000 Å. For example, the thickness of the first electrode EL1 may be from about 1,000 Å to about 3,000 Å.

The hole transport region HTR is provided on the first electrode EL1. The hole transport region HTR may include at least one of a hole injection layer HIL, a hole transport layer HTL, a buffer layer or an emission-auxiliary layer, or an electron blocking layer EBL. The thickness of the hole transport region HTR may be, for example, from about 50 Å to about 15,000 Å.

The hole transport region HTR may have a single layer formed of a single material, a single layer formed of a plurality of different materials, or a multilayer structure including a plurality of layers formed of a plurality of different materials.

For example, the hole transport region HTR may have a single layer structure of the hole injection layer HIL or the hole transport layer HTL, or may have a single layer structure formed of a hole injection material and a hole transport material. In addition, the hole transport region HTR may have a single layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order from the first electrode EL1, but embodiments of the present disclosure are not limited thereto.

The hole transport region HTR may be formed using various suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may include a compound represented by Formula H-2 below:

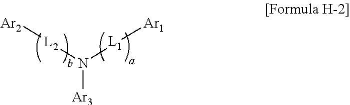

In Formula H-2 above, L₁ and L₂ may be each independently a direct linkage, a substituted or unsubstituted arylene group having 6 to 30 ring-forming carbon atoms, or a substituted or unsubstituted heteroarylene group having 2 to 30 ring-forming carbon atoms. a and b may be each independently an integer of 0 to 10. When a or b is an integer of 2 or greater, a plurality of L₁′s and L₂′s may be each independently a substituted or unsubstituted arylene group having 6 to 30 ring-forming carbon atoms, or a substituted or unsubstituted heteroarylene group having 2 to 30 ring-forming carbon atoms.

In Formula H-2, Ar₁ and Ar₂ may be each independently a substituted or unsubstituted aryl group having 6 to 30 ring-forming carbon atoms, or a substituted or unsubstituted heteroaryl group having 2 to 30 ring-forming carbon atoms. In addition, in Formula H-2, Ar₃ may be a substituted or unsubstituted aryl group having 6 to 30 ring-forming carbon atoms, or a substituted or unsubstituted heteroaryl group having 2 to 30 ring-forming carbon atoms.

The compound represented by Formula H-2 above may be a monoamine compound. In some embodiments, the compound represented by Formula H-2 above may be a diamine compound in which at least one selected from among Ar₁ to Ar₃ includes the amine group as a substituent. In addition, the compound represented by Formula H-2 above may be a carbazole-based compound including a substituted or unsubstituted carbazole group in at least one of Ar₁ or Ar₂, or a fluorene-based compound including a substituted or unsubstituted fluorene group in at least one of Ar₁ or Ar₂.

The compound represented by Formula H-2 may be represented by any one selected from among the compounds of Compound Group H below. However, the compounds listed in Compound Group H below are examples, and the compounds represented by Formula H-2 are not limited to those represented by Compound Group H below:

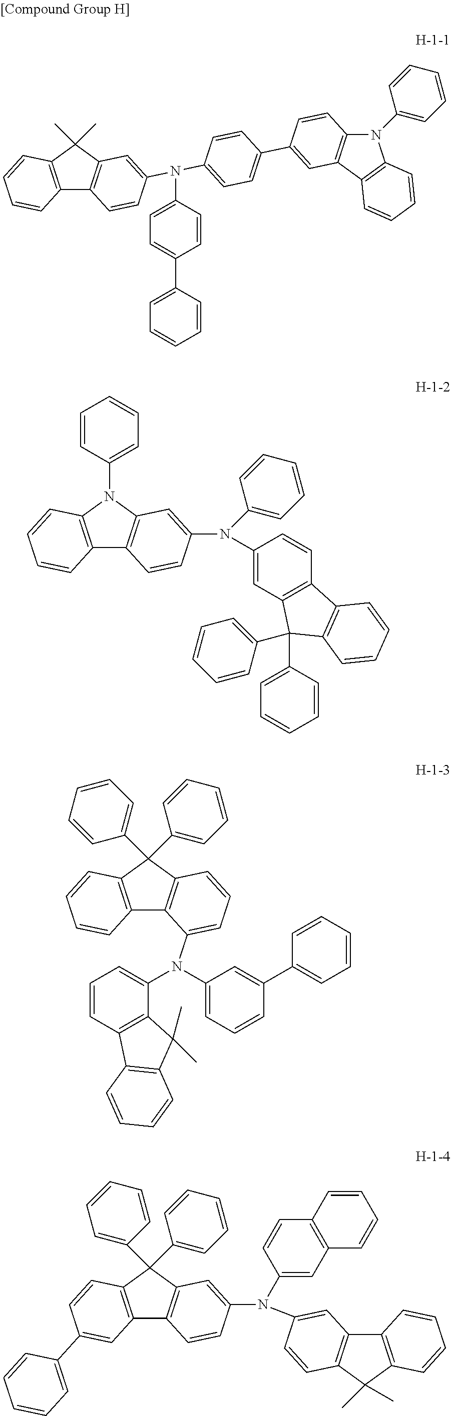 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

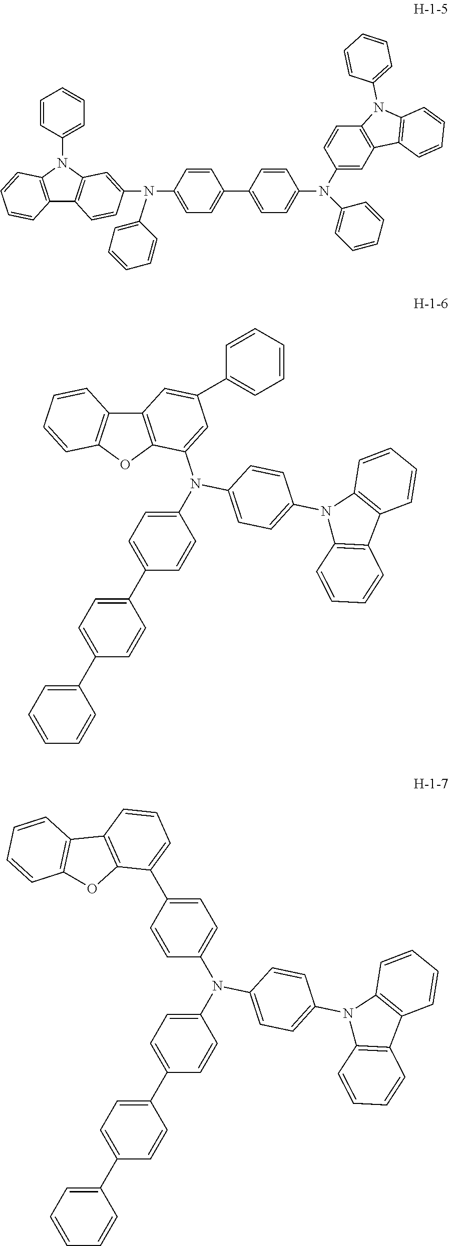 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

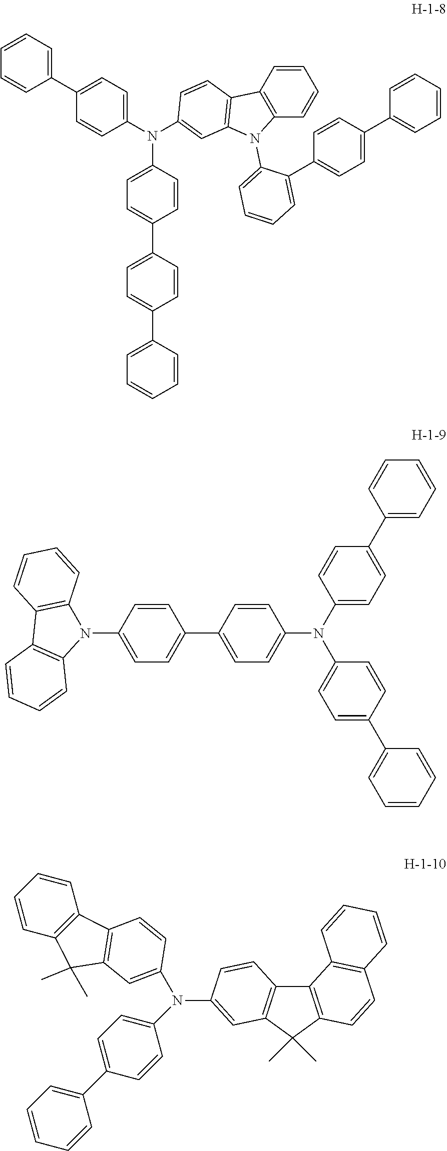 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

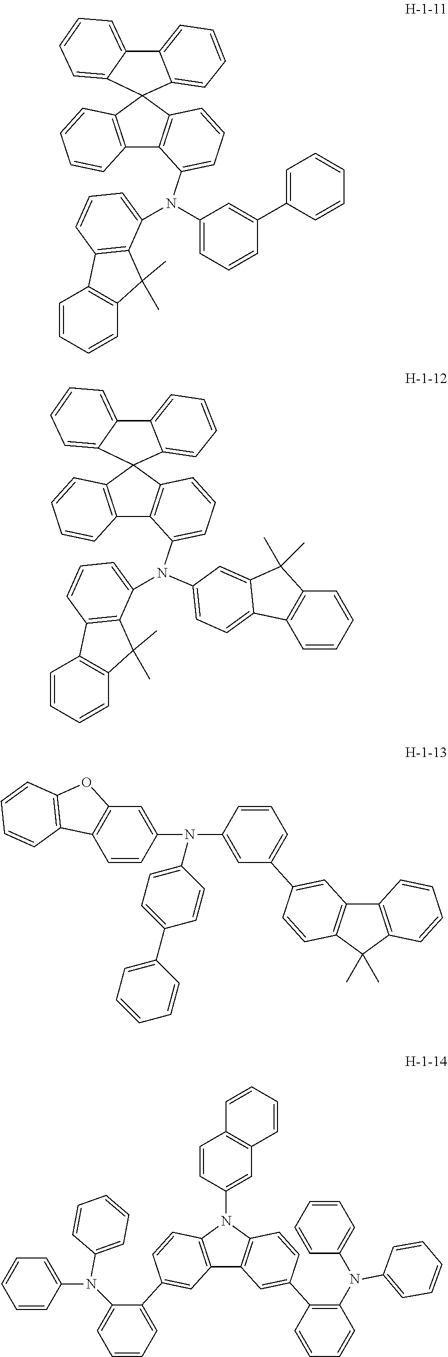

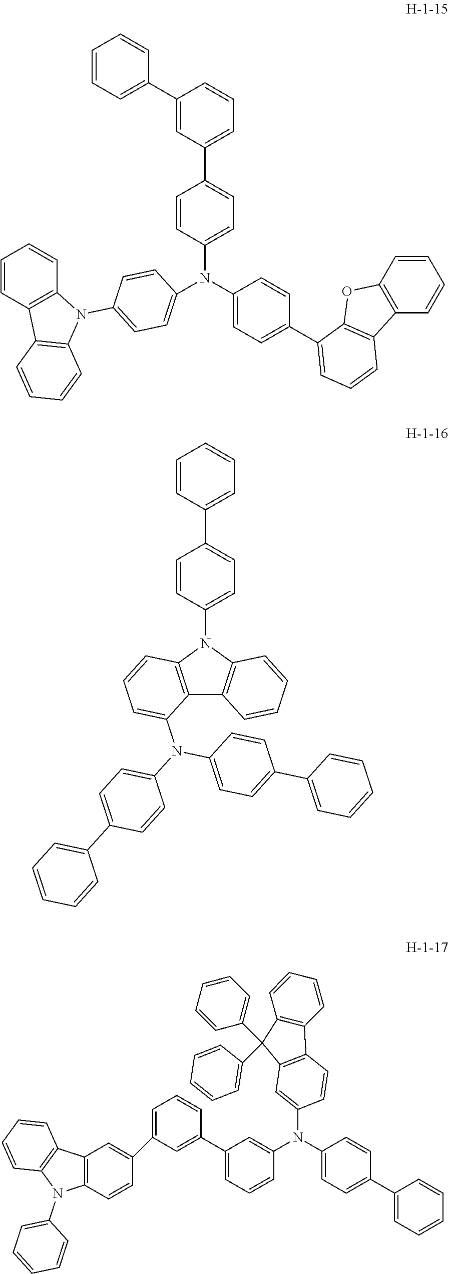 [SMILES: c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1]

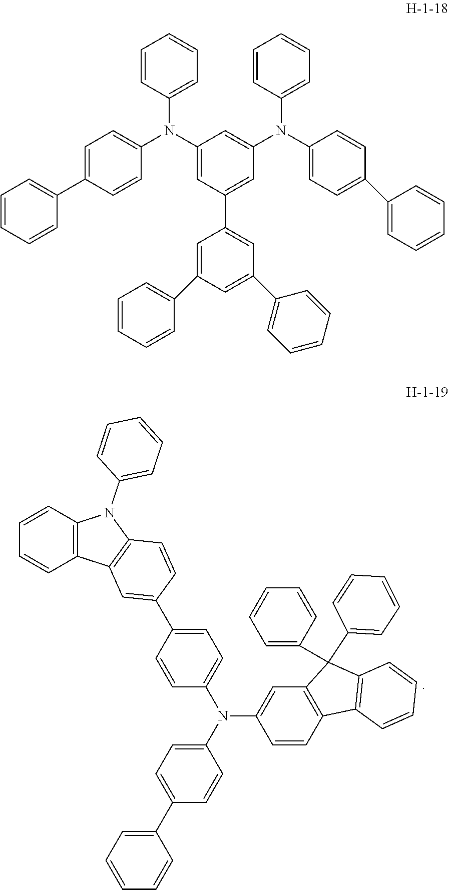 [SMILES: c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

In addition, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 250 Å to about 1,000 Å. For example, when the hole transport region HTR includes the electron blocking layer EBL, the electron blocking layer EBL may have a thickness of about 10 Å to about 1,000 Å. If the thicknesses of the hole transport region HTR, the hole injection layer HIL, the hole transport layer HTL and the electron blocking layer EBL satisfy the above-described ranges, suitable or satisfactory hole transport properties may be achieved without a substantial increase in driving voltage.

The hole transport region HTR may further include a charge generating material to increase conductivity (e.g., electrical conductivity) in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but embodiments of the present disclosure are not limited thereto. For example, the p-dopant may include a metal halide compound such as CuI and/or RbI, a quinone derivative such as tetracyanoquinodimethane (TCNQ) and/or 2,3,5,6-tetrafluoro-7,7′8,8-tetracyanoquinodimethane (F4-TCNQ), a metal oxide such as tungsten oxide and/or molybdenum oxide, a cyano group-containing compound such as dipyrazino[2,3-f: 2′,3′-h] quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments of the present disclosure are not limited thereto.

As described above, the hole transport region HTR may further include at least one of the buffer layer or the electron blocking layer EBL in addition to the hole injection layer HIL and the hole transport layer HTL. The buffer layer may compensate for a resonance distance according to the wavelength of light emitted from the emission layer EML and may thus increase light emission efficiency. A material that may be contained in the hole transport region HTR may be used as a material to be contained in the buffer layer. The electron blocking layer EBL is a layer that serves to prevent or reduce injection of electrons from the electron transport region ETR to the hole transport region HTR.

The emission layer EML is provided on the hole transport region HTR. The emission layer EML may have a thickness of, for example, about 100 Å to about 1,000 Å or about 100 Å to about 300 Å. The emission layer EML may have a single layer formed of a single material, a single layer formed of a plurality of different materials, or a multilayer structure having a plurality of layers formed of a plurality of different materials.

The emission layer EML in the light emitting device ED according to an embodiment may include a fused polycyclic compound of an embodiment. In an embodiment, the emission layer EML may include the fused polycyclic compound of an embodiment as a dopant. The fused polycylic compound of an embodiment may be a dopant material of the emission layer EML. In the present specification, the fused polycyclic compound of an embodiment, which will be further described herein below, may be referred to as a first compound.

The fused polycyclic compound of an embodiment may include a structure in which a plurality of aromatic rings are fused through at least one boron atom, at least one nitrogen atom, and at least one oxygen atom. In addition, the fused polycyclic compound of an embodiment may include a first substituent, which is a steric hindrance substituent, in the molecular structure. The first substituent may be linked to a nitrogen atom constituting a fused ring in the fused polycyclic compound of an embodiment. The first substituent may be a substituent which contains a benzene moiety and in which a substituted or unsubstituted aryl group having 6 to 30 ring-forming carbon atoms, or a substituted or unsubstituted heteroaryl group having 2 to 30 ring-forming carbon atoms is introduced into a carbon at the position of the benzene moiety. In some embodiments, the first substituent may be linked to the nitrogen atom constituting the fused ring, and include a structure in which an aryl group or heteroaryl group is introduced at the ortho-position with respect to the nitrogen atom.

The fused polycyclic compound of an embodiment may be represented by Formula 1 below:

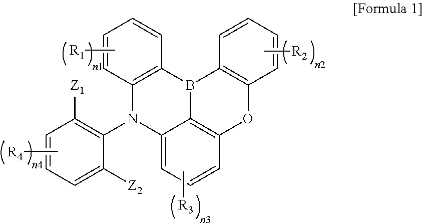

The fused polycyclic compound represented by Formula 1 of an embodiment may include a structure in which three aromatic rings are fused via one boron atom, one nitrogen atom, and one oxygen atom.

In Formula 1, R₁ to R₄ may be each independently a hydrogen atom, a deuterium atom, a halogen atom, a cyano group, a nitro group, a substituted or unsubstituted oxy group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, each of R₁ to R₄ may be bonded to an adjacent group to form a ring. For example, R₁ to R₄ may be each independently a hydrogen atom, a deuterium atom, a substituted or unsubstituted t-butyl group, a substituted or unsubstituted phenyl group, a substituted or unsubstituted biphenyl group, a substituted or unsubstituted terphenyl group, a substituted or unsubstituted arylamine group, a substituted or unsubstituted carbazole group, a substituted or unsubstituted dibenzofuran group, a substituted or unsubstituted dibenzothiophene group, a substituted or unsubstituted dibenzosilole group, or a substituted or unsubstituted pyridine group.

In Formula 1, Z₁ and Z₂ may be each independently a substituted or unsubstituted aryl group having 6 to 30 ring-forming carbon atoms, or a substituted or unsubstituted heteroaryl group having 2 to 30 ring-forming carbon atoms. For example, Z₁ and Z₂ may be each independently a substituted or unsubstituted phenyl group, a substituted or unsubstituted naphthyl group, a substituted or unsubstituted dibenzofuran group, or a substituted or unsubstituted dibenzothiophene group.

In Formula 1, n1 and n2 are each independently an integer of 0 to 4. If each of n1 and n2 is 0, the fused polycyclic compound of an embodiment may not be substituted with each of R₁ and R₂. The case where each of n1 and n2 is 4 and R₁′s and R₂′s are each hydrogen atoms may be the same as the case where each of n1 and n2 is 0. When each of n1 and n2 is an integer of 2 or more, a plurality of R₁′s and R₂′s may each be the same or at least one selected from among the plurality of R₁′s and R₂′s may be different from the others.

In Formula 1, n3 and n4 are each independently an integer of 0 to 3. If each of n3 and n4 is 0, the fused polycyclic compound of an embodiment may not be substituted with each of R₃ and R₄. The case where each of n3 and n4 is 3 and R₃′s and R₄′s are each hydrogen atoms may be the same as the case where each of n3 and n4 is 0. When each of n3 and n4 is an integer of 2 or more, a plurality of R₃′s and R₄′s may each be the same or at least one selected from among the plurality of R₃′s and R₄′s may be different from the others.

In an embodiment, the fused polycyclic compound represented by Formula 1 may be represented by Formula 2 below:

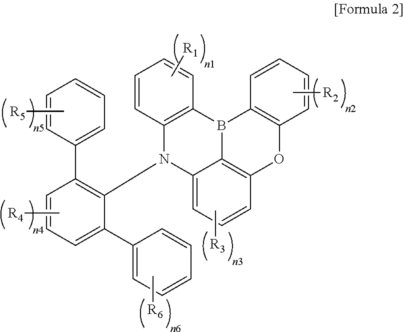

Formula 2 represents the case where a substituent type of Z₁ and Z₂ in Formula 1 is specified as a substituted or unsubstituted phenyl group.

In Formula 2, R₅ and R₆ may be each independently a hydrogen atom, a deuterium atom, a halogen atom, a cyano group, a nitro group, a substituted or unsubstituted oxy group, a substituted or unsubstituted thio group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, each of R₅ and R₆ may be bonded to an adjacent group to form a ring. For example, R₅ and R₆ may be each independently a hydrogen atom, a deuterium atom, a halogen atom, a cyano group, a substituted or unsubstituted methyl group, a substituted or unsubstituted isopropyl group, a substituted or unsubstituted t-butyl group, a substituted or unsubstituted methoxy group, a substituted or unsubstituted cyclohexyl group, a substituted or unsubstituted trimethylsilyl group, a substituted or unsubstituted cumyl group, or a substituted or unsubstituted phenoxy group.

In Formula 2, n5 and n6 are each independently an integer of 0 to 5. If each of n5 and n6 is 0, the fused polycyclic compound of an embodiment may not be substituted with each of R₅ and R₆. The case where each of n5 and n6 is 5 and R₅′s and R₆′s are each hydrogen atoms may be the same as the case where each of n5 and n6 is 0. When each of n5 and n6 is an integer of 2 or more, a plurality of R₅′s and R₆′s may each be the same or at least one selected from among the plurality of R₅′s and R₆′s may be different from the others.

In Formula 2, the same as described with respect to Formula 1 above may be applied to R₁ to R₄, and n1 to n4.

In an embodiment, the fused polycyclic compound represented by Formula 1 may be represented by any one selected from among Formula 3-1 to Formula 3-3 below:

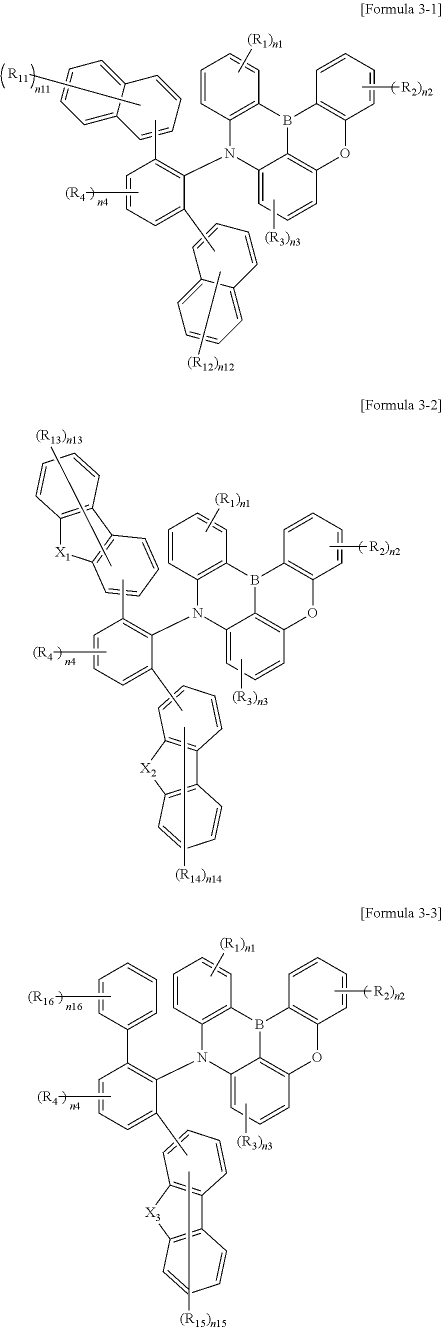

Formula 3-1 to Formula 3-3 represent the cases where the substituent types of Z₁ and Z₂ are specified. Formula 3-1 represents the case where substituents represented by Z₁ and Z₂ in Formula 1 are both substituted or unsubstituted naphthyl groups. Formula 3-2 represents the case where substituents represented by Z₁ and Z₂ in Formula 1 are both substituted or unsubstituted dibenzoheterol groups. Formula 3-3 represents the case where a substituent represented by Z₁ in Formula 1 is a substituted or unsubstituted phenyl group, and a substituent represented by Z₂ is a substituted or unsubstituted dibenzoheterol group.

In Formula 3-2 and Formula 3-3, X₁ to X₃ may be each independently NR₁₇, O, or S. For example, X₁ to X₃ may be each independently O or S.

In Formula 3-1 to Formula 3-3, R₁₁ to R₁₇ may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₁₁ to R₁₇ may be each independently a hydrogen atom or a substituted or unsubstituted t-butyl group.

In Formula 3-1 to Formula 3-3, n11 to n15 are each independently an integer of 0 to 7. If each of n11 to n15 is 0, the fused polycyclic compound of an embodiment may not be substituted with each of R₁₁ to R₁₅. The case where each of n11 to n15 is 7 and R₁₁′s to R₁₅′ are each hydrogen atoms may be the same as the case where each of n11 to n15 is 0. When each of n11 to n15 is an integer of 2 or more, a plurality of R₁₁′s to R₁₅′s may each be the same or at least one selected from among the plurality of R₁₁′s to R₁₅′s may be different from the others.

In Formula 3-3, n16 is an integer of 0 to 5. In Formula 3-3, if n16 is 0, the fused polycyclic compound of an embodiment may not be substituted with R₁₆. In Formula 3-3, the case where n16 is 5 and R₁₆′s are all hydrogen atoms may be the same as the case where n16 is 0 in Formula 3-3. If n16 is an integer of 2 or more, a plurality of R₁₆′s may all be the same, or at least one of the plurality of R₁₆′s may be different from the others.

In Formula 3-1 to Formula 3-3 above, the same as described with respect to Formula 1 above may be applied to R₁ to R₄, and n1 to n4.

In an embodiment, the fused polycyclic compound represented by Formula 1 may be represented by Formula 4 below:

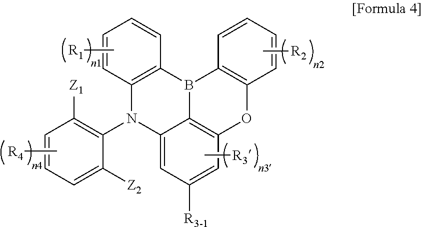

Formula 4 represents the case where in Formula 1, the substituted position of the substituent represented by R₃ is specified. Formula 4 represents the case where in Formula 1, the substituent represented by R₃ is substituted at the para-position with the boron atom.

In Formula 4, R₃₋₁ may be a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₃₋₁ may be a substituent rather than a hydrogen atom. For example, R₃₋₁ may be a deuterium atom, a substituted or unsubstituted t-butyl group, a substituted or unsubstituted phenyl group, a substituted or unsubstituted biphenyl group, a substituted or unsubstituted terphenyl group, a substituted or unsubstituted arylamine group, a substituted or unsubstituted carbazole group, a substituted or unsubstituted dibenzofuran group, a substituted or unsubstituted dibenzothiophene group, a substituted or unsubstituted dibenzosilole group, or a substituted or unsubstituted pyridine group.

In Formula 4, R₃′ may be a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₃′ may be a hydrogen atom.

In Formula 4, n3′ is an integer of 0 to 2. In Formula 4, if n3′ is 0, the fused polycyclic compound of an embodiment may not be substituted with R₃′. In Formula 4, the case where n3′ is 2 and R₃″s are all hydrogen atoms may be the same as the case where n3′ is 0 in Formula 4. If n3′ is 2, a plurality of R₃″s may all be the same, or at least one of the plurality of R₃″s may be different from the others.

In Formula 4, the same as described with respect to Formula 1 above may be applied to R₁, R₂, R₄, n1, n2, n4, Z₁, and Z₂.

In an embodiment, R₃₋₁ may be a deuterium atom or a substituted or unsubstituted alkyl group having 1 to 10 carbon atoms, or may be represented by any one selected from among Formula 5-1 to Formula 5-4 below:

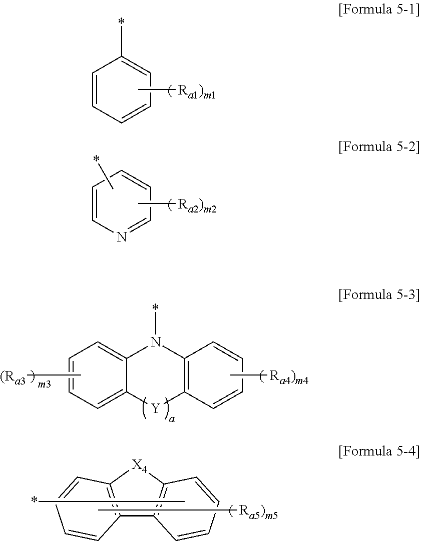

In Formula 5-4, X₄ may be NRₐ₆, O, S, or Se.

In Formula 5-1 to Formula 5-4, Rₐ₁ to Rₐ₆ may be each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Rₐ₁ to Rₐ₆ may be each independently a hydrogen atom, a deuterium atom, a halogen atom, a cyano group, a substituted or unsubstituted t-butyl group, a substituted or unsubstituted phenyl group, or a substituted or unsubstituted carbazole group.

In Formula 5-1 to Formula 5-4, m1, m3, and m4 are each independently an integer of 0 to 5, m2 is an integer of 0 to 4, and m5 is an integer of 0 to 7.

In Formula 5-1, m1 is an integer of 0 to 5. In Formula 5-1, if m1 is 0, the fused polycyclic compound of an embodiment may not be substituted with Rₐ₁. In Formula 5-1, the case where m1 is 5 and Rₐ₁′s are all hydrogen atoms may be the same as the case where m1 is 0 in Formula 5-1. If m1 is an integer of 2 or more, a plurality of Rₐ₁′s may all be the same, or at least one of the plurality of Rₐ₁′s may be different from the others.

In Formula 5-2, m2 is an integer of 0 to 4. In Formula 5-2, if m2 is 0, the fused polycyclic compound of an embodiment may not be substituted with Rₐ₂. In Formula 5-2, the case where m2 is 4 and Rₐ₂′s are all hydrogen atoms may be the same as the case where m2 is 0 in Formula 5-2. If m2 is an integer of 2 or more, a plurality of Rₐ₂′s may be all the same or at least one of the plurality of Rₐ₂′s may be different from the others.

In Formula 5-4, m5 is an integer of 0 to 7. In Formula 5-4, if m5 is 0, the fused polycyclic compound of an embodiment may not be substituted with Rₐ₅. In Formula 5-4, the case where m5 is 7 and Rₐ₅′s are all hydrogen atoms may be the same as the case where m5 is 0 in Formula 5-4. If m5 is an integer of 2 or more, a plurality of Rₐ₅′s may be all the same or at least one of the plurality of Rₐ₅′s may be different from the others.

In Formula 5-3, a may be 0 or 1. However, the sum of a and m3 is 5 or less, and the sum of a and m4 is 5 or less. For example, when a is 0, m3 and m4 are each independently an integer of 0 to 5, and when a is 1, m3 and m4 are each independently an integer of 0 to 4. In Formula 5-3, when a is 1, Y is a direct linkage. For example, the case where a is 0 may mean that the two benzene rings linked to the nitrogen atom in Formula 5-3 are not linked via Y. In some embodiments, when a is 0, the substituent represented by Formula 5-3 may include a diphenylamine moiety. In addition, the case where a is 1 may mean that the two benzene rings linked to the nitrogen atom in Formula 5-3 are linked via a direct linkage. In some embodiments, when a is 1, the substituent represented by Formula 5-3 may include a carbazole moiety.

In Formula 5-3, if each of m3 and m4 is 0, the fused polycyclic compound of an embodiment may not be substituted with each of Rₐ₃ and Rₐ₄. The case where a is 0, each of m3 and m4 is 5 and Rₐ₁′s and Rₐ₄′s are each hydrogen atoms may be the same as the case where a is 0 and each of m3 and m4 is 0. In addition, the case where a is 1, each of m3 and m4 is 4, and Rₐ₁′s and Rₐ₄′s are each hydrogen atoms may be the same as the case where a is 1 and each of m3 and m4 is 0. When each of m3 and m4 is an integer of 2 or more, a plurality of Rₐ₁′s and Rₐ₄′s may each be the same or at least one selected from among the plurality of Rₐ₁′s and Rₐ₄′s may be different from the others.

In an embodiment, the substituent represented by Formula 5-3 may be represented by Formula 5-3-1 or Formula 5-3-2 below. In some embodiments, when R₃₋₁ is represented by Formula 5-3, R₃₋₁ may be represented by Formula 5-3-1 or Formula 5-3-2 below:

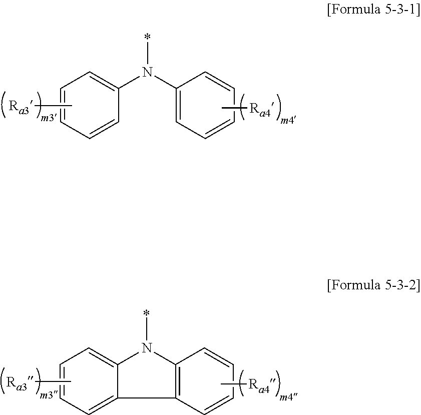

In Formula 5-3-1 to Formula 5-3-2, Rₐ₃′, Rₐ₄′, Rₐ₃″, and Rₐ₄″ may be each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula 5-3-1, m3′ and m4′ are each independently an integer of 0 to 5. If each of m3′ and m4′ is 0, the fused polycyclic compound of an embodiment may not be substituted with each of Rₐ₃′ and Rₐ₄′. The case where each of m3′ and m4′ is 5 and Rₐ₃″s and Rₐ₄″s each are hydrogen atoms may be the same as the case where each of m3′ and m4′ is 0. If each of m3′ and m4′ is an integer of 2 or more, a plurality of Rₐ₃″s and Rₐ₄″s may each be the same or at least one selected from among the plurality of Rₐ₃″s and Rₐ₄″s may be different from the others.

In Formula 5-3-2, m3″ and m4″ are each independently an integer of 0 to 4. If each of m3″ and m4″ is 0, the fused polycyclic compound of an embodiment may not be substituted with each of Rₐ₃″ and Rₐ₄″. The case where each of m3″ and m4″ is 4 and Rₐ₃′″s and Rₐ₄′″s are each hydrogen atoms may be the same as the case where each of m3″ and m4″ is 0. If each of m3″ and m4″ is an integer of 2 or more, a plurality of Rₐ₃′″s and Rₐ₄′″s may each be the same or at least one selected from among the plurality of Rₐ₃′″s and Rₐ₄′″s may be different from the others.

In an embodiment, the fused polycyclic compound represented by Formula 4 may be represented by Formula 4-1 below:

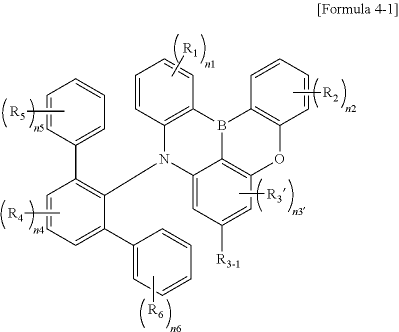

In Formula 4-1, R₅ and R₆ may be each independently a hydrogen atom, a deuterium atom, a halogen atom, a cyano group, a nitro group, a substituted or unsubstituted oxy group, a substituted or unsubstituted thio group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, each of R₅ and R₆ may be bonded to an adjacent group to form a ring. For example, R₅ and R₆ may be each independently a hydrogen atom, a deuterium atom, a halogen atom, a cyano group, a substituted or unsubstituted methyl group, a substituted or unsubstituted isopropyl group, a substituted or unsubstituted t-butyl group, a substituted or unsubstituted methoxy group, a substituted or unsubstituted cyclohexyl group, a substituted or unsubstituted trimethylsilyl group, a substituted or unsubstituted cumyl group, or a substituted or unsubstituted phenoxy group.

In Formula 4-1, n5 and n6 are each independently an integer of 0 to 5. If each of n5 and n6 is 0, the fused polycyclic compound of an embodiment may not be substituted with each of R₅ and R₆. The case where each of n5 and n6 is 5 and R₅′s and R₆′s are each hydrogen atoms may be the same as the case where each of n5 and n6 is 0. When each of n5 and n6 is an integer of 2 or more, a plurality of R₅′s and R₆′s may each be the same or at least one selected from among the plurality of R₅′s and R₆′s may be different from the others.

In Formula 4-1, the same as described with respect to Formula 1 and Formula 4 above may be applied to R₁, R₂, R₄, R₃₋₁, R₃′, n1, n2, n4, and n3′.

In an embodiment, the fused polycyclic compound represented by Formula 4 may be represented by any one selected from among Formula 4-1-1 to Formula 4-1-4 below:

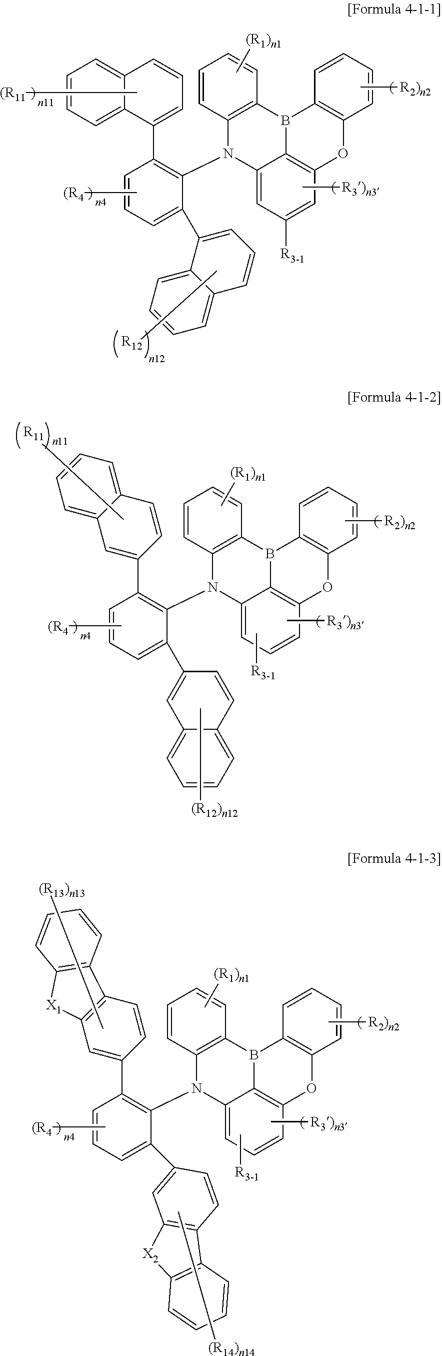

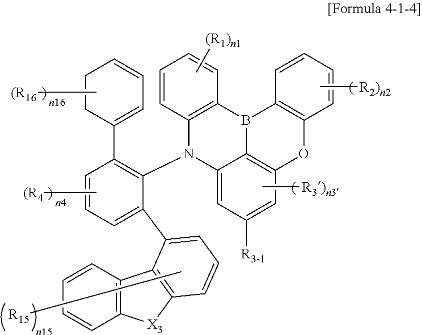

Formula 4-1-1 to Formula 4-1-4 represent the cases where the substituent types and substituted positions of Z₁ and Z₂ are specified in Formula 4.

In Formula 4-1-3 and Formula 4-1-4, X₁ to X₃ may be each independently NR₁₇, O, or S. For example, X₁ to X₃ may be each independently O or S.

In Formula 4-1-1 to Formula 4-1-4, R₁₁ to R₁₇ may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₁₁ to R₁₇ may be each independently a hydrogen atom or a substituted or unsubstituted t-butyl group.

In Formula 4-1-1 to Formula 4-1-4, n11 to n15 are each independently an integer of 0 to 7, and n16 is an integer of 0 to 5. The same as described with respect to Formula 3-1 to Formula 3-3 may be applied to n11 to n16.

In Formula 4-1-1 to Formula 4-1-4, the same as described with respect to Formula 1 and Formula 4 above may be applied to R₁, R₂, R₄, R₃₋₁, R₃′, n1, n2, n4, and n3′.

In an embodiment, the fused polycyclic compound represented by Formula 1 may be represented by any one selected from among Formula 6-1 to Formula 6-4 below:

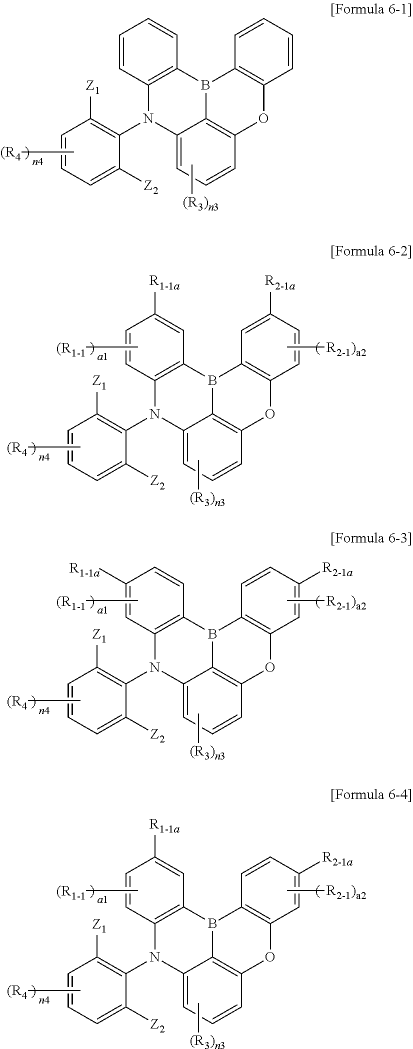

Formula 6-1 to Formula 6-4 represent the cases where in Formula 1, the substituent types or substituted positions of R₁ and R₂ are specified. Formula 6-1 represents the case where in Formula 1, the substituents represented by R₁ and R₂ are all hydrogen atoms. Formula 6-2 represents the case where in Formula 1, each of the substituents represented by R₁ and R₂ is represented at the meta-position with the boron atom. Formula 6-3 represents the case where in Formula 1, each of the substituents represented by R₁ and R₂ is substituted at the para-position with the boron atom. Formula 6-4 represents the case where in Formula 1, the substituent represented by R₁ is substituted at the meta-position with the boron atom, and the substituent represented by R₂ is substituted at the para-position with the boron atom.

In Formula 6-2 to Formula 6-4, R₁₋₁ and R₂₋₁ may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₁₋₁ and R₂₋₂ may be each independently a hydrogen atom.

In Formula 6-2 to Formula 6-4, R₁₋₁ₐ and R₂₋₁ₐ may be each independently a substituted or unsubstituted amine group, a substituted or unsubstituted phenyl group, a substituted or unsubstituted dibenzofuran group, or a substituted or unsubstituted carbazole group. For example, R₁₋₁ₐ and R₂₋₁ₐ may be each independently a substituted or unsubstituted phenyl group, a substituted or unsubstituted diphenylamine group, a substituted or unsubstituted carbazole group, or a substituted or unsubstituted dibenzofuran group.

In Formula 6-2 to Formula 6-4, a1 and a2 are each independently an integer of 0 to 3. If each of a1 and a2 is 0, the fused polycyclic compound of an embodiment may not be substituted with each of R₁₋₁ and R₂₋₁. The case where each of a1 and a2 is 3 and R₁₋₁′s and R₂₋₁′s are each hydrogen atoms may be the same as the case where each of a1 and a2 is 0. If each of a1 and a2 is an integer of 2 or more, a plurality of R₁₋₁′s and R₂₋₁′s may each be the same or at least one selected from among the plurality of R₁₋₁′s and R₂₋₁′s may be different from the others.

In Formula 6-1 to Formula 6-4, the same as described with respect to Formula 1 above may be applied to R₃, R₄, n3, n4, Z₁, and Z₂.

In an embodiment, the fused polycyclic compound represented by Formula 1 may be represented by any one selected from among Formula 7-1 to Formula 7-5 below:

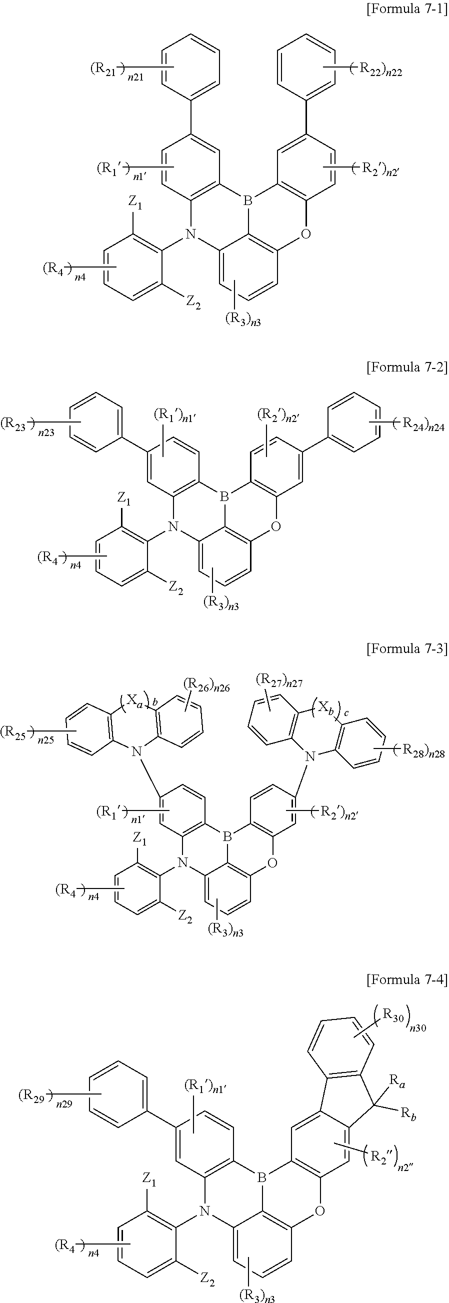

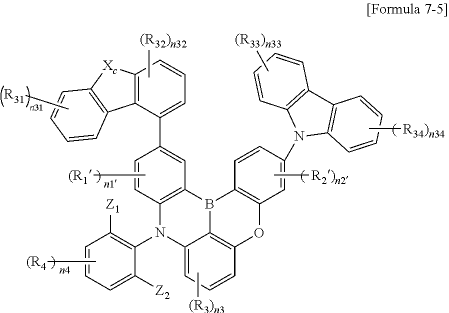

Formula 7-1 to Formula 7-5 represent the cases where in Formula 1, the substituent types and substituted positions of R₁ and R₂ are specified.

In Formula 7-3, Xₐ to X_{c} may be each independently a direct linkage, O, NR₃₅, CR₃₆R₃₇, S, or Se. For example, Xₐ and X_{b} may be each independently a direct linkage. X_{c} may be O or S.

In Formula 7-1 to Formula 7-5, R₂₁ to R₃₇ may be each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₂₁ to R₃₇ may be each independently a hydrogen atom, a deuterium atom, a cyano group, a substituted or unsubstituted methyl group, or a substituted or unsubstituted t-butyl group.

In Formula 7-4, Rₐ and R_{b} may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In some embodiments, each of Ra and Rb may be bonded to an adjacent group to form a ring. For example, Ra and Rb may be bonded to each other to form a ring. Ra and Rb may be bonded to each other to form a spiro structure.

In Formula 7-1 to Formula 7-5, R₁′, R₂′, and R₂″ may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, each of R₁′, R₂′, and R₂″ may be each independently a hydrogen atom.

In Formula 7-1 to Formula 7-5, n1′, n2′, and n32 are each independently an integer of 0 to 3. If each of n1′, n2′, and n32 is 0, the fused polycyclic compound of an embodiment may not be substituted with each of R₁′, R₂′, and R₃₂. The case where each of n1′, n2′, and n32 is 3 and R₁″s, R₂″s, and R₃₂′s are each hydrogen atoms may be the same as the case where each of n1′, n2′, and n32 is 0. If each of n1′, n2′, and n32 is an integer of 2 or more, a plurality of R₁″s, R₂″s, and R₃₂′s may each be the same or at least one selected from among the plurality of R₁″s, R₂″s, and R₃₂′s may be different from the others.

In Formula 7-4, n2″ is an integer of 0 to 2. In Formula 7-4, if n2″ is 0, the fused polycyclic compound of an embodiment may not be substituted with R₂″. In Formula 7-4, the case where n2″ is 2 and R₂′″s are all hydrogen atoms may be the same as the case where n2″ is 0 in Formula 7-4. If n2″ is 2, a plurality of R₂′″s may all be the same, or at least one of the plurality of R₂′″s may be different from the others.

In Formula 7-1, Formula 7-2, and Formula 7-4, n21 to n24, and n29 are each independently an integer of 0 to 5. If each of n21 to n24, and n29 is 0, the fused polycyclic compound of an embodiment may not be substituted with each of R₂₁ to R₂₄, and R₂₉. The case where each of n21 to n24, and n29 is 5 and R₂₁′s to R₂₄′s, and R₂₉′s are each hydrogen atoms may be the same as the case where each of n21 to n24, and n29 is 0. If each of n21 to n24, and n29 is an integer of 2 or more, a plurality of R₂₁′s to R₂₄′s, and R₂₉′s may each be the same or at least one selected from among the plurality of R₂₁′s to R₂₄′s, and R₂₉′s may be different from the others.

In Formula 7-4 and Formula 7-5, n30, n31, n33, and n34 are each independently an integer of 0 to 4. If each of n30, n31, n33, and n34 is 0, the fused polycyclic compound of an embodiment may not be substituted with each of R₃₀, R₃₁, R₃₃, and R₃₄. The case where each of n30, n31, n33, and n34 is 4 and R₃₀′s, R₃₁′s, R₃₃′s, and R₃₄′s are each hydrogen atoms may be the same as the case where each of n30, n31, n33, and n34 is 0. If each of n30, n31, n33, and n34 is an integer of 2 or more, a plurality of R₃₀′s, R₃₁′s, R₃₃′s, and R₃₄′s may each be the same or at least one selected from among the plurality of R₃₀′s, R₃₁′s, R₃₃′s, and R₃₄′s may be different from the others.

In Formula 7-3, b and c are each independently 0 or 1. However, the sum of b and n25 is 5 or less, the sum of b and n26 is 5 or less, the sum of c and n27 is 5 or less, and the sum of c and n28 is 5 or less.

In Formula 7-3, n25 to n28 are each independently an integer of 0 to 5. In Formula 7-3, if each of n25 to n28 is 0, the fused polycyclic compound of an embodiment may not be substituted with each of R₂₅ to R₂₈. The case where each of b and c is 0, each of n25 to n28 is 5, and R₂₅′s to R₂₈′s are each hydrogen atoms may be the same as the case where each of b and c is 0 and each of n25 to n28 is 0. In addition, the case where each of b and c is 1, each of n25 to n28 is 4, and R₂₅′s to R₂₈′s are each hydrogen atoms may be the same as the case where each of b and c is 1 and each of n25 to n28 is 0. When each of n25 to n28 is an integer of 2 or more, a plurality of R₂₅′s to R₂₈′s may each be the same or at least one selected from among the plurality of R₂₅′s to R₂₈′s may be different from the others.

In Formula 7-1 to Formula 7-5, the same as described with respect to Formula 1 above may be applied to R₃, R₄, n3, n4, Z₁, and Z₂.

The fused polycyclic compound represented by Formula 7-3 may be represented by Formula 7-3-1 or Formula 7-3-2 below:

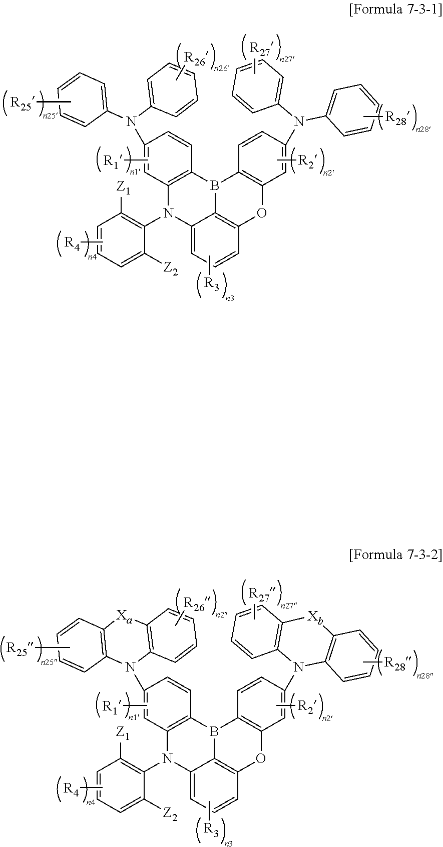

In Formula 7-3-1 and Formula 7-3-2, R₂₅′ to R₂₈′ and R₂₅″ to R₂₈″ may be each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula 7-3-1, n25′ to n28′ are each independently an integer of 0 to 5. If each of n25′ to n28′ is 0, the fused polycyclic compound of an embodiment may not be substituted with each of R₂₅′ to R₂₈′. The case where each of n25′ to n28′ is 5 and R₂₅″s to R₂₈″s are each hydrogen atoms may be the same as the case where each of n25′ to n28′ is 0. When each of n25′ to n28′ is an integer of 2 or more, a plurality of R₂₅″s to R₂₈″s may each be the same or at least one selected from among the plurality of R₂₅″s to R₂₈″s may be different from the others.

In Formula 7-3-2, n25″ to n28″ are each independently an integer of 0 to 4.

If each of n25″ to n28″ is 0, the fused polycyclic compound of an embodiment may not be substituted with each of R₂₅″ to R₂₈″. The case where each of n25″ to n28″ is 4 and R₂₅′″s to R₂₈′″s are each hydrogen atoms may be the same as the case where each of n25″ to n28″ is 0. When each of n25″ to n28″ is an integer of 2 or more, a plurality of R₂₅′″s to R₂₈′″s may each be the same or at least one selected from among the plurality of R₂₅′″s to R₂₈′″s may be different from the others.

In Formula 7-3-1 and Formula 7-3-2, the same as described with respect to Formula 1 and Formula 7-3 above may be applied to R₁′, R₂′, R₃, R₄, Z₁, Z₂, n1′, n2′, n3, n4, Xₐ, and X_{b}.

In an embodiment, Z₁ and Z₂ may be each independently represented by any one selected from among Formula 8-1 to Formula 8-4 below:

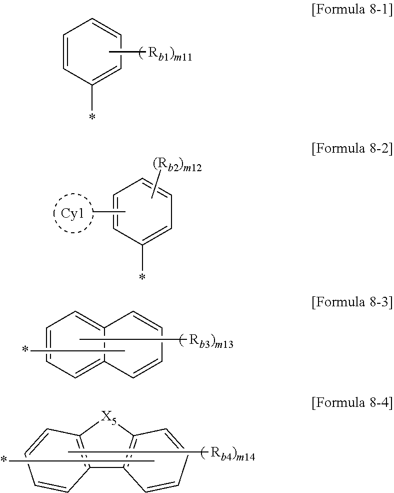

In Formula 8-2, Cy1 may be a substituted or unsubstituted cycloalkyl group having 3 to 10 carbon atoms. For example, Cy1 may be a substituted or unsubstituted cyclohexyl group.

In Formula 8-4, X₅ may be NR_{b5}, O, or S. For example, X₅ may be O or S.

In Formula 8-1 to Formula 8-4, R_{b1} to R_{b5} may be each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R_{b1} to R_{b5} may be each independently a hydrogen atom, a deuterium atom, a halogen atom, a cyano group, a substituted or unsubstituted methyl group, a substituted or unsubstituted isopropyl group, a substituted or unsubstituted t-butyl group, a substituted or unsubstituted trimethylsilyl group, a substituted or unsubstituted methoxy group, a substituted or unsubstituted cumyl group, or a substituted or unsubstituted phenoxy group.

In Formula 8-1, m11 is an integer of 0 to 5. In Formula 8-1, if m11 is 0, the fused polycyclic compound of an embodiment may not be substituted with R_{b1}. In Formula 8-1, the case where m11 is 5 and R_{b1}′s are all hydrogen atoms may be the same as the case where m11 is 0 in Formula 8-1. If m11 is an integer of 2 or more, a plurality of R_{b1}′s may all be the same, or at least one of the plurality of R_{b1}′s may be different from the others.

In Formula 8-2, m12 is an integer of 0 to 4. In Formula 8-2, if m12 is 0, the fused polycyclic compound of an embodiment may not be substituted with R_{b2}. In Formula 8-2, the case where m12 is 4 and R_{b2}′s are all hydrogen atoms may be the same as the case where m12 is 0 in Formula 8-2. If m12 is an integer of 2 or more, a plurality of R_{b2}′s may be all the same or at least one of the plurality of R_{b2}′s may be different from the others.

In Formula 8-3 and Formula 8-4, m13 and m14 are each independently an integer of 0 to 7. If each of m13 and m14 is 0, the fused polycyclic compound of an embodiment may not be substituted with each of R_{b3} and R₄. The case where each of m13 and m14 is 7 and R_{b3}′s and R_{b4}′s each are hydrogen atoms may be the same as the case where each of m13 and m14 is 0. When each of m13 and m14 is an integer of 2 or more, a plurality of R_{b3}′s and R_{b4}′s may each be the same or at least one selected from among the plurality of R_{b3}′s and R_{b4}′s may be different from the others.

The fused polycyclic compound of an embodiment may be any one selected from among the compounds represented in Compound Group 1 below. The light emitting device ED of an embodiment may include at least one fused polycyclic compound among the compounds represented by Compound Group 1 in the emission layer EML.

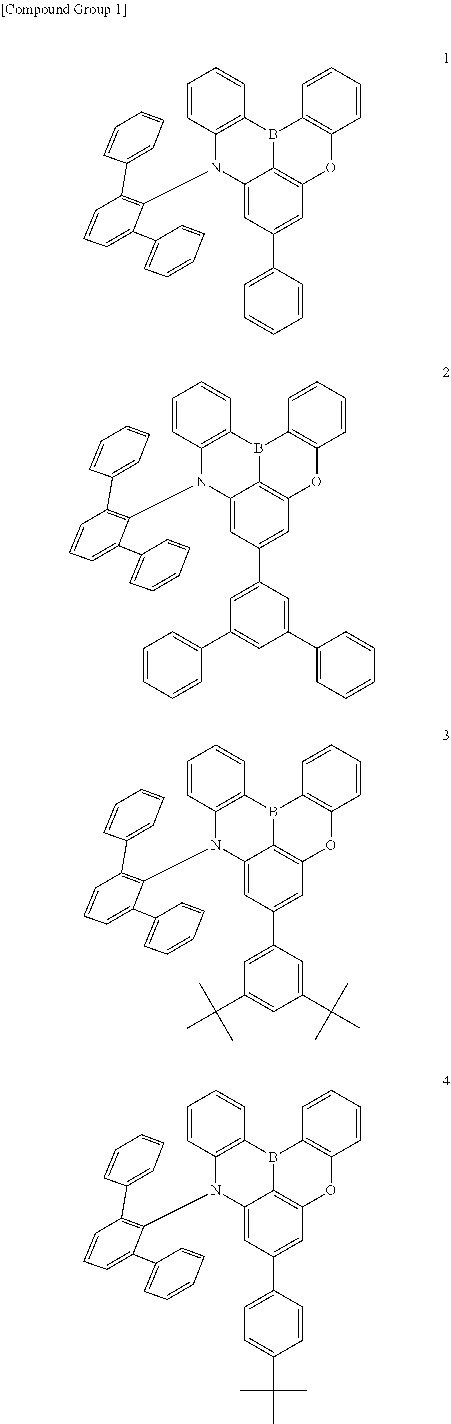 [SMILES: c1ccc(-c2cc3c4c(c2)N(c2c(-c5ccccc5)cccc2-c2ccccc2)c2ccccc2B4c2ccccc2O3)cc1 ; c1ccc(-c2cc(-c3ccccc3)cc(-c3cc4c5c(c3)N(c3c(-c6ccccc6)cccc3-c3ccccc3)c3ccccc3B5c3ccccc3O4)c2)cc1 ; CC(C)(C)c1cc(-c2cc3c4c(c2)N(c2c(-c5ccccc5)cccc2-c2ccccc2)c2ccccc2B4c2ccccc2O3)cc(C(C)(C)C)c1 ; CC(C)(C)c1ccc(-c2cc3c4c(c2)N(c2c(-c5ccccc5)cccc2-c2ccccc2)c2ccccc2B4c2ccccc2O3)cc1]

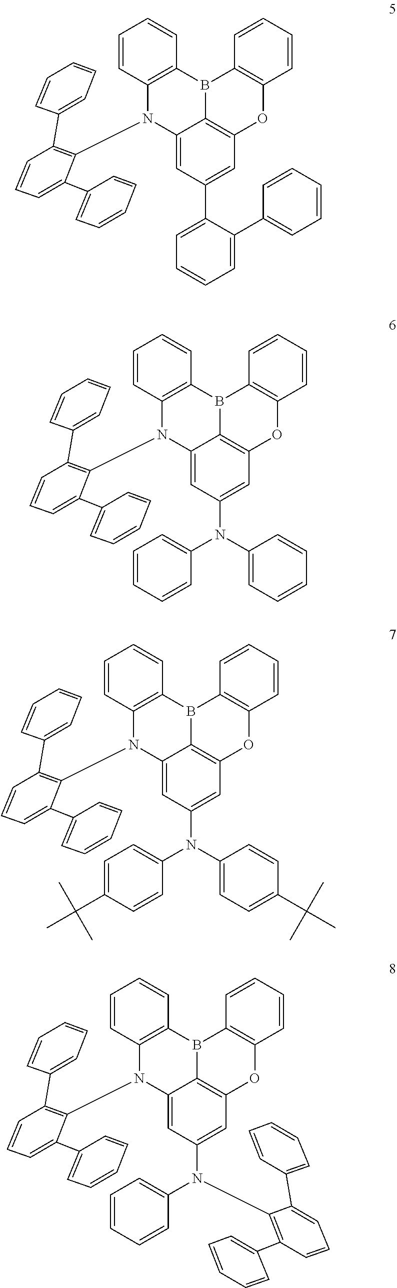 [SMILES: c1ccc(-c2ccccc2-c2cc3c4c(c2)N(c2c(-c5ccccc5)cccc2-c2ccccc2)c2ccccc2B4c2ccccc2O3)cc1 ; c1ccc(-c2cccc(-c3ccccc3)c2N2c3ccccc3B3c4ccccc4Oc4cc(N(c5ccccc5)c5ccccc5)cc2c43)cc1 ; CC(C)(C)c1ccc(N(c2ccc(C(C)(C)C)cc2)c2cc3c4c(c2)N(c2c(-c5ccccc5)cccc2-c2ccccc2)c2ccccc2B4c2ccccc2O3)cc1 ; c1ccc(-c2cccc(-c3ccccc3)c2N(c2ccccc2)c2cc3c4c(c2)N(c2c(-c5ccccc5)cccc2-c2ccccc2)c2ccccc2B4c2ccccc2O3)cc1]

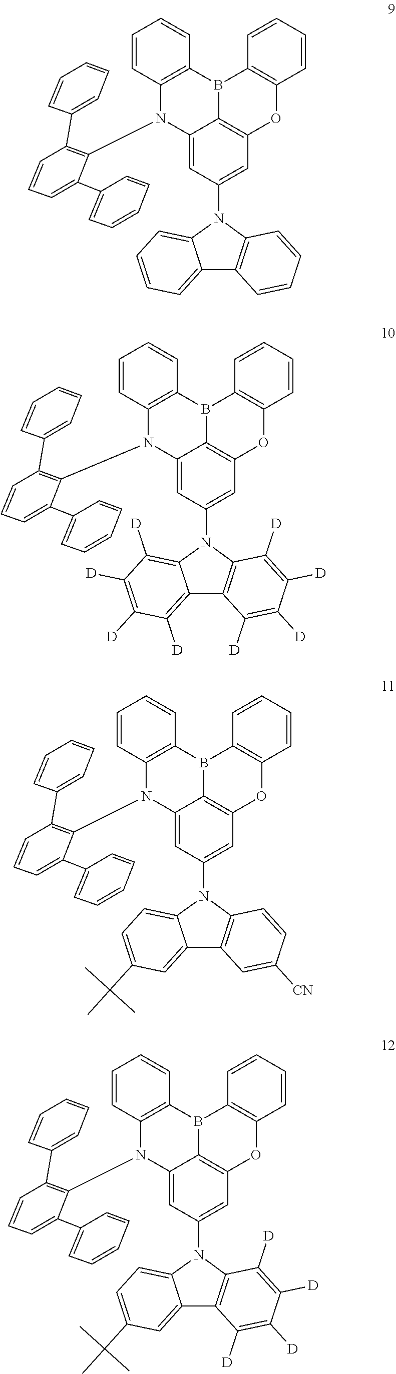

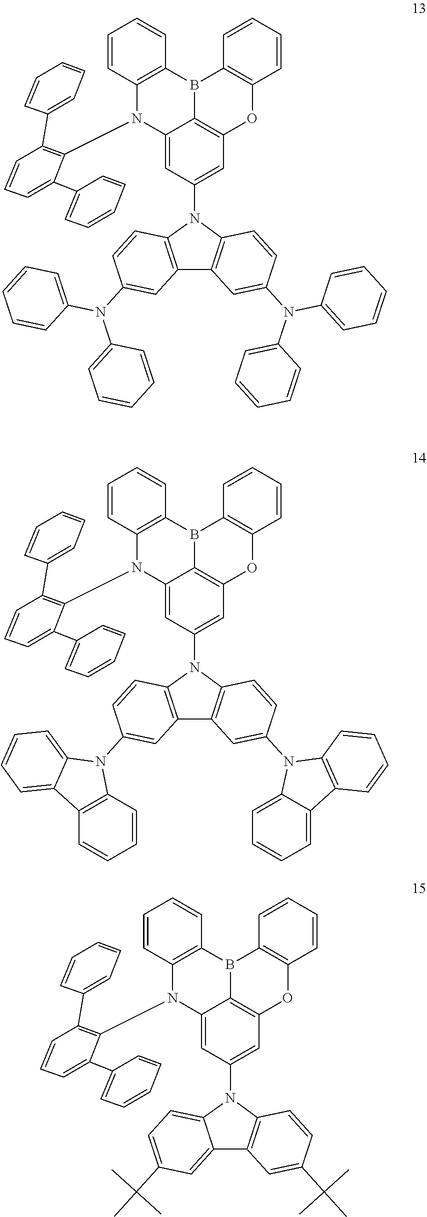

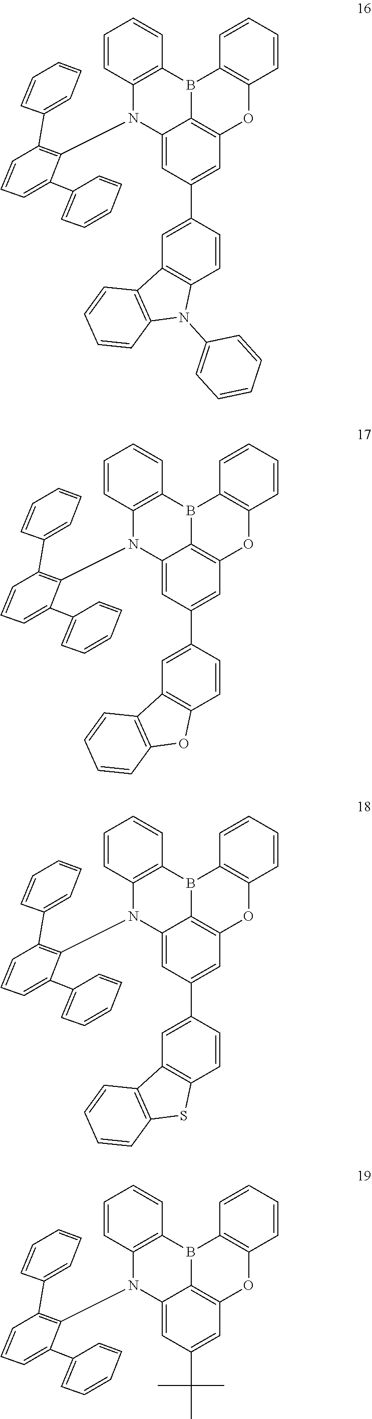

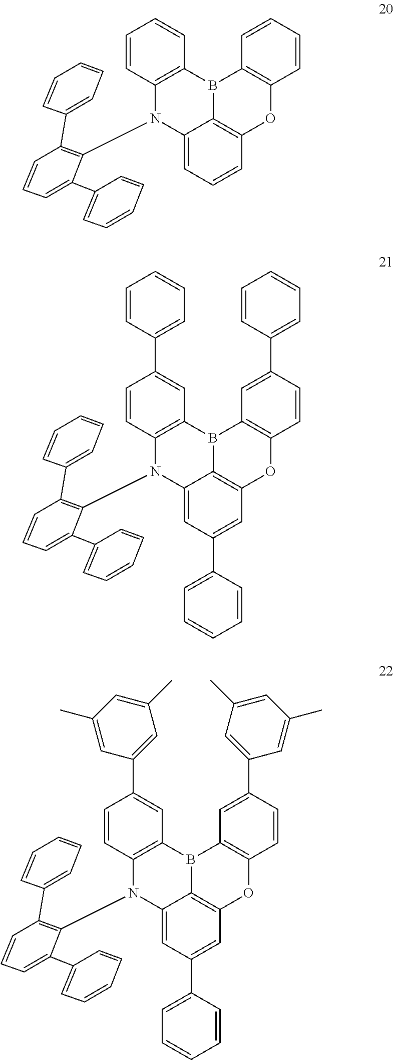

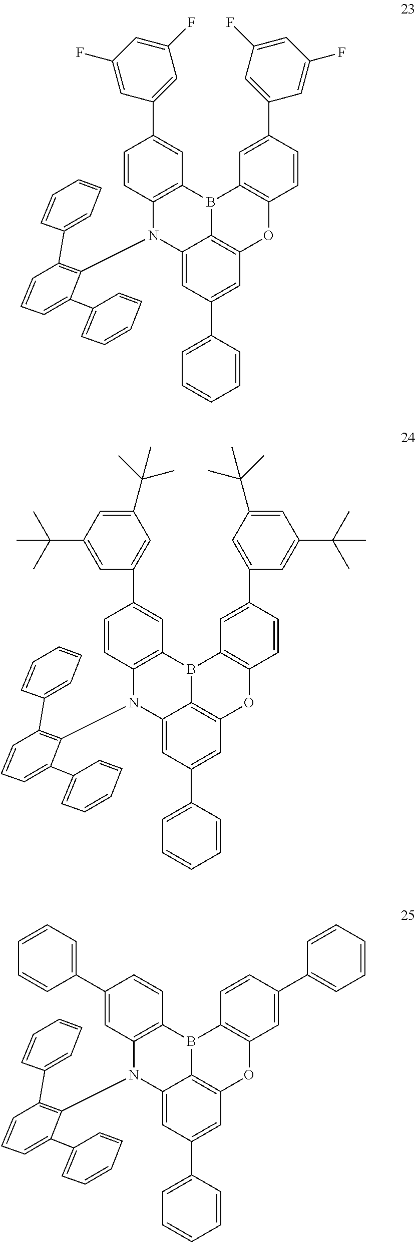 [SMILES: Fc1cc(F)cc(-c2ccc3c(c2)B2c4cc(-c5cc(F)cc(F)c5)ccc4N(c4c(-c5ccccc5)cccc4-c4ccccc4)c4cc(-c5ccccc5)cc(c42)O3)c1 ; CC(C)(C)c1cc(-c2ccc3c(c2)B2c4cc(-c5cc(C(C)(C)C)cc(C(C)(C)C)c5)ccc4N(c4c(-c5ccccc5)cccc4-c4ccccc4)c4cc(-c5ccccc5)cc(c42)O3)cc(C(C)(C)C)c1 ; c1ccc(-c2ccc3c(c2)Oc2cc(-c4ccccc4)cc4c2B3c2ccc(-c3ccccc3)cc2N4c2c(-c3ccccc3)cccc2-c2ccccc2)cc1]

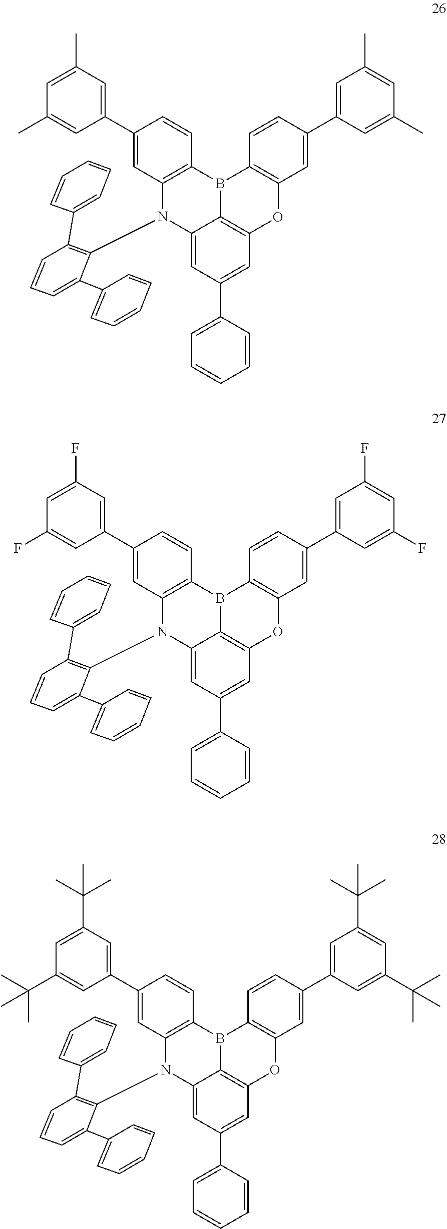

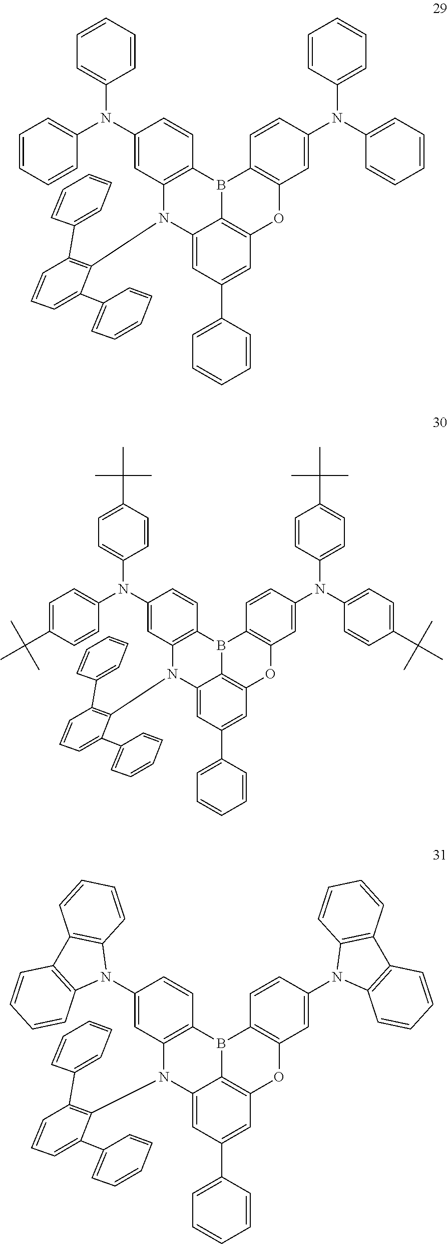 [SMILES: c1ccc(-c2cc3c4c(c2)N(c2c(-c5ccccc5)cccc2-c2ccccc2)c2cc(N(c5ccccc5)c5ccccc5)ccc2B4c2ccc(N(c4ccccc4)c4ccccc4)cc2O3)cc1 ; CC(C)(C)c1ccc(N(c2ccc(C(C)(C)C)cc2)c2ccc3c(c2)Oc2cc(-c4ccccc4)cc4c2B3c2ccc(N(c3ccc(C(C)(C)C)cc3)c3ccc(C(C)(C)C)cc3)cc2N4c2c(-c3ccccc3)cccc2-c2ccccc2)cc1 ; c1ccc(-c2cc3c4c(c2)N(c2c(-c5ccccc5)cccc2-c2ccccc2)c2cc(-n5c6ccccc6c6ccccc65)ccc2B4c2ccc(-n4c5ccccc5c5ccccc54)cc2O3)cc1]

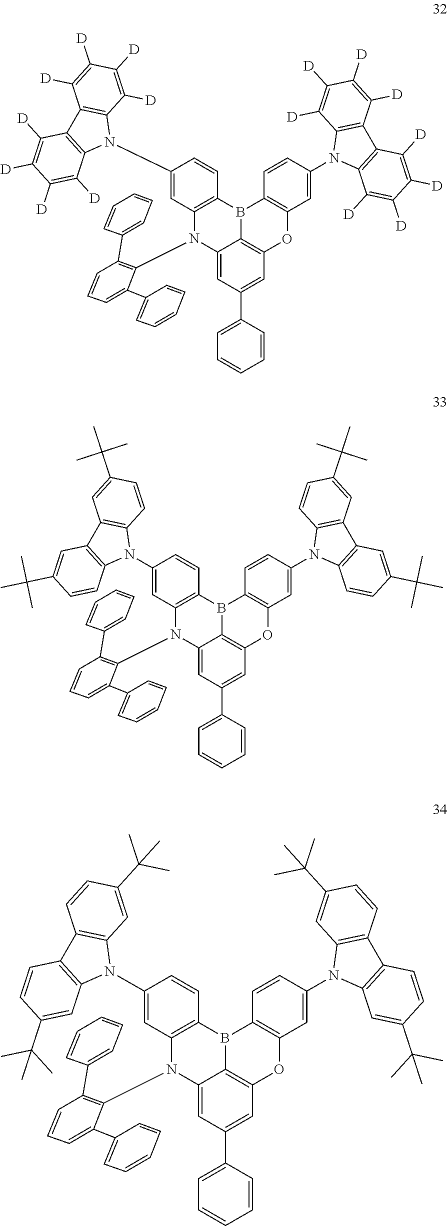

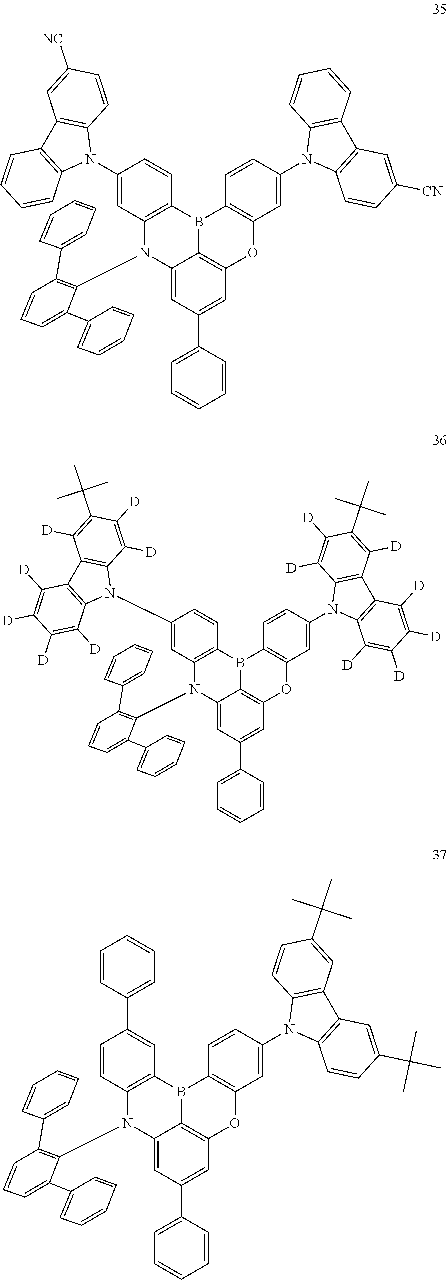 [SMILES: N#Cc1ccc2c(c1)c1ccccc1n2-c1ccc2c(c1)Oc1cc(-c3ccccc3)cc3c1B2c1ccc(-n2c4ccccc4c4cc(C#N)ccc42)cc1N3c1c(-c2ccccc2)cccc1-c1ccccc1 ; [2H]c1c([2H])c([2H])c2c(c1[2H])c1c([2H])c(C(C)(C)C)c([2H])c([2H])c1n2-c1ccc2c(c1)Oc1cc(-c3ccccc3)cc3c1B2c1ccc(-n2c4c([2H])c([2H])c([2H])c([2H])c4c4c([2H])c(C(C)(C)C)c([2H])c([2H])c42)cc1N3c1c(-c2ccccc2)cccc1-c1ccccc1 ; CC(C)(C)c1ccc2c(c1)c1cc(C(C)(C)C)ccc1n2-c1ccc2c(c1)Oc1cc(-c3ccccc3)cc3c1B2c1cc(-c2ccccc2)ccc1N3c1c(-c2ccccc2)cccc1-c1ccccc1]

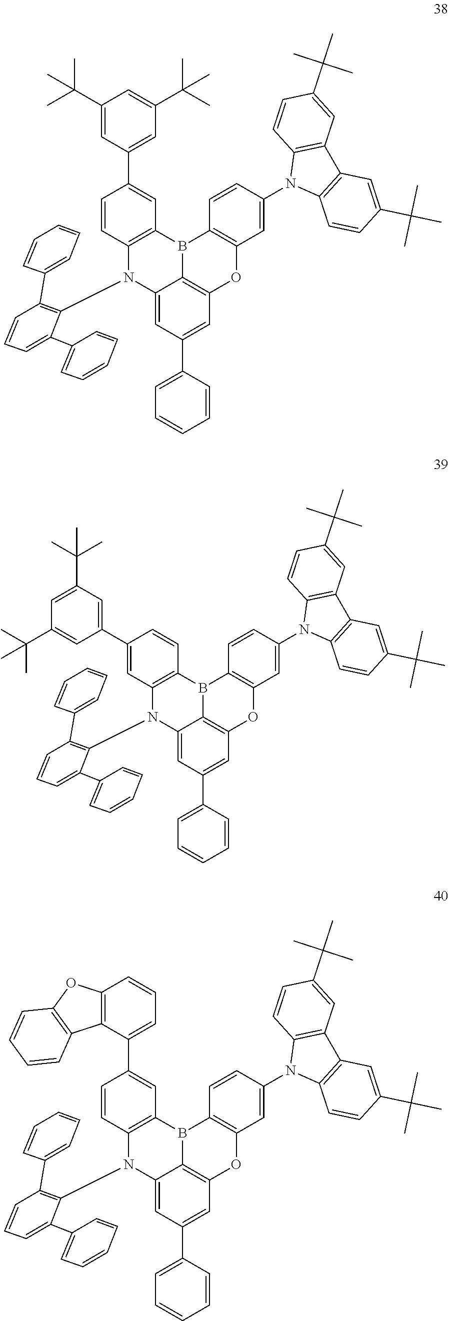

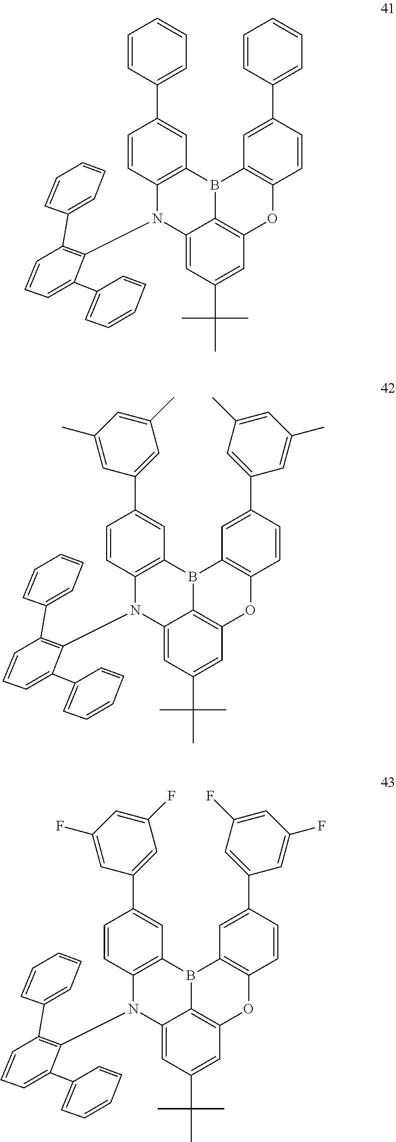

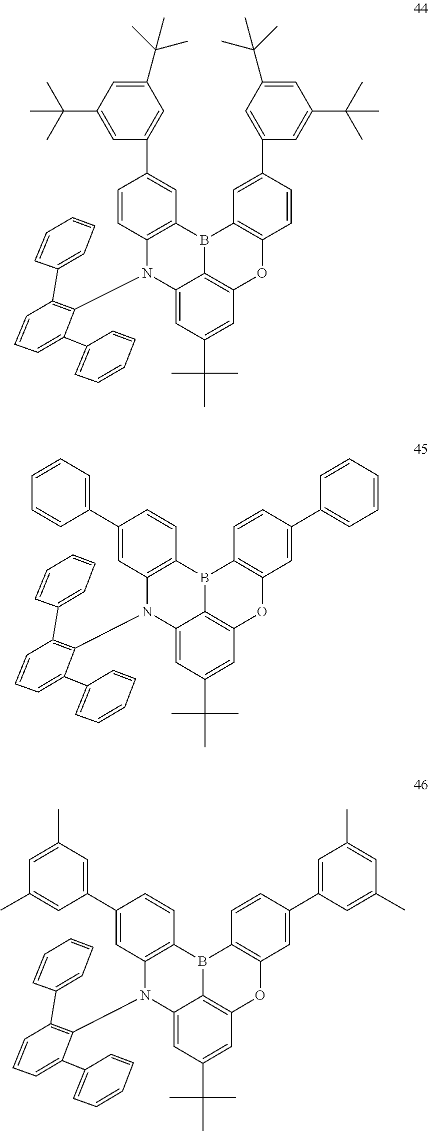

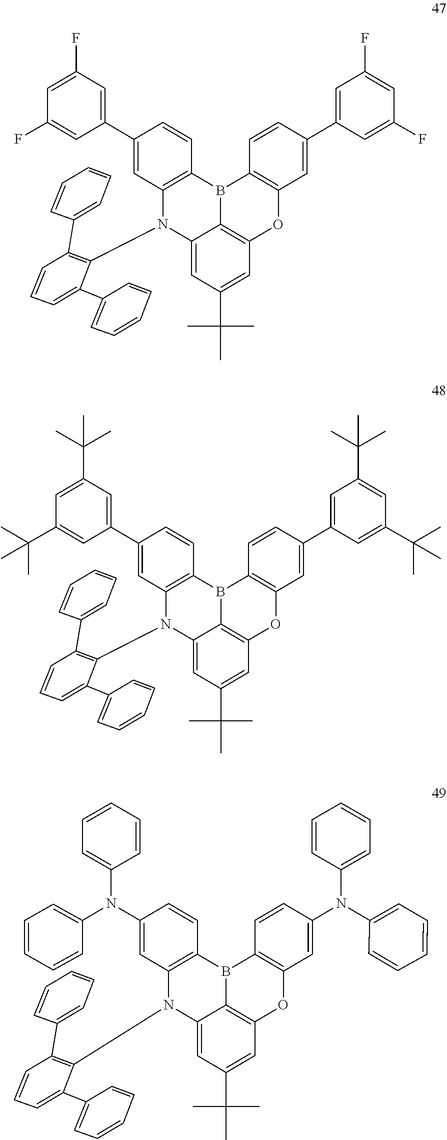 [SMILES: CC(C)(C)c1cc2c3c(c1)N(c1c(-c4ccccc4)cccc1-c1ccccc1)c1cc(-c4cc(F)cc(F)c4)ccc1B3c1ccc(-c3cc(F)cc(F)c3)cc1O2 ; CC(C)(C)c1cc(-c2ccc3c(c2)Oc2cc(C(C)(C)C)cc4c2B3c2ccc(-c3cc(C(C)(C)C)cc(C(C)(C)C)c3)cc2N4c2c(-c3ccccc3)cccc2-c2ccccc2)cc(C(C)(C)C)c1 ; CC(C)(C)c1cc2c3c(c1)N(c1c(-c4ccccc4)cccc1-c1ccccc1)c1cc(N(c4ccccc4)c4ccccc4)ccc1B3c1ccc(N(c3ccccc3)c3ccccc3)cc1O2]

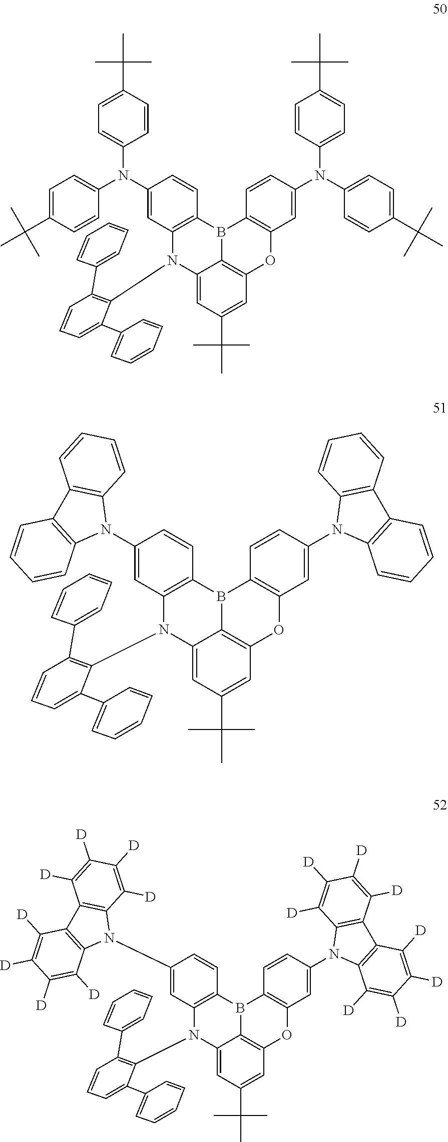 [SMILES: CC(C)(C)c1ccc(N(c2ccc(C(C)(C)C)cc2)c2ccc3c(c2)Oc2cc(C(C)(C)C)cc4c2B3c2ccc(N(c3ccc(C(C)(C)C)cc3)c3ccc(C(C)(C)C)cc3)cc2N4c2c(-c3ccccc3)cccc2-c2ccccc2)cc1 ; CC(C)(C)c1cc2c3c(c1)N(c1c(-c4ccccc4)cccc1-c1ccccc1)c1cc(-n4c5ccccc5c5ccccc54)ccc1B3c1ccc(-n3c4ccccc4c4ccccc43)cc1O2 ; [2H]c1c([2H])c([2H])c2c(c1[2H])c1c([2H])c([2H])c([2H])c([2H])c1n2-c1ccc2c(c1)Oc1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2ccccc2)cccc1-c1ccccc1]

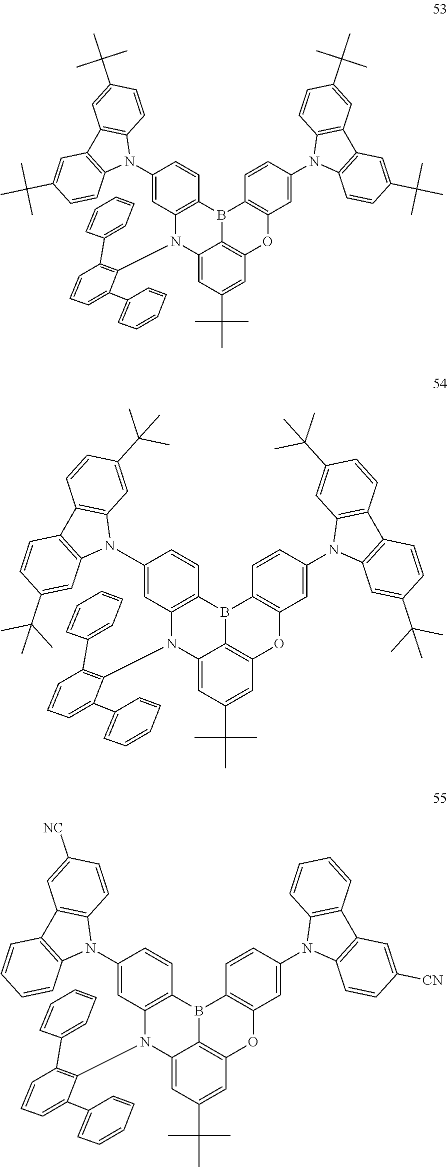

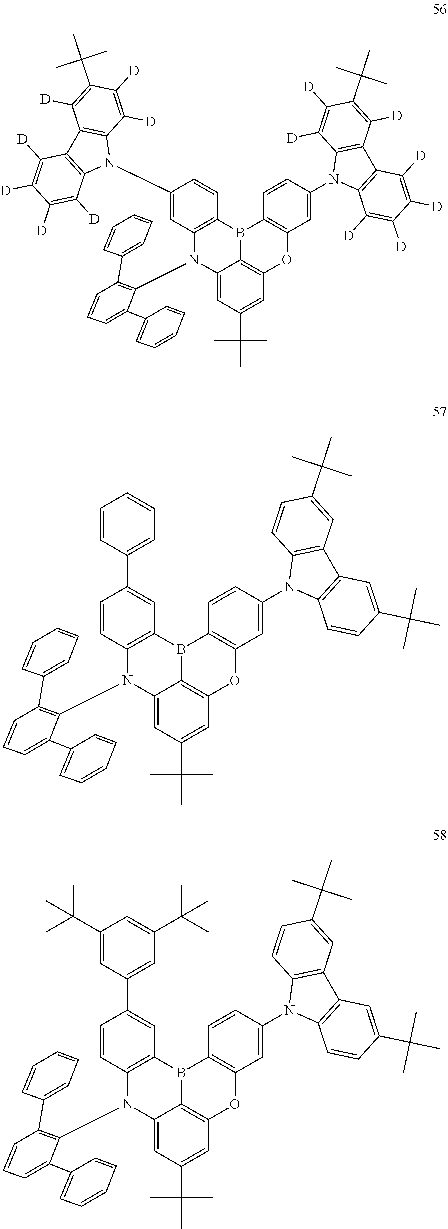 [SMILES: [2H]c1c([2H])c([2H])c2c(c1[2H])c1c([2H])c(C(C)(C)C)c([2H])c([2H])c1n2-c1ccc2c(c1)Oc1cc(C(C)(C)C)cc3c1B2c1ccc(-n2c4c([2H])c([2H])c([2H])c([2H])c4c4c([2H])c(C(C)(C)C)c([2H])c([2H])c42)cc1N3c1c(-c2ccccc2)cccc1-c1ccccc1 ; CC(C)(C)c1cc2c3c(c1)N(c1c(-c4ccccc4)cccc1-c1ccccc1)c1ccc(-c4ccccc4)cc1B3c1ccc(-n3c4ccc(C(C)(C)C)cc4c4cc(C(C)(C)C)ccc43)cc1O2 ; CC(C)(C)c1cc(-c2ccc3c(c2)B2c4ccc(-n5c6ccc(C(C)(C)C)cc6c6cc(C(C)(C)C)ccc65)cc4Oc4cc(C(C)(C)C)cc(c42)N3c2c(-c3ccccc3)cccc2-c2ccccc2)cc(C(C)(C)C)c1]

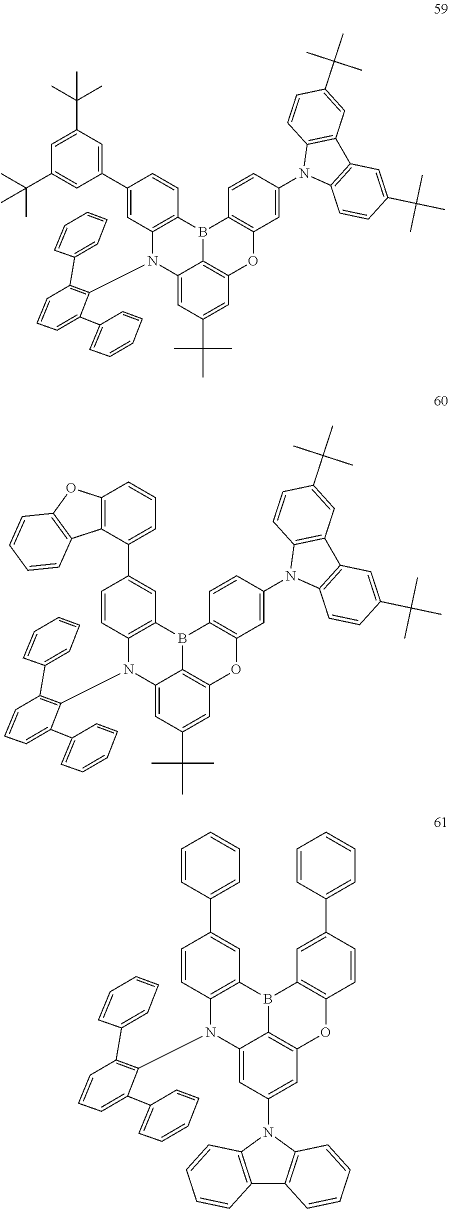 [SMILES: CC(C)(C)c1cc(-c2ccc3c(c2)N(c2c(-c4ccccc4)cccc2-c2ccccc2)c2cc(C(C)(C)C)cc4c2B3c2ccc(-n3c5ccc(C(C)(C)C)cc5c5cc(C(C)(C)C)ccc53)cc2O4)cc(C(C)(C)C)c1 ; CC(C)(C)c1cc2c3c(c1)N(c1c(-c4ccccc4)cccc1-c1ccccc1)c1ccc(-c4cccc5oc6ccccc6c45)cc1B3c1ccc(-n3c4ccc(C(C)(C)C)cc4c4cc(C(C)(C)C)ccc43)cc1O2 ; c1ccc(-c2ccc3c(c2)B2c4cc(-c5ccccc5)ccc4N(c4c(-c5ccccc5)cccc4-c4ccccc4)c4cc(-n5c6ccccc6c6ccccc65)cc(c42)O3)cc1]

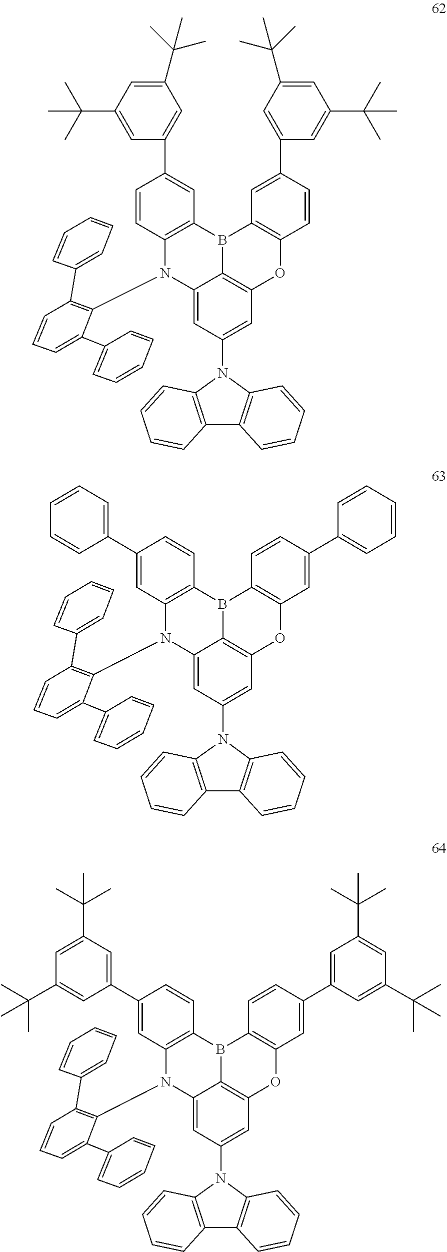

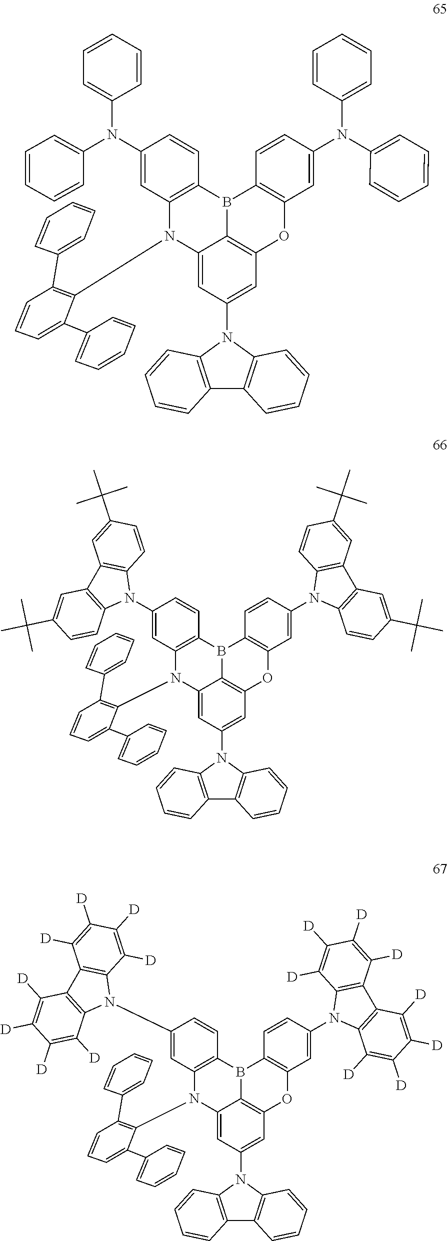

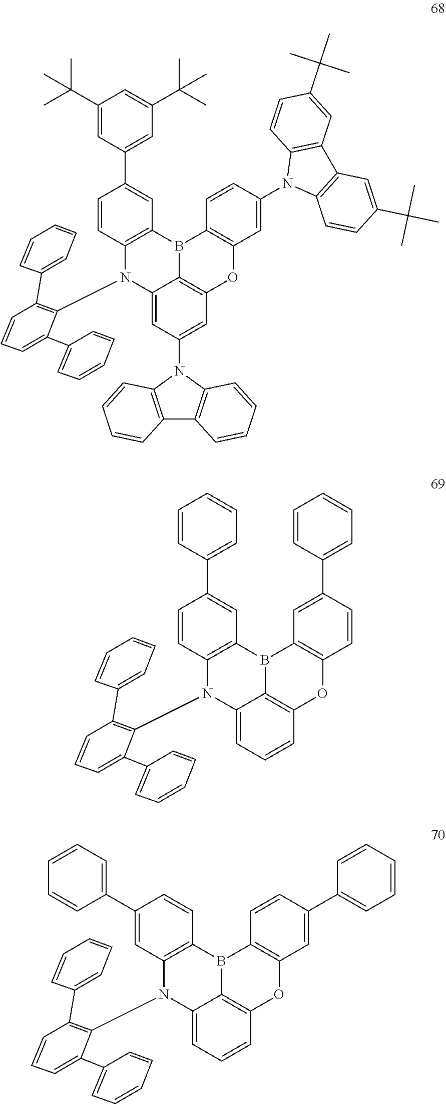 [SMILES: CC(C)(C)c1cc(-c2ccc3c(c2)B2c4ccc(-n5c6ccc(C(C)(C)C)cc6c6cc(C(C)(C)C)ccc65)cc4Oc4cc(-n5c6ccccc6c6ccccc65)cc(c42)N3c2c(-c3ccccc3)cccc2-c2ccccc2)cc(C(C)(C)C)c1 ; c1ccc(-c2ccc3c(c2)B2c4cc(-c5ccccc5)ccc4N(c4c(-c5ccccc5)cccc4-c4ccccc4)c4cccc(c42)O3)cc1 ; c1ccc(-c2ccc3c(c2)Oc2cccc4c2B3c2ccc(-c3ccccc3)cc2N4c2c(-c3ccccc3)cccc2-c2ccccc2)cc1]

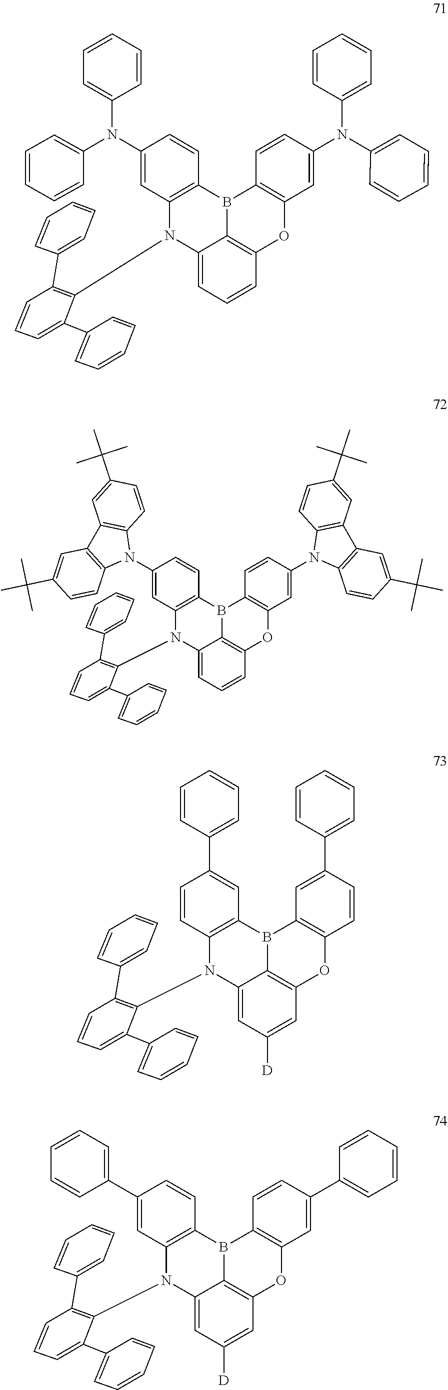 [SMILES: c1ccc(-c2cccc(-c3ccccc3)c2N2c3cc(N(c4ccccc4)c4ccccc4)ccc3B3c4ccc(N(c5ccccc5)c5ccccc5)cc4Oc4cccc2c43)cc1 ; CC(C)(C)c1ccc2c(c1)c1cc(C(C)(C)C)ccc1n2-c1ccc2c(c1)Oc1cccc3c1B2c1ccc(-n2c4ccc(C(C)(C)C)cc4c4cc(C(C)(C)C)ccc42)cc1N3c1c(-c2ccccc2)cccc1-c1ccccc1 ; [2H]c1cc2c3c(c1)N(c1c(-c4ccccc4)cccc1-c1ccccc1)c1ccc(-c4ccccc4)cc1B3c1cc(-c3ccccc3)ccc1O2 ; [2H]c1cc2c3c(c1)N(c1c(-c4ccccc4)cccc1-c1ccccc1)c1cc(-c4ccccc4)ccc1B3c1ccc(-c3ccccc3)cc1O2]

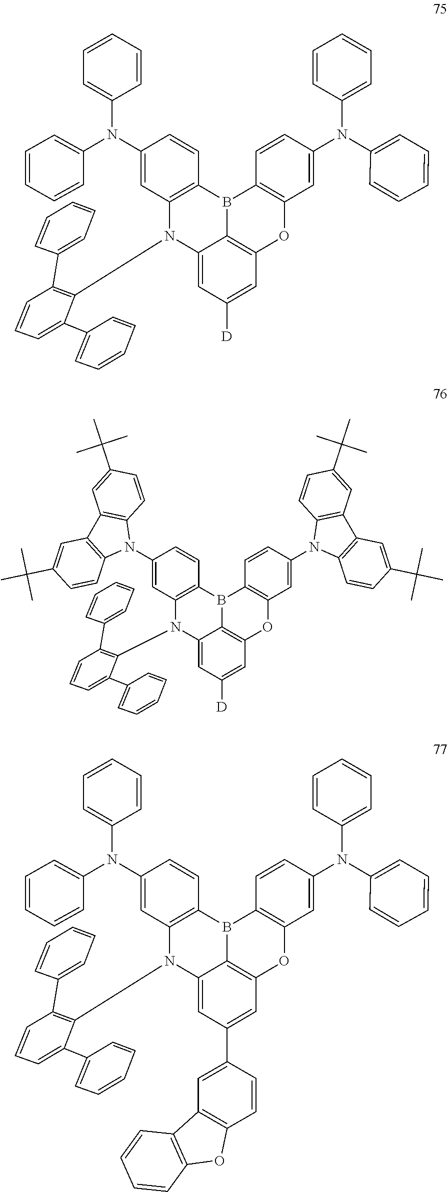 [SMILES: [2H]c1cc2c3c(c1)N(c1c(-c4ccccc4)cccc1-c1ccccc1)c1cc(N(c4ccccc4)c4ccccc4)ccc1B3c1ccc(N(c3ccccc3)c3ccccc3)cc1O2 ; [2H]c1cc2c3c(c1)N(c1c(-c4ccccc4)cccc1-c1ccccc1)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1O2 ; c1ccc(-c2cccc(-c3ccccc3)c2N2c3cc(N(c4ccccc4)c4ccccc4)ccc3B3c4ccc(N(c5ccccc5)c5ccccc5)cc4Oc4cc(-c5ccc6oc7ccccc7c6c5)cc2c43)cc1]

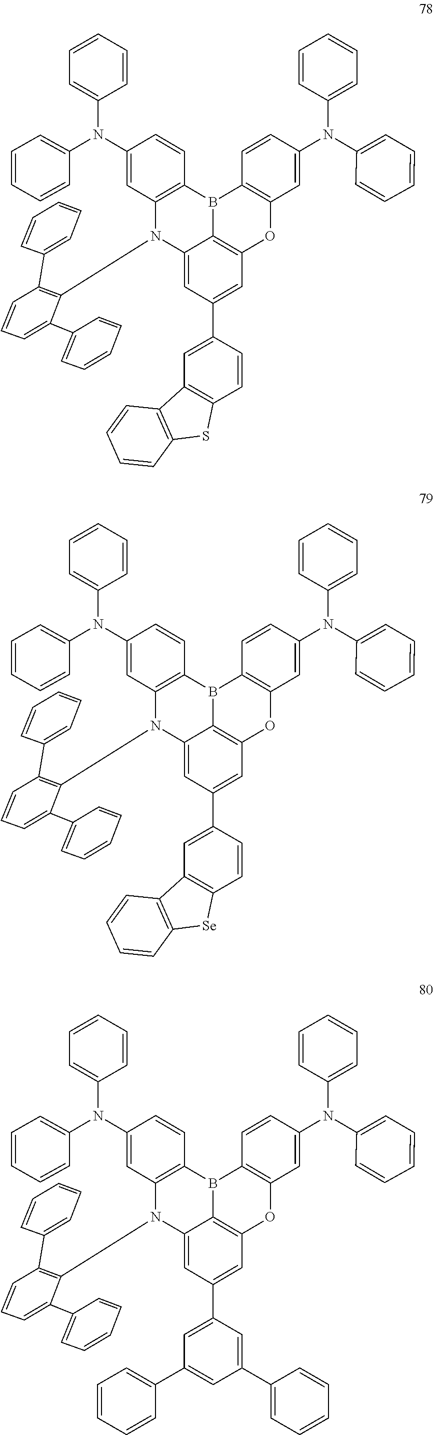 [SMILES: c1ccc(-c2cccc(-c3ccccc3)c2N2c3cc(N(c4ccccc4)c4ccccc4)ccc3B3c4ccc(N(c5ccccc5)c5ccccc5)cc4Oc4cc(-c5ccc6sc7ccccc7c6c5)cc2c43)cc1 ; c1ccc(-c2cccc(-c3ccccc3)c2N2c3cc(N(c4ccccc4)c4ccccc4)ccc3B3c4ccc(N(c5ccccc5)c5ccccc5)cc4Oc4cc(-c5ccc6[se]c7ccccc7c6c5)cc2c43)cc1 ; c1ccc(-c2cc(-c3ccccc3)cc(-c3cc4c5c(c3)N(c3c(-c6ccccc6)cccc3-c3ccccc3)c3cc(N(c6ccccc6)c6ccccc6)ccc3B5c3ccc(N(c5ccccc5)c5ccccc5)cc3O4)c2)cc1]

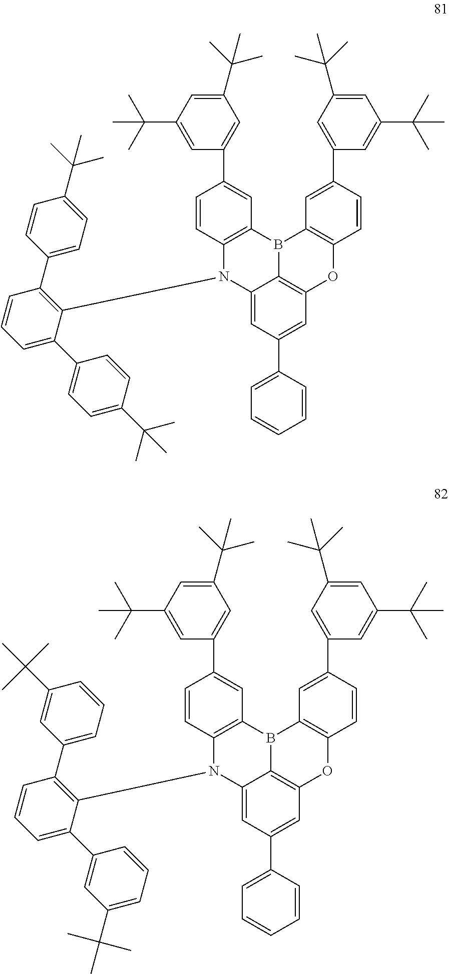

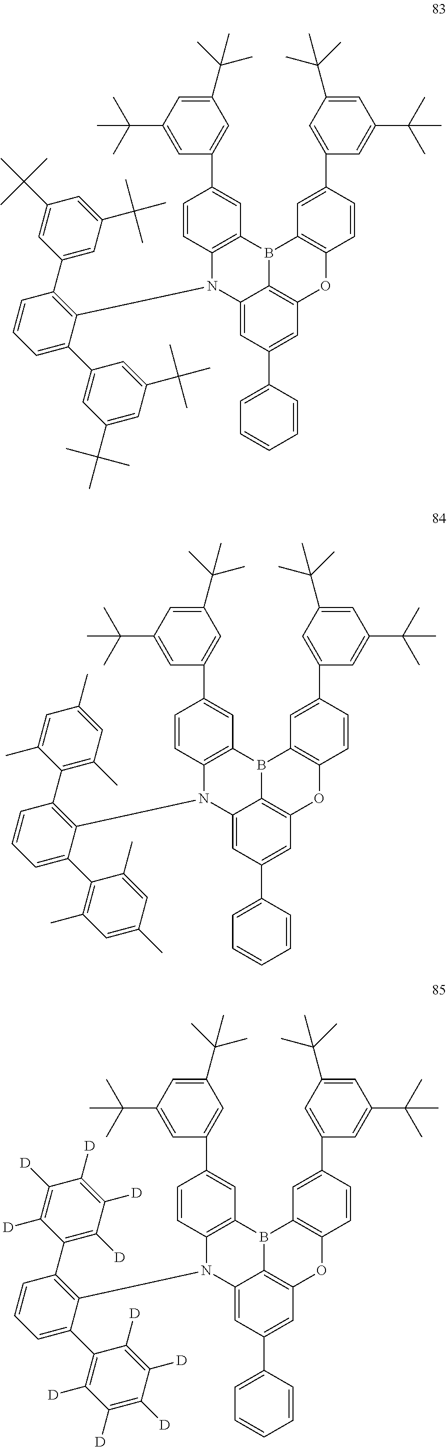

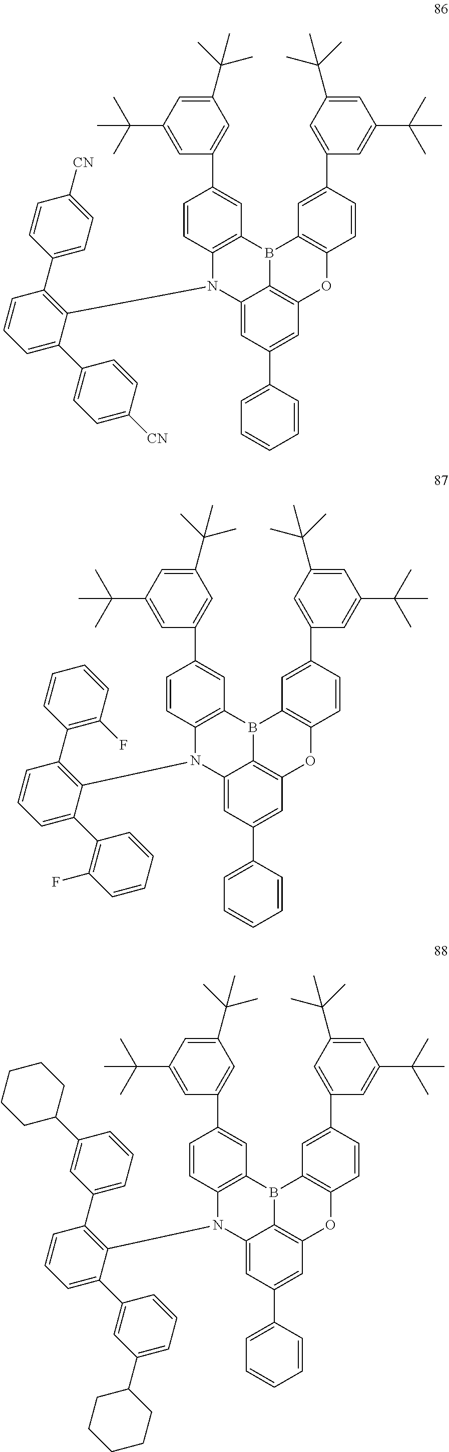 [SMILES: CC(C)(C)c1cc(-c2ccc3c(c2)B2c4cc(-c5cc(C(C)(C)C)cc(C(C)(C)C)c5)ccc4N(c4c(-c5ccc(C#N)cc5)cccc4-c4ccc(C#N)cc4)c4cc(-c5ccccc5)cc(c42)O3)cc(C(C)(C)C)c1 ; CC(C)(C)c1cc(-c2ccc3c(c2)B2c4cc(-c5cc(C(C)(C)C)cc(C(C)(C)C)c5)ccc4N(c4c(-c5ccccc5F)cccc4-c4ccccc4F)c4cc(-c5ccccc5)cc(c42)O3)cc(C(C)(C)C)c1 ; CC(C)(C)c1cc(-c2ccc3c(c2)B2c4cc(-c5cc(C(C)(C)C)cc(C(C)(C)C)c5)ccc4N(c4c(-c5cccc(C6CCCCC6)c5)cccc4-c4cccc(C5CCCCC5)c4)c4cc(-c5ccccc5)cc(c42)O3)cc(C(C)(C)C)c1]

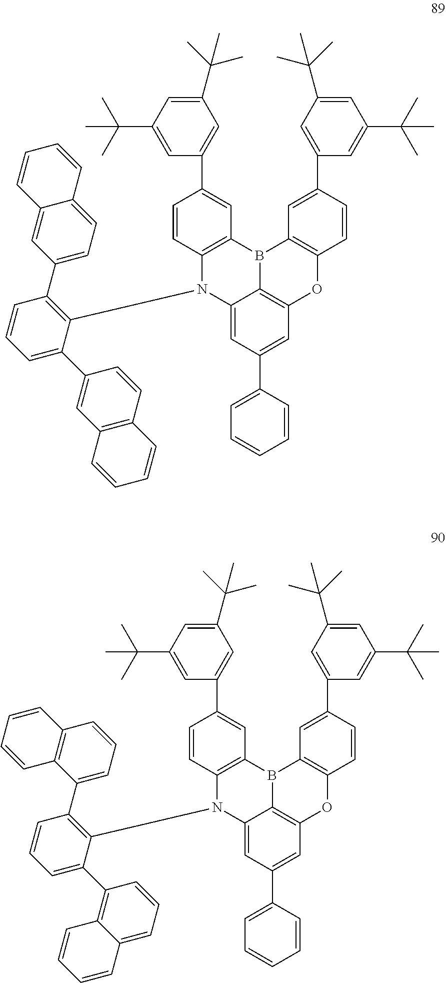 [SMILES: CC(C)(C)c1cc(-c2ccc3c(c2)B2c4cc(-c5cc(C(C)(C)C)cc(C(C)(C)C)c5)ccc4N(c4c(-c5ccc6ccccc6c5)cccc4-c4ccc5ccccc5c4)c4cc(-c5ccccc5)cc(c42)O3)cc(C(C)(C)C)c1 ; CC(C)(C)c1cc(-c2ccc3c(c2)B2c4cc(-c5cc(C(C)(C)C)cc(C(C)(C)C)c5)ccc4N(c4c(-c5cccc6ccccc56)cccc4-c4cccc5ccccc45)c4cc(-c5ccccc5)cc(c42)O3)cc(C(C)(C)C)c1]

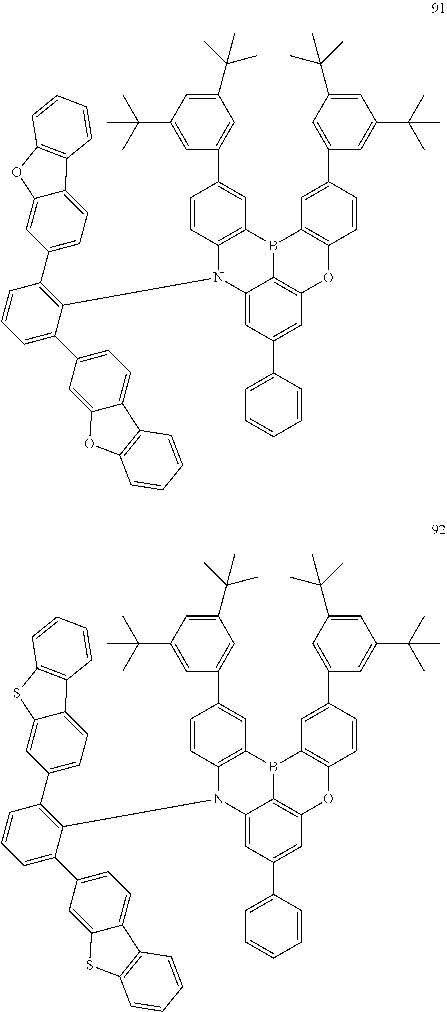 [SMILES: CC(C)(C)c1cc(-c2ccc3c(c2)B2c4cc(-c5cc(C(C)(C)C)cc(C(C)(C)C)c5)ccc4N(c4c(-c5ccc6c(c5)oc5ccccc56)cccc4-c4ccc5c(c4)oc4ccccc45)c4cc(-c5ccccc5)cc(c42)O3)cc(C(C)(C)C)c1 ; CC(C)(C)c1cc(-c2ccc3c(c2)B2c4cc(-c5cc(C(C)(C)C)cc(C(C)(C)C)c5)ccc4N(c4c(-c5ccc6c(c5)sc5ccccc56)cccc4-c4ccc5c(c4)sc4ccccc45)c4cc(-c5ccccc5)cc(c42)O3)cc(C(C)(C)C)c1]

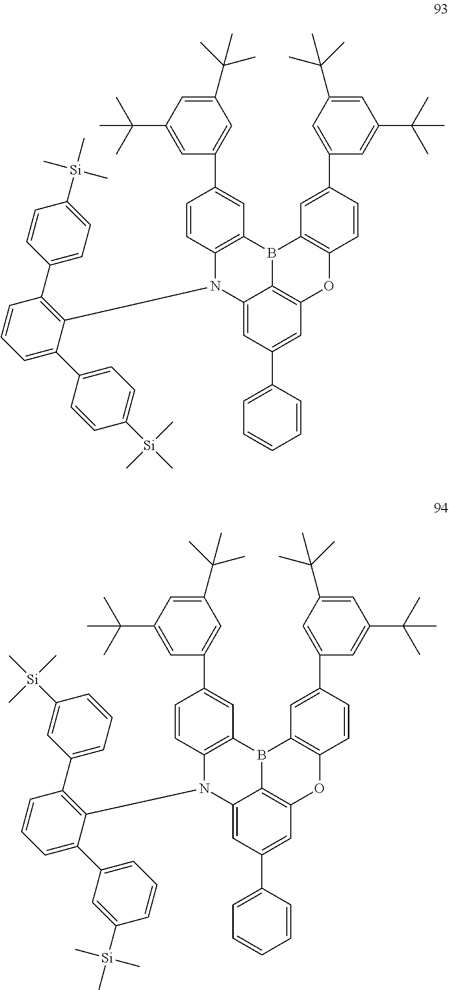

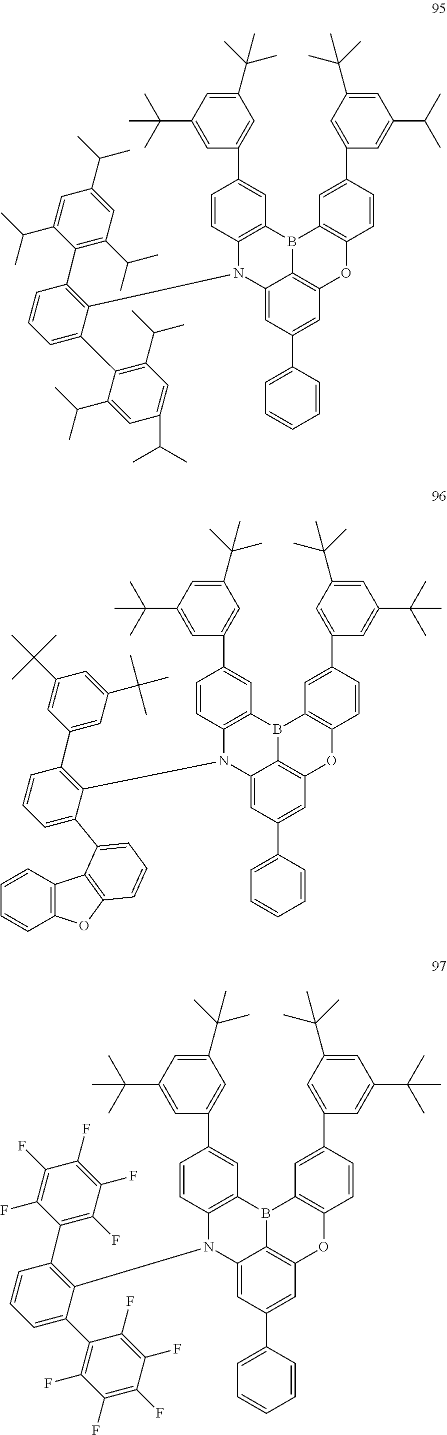

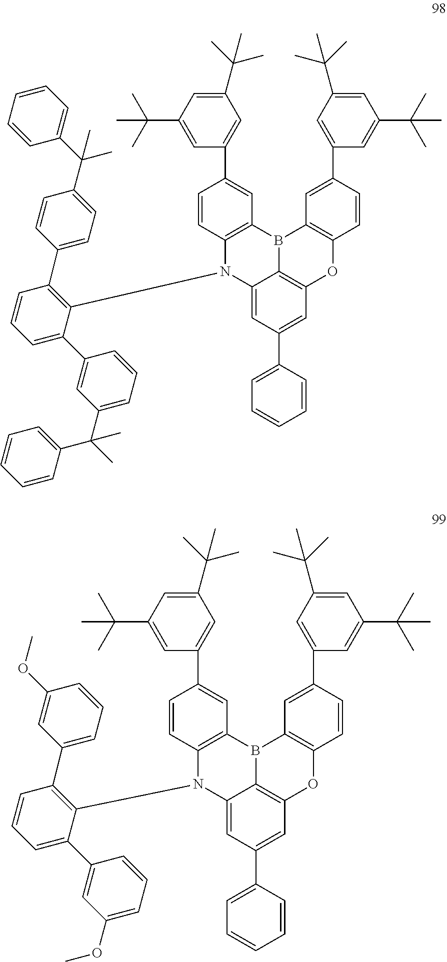 [SMILES: CC(C)(C)c1cc(-c2ccc3c(c2)B2c4cc(-c5cc(C(C)(C)C)cc(C(C)(C)C)c5)ccc4N(c4c(-c5ccc(C(C)(C)c6ccccc6)cc5)cccc4-c4cccc(C(C)(C)c5ccccc5)c4)c4cc(-c5ccccc5)cc(c42)O3)cc(C(C)(C)C)c1 ; COc1cccc(-c2cccc(-c3cccc(OC)c3)c2N2c3ccc(-c4cc(C(C)(C)C)cc(C(C)(C)C)c4)cc3B3c4cc(-c5cc(C(C)(C)C)cc(C(C)(C)C)c5)ccc4Oc4cc(-c5ccccc5)cc2c43)c1]

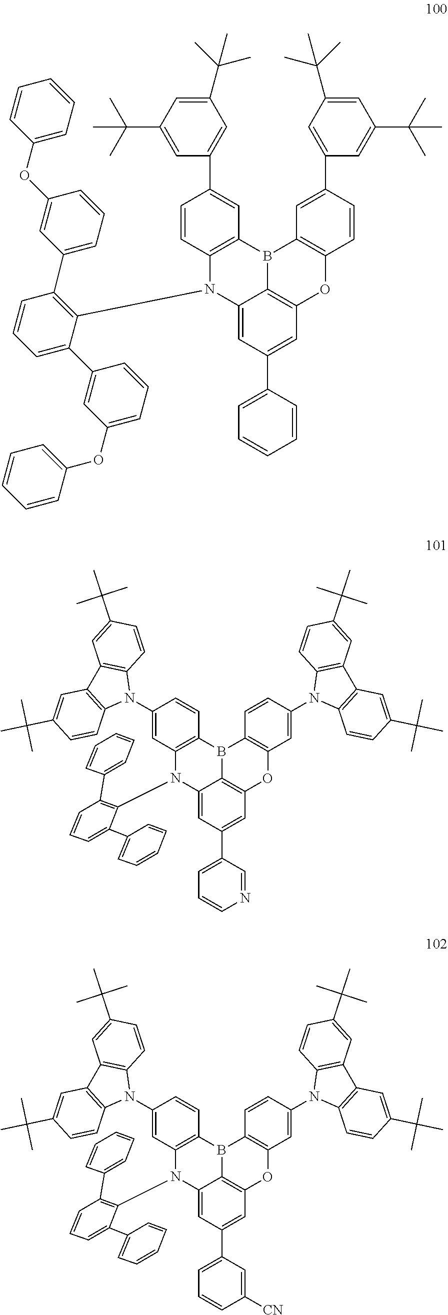

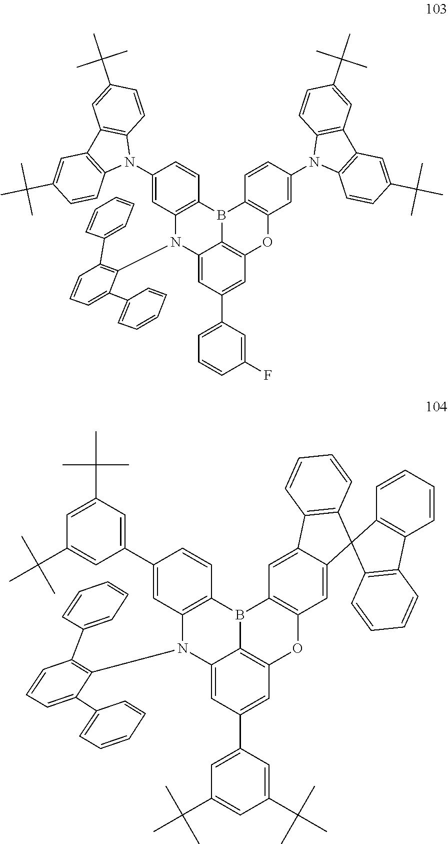

In the embodiment compounds presented in Compound Group 1, “D” corresponds to a deuterium atom.

The fused polycyclic compound represented by Formula 1 according to an embodiment may achieve along service life, may cause a blue shift of the luminescence wavelength, and at the same time may finely control the luminescence wavelength, by introducing the first substituent, which is a steric hindrance substituent, into the fused ring structure.

The fused polycyclic compound of an embodiment has a structure in which a plurality of aromatic rings are fused by at least one boron atom, at least one nitrogen atom, and at least one oxygen atom, and necessarily includes, as a substituent, the first substituent linked to the nitrogen atom constituting the fused ring. The first substituent may be a substituent which contains a benzene moiety and in which a substituted or unsubstituted aryl group having 6 to 30 ring-forming carbon atoms, or a substituted or unsubstituted heteroaryl group having 2 to 30 ring-forming carbon atoms is introduced into a carbon at the position of the benzene moiety. The fused polycyclic compound of an embodiment having such a structure may effectively maintain a trigonal planar structure of the boron atom through the steric hindrance effect of the first substituent. The boron atom may have electron deficiency characteristics by an empty p-orbital, thereby form a bond with other nucleophiles, and thus, be changed into a tetrahedral structure, which may cause deterioration of the device. According to embodiments of the present disclosure, the fused polycyclic compound represented by Formula 1 includes the first substituent having the steric hindrance structure, and thereby may effectively protect the empty p-orbital of the boron atom, and thus, may prevent or reduce the deterioration phenomenon due to a structural change.

In addition, the fused polycyclic compound of an embodiment may have an increase in the luminous efficiency because the intermolecular interaction may be suppressed or reduced by the introduction of the first substituent, thereby controlling the formation of an excimer and/or exciplex. In addition, the fused polycyclic compound of an embodiment includes the first substituent, thereby a dihedral angle between the plane containing the fused ring core structure having the boron atom at the center thereof and the plane containing the first substituent may increase, and thus, the intermolecular distance increases so that there is an effect of reducing Dexter energy transfer. The Dexter energy transfer is a phenomenon, in which a triplet exciton moves between molecules, and increases when the intermolecular distance is short, and may become a factor that increases a quenching phenomenon due to the increase of triplet concentration. According to embodiments of the present disclosure, the fused polycyclic compound of an embodiment has an Increase in the distance between adjacent molecules due to the large steric hindrance structure to thereby suppress or reduce the Dexter energy transfer, and thus, may suppress or reduce the deterioration of service life due to the increase of triplet concentration. Therefore, when the fused polycyclic compound of an embodiment is applied to the emission layer EML of the light emitting device ED, the luminous efficiency may be increased and the device service life may also be improved.

In addition, the fused polycyclic compound represented by Formula 1 of an embodiment may easily control the electron distribution of the orbital in a light emitting core by the introduction of an oxygen atom as an atom constituting the fused ring. In some embodiments, the fused polycyclic compound of an embodiment may cause a blue shift of the luminescence wavelength as compared another compound containing a fused ring only composed of a boron atom and a nitrogen atom. The oxygen atom has a lower atomic orbital energy than a nitrogen atom, and thus, when the oxygen atom is introduced as an atom constituting the fused ring, it may be possible to easily control a highest occupied molecular orbital (HOMO) energy level and a lowest unoccupied molecular orbital (LUMO) energy level. Accordingly, the fused polycyclic compound of an embodiment essentially includes the oxygen atom as an atom constituting the fused ring and has a change in kinds of substituents linked to the fused ring, thereby causing a blue shift of the luminescence wavelength and at the same time finely controlling the luminescence wavelength. In some embodiments, the fused polycyclic compound of an embodiment is possible to control a desired luminescence wavelength within a wavelength range of about 440 nm to about 460 nm while the optical and physical properties are not greatly or substantially changed.

The fused polycyclic compound of an embodiment may be included in the emission layer EML. The fused polycyclic compound of an embodiment may be included as a dopant material in the emission layer EML. The fused polycyclic compound of an embodiment may be a thermally activated delayed fluorescence material. The fused polycyclic compound of an embodiment may be used as a thermally activated delayed fluorescence dopant. For example, in the light emitting device ED of an embodiment, the emission layer EML may include, as a thermally activated delayed fluorescence dopant, at least one selected from among the polycyclic compounds represented by Compound Group 1 as described above. However, a use of the fused polycyclic compound of an embodiment is not limited thereto.

In an embodiment, the emission layer EML may include a plurality of compounds. The emission layer EML of an embodiment may include the fused polycyclic compound represented by Formula 1, e.g., the first compound, and at least one of the second compound represented by Formula H-1 below, the third compound represented by Formula H-2 below, or the fourth compound represented by Formula D-1 below.

In an embodiment, the emission layer EML may include the second compound represented by Formula H-1 below. For example, the second compound represented by Formula H-1 may be used as a hole transport host material of the emission layer EML.

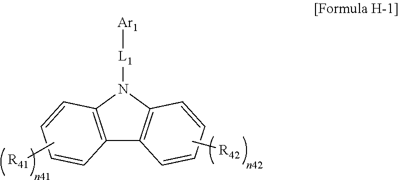

In Formula H-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, etc., but embodiments of the present disclosure are not limited thereto.

In Formula H-1, Ar₁ may be a substituted or unsubstituted aryl group having 6 to 30 ring-forming carbon atoms, or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, etc., but embodiments of the present disclosure are not limited thereto.

In Formula H-1, R₄₁ and R₄₂ may be each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In some embodiments, each of R₄₁ and R₄₂ may be bonded to an adjacent group to form a ring. For example, R₄₁ and R₄₂ may be each independently a hydrogen atom or a deuterium atom.

In Formula H-1, n41 and n42 are each independently an integer of 0 to 4. If each of n41 and n42 is 0, the fused polycyclic compound of an embodiment may not be substituted with each of R₄₁ and R₄₂. The case where each of n41 and n42 is 4 and R₄₁′s and R₄₂′s are each hydrogen atoms may be the same as the case where each of n41 and n42 is 0. When each of n41 and n42 is an integer of 2 or more, a plurality of R₄₁′s and R₄₂′s may each be the same or at least one selected from among the plurality of R₄₁′s and R₄₂′s may be different from the others.

In an embodiment, the emission layer EML may include the third compound represented by Formula H-2 below. For example, the third compound may be used as an electron transport host material of the emission layer EML.

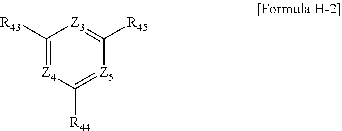

In Formula H-2, Z₃ to Z₅ may be each independently N or CR₄₆, but at least one selected from among Z₃ to Z₅ may be N.

In Formula H-2, R₄₃ to R₄₆ may be each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In some embodiments, each of R₄₃ to R₄₆ may be bonded to an adjacent group to form a ring. For example, R₄₃ to R₄₆ may be each independently a substituted or unsubstituted phenyl group, a substituted or unsubstituted carbazole group, etc., but embodiments of the present disclosure are not limited thereto.

For example, the emission layer EML may include the second compound and the third compound, and the second compound and the third compound may form an exciplex. In the emission layer EML, an exciplex may be formed by the hole transport host and the electron transport host. In this case, a triplet energy of the exciplex formed by the hole transporting host and the electron transporting host may correspond to the difference between a lowest unoccupied molecular orbital (LUMO) energy level of the electron transporting host and a highest occupied molecular orbital (HOMO) energy level of the hole transporting host.

For example, the absolute value of the triplet energy (T1) of the exciplex formed by the hole transporting host and the electron transporting host may be about 2.4 eV to about 3.0 eV. In addition, the triplet energy of the exciplex may be a value smaller than an energy gap of each host material. The exciplex may have a triplet energy of about 3.0 eV or less that is an energy gap between the hole transporting host and the electron transporting host.

In an embodiment, the emission layer EML may include a fourth compound in addition to the first compound to the third compound. The fourth compound may be used as a phosphorescent sensitizer of the emission layer EML. The energy may be transferred from the fourth compound to the first compound, thereby emitting light.

For example, the emission layer EML may include, as the fourth compound, an organometallic complex containing platinum (Pt) as a central metal atom and ligands linked to the central metal atom. The emission layer EML in the light emitting device ED of an embodiment may include, as the fourth compound, a compound represented by Formula D-1 below:

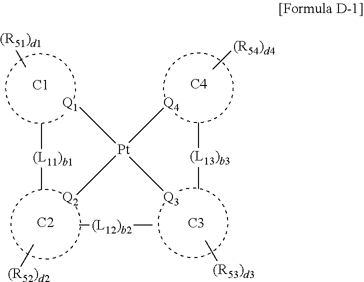

In Formula D-1, Q₁ to Q₄ may be each independently C or N.

In Formula D-1, C1 to C4 may be each independently a substituted or unsubstituted hydrocarbon ring having 5 to 30 ring-forming carbon atoms, or a substituted or unsubstituted heterocycle having 2 to 30 ring-forming carbon atoms.

In Formula D-1, L₁₁ to L₁₃ may be each independently a direct linkage,

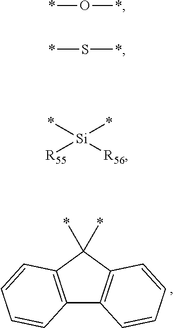

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, “ [symbol] ” means a part linked to C1 to C4.

In Formula D-1, b1 to b3 may be each independently 0 or 1. If b1 is 0, C1 and C2 may not be linked to each other. If b2 is 0, C2 and C3 may not be linked to each other. If b3 is 0, C3 and C4 may not be linked to each other.

In Formula D-1, R₅₁ to R₅₆ may be each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms. In some embodiments, each of R₅₁ to R₅₆ may be bonded to an adjacent group to form a ring. R₅₁ to R₅₆ may be each independently a substituted or unsubstituted methyl group, or a substituted or unsubstituted t-butyl group.

In Formula D-1, d1 to d4 are each independently an integer of 0 to 4. In Formula D-1, if each of d1 to d4 is 0, the fused polycyclic compound of an embodiment may not be substituted with each R₅₁ to R₅₄. The case where each of d1 to d4 is 4 and R₅₁′s to R₅₄′ are each hydrogen atoms may be the same as the case where each of d1 to d4 is 0. When each of d1 to d4 is an integer of 2 or more, a plurality of R₅₁′s to R₅₄′s may each be the same or at least one selected from among the plurality of R₅₁′s to R₅₄′s may be different from the others.

In Formula D-1, C1 to C4 may be each independently a substituted or unsubstituted hydrocarbon ring or a substituted or unsubstituted heterocycle represented by any one selected from among C-1 to C-4 below:

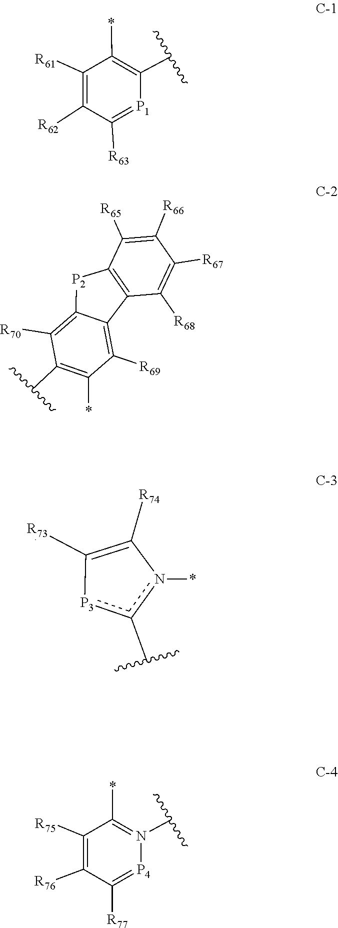

In C-1 to C-4, P₁ may be C—* or CR₆₄, P₂ may be N—* or NR₇₁, P3 may be N—* or NR₇₂, and P₄ may be C—* or CR₇₈. R₆₁ to R₇₈ may be each independently a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In addition, in C-1 to C-4, “

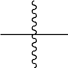

” corresponds to a part linked to Pt that is a central metal atom, and “ [symbol] ” corresponds to a part linked to a neighboring cyclic group (C1 to C4) or a linker (L₁₁ to L₁₃).

The emission layer EML of an embodiment may include the first compound, and at least one selected from the second to fourth compounds. For example, the emission layer EML may include the first compound, the second compound, and the third compound. In the emission layer EML, the second compound and the third compound may form an exciplex, and the energy may be transferred from the exciplex to the first compound, thereby emitting light.

In addition, the emission layer EML may include the first compound, the second compound, the third compound, and the fourth compound. In the emission layer EML, the second compound and the third compound may form an exciplex, and the energy may be transferred from the exciplex to the fourth compound and the first compound, thereby emitting light. In an embodiment, the fourth compound may be a sensitizer. The fourth compound included in the emission layer EML in the light emitting device ED of an embodiment may serve as a sensitizer to deliver energy from the host to the first compound that is a light emitting dopant. In some embodiments, the fourth compound serving as an auxiliary dopant accelerates energy delivery to the first compound that is a light emitting dopant, thereby increasing the emission ratio of the first compound. Therefore, the emission layer EML of an embodiment may improve luminous efficiency. In addition, when the energy delivery to the first compound is increased, an exciton formed in the emission layer EML is not accumulated inside the emission layer EML and emits light rapidly, and thus, deterioration of the element may be reduced. Therefore, the service life of the light emitting device ED of an embodiment may increase.

The light emitting device ED of an embodiment may include all of the first compound, the second compound, the third compound, and the fourth compound, and the emission layer EML may include the combination of two host materials and two dopant materials. In the light emitting device ED of an embodiment, the emission layer EML may concurrently (e.g., simultaneously) include two different hosts, the first compound that emits a delayed fluorescence, and the fourth compound including an organometallic complex, thereby exhibiting excellent luminous efficiency characteristics.

In an embodiment, the second compound represented by Formula 2 may be represented by any one selected from among the compounds represented by Compound Group 2 below. The emission layer EML may include at least one selected from among the compounds represented by Compound Group 2 as a hole transporting host material.

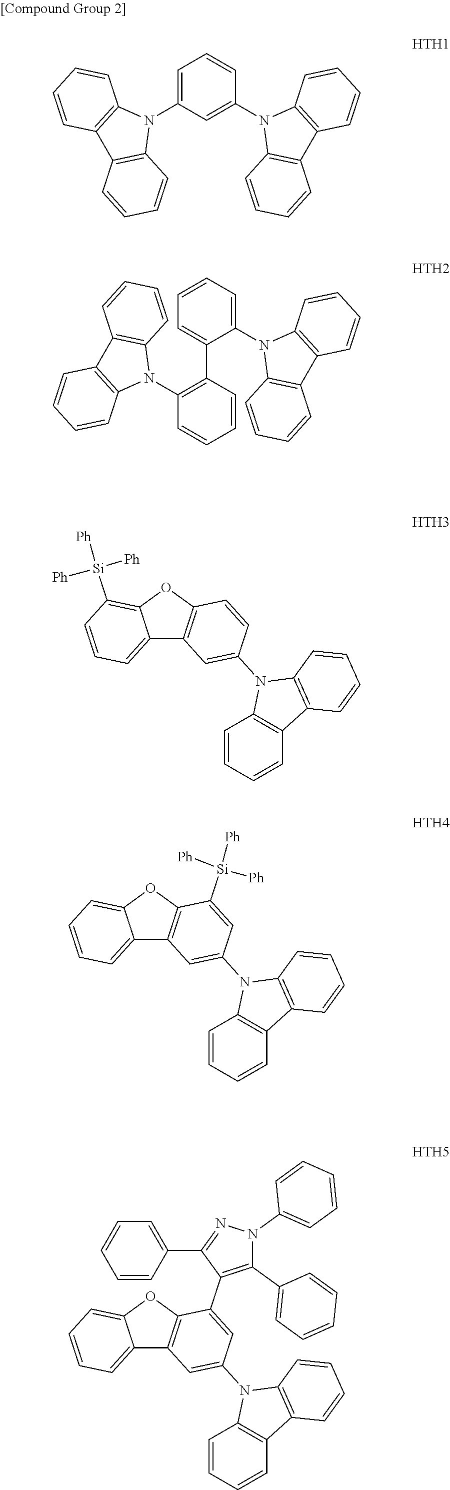 [SMILES: c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1]

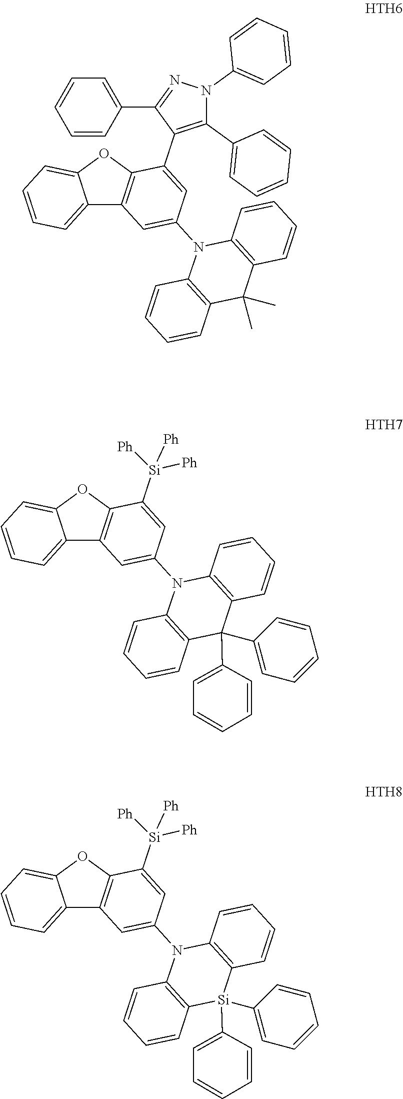 [SMILES: CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

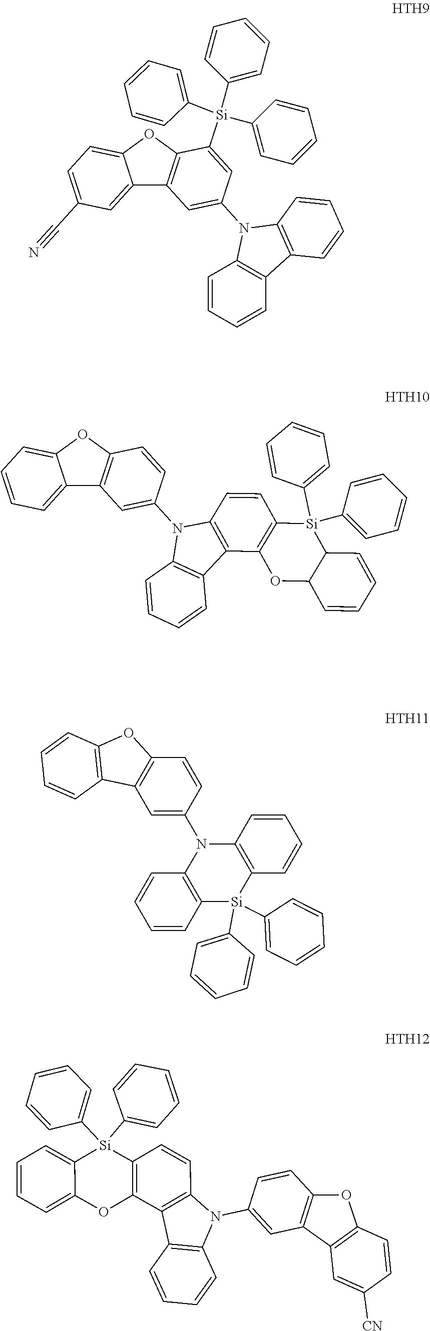 [SMILES: N#Cc1ccc2oc3c([Si](c4ccccc4)(c4ccccc4)c4ccccc4)cc(-n4c5ccccc5c5ccccc54)cc3c2c1 ; C1=CC2Oc3c(ccc4c3c3ccccc3n4-c3ccc4oc5ccccc5c4c3)[Si](c3ccccc3)(c3ccccc3)C2C=C1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

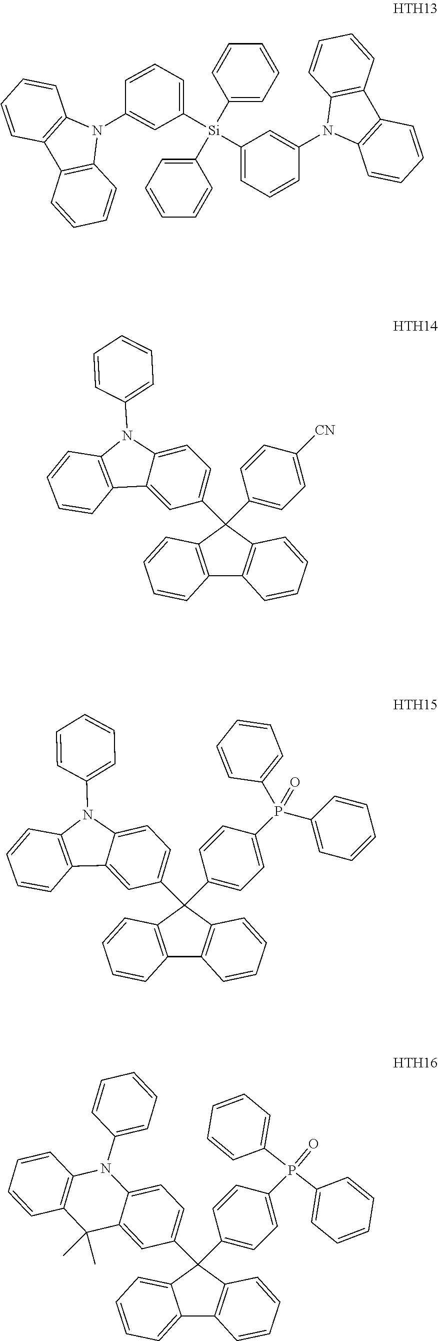 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

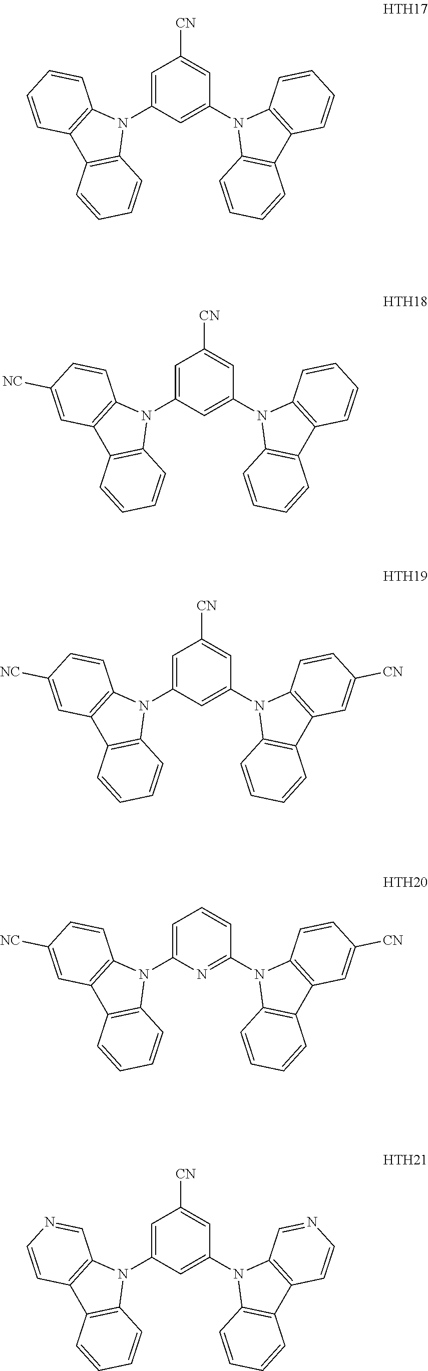 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1]

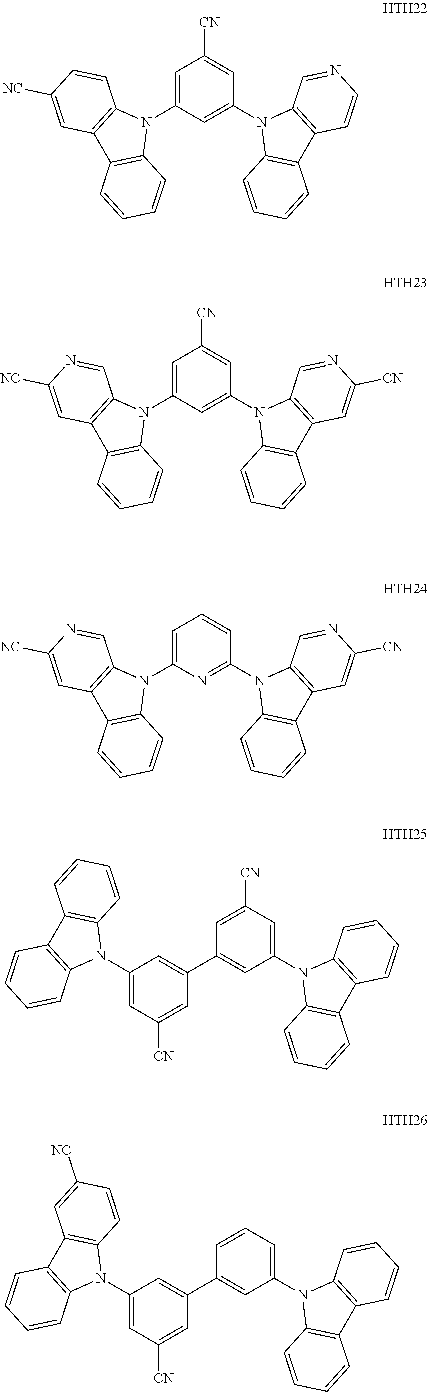 [SMILES: N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1]

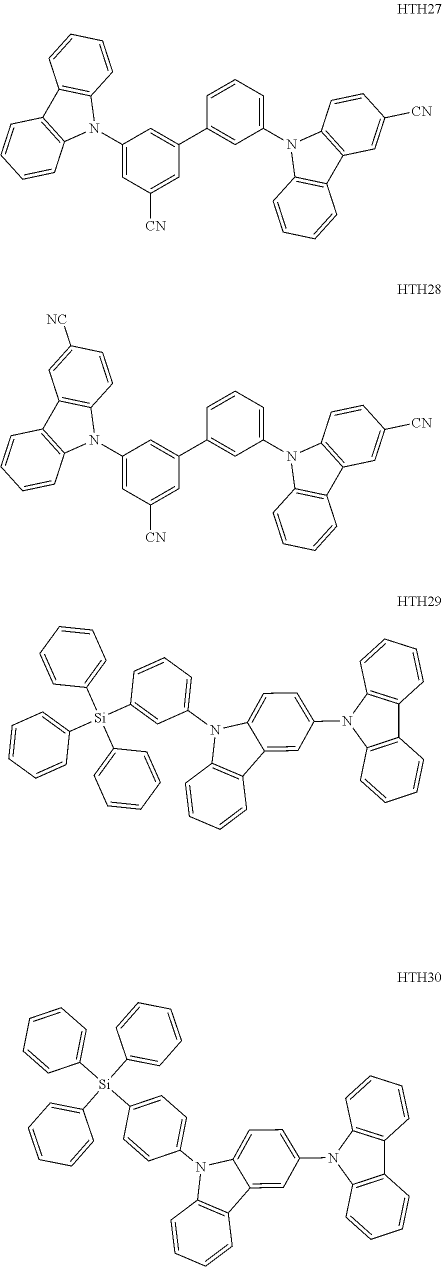 [SMILES: N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2ccc(-n3c4ccccc4c4cc(-n5c6ccccc6c6ccccc65)ccc43)cc2)cc1]

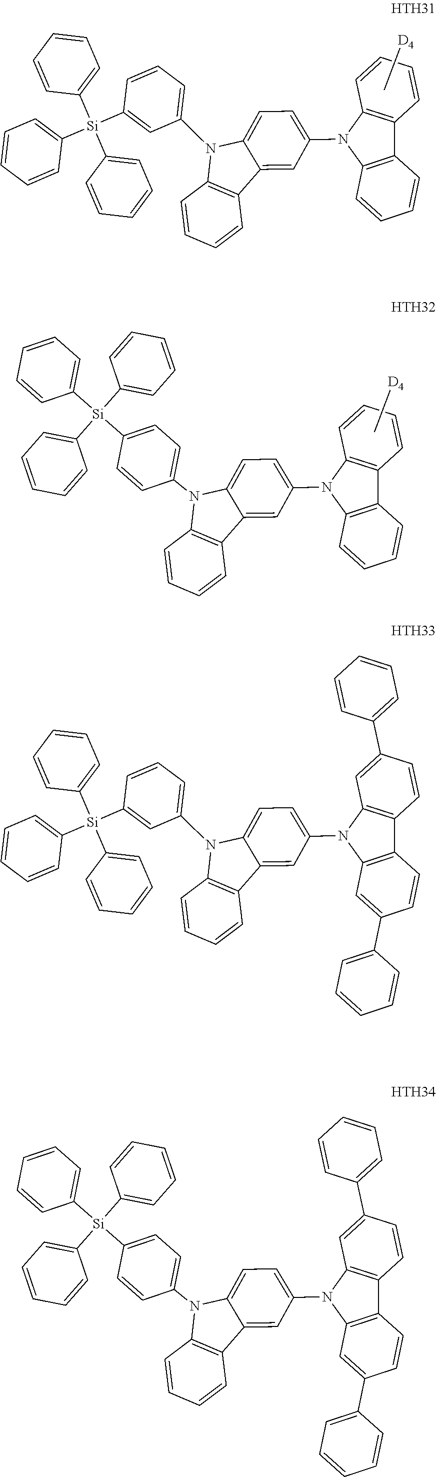

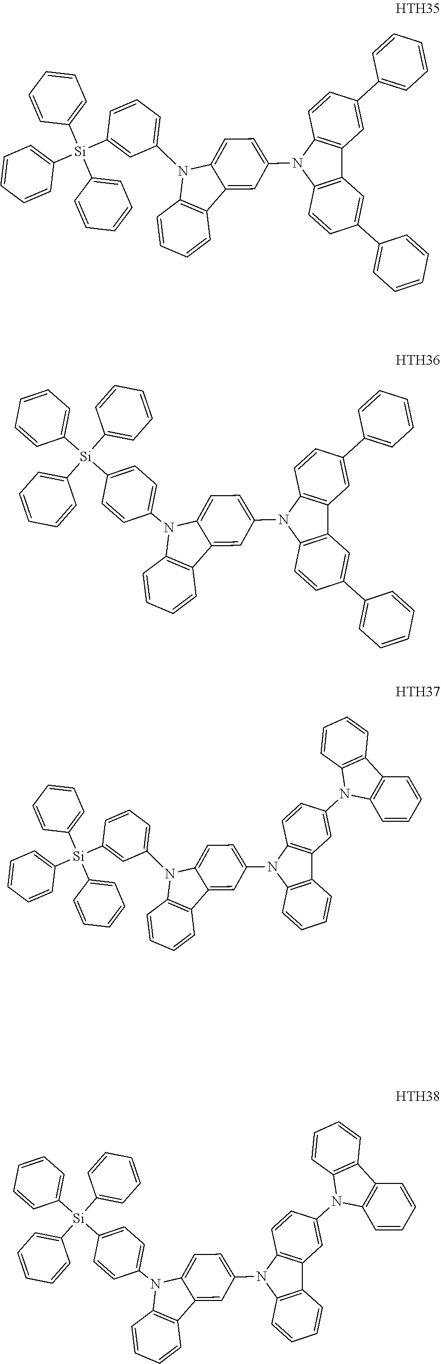 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

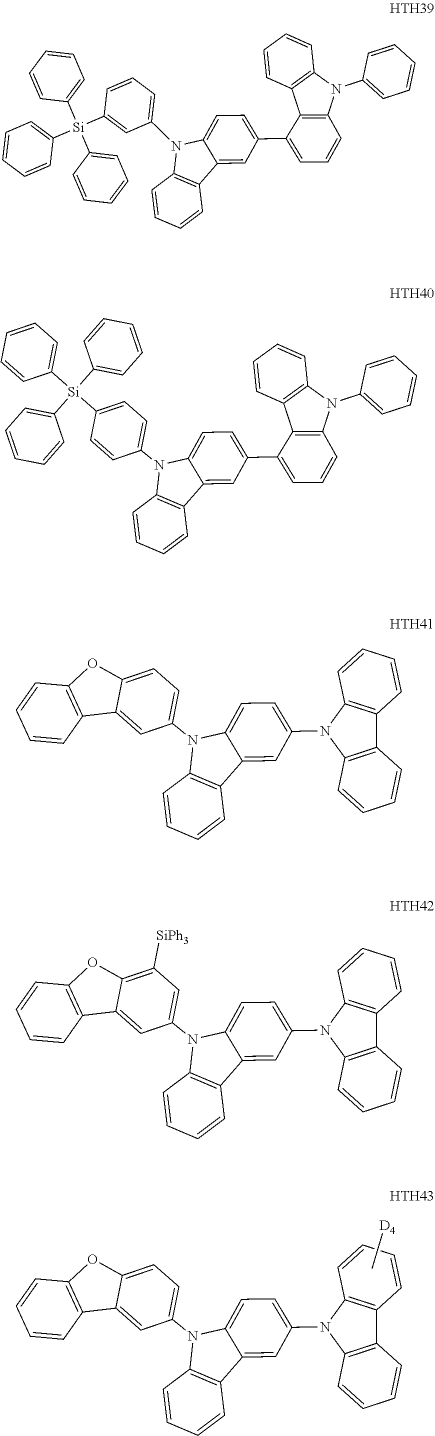

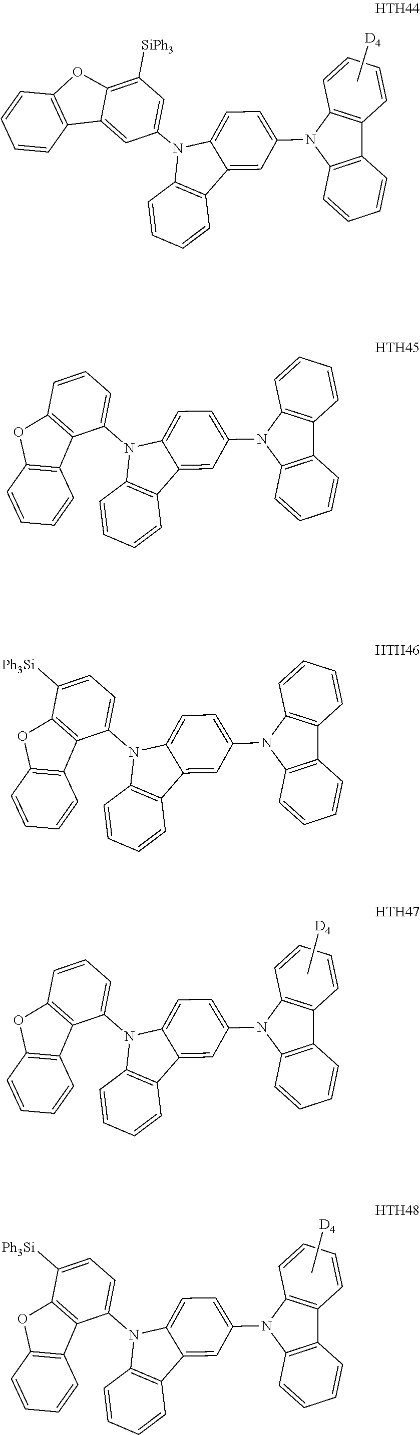

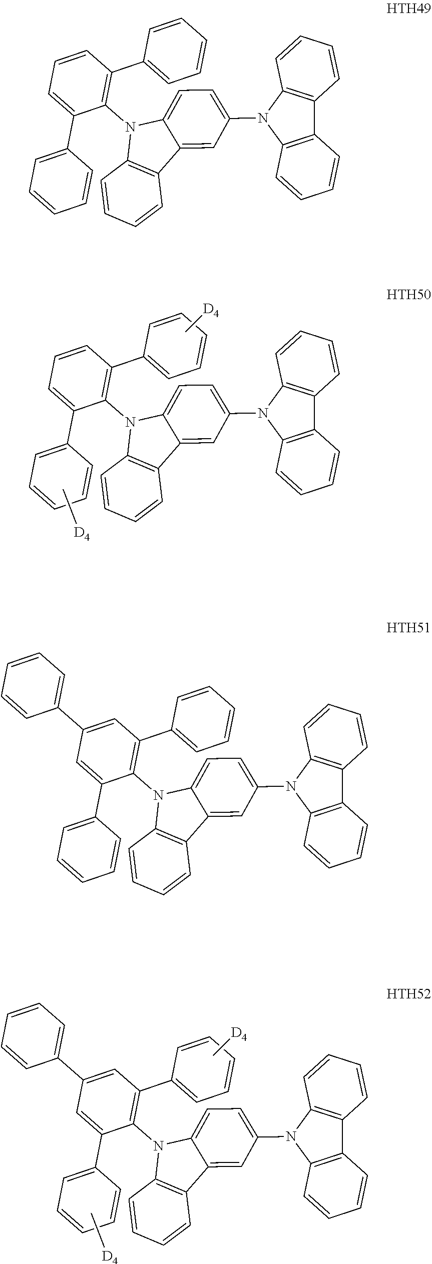

In embodiment compounds presented in Compound Group 2, “D” may mean a deuterium atom, and “Ph” may mean a substituted or unsubstituted phenyl group. For example, in embodiment compounds presented in Compound Group 2, “Ph” may mean an unsubstituted phenyl group.

In an embodiment, the third compound represented by Formula 3 may be represented by any one selected from among the compounds represented by Compound Group 3 below. The emission layer EML may include at least one selected from among the compounds represented by Compound Group 3 as an electron transporting host material.

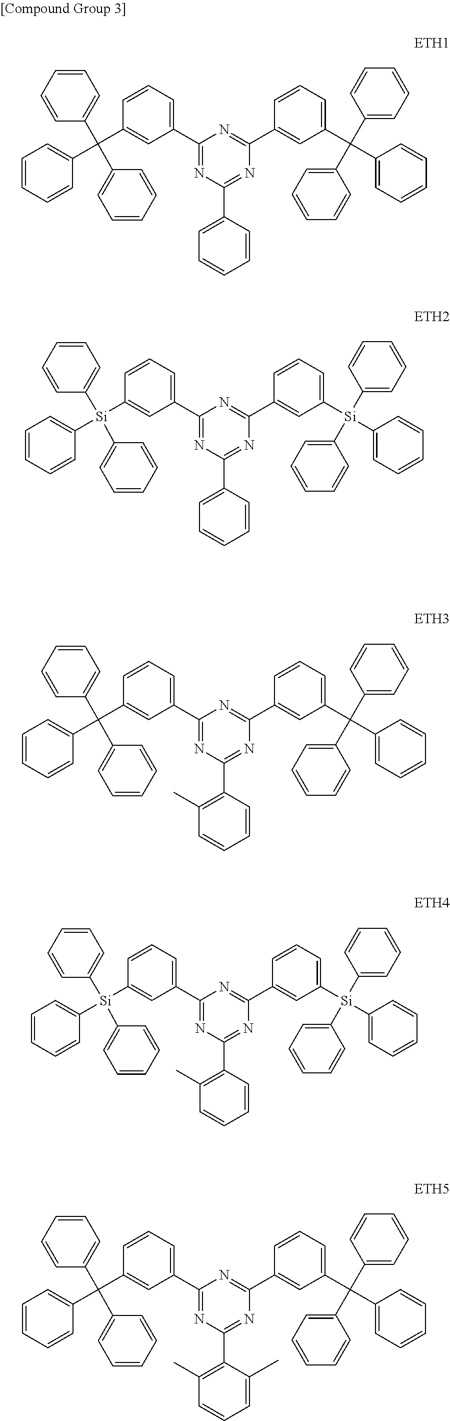

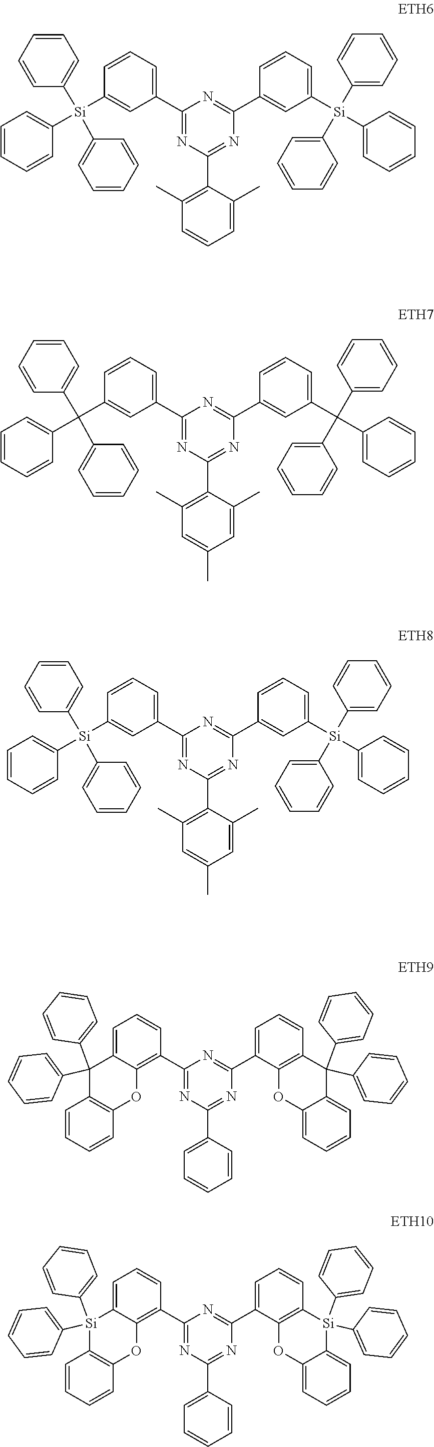

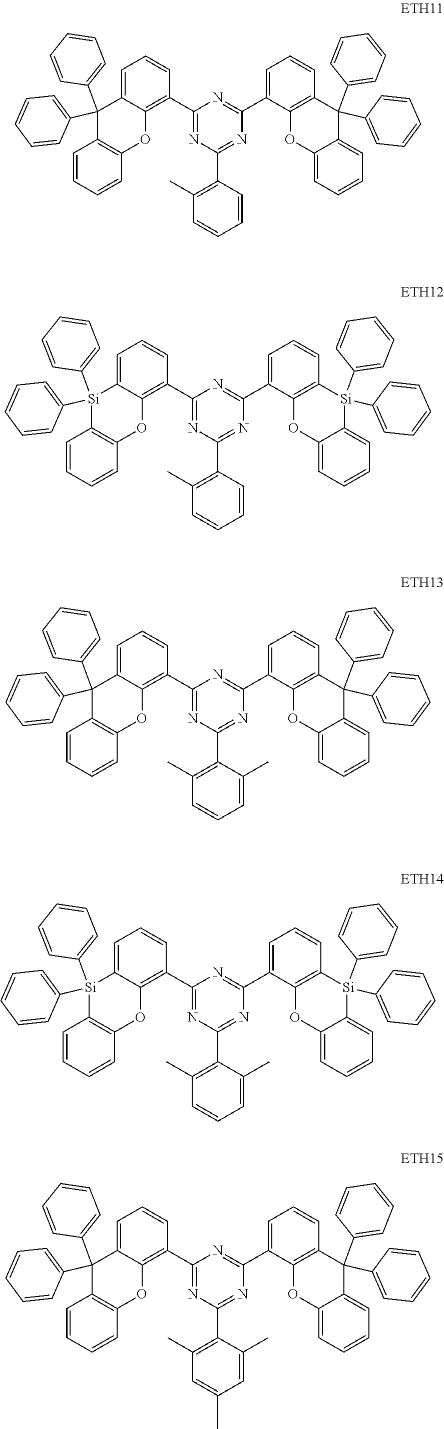

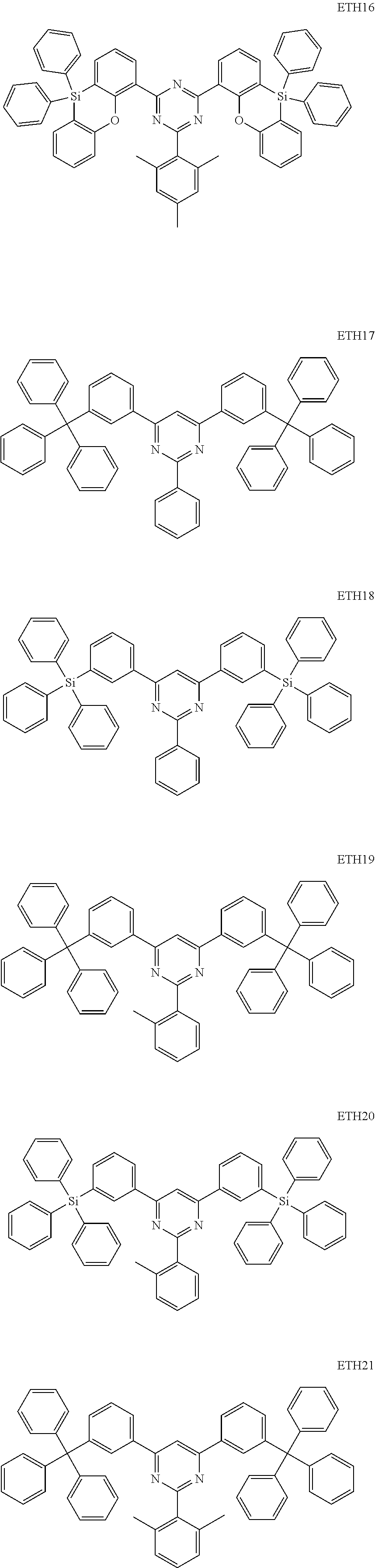

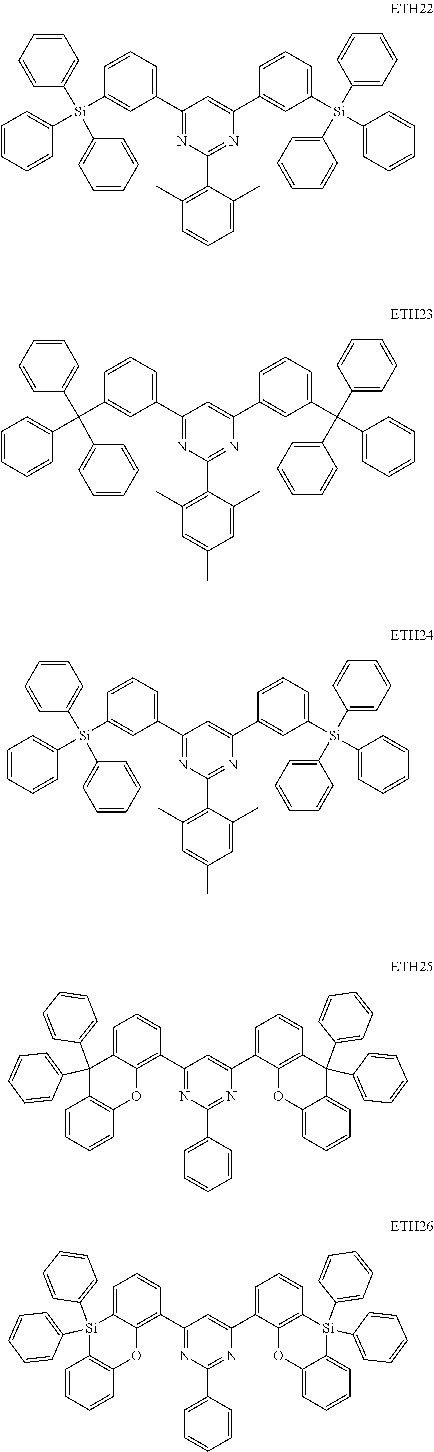

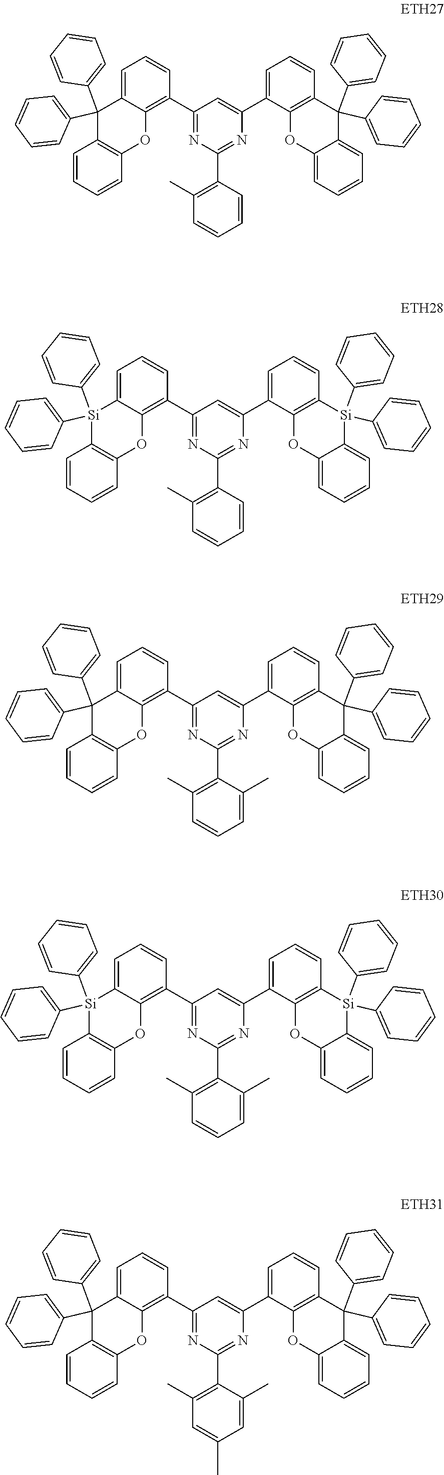

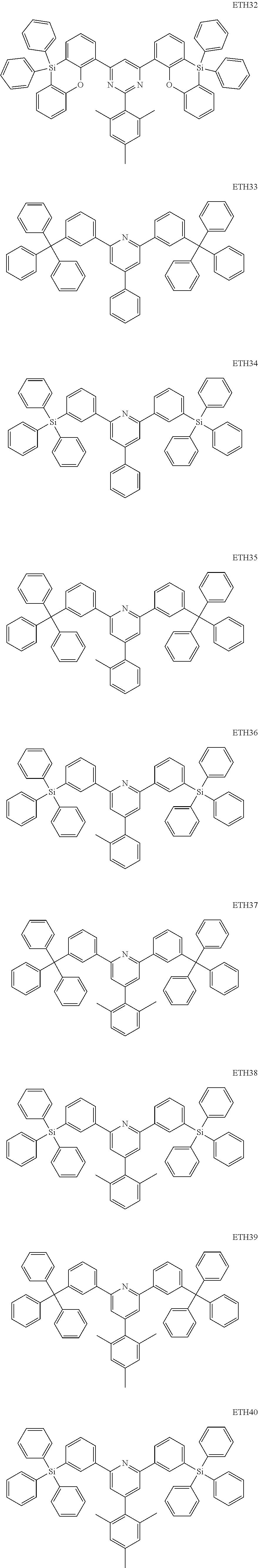

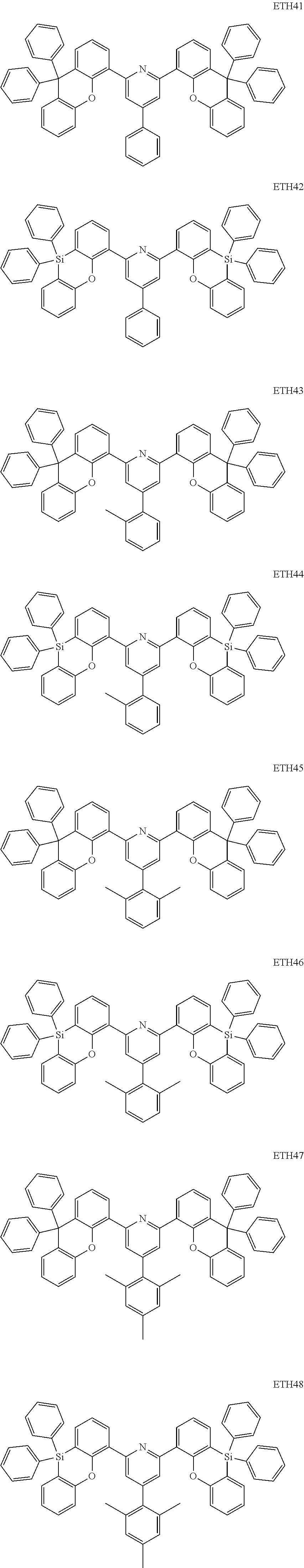

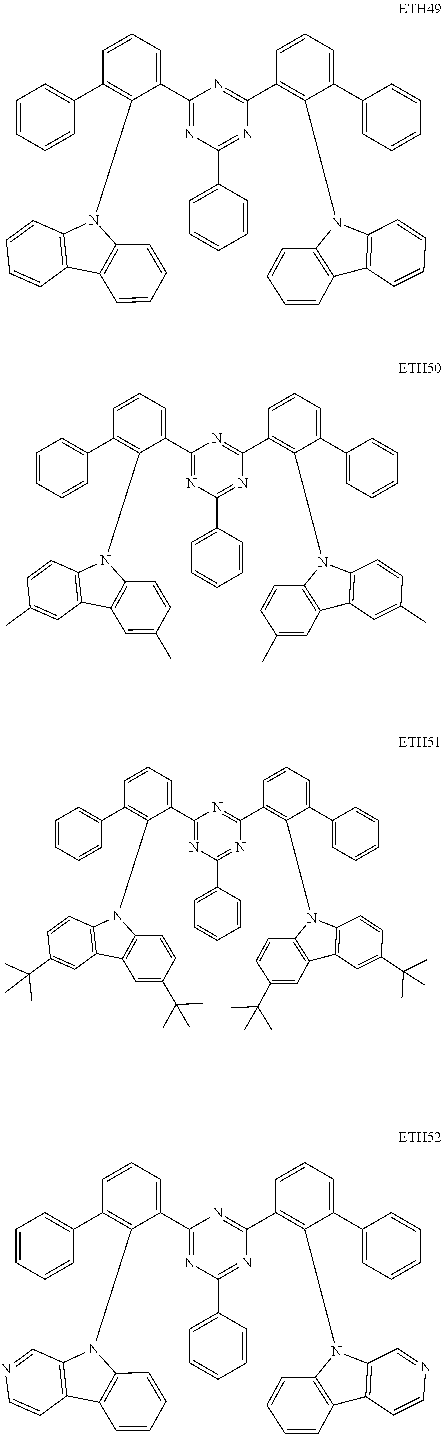

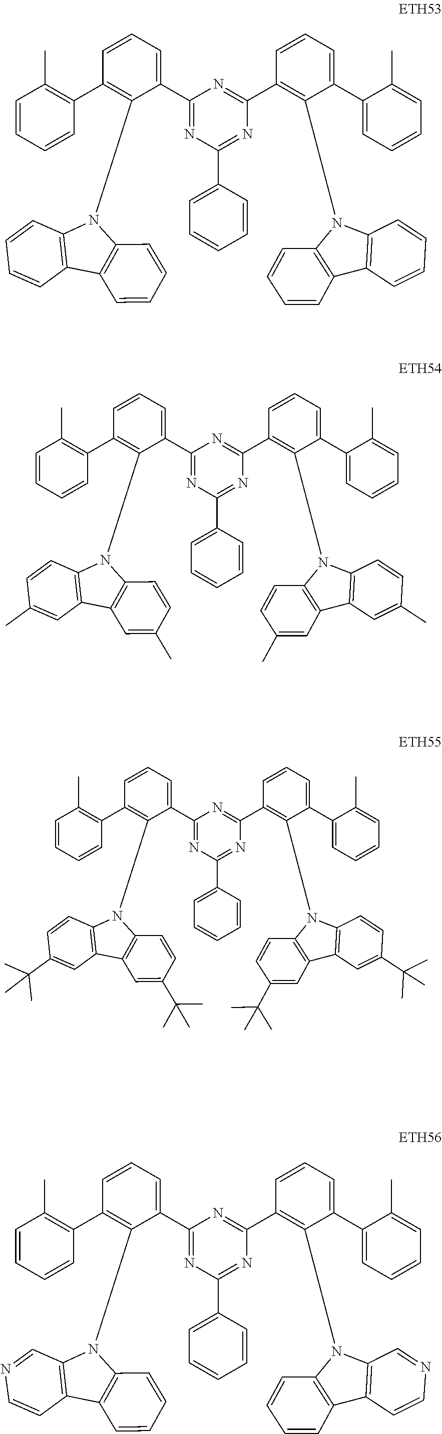

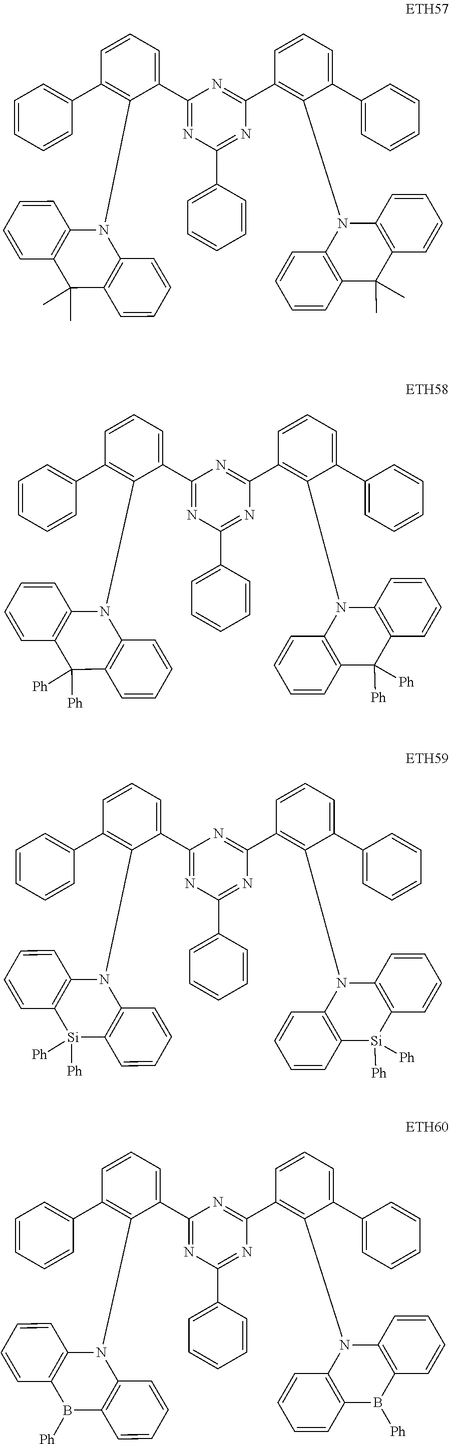

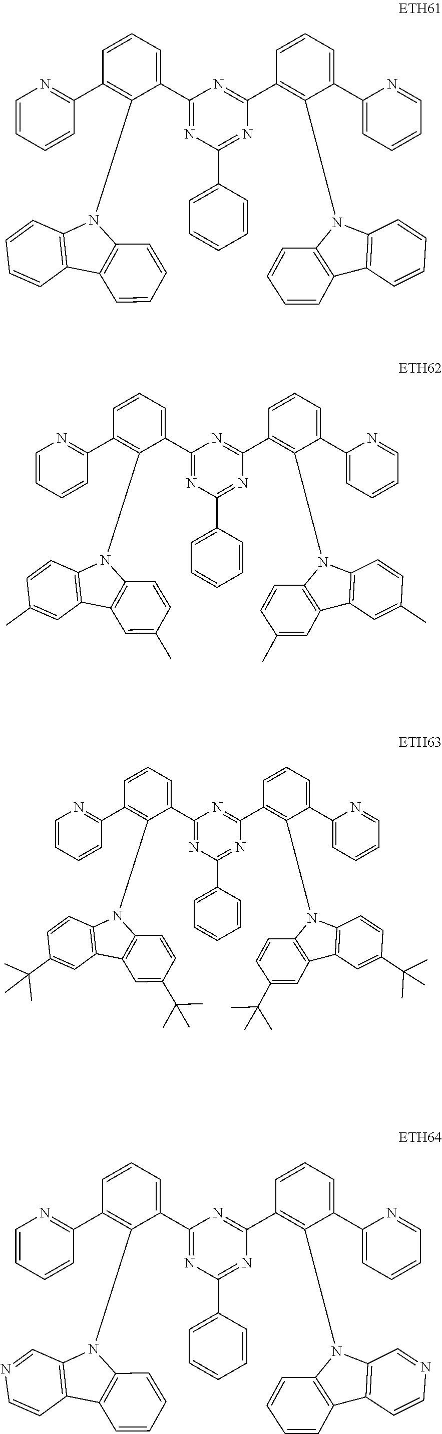

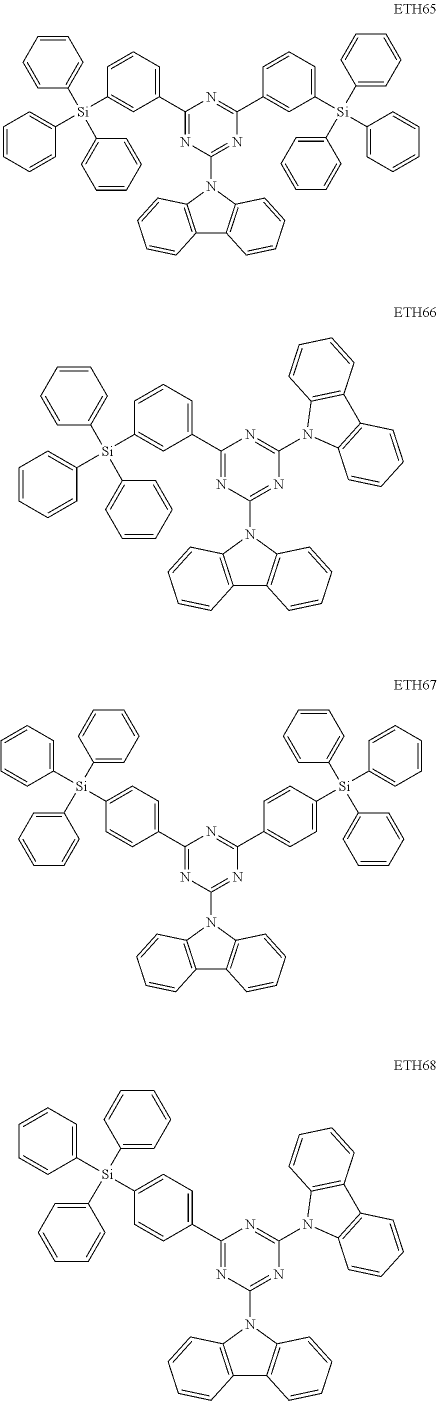 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

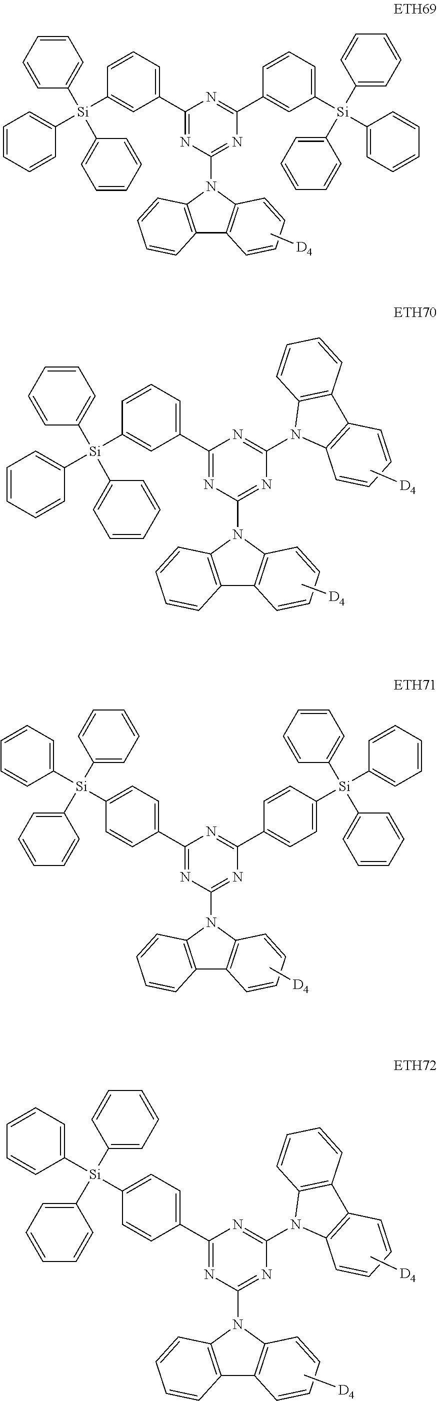

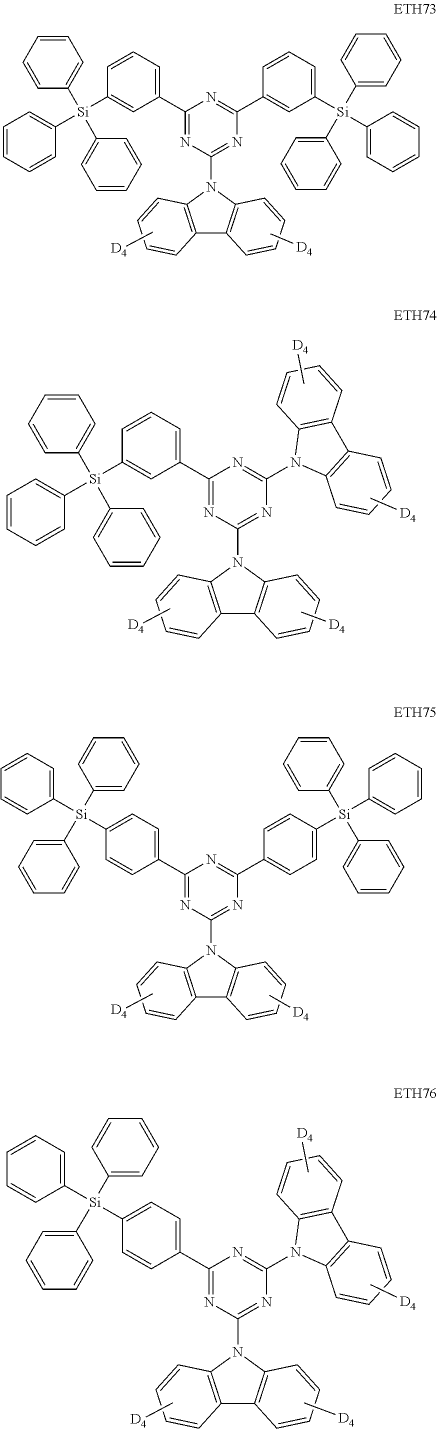

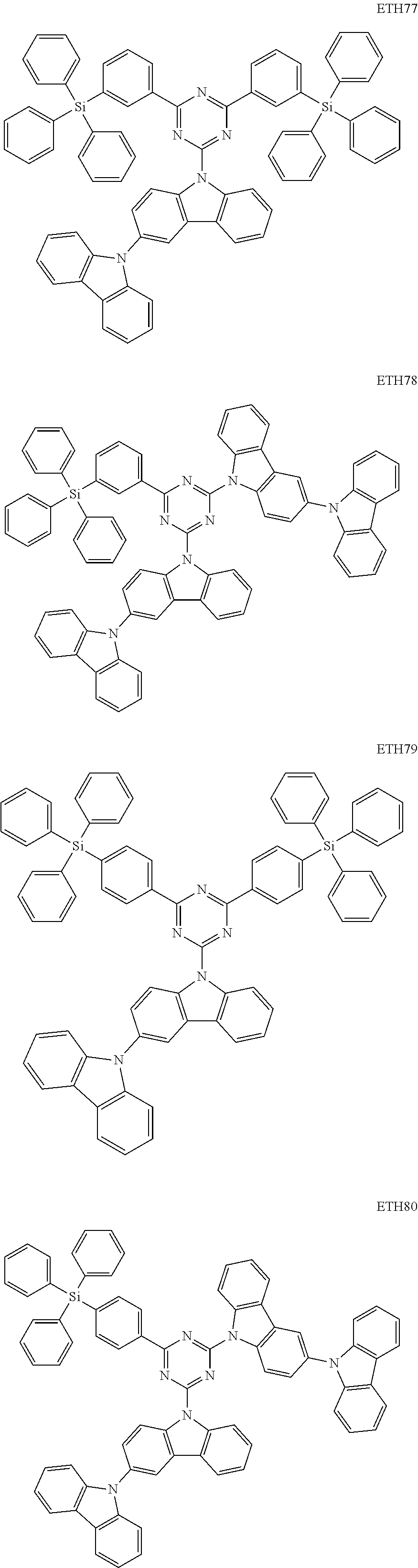

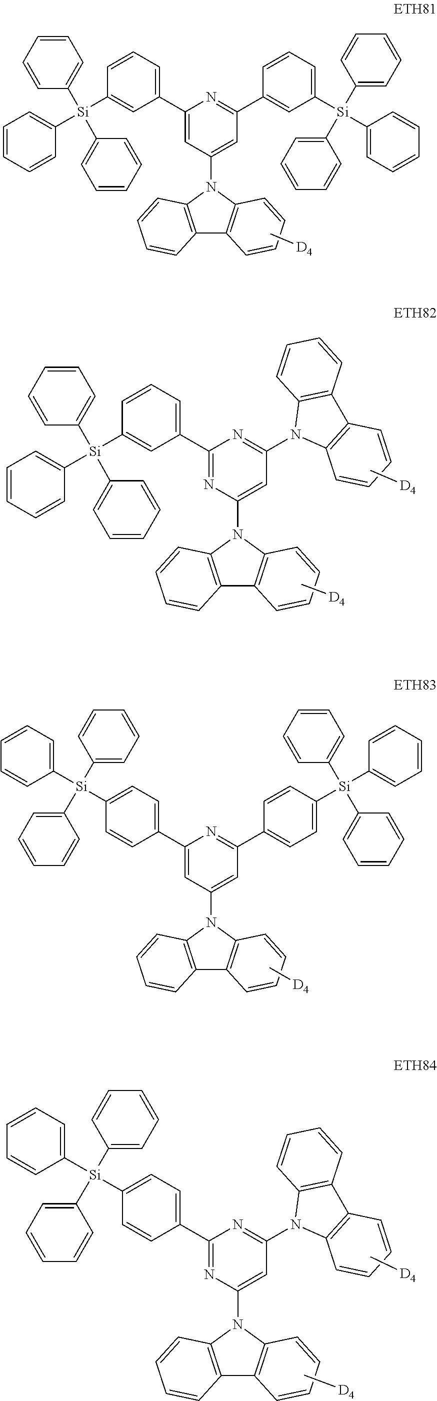

In embodiment compounds presented in Compound Group 3, “D” may mean a deuterium atom, and “Ph” may mean a substituted or unsubstituted phenyl group. For example, in embodiment compounds presented in Compound Group 2, “Ph” may mean an unsubstituted phenyl group.

In an embodiment, the fourth compound represented by Formula D-1 may represented at least one selected from among the compounds represented by Compound Group 4 below. The emission layer EML may include at least one selected from among the compounds represented by Compound Group 4 as a sensitizer material.

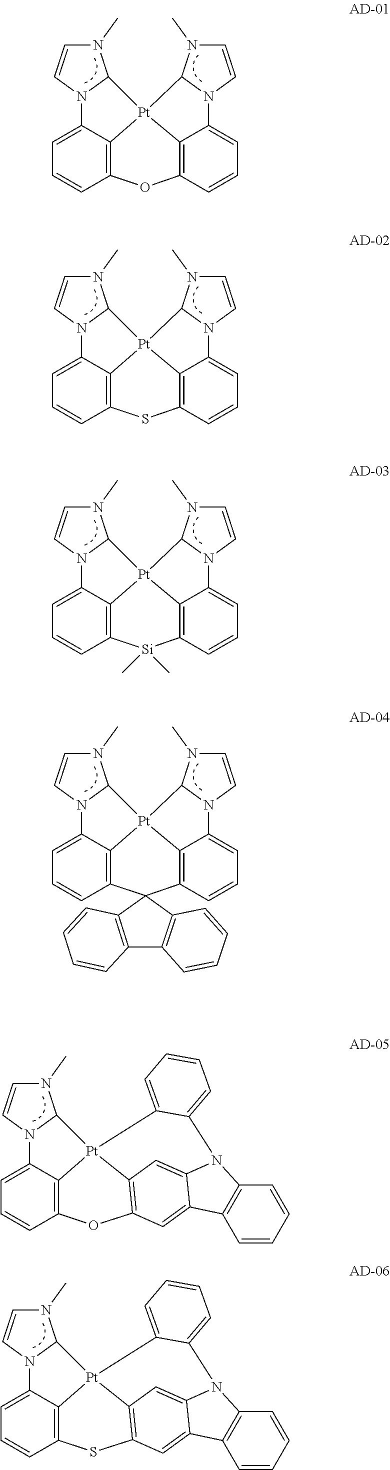

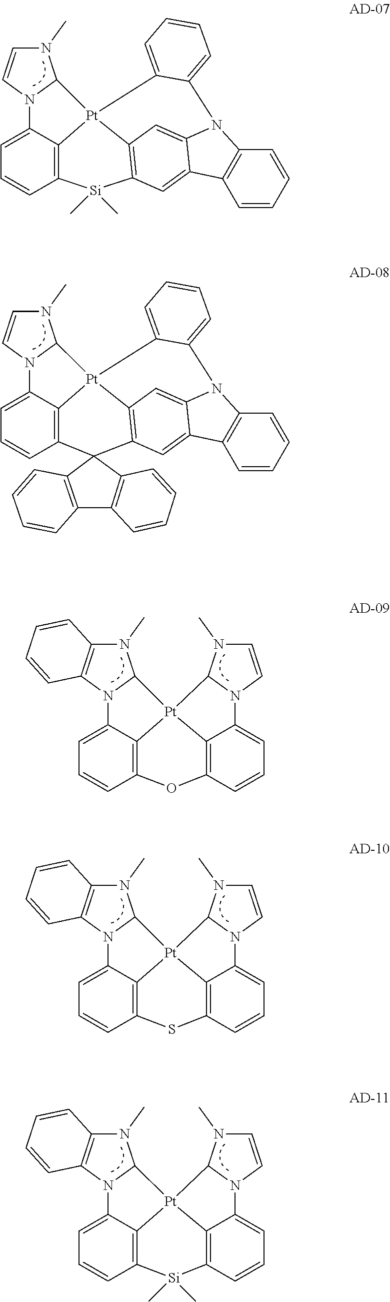

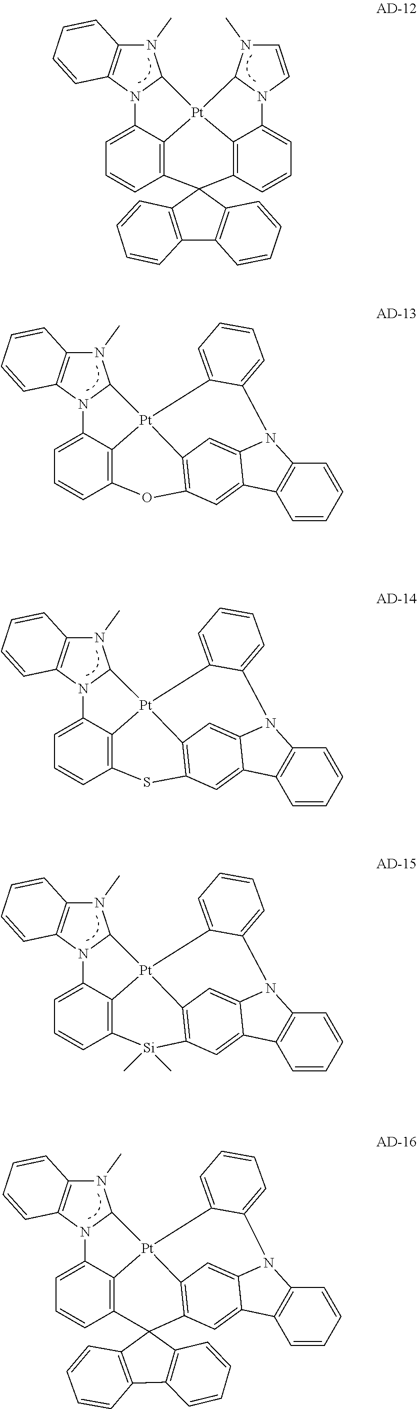

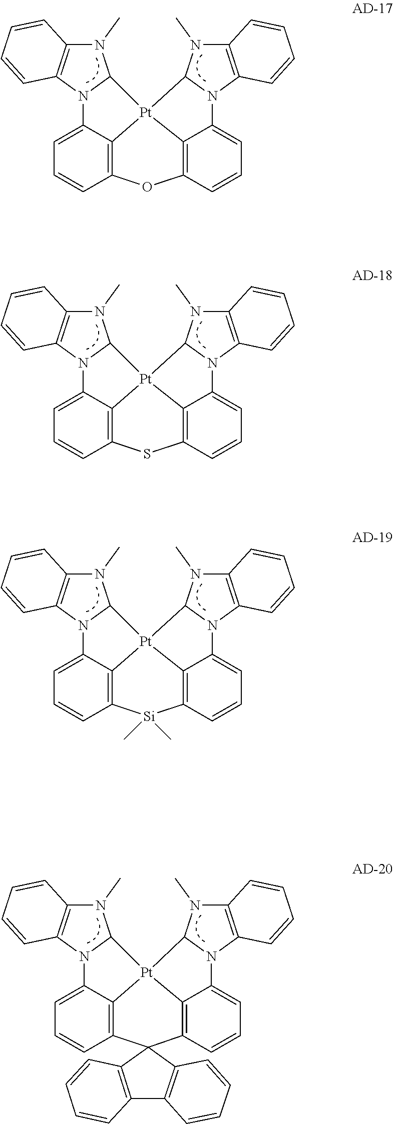

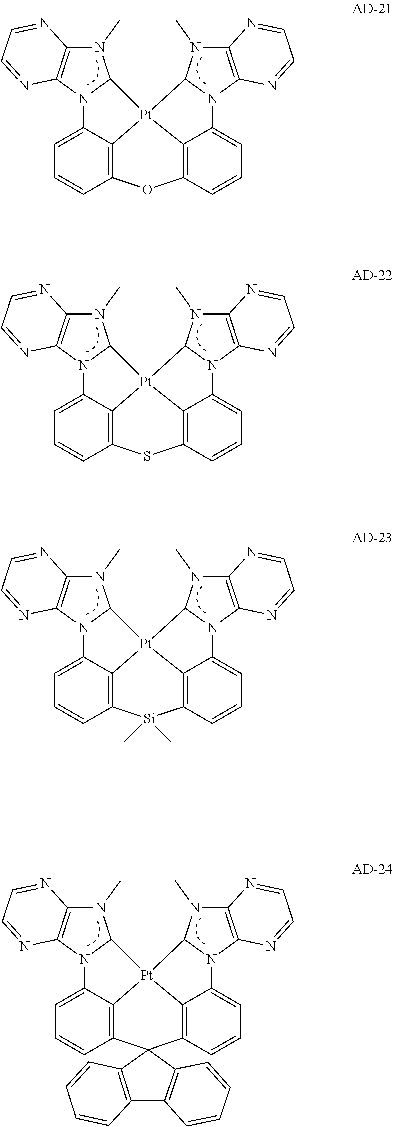

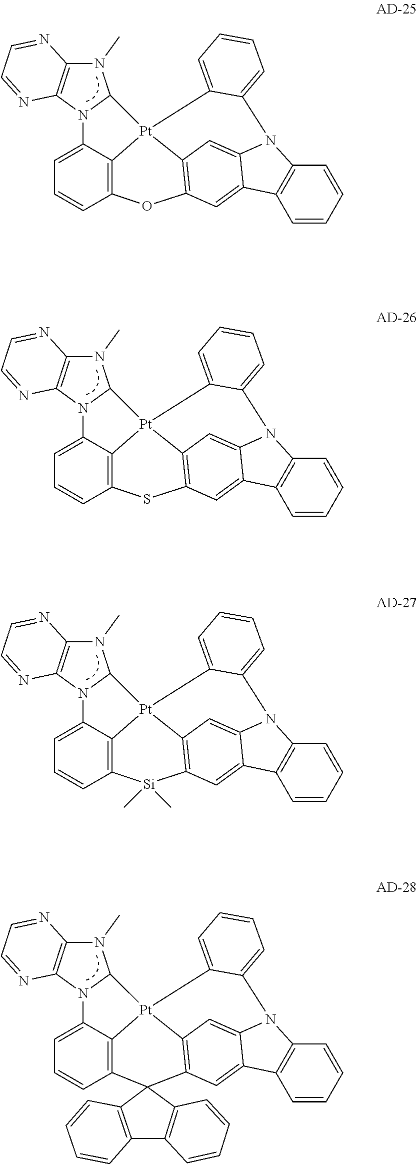

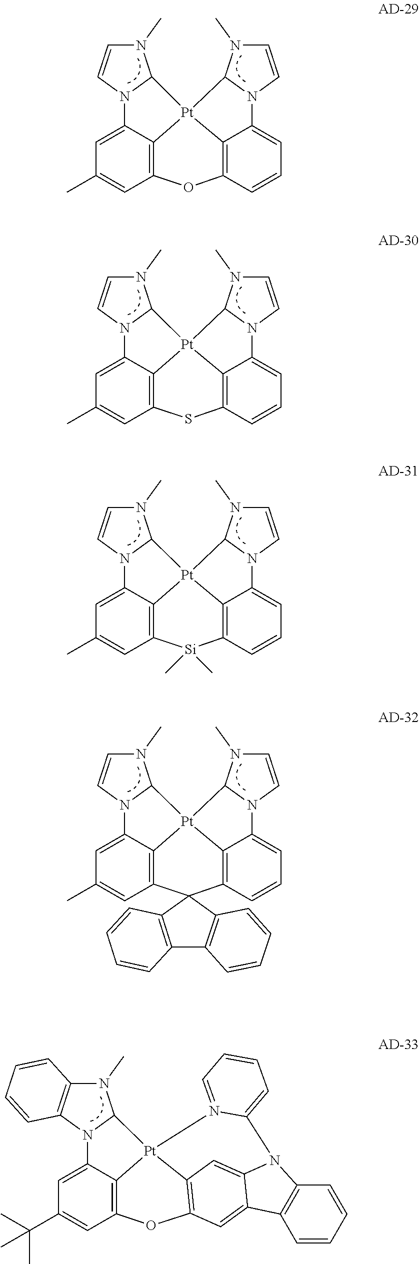

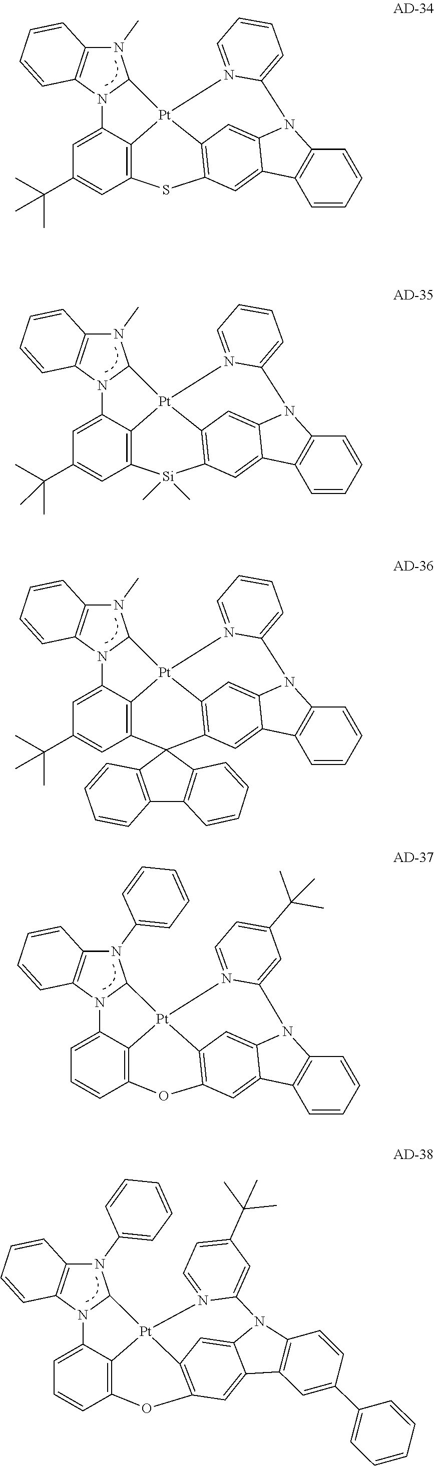

The light emitting device ED of an embodiment may include a plurality of emission layers. The plurality of emission layers may be sequentially stacked and provided, and for example, the light emitting device ED including the plurality of emission layers may emit white light. The light emitting device including the plurality of emission layers may be a light emitting device having a tandem structure. When the light emitting device ED includes a plurality of emission layers, at least one emission layer EML may include the first compound represented by Formula 1 of an embodiment. In addition, when the light emitting device ED includes the plurality of emission layers, at least one emission layer EML may include all of the first compound, the second compound, the third compound, and the fourth compound as described above.

When the emission layer EML in the light emitting device ED of an embodiment includes all of the first compound, the second compound, and the third compound, with respect to the total weight (100 wt %) of the first compound, the second compound, and the third compound, the content of the first compound may be about 1 wt % to about 3 wt %. However, embodiments of the present disclosure are not limited thereto. When the content of the first compound satisfies the above-described proportion, the energy transfer from the second compound and the third compound to the first compound may increase, and thus the luminous efficiency and device service life may increase.

The contents of the second compound and the third compound in the emission layer EML may be the rest excluding the weight of the first compound. For example, the contents of the second compound and the third compound in the emission layer EML may be about 97 wt % to about 99 wt % with respect to the total weight (100 wt %) of the first compound, the second compound, and the third compound.

In the total weight of the second compound and the third compound, the weight ratio of the second compound and the third compound may be about 4:6 to about 7:3. For example, the weight ratio of the second compound and the third compound may be about 5:5 to about 7:3. However, embodiments of the present disclosure are not limited thereto.

When the contents of the second compound and the third compound satisfy the above-described ratio, a charge balance characteristic in the emission layer EML are improved, and thus, the luminous efficiency and device service life may increase. When the contents of the second compound and the third compound deviate from the above-described ratio range, a charge balance in the emission layer EML is broken, and thus, the luminous efficiency may be reduced and the device may be easily deteriorated.

When the first compound, the second compound, and the third compound included in the emission layer EML satisfies the above-described ratio range, excellent luminous efficiency and long service life may be achieved.

In the light emitting device ED of an embodiment, the emission layer EML may include an anthracene derivative, a pyrene derivative, a fluoranthene derivative, a chrysene derivative, a dehydrobenzanthracene derivative, or a triphenylene derivative. In some embodiments, the emission layer EML may include the anthracene derivative or the pyrene derivative.

In each light emitting device ED of embodiments illustrated in FIGS. 3 to 6, the emission layer EML may further include any suitable host and dopant generally used in the art besides the above-described host and dopant, and for example, the emission layer EML may include a compound represented by Formula E-1 below. The compound represented by Formula E-1 below may be used as a fluorescent host material.

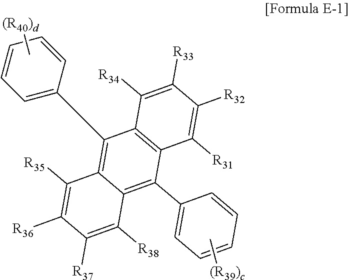

In Formula E-1, R₃₁ to R₄₀ may be each independently a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In some embodiments, R₃₁ to R₄₀ may be bonded to an adjacent group to form a saturated hydrocarbon ring or an unsaturated hydrocarbon ring, a saturated heterocycle, or an unsaturated heterocycle.

In Formula E-1, c and d may be each independently an integer of 0 to 5.

Formula E-1 may be represented by any one selected from among Compound E1 to Compound E19 below:

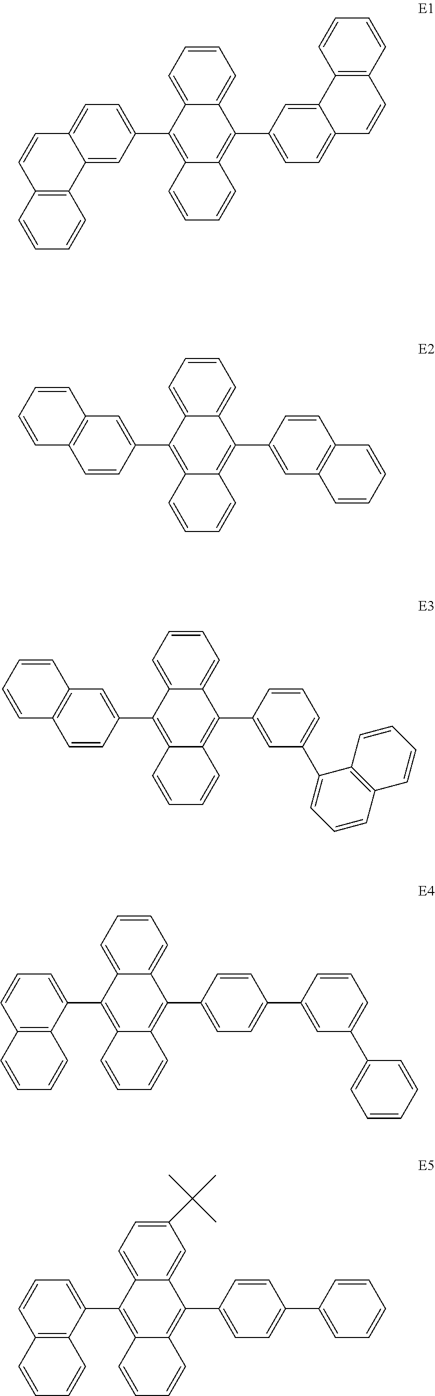

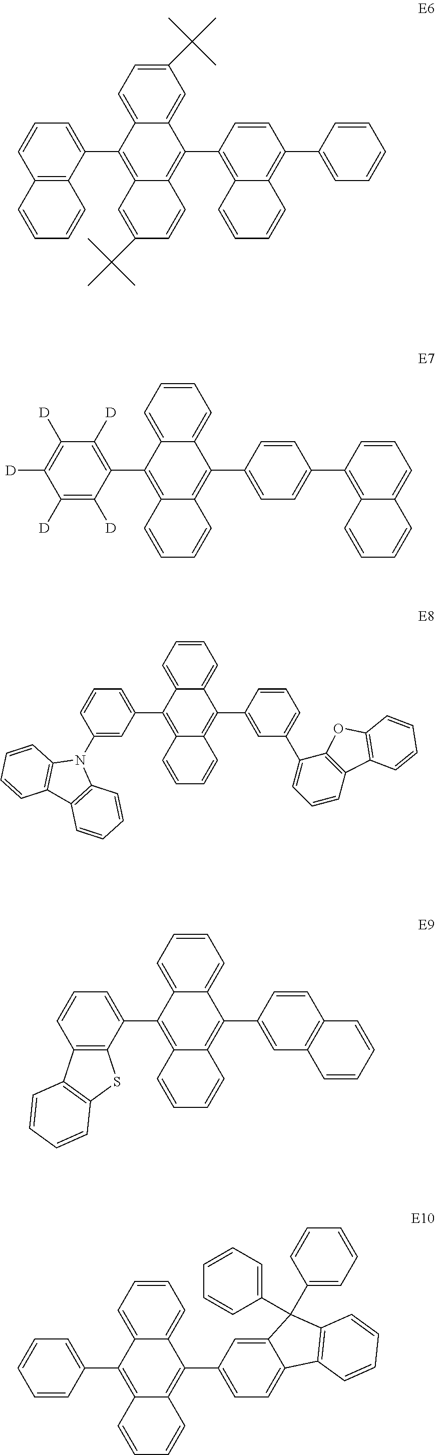

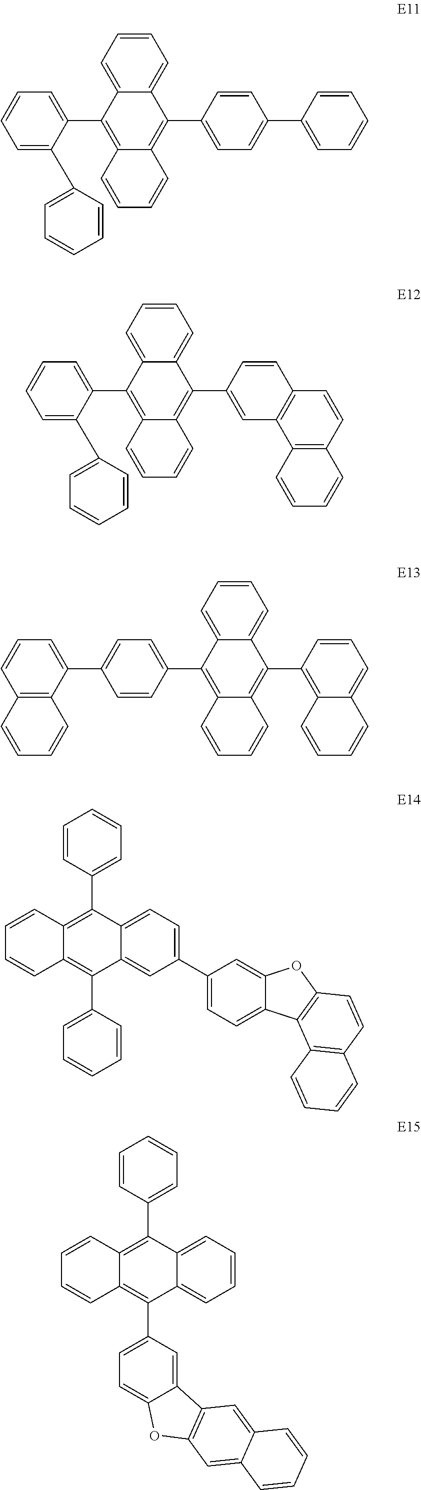

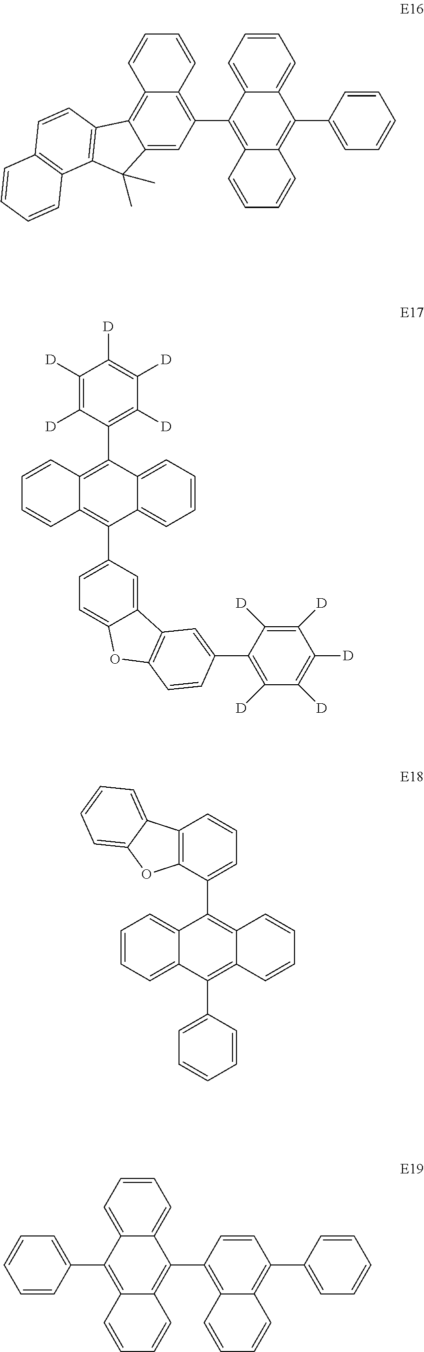

In an embodiment, the emission layer EML may include a compound represented by Formula E-2a or Formula E-2b below. The compound represented by Formula E-2a or Formula E-2b below may be used as a phosphorescent host material.

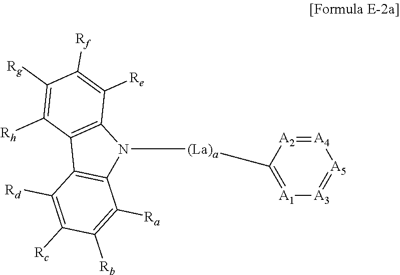

In Formula E-2a, and a may be an integer of 0 to 10, La may be a direct linkage, a substituted or unsubstituted arylene group having 6 to 30 ring-forming carbon atoms, or a substituted or unsubstituted heteroarylene group having 2 to 30 ring-forming carbon atoms. When a is an integer of 2 or more, a plurality of Lₐ′s may be each independently a substituted or unsubstituted arylene group having 6 to 30 ring-forming carbon atoms, or a substituted or unsubstituted heteroarylene group having 2 to 30 ring-forming carbon atoms.

In addition, in Formula E-2a, A₁ to A₅ may be each independently N or CRᵢ. Rₐ to Rᵢ may be each independently a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. Rₐ to Rᵢ may be bonded to an adjacent group to form a hydrocarbon ring or a heterocycle containing N, O, S, etc. as a ring-forming atom.

In some embodiments, in Formula E-2a, two or three selected from among A₁ to A₅ may be N, and the rest may be CRᵢ.

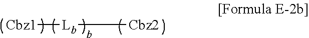

In Formula E-2b, Cbz1 and Cbz2 may be each independently an unsubstituted carbazole group, or a carbazole group substituted with an aryl group having 6 to 30 ring-forming carbon atoms. L_{b} is a direct linkage, a substituted or unsubstituted arylene group having 6 to 30 ring-forming carbon atoms, or a substituted or unsubstituted heteroarylene group having 2 to 30 ring-forming carbon atoms. In some embodiments, b is an integer of 0 to 10, and when b is an integer of 2 or more, a plurality of L_{b}′s may be each independently a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one selected from among the compounds of Compound Group E-2 below. However, the compounds listed in Compound Group E-2 below are examples, and the compound represented by Formula E-2a or Formula E-2b is not limited to those represented in Compound Group E-2 below.

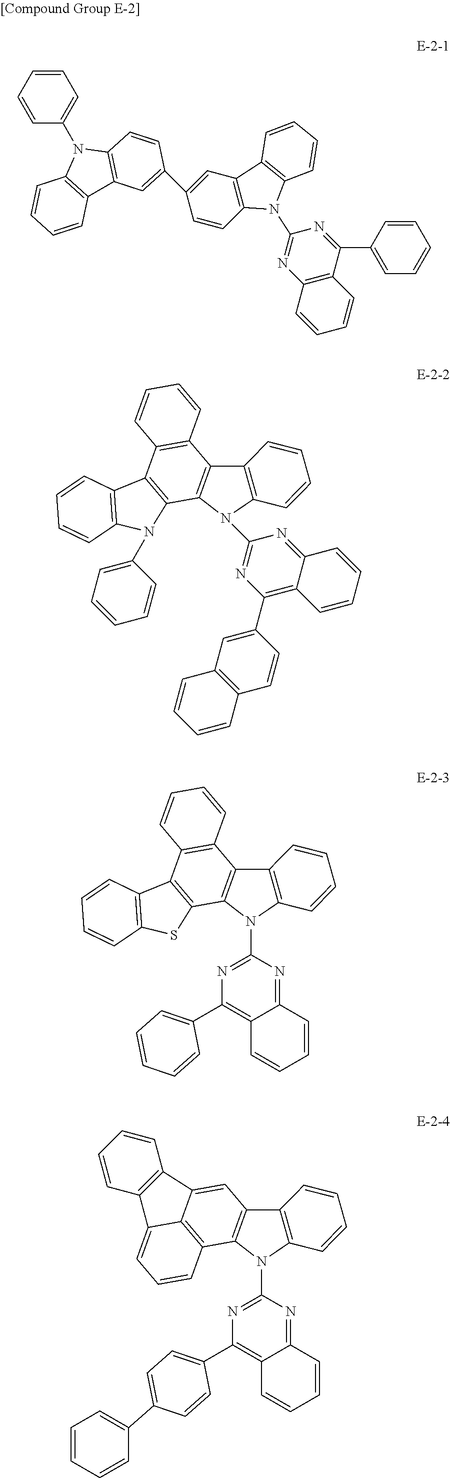 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1 ; c1ccc(-c2ccc(-c3nc(-n4c5ccccc5c5cc6c7c(cccc7c54)-c4ccccc4-6)nc4ccccc34)cc2)cc1]

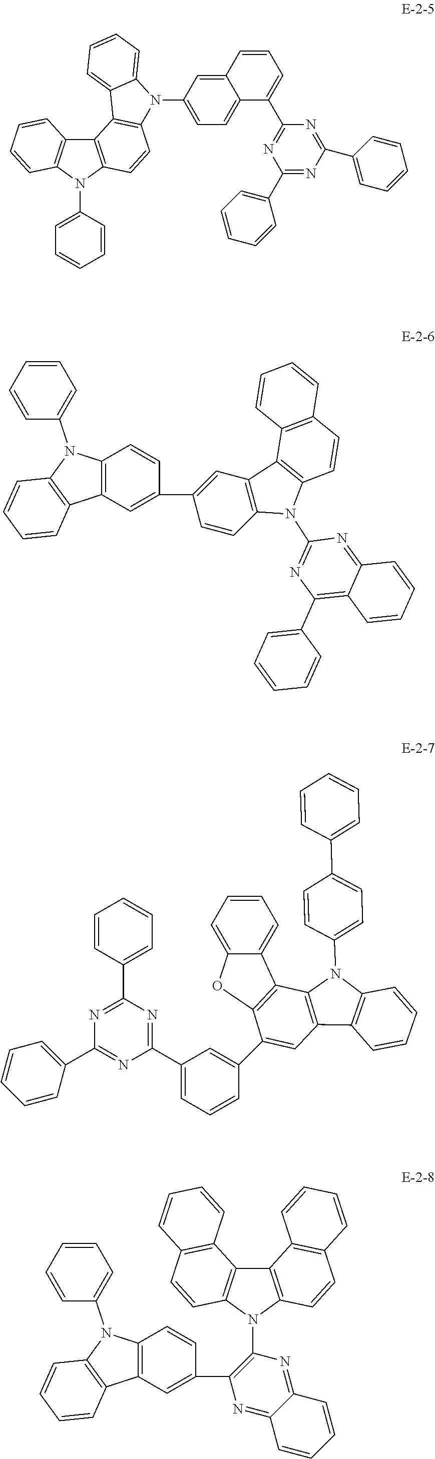 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3cc(-c4nc5ccccc5nc4-n4c5ccc6ccccc6c5c5c6ccccc6ccc54)ccc32)cc1]

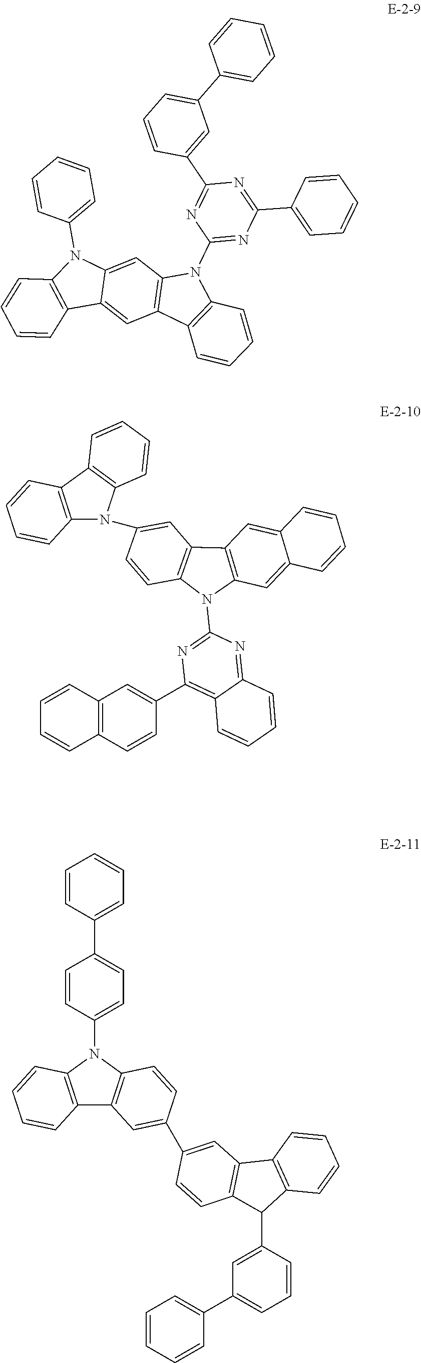 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)-c5ccccc5C6c5cccc(-c6ccccc6)c5)ccc43)cc2)cc1]

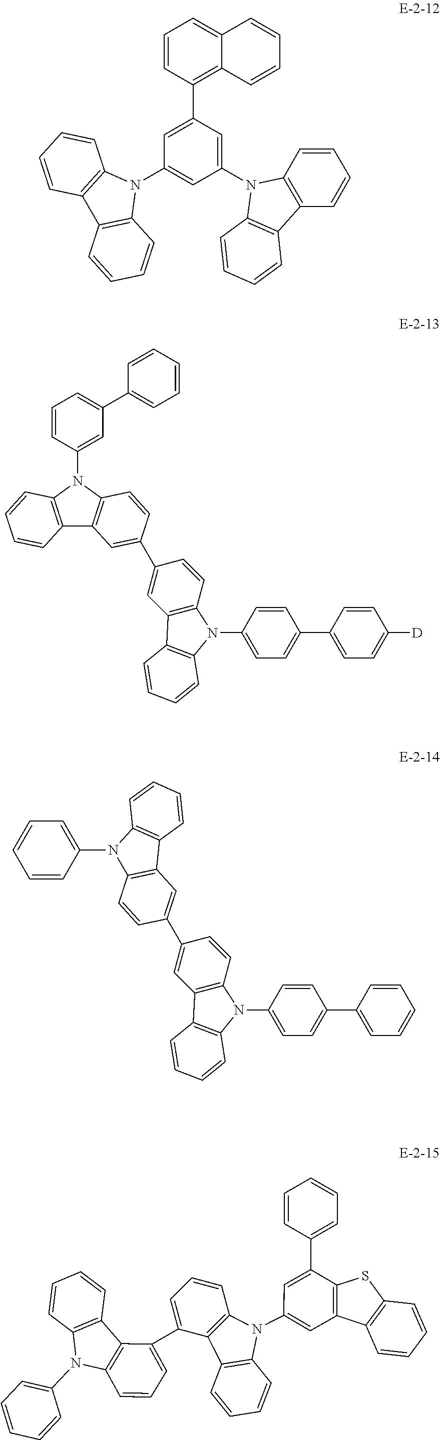 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

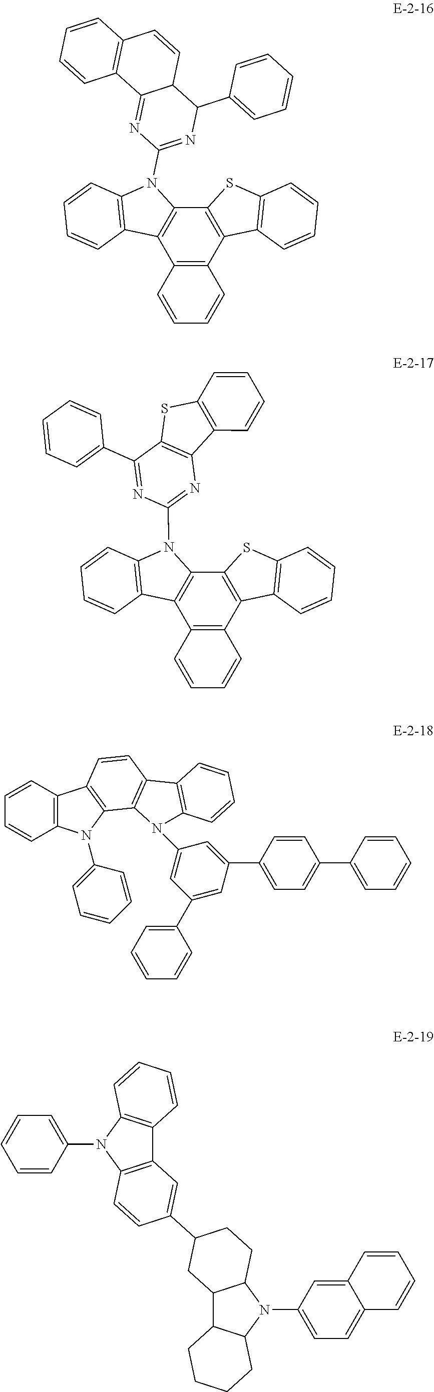 [SMILES: C1=CC2C(=NC(n3c4ccccc4c4c5ccccc5c5c6ccccc6sc5c43)=NC2c2ccccc2)c2ccccc21 ; c1ccc(-c2nc(-n3c4ccccc4c4c5ccccc5c5c6ccccc6sc5c43)nc3c2sc2ccccc23)cc1 ; c1ccc(-c2ccc(-c3cc(-c4ccccc4)cc(-n4c5ccccc5c5ccc6c7ccccc7n(-c7ccccc7)c6c54)c3)cc2)cc1 ; c1ccc(-n2c3ccccc3c3cc(C4CCC5C(C4)C4CCCCC4N5c4ccc5ccccc5c4)ccc32)cc1]

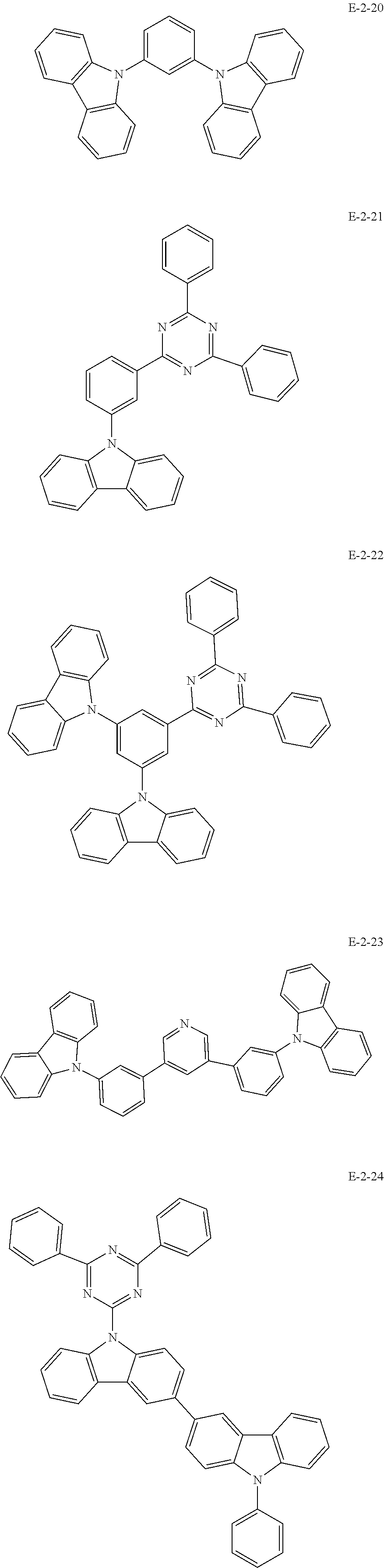 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may further include any suitable material generally used in the art as a host material. In some embodiments, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, embodiments of the present disclosure are not limited thereto, for example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA′, 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as a host material.

The emission layer EML may include the compound represented by Formula M-a below. The compound represented by Formula M-a below may be used as a phosphorescent dopant material.

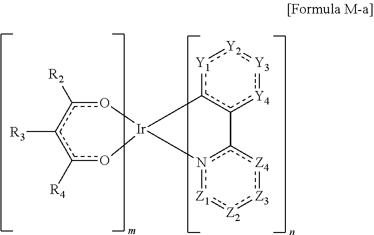

In Formula M-a above, Y₁ to Y₄ and Z₁ to Z₄ may be each independently CR₁ or N, R₁ to R₄ may be each independently a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. In Formula M-a, m is 0 or 1, and n is 2 or 3. In Formula M-a, when m is 0, n is 3, and when m is 1, n is 2.

The compound represented by Formula M-a may be used as a phosphorescent dopant.

The compound represented by Formula M-a may be represented by any one selected from among Compound M-a1 to Compound M-a25 below. However, Compounds M-a1 to M-a25 below are examples, and the compound represented by Formula M-a is not limited to those represented by Compounds M-a1 to M-a25 below.

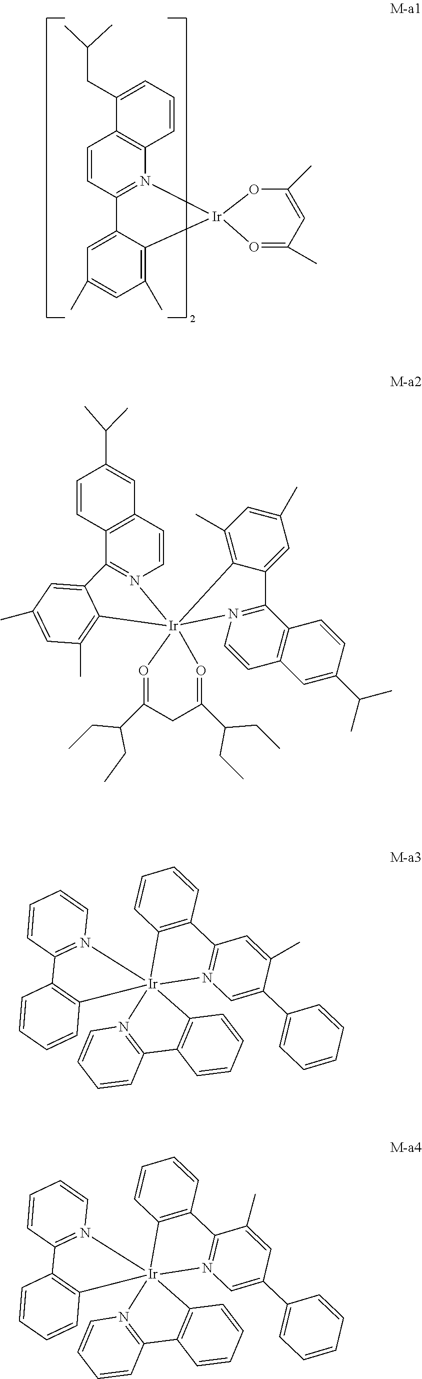

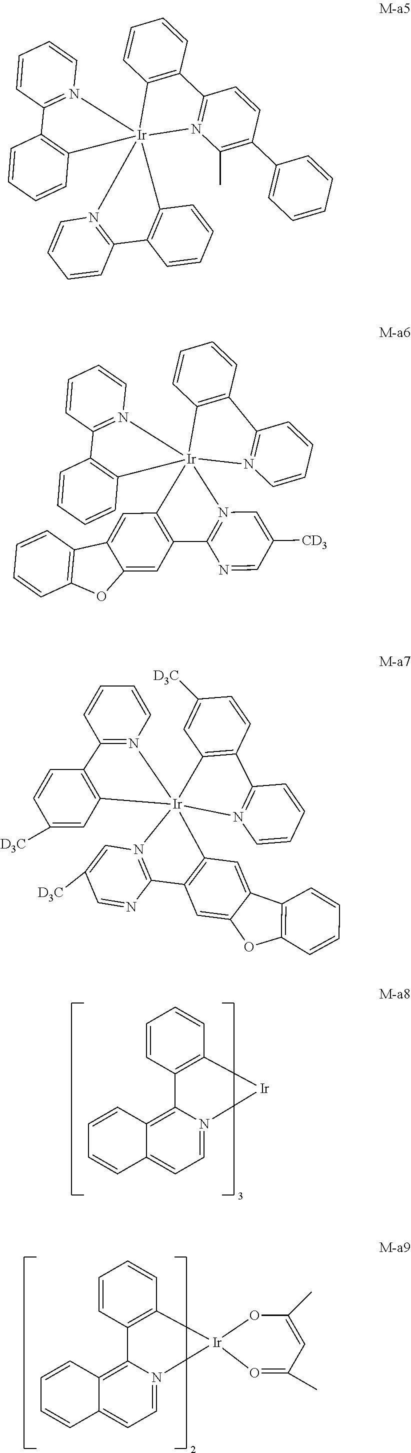

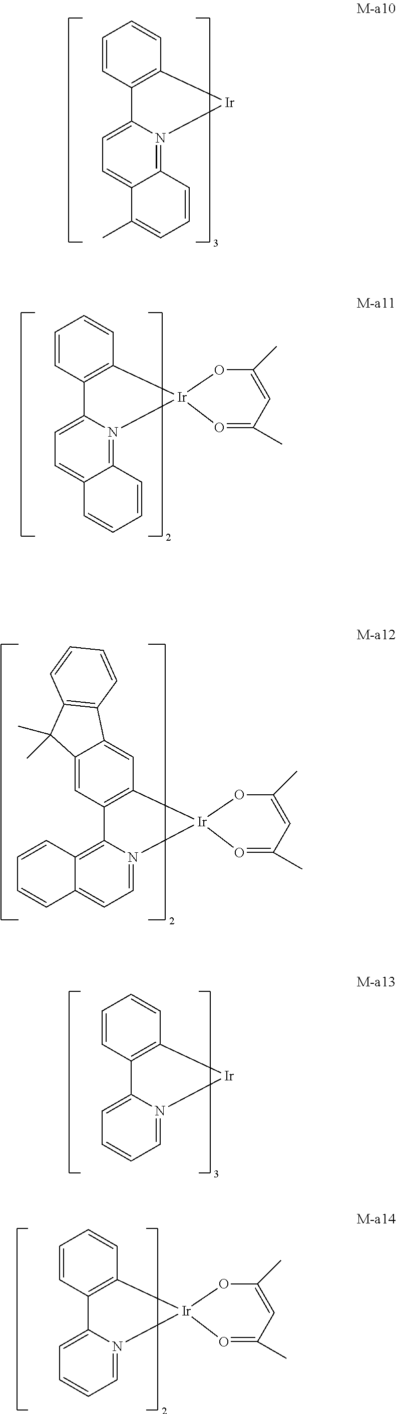

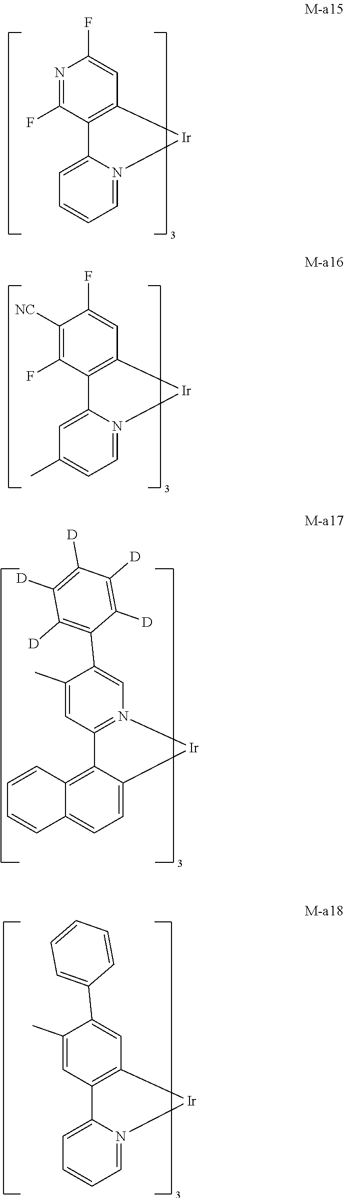

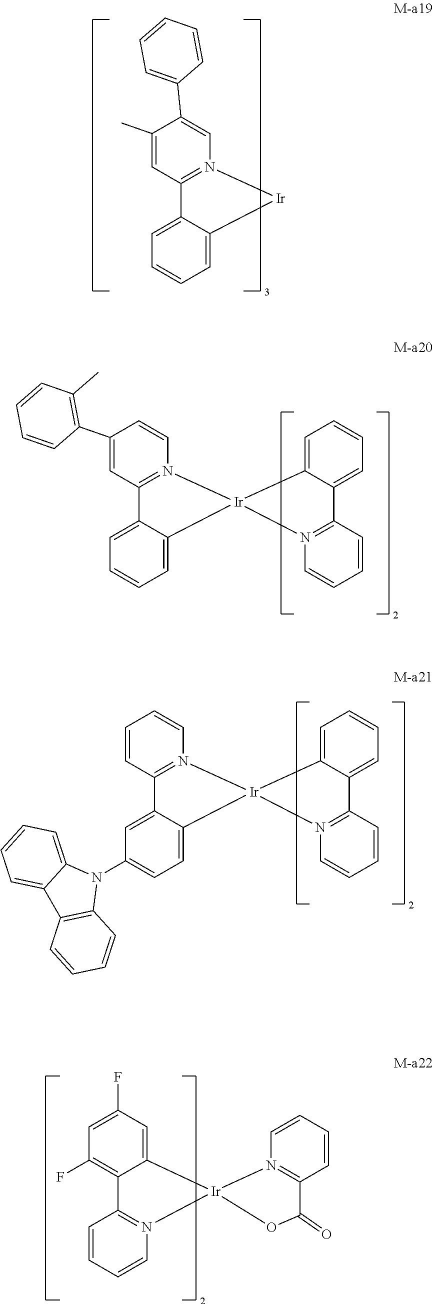

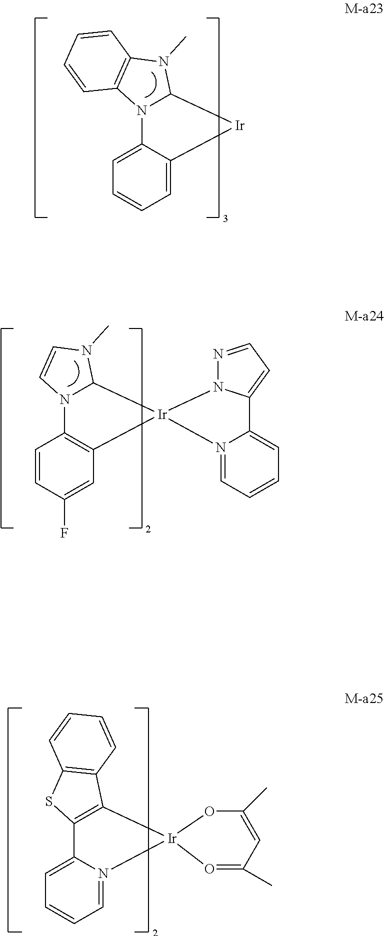

The emission layer EML may include a compound represented by any one selected from among Formula F-a to Formula F-c below. The compound represented by Formula F-a or Formula F-c below may be used as a fluorescence dopant material.

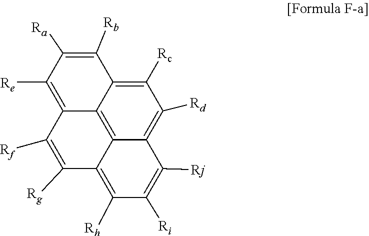

In Formula F-a above, two selected from among Rₐ to Rⱼ may each independently be substituted with *—NAr₁Ar₂. The others, which are not substituted with *—NAr₁Ar₂, among Rₐ to Rⱼ may be each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In *—NAr₁Ar₂, Ar₁ and Ar₂ may be each independently a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

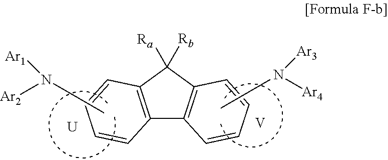

In Formula F-b above, Ra and Rb may be each independently a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring. Ar₁ to Ar₄ may be each independently a substituted or unsubstituted aryl group having 6 to 30 ring-forming carbon atoms, or a substituted or unsubstituted heteroaryl group having 2 to 30 ring-forming carbon atoms.

In Formula F-b, U and V may be each independently a substituted or unsubstituted hydrocarbon ring having 5 to 30 ring-forming carbon atoms, or a substituted or unsubstituted heterocycle having 2 to 30 ring-forming carbon atoms. At least one selected from among Ar₁ to Ar₄ may be a heteroaryl group containing O or S as a ring-forming atom.

In Formula F-b, the number of rings represented by U and V may be each independently 0 or 1. For example, in Formula F-b, it means that when the number of U or V is 1, one ring constitutes a fused ring at a portion indicated by U or V, and when the number of U or V is 0, a ring indicated by U or V does not exist. In some embodiments, when the number of U is 0 and the number of V is 1, or when the number of U is 1 and the number of V is 0, the fused ring having a fluorene core in Formula F-b may be a cyclic compound having four rings. In addition, when each number of U and V is 0, the fused ring in Formula F-b may be a cyclic compound having three rings. In addition, when each number of U and V is 1, the fused ring having a fluorene core in Formula F-b may be a cyclic compound having five rings.

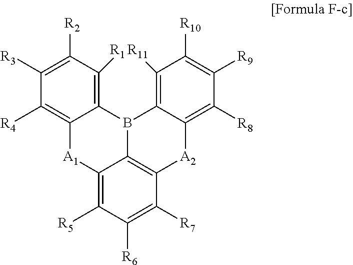

In Formula F-c, A₁ and A₂ may be each independently O, S, Se, or NRₘ, and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ are each independently a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring.

In Formula F-c, A₁ and A₂ may each independently be bonded to substituents of an adjacent ring to form a condensed ring. For example, when A₁ and A₂ are each independently NRₘ, A₁ may be bonded to R₄ or R₅ to form a ring. In addition, A₂ may be bonded to R₇ or R₈ to form a ring.

In an embodiment, the emission layer EML may further include any suitable dopant material generally used in the art. In some embodiments, the emission layer may further include styryl derivatives (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), 4,4′-bis[2-(4-(N,N-diphenylamino)phenyl)vinyl]biphenyl (DPAVBi), perylene and the derivatives thereof (e.g., 2,5,8,11-tetra-t-butylperylene (TBP)), pyrene and the derivatives thereof (e.g., 1,1-dipyrene, 1,4-dipyrenylbenzene, 1,4-bis(N,N-diphenylamino)pyrene), etc.

The emission layer EML may further include any suitable phosphorescence dopant material generally used in the art. In some embodiments, a metal complex containing iridium (Ir), platinum (Pt), osmium (Os), aurum (Au), titanium (Ti), zirconium (Zr), hafnium (Hf), europium (Eu), terbium (Tb), and thulium (Tm) may be used as a phosphorescent dopant. In some embodiments, iridium(III) bis(4,6-difluorophenylpyridinato-N,C2′)picolinate (Flrpic), bis(2,4-difluorophenylpyridinato)-tetrakis(1-pyrazolyl)borate iridium(III) (Fir6), or platinum octaethyl porphyrin (PtOEP) may be used as a phosphorescent dopant. However, embodiments of the present disclosure are not limited thereto.

The emission layer EML may include a quantum dot material. The core of the quantum dot may be selected from among a Group II-VI compound, a Group III-VI compound, a Group I-III-IV compound, a Group III-V compound, a Group III-II-V compound, a Group IV-VI compound, a Group IV element, a Group IV compound, and a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-VI compound may include a binary compound such as In₂S₃ and/or In₂Se₃, a ternary compound such as InGaS₃ and/or InGaSe₃, or any combination thereof.

The Group I-III-VI compound may be selected from a ternary compound selected from the group consisting of AgInS, AgInS₂, CuInS, CuInS₂, AgGaS₂, CuGaS₂ CuGaO₂, AgGaO₂, AgAlO₂, and a mixture thereof, and/or a quaternary compound such as AgInGaS₂ and/or CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. In some embodiments, the Group III-V compound may further include a Group II metal. For example, InZnP, etc. may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

In this case, a binary compound, a ternary compound, or a quaternary compound may be present in a particle with a uniform (e.g., substantially uniform) concentration distribution, or may be present in the same particle with a partially different concentration distribution. In addition, a core/shell structure in which one quantum dot surrounds another quantum dot may also be possible. The core/shell structure may have a concentration gradient in which the concentration of elements present in the shell decreases along a direction toward the core.

In some embodiments, the quantum dot may have the above-described core/shell structure including a core containing nanocrystals and a shell surrounding the core. The shell of the quantum dot may serve as a protection layer to prevent or reduce the chemical deformation of the core to maintain semiconductor properties, and/or a charging layer to impart electrophoresis properties to the quantum dot. The shell may be a single layer or a multilayer. An example of the shell of the quantum dot may include a metal and/or non-metal oxide, a semiconductor compound, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, and/or a ternary compound such as MgAlO₄, CoFe₂O₄, NiFe₂O₄, and/or CoMn₂O₄, but embodiments of the present disclosure are not limited thereto.

Also, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments of the present disclosure are not limited thereto.

The quantum dot may have a full width of half maximum (FWHM) of a light emitting wavelength spectrum of about 45 nm or less, for example, about 40 nm or less, or about 30 nm or less, and color purity and/or color reproducibility may be improved in the above range. In addition, light emitted through such a quantum dot is emitted in all directions (e.g., substantially all directions), and thus a wide viewing angle may be improved.

In addition, the form of the quantum dot is not particularly limited and may be any suitable form generally used in the art. In some embodiments, the quantum dot in the form of spherical, pyramidal, multi-arm, and/or cubic nanoparticles, nanotubes, nanowires, nanofibers, nanoplate particles, etc. may be used.

A quantum dot may control the color of emitted light according to the particle size thereof and thus the quantum dot may have various suitable light emission colors such as green, red, etc.

In each light emitting device ED of embodiments illustrated in FIGS. 3 to 6, the electron transport region ETR is provided on the emission layer EML. The electron transport region ETR may include at least one of the hole blocking layer HBL, the electron transport layer ETL, or the electron injection layer EIL, but embodiments of the present disclosure are not limited thereto.

The electron transport region ETR may have a single layer formed of a single material, a single layer formed of a plurality of different materials, or a multilayer structure including a plurality of layers formed of a plurality of different materials.

For example, the electron transport region ETR may have a single layer structure of the electron injection layer EIL or the electron transport layer ETL, and may have a single layer structure formed of an electron injection material and an electron transport material. In addition, the electron transport region ETR may have a single layer structure formed of a plurality of different materials, or may have a structure in which an electron transport layer ETL/electron injection layer EIL, a hole blocking layer HBL/electron transport layer ETL/electron injection layer EIL are stacked in order from the emission layer EML, but embodiments of the present disclosure are and not limited thereto. The electron transport region ETR may have a thickness, for example, from about 1,000 Å to about 1,500 Å.

The electron transport region ETR may be formed by using various suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-1 below:

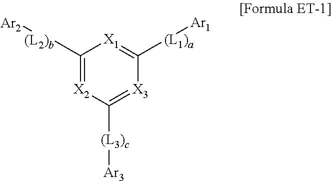

In Formula ET-1, at least one selected from among X₁ to X₃ is N, and the rest are CRₐ. Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may be each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may be each independently an integer of 0 to 10. In Formula ET-1, L₁ to L₃ may be each independently a direct linkage, a substituted or unsubstituted arylene group having 6 to 30 ring-forming carbon atoms, or a substituted or unsubstituted heteroarylene group having 2 to 30 ring-forming carbon atoms. When a to c are an integer of 2 or more, L₁ to L₃ may be each independently a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, embodiments of the present disclosure are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), berylliumbis(benzoquinolin-10-olate (Bebq₂), 9,10-di(naphthalene-2-yl)anthracene (ADN), 1,3-Bis[3,5-di(pyridin-3-yl)phenyl]benzene (BmPyPhB), or a mixture thereof.

The electron transport region ETR may include at least one selected from among Compound ET1 to Compound ET36 below:

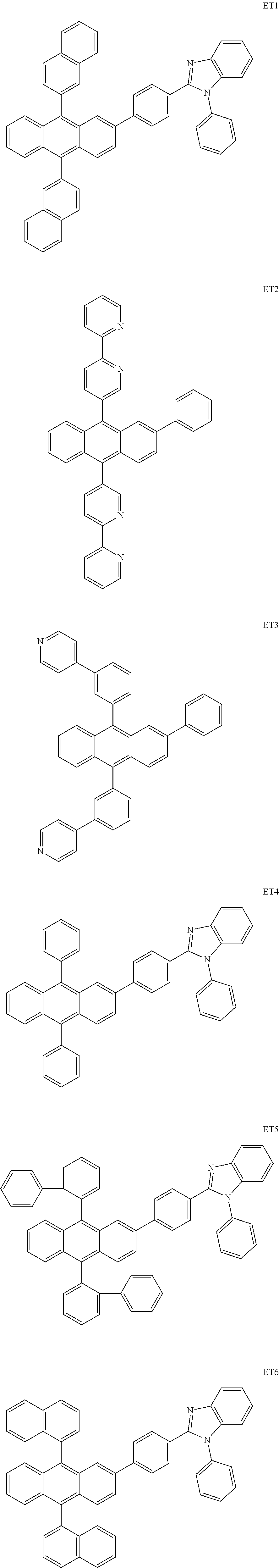

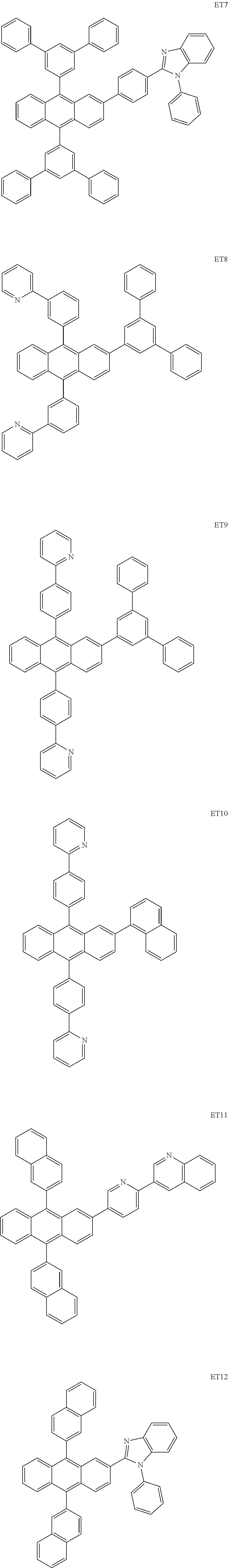

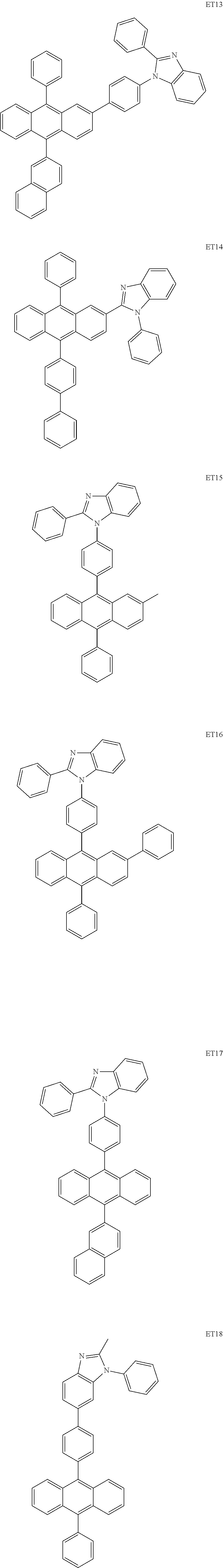 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

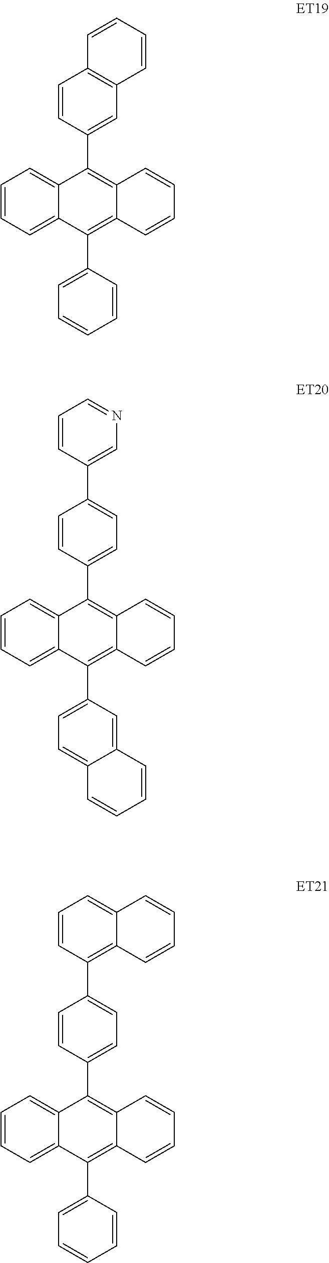

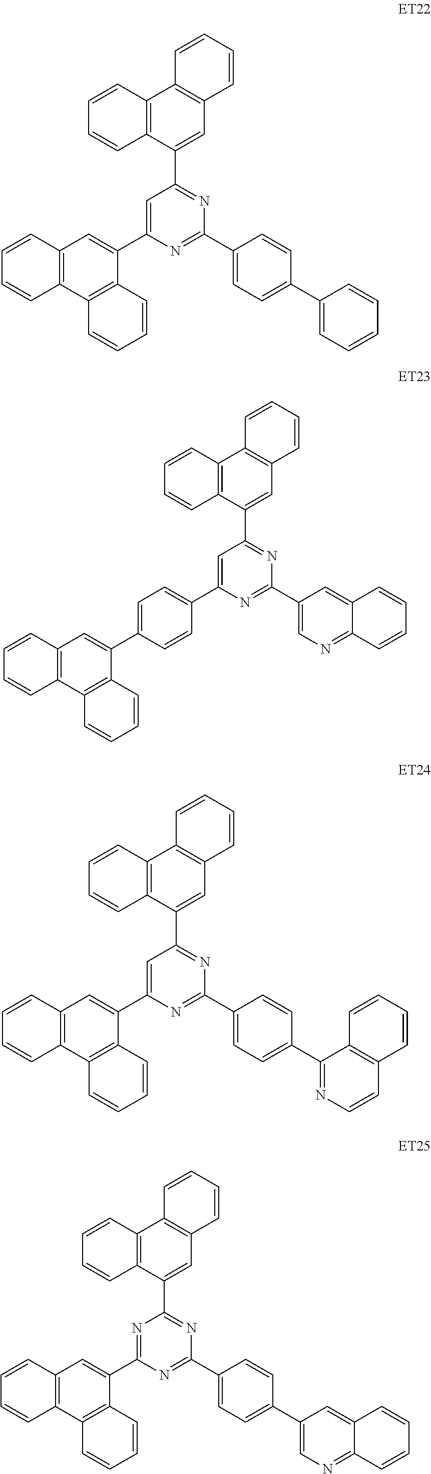 [SMILES: c1ccc(-c2ccc(-c3nc(-c4cc5ccccc5c5ccccc45)cc(-c4cc5ccccc5c5ccccc45)n3)cc2)cc1 ; c1ccc2ncc(-c3nc(-c4ccc(-c5cc6ccccc6c6ccccc56)cc4)cc(-c4cc5ccccc5c5ccccc45)n3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1]

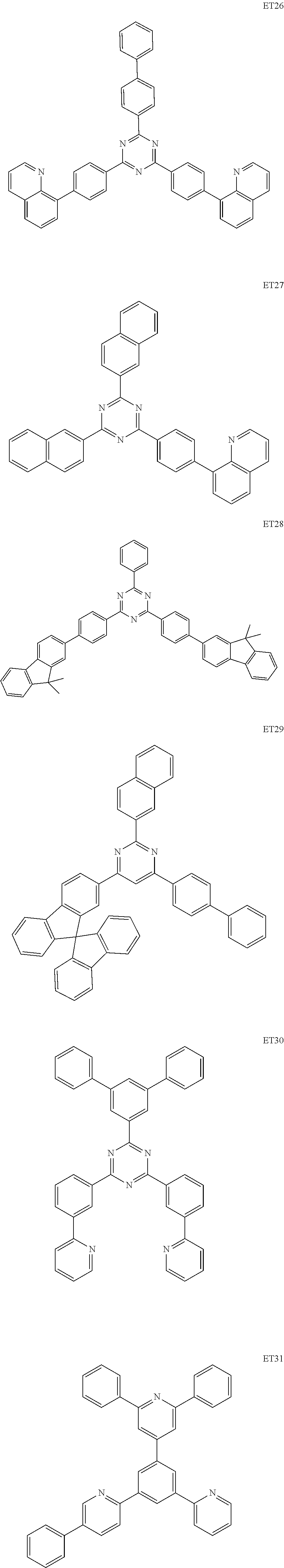

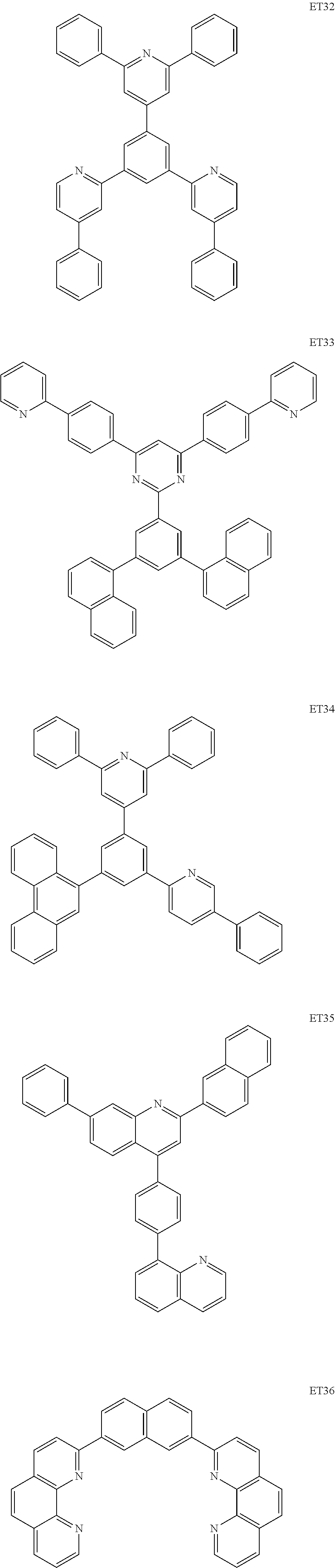 [SMILES: c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1 ; c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In addition, the electron transport regions ETR may include a metal halide such as LiF, NaCl, CsF, RbCl, RbI, CuI, and/or KI, a lanthanide metal such as Yb, and/or a co-deposited material of the metal halide and the lanthanide metal. For example, the electron transport region ETR may include KI:Yb, RbI:Yb, LiF:Yb, etc. as a co-deposited material. In some embodiments, the electron transport region ETR may be formed using a metal oxide such as Li₂O and/or BaO, and/or 8-hydroxyl-lithium quinolate (Liq), etc., but embodiments of the present disclosure are not limited thereto. The electron transport region ETR may also be formed of a mixture material of an electron transport material and an insulating organometallic salt. The organometallic salt may be a material having an energy band gap of about 4 eV or more. In some embodiments, the organometallic salt may include, for example, a metal acetate, a metal benzoate, a metal acetoacetate, a metal acetylacetonate, and/or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the above-described materials, but embodiments of the present disclosure are not limited thereto.

The electron transport region ETR may include the above-described compounds of the hole transport region in at least one of the electron injection layer EIL, the electron transport layer ETL, or the hole blocking layer HBL.

When the electron transport region ETR includes the electron transport layer ETL, the electron transport layer ETL may have a thickness of about 100 Å to about 1,000 Å, for example, about 150 Å to about 500 Å. If the thickness of the electron transport layer ETL satisfies the aforementioned range, suitable or satisfactory electron transport characteristics may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. If the thickness of the electron injection layer EIL satisfies the above-described range, suitable or satisfactory electron injection characteristics may be obtained without a substantial increase in driving voltage.

The second electrode EL2 is provided on the electron transport region ETR. The second electrode EL2 may be a common electrode. The second electrode EL2 may be a cathode or an anode, but embodiments of the present disclosure are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is the transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, and/or a compound or mixture thereof (e.g., AgMg, AgYb, or MgAg). In some embodiments, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of at least two metal materials of the above-described metal materials, oxides of the above-described metal materials, and/or the like.

In some embodiments, the second electrode EL2 may be connected with an auxiliary electrode. If the second electrode EL2 is connected with the auxiliary electrode, the resistance of the second electrode EL2 may be decreased.

A capping layer CPL may further be on the second electrode EL2 of the light emitting device ED of an embodiment. The capping layer CPL may include a multilayer or a single layer.

In an embodiment, the capping layer CPL may be an organic layer and/or an inorganic layer. For example, when the capping layer CPL contains an inorganic material, the inorganic material may include an alkaline metal compound (for example, LiF), an alkaline earth metal compound (for example, MgF₂), SiON, SiNₓ, SiOy, etc.

For example, when the capping layer CPL contains an organic material, the organic material may include 2,2′-dimethyl-N,N′-di-[(1-naphthyl)-N,N′-diphenyl]-1,1′-biphenyl-4,4′-diamine(a-NPD), NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., and/or may include an epoxy resin, and/or an acrylate such as a methacrylate. However, embodiments of the present disclosure are not limited thereto, and the capping layer CPL may include at least one selected from among Compounds P1 to P5 below:

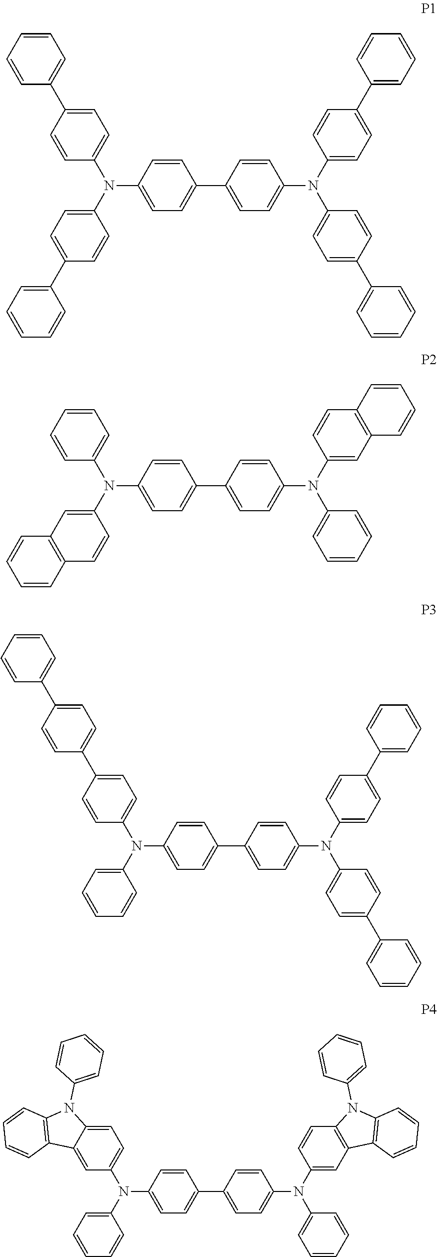 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

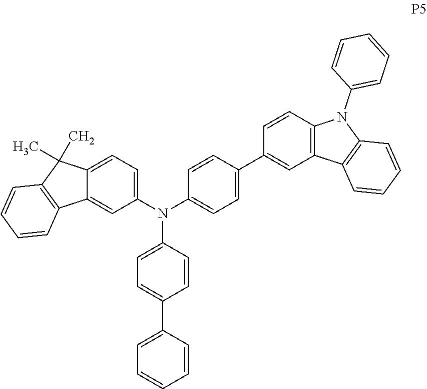 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

The refractive index of the capping layer CPL may be about 1.6 or more. In some embodiments, the refractive index of the capping layer CPL may be about 1.6 or more with respect to light in a wavelength range of about 550 nm to about 660 nm.

Each of FIGS. 7 and 8 is a cross-sectional view of a display apparatus according to an embodiment of the present disclosure. Hereinafter, in describing the display apparatuses of embodiments with reference to FIGS. 7 and 8, the duplicated features which have been described with respect to FIGS. 1 to 6 are not described again here, but their differences will be mainly described.

Referring to FIG. 7, the display apparatus DD according to an embodiment may include a display panel DP including a display device layer DP-ED, a light control layer CCL on the display panel DP, and a color filter layer CFL.

In an embodiment illustrated in FIG. 7, the display panel DP may include a base layer BS, a circuit layer DP-CL provided on the base layer BS, and the display device layer DP-ED, and the display device layer DP-ED may include a light emitting device ED.

The light emitting device ED may include a first electrode EL1, a hole transport region HTR on the first electrode EL1, an emission layer EML on the hole transport region HTR, an electron transport region ETR on the emission layer EML, and a second electrode EL2 on the electron transport region ETR. The structures of the light emitting devices of FIGS. 3 to 6 as described above may be equally applied to the structure of the light emitting device ED illustrated in FIG. 7.

The emission layer EML of the light emitting device ED included in the display apparatus DD-a according to an embodiment may include the above-described fused polycyclic compound of an embodiment.

Referring to FIG. 7, the emission layer EML may be in an opening OH defined in a pixel defining film PDL. For example, the emission layer EML which is divided by the pixel defining film PDL and provided corresponding to each light emitting regions PXA-R, PXA-G, and PXA-B may emit light in the same (e.g., substantially same) wavelength range. In the display apparatus DD of an embodiment, the emission layer EML may emit blue light. Unlike the configuration illustrated, in an embodiment, the emission layer EML may be provided as a common layer in the entire light emitting regions PXA-R, PXA-G, and PXA-B.

The light control layer CCL may be on the display panel DP. The light control layer CCL may include a light conversion body. The light conversion body may be a quantum dot, a phosphor, and/or the like. The light conversion body may emit provided light by converting the wavelength thereof. In some embodiments, the light control layer CCL may include a layer containing the quantum dot and/or a layer containing the phosphor.

The light control layer CCL may include a plurality of light control parts CCP1, CCP2, and CCP3. The light control parts CCP1, CCP2, and CCP3 may be spaced apart from each other.

Referring to FIG. 7, divided patterns BMP may be between the light control parts CCP1, CCP2, and CCP3 which are spaced apart from each other, but embodiments of the present disclosure are not limited thereto. FIG. 7 illustrates that the divided patterns BMP do not overlap the light control parts CCP1, CCP2, and CCP3, but at least a portion of the edges of the light control parts CCP1, CCP2, and CCP3 may overlap the divided patterns BMP.

The light control layer CCL may include a first light control part CCP1 containing a first quantum dot QD1 which converts a first color light provided from the light emitting device ED into a second color light, a second light control part CCP2 containing a second quantum dot QD2 which converts the first color light into a third color light, and a third light control part CCP3 which transmits the first color light.

In an embodiment, the first light control part CCP1 may provide red light that is the second color light, and the second light control part CCP2 may provide green light that is the third color light. The third light control part CCP3 may provide blue light by transmitting the blue light that is the first color light provided from the light emitting device ED. For example, the first quantum dot QD1 may be a red quantum dot, and the second quantum dot QD2 may be a green quantum dot. The same as described above may be applied with respect to the quantum dots QD1 and QD2.

In addition, the light control layer CCL may further include a scatterer SP (e.g., a light scatterer SP). The first light control part CCP1 may include the first quantum dot QD1 and the scatterer SP, the second light control part CCP2 may include the second quantum dot QD2 and the scatterer SP, and the third light control part CCP3 may not include any quantum dot but include the scatterer SP.

The scatterer SP may be inorganic particles. For example, the scatterer SP may include at least one of TiO₂, ZnO, Al₂O₃, SiO₂, or hollow sphere silica. The scatterer SP may include any one selected from among TiO₂, ZnO, Al₂O₃, SiO₂, and hollow sphere silica, and/or may be a mixture of at least two materials selected from among TiO₂, ZnO, Al₂O₃, SiO₂, and hollow sphere silica.

The first light control part CCP1, the second light control part CCP2, and the third light control part CCP3 each may include base resins BR1, BR2, and BR3 in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3. The base resins BR1, BR2, and BR3 are media in which the quantum dots QD1 and QD2 and the scatterer SP are dispersed, and may be formed of various suitable resin compositions, which may be generally referred to as a binder. For example, the base resins BR1, BR2, and BR3 may be acrylic-based resins, urethane-based resins, silicone-based resins, epoxy-based resins, etc. The base resins BR1, BR2, and BR3 may be transparent resins. In an embodiment, the first base resin BR1, the second base resin BR2, and the third base resin BR3 may be the same as or different from each other.

The light control layer CCL may include a barrier layer BFL1. The barrier layer BFL1 may serve to prevent or reduce the penetration of moisture and/or oxygen (hereinafter, may be referred to as ‘moisture/oxygen’). The barrier layer BFL1 may be on the light control parts CCP1, CCP2, and CCP3 to block or reduce exposure of the light control parts CCP1, CCP2, and CCP3 to moisture/oxygen. In some embodiments, the barrier layer BFL1 may cover the light control parts CCP1, CCP2, and CCP3. In addition, the barrier layer BFL2 may be provided between the light control parts CCP1, CCP2, and CCP3 and the color filter layer CFL.

The barrier layers BFL1 and BFL2 may include at least one inorganic layer. In some embodiments, the barrier layers BFL1 and BFL2 may include an inorganic material. For example, the barrier layers BFL1 and BFL2 may include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film which secures a transmittance, etc. In some embodiments, the barrier layers BFL1 and BFL2 may further include an organic film. The barrier layers BFL1 and BFL2 may be formed of a single layer or a plurality of layers.

In the display apparatus DD of an embodiment, the color filter layer CFL may be on the light control layer CCL. For example, the color filter layer CFL may be directly on the light control layer CCL. In this case, the barrier layer BFL2 may be omitted.

The color filter layer CFL may include a light shielding part BM and color filters CF1, CF2, and CF3. The color filter layer CFL may include a first filter CF1 configured to transmit the second color light, a second filter CF2 configured to transmit the third color light, and a third filter CF3 configured to transmit the first color light. For example, the first filter CF1 may be a red filter, the second filter CF2 may be a green filter, and the third filter CF3 may be a blue filter. The filters CF1, CF2, and CF3 each may include a polymeric photosensitive resin and a pigment and/or dye. The first filter CF1 may include a red pigment and/or dye, the second filter CF2 may include a green pigment and/or dye, and the third filter CF3 may include a blue pigment and/or dye. Embodiments of the present disclosure, however, are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

Furthermore, in an embodiment, the first filter CF1 and the second filter CF2 may be a yellow filter. The first filter CF1 and the second filter CF2 may not be separated (e.g., not spaced apart) but be provided as one filter.

The light shielding part BM may be a black matrix. The light shielding part BM may include an organic light shielding material and/or an inorganic light shielding material containing a black pigment and/or dye. The light shielding part BM may prevent or reduce light leakage, and may separate boundaries between the adjacent filters CF1, CF2, and CF3. In addition, in an embodiment, the light shielding part BM may be formed of a blue filter.

The first to third filters CF1, CF2, and CF3 may correspond to the red light emitting region PXA-R, the green light emitting region PXA-G, and the blue light emitting region PXA-B, respectively.

A base substrate BL may be on the color filter layer CFL. The base substrate BL may be a member which provides a base surface on which the color filter layer CFL, the light control layer CCL, and the like are located. The base substrate BL may be a glass substrate, a metal substrate, a plastic substrate, etc. However, embodiments of the present disclosure are not limited thereto, and the base substrate BL may be an inorganic layer, an organic layer, or a composite material layer. In addition, unlike the configuration illustrated, in an embodiment, the base substrate BL may be omitted.

FIG. 8 is a cross-sectional view illustrating a portion of a display apparatus according to an embodiment of the present disclosure. In the display apparatus DD-TD of an embodiment, the light emitting device ED-BT may include a plurality of light emitting structures OL-B1, OL-B2, and OL-B3. The light emitting device ED-BT may include a first electrode EL1 and a second electrode EL2 which face each other, and the plurality of light emitting structures OL-B1, OL-B2, and OL-B3 sequentially stacked in the thickness direction between the first electrode EL1 and the second electrode EL2. The light emitting structures OL-B1, OL-B2, and OL-B3 each may include an emission layer EML (FIG. 7) and a hole transport region HTR and an electron transport region ETR having the emission layer EML (FIG. 7) located therebetween.

In some embodiments, the light emitting device ED-BT included in the display apparatus DD-TD of an embodiment may be a light emitting device having a tandem structure and including a plurality of emission layers.

In an embodiment illustrated in FIG. 8, all light beams respectively emitted from the light emitting structures OL-B1, OL-B2, and OL-B3 may be blue light. However, embodiments of the present disclosure are not limited thereto, and the light beams respectively emitted from the light emitting structures OL-B1, OL-B2, and OL-B3 may have wavelength ranges different from each other. For example, the light emitting device ED-BT including the plurality of light emitting structures OL-B1, OL-B2, and OL-B3 which emit light beams having wavelength ranges different from each other may emit white light.

Charge generation layers CGL1 and CGL2 may be respectively between two of the neighboring light emitting structures OL-B1, OL-B2, and OL-B3. The charge generation layers CGL1 and CGL2 may include a p-type charge generation layer and/or an n-type charge generation layer.

At least one selected from among the light emitting structures OL-B1, OL-B2, and OL-B3 included in the display apparatus DD-TD of an embodiment may contain the above-described fused polycyclic compound of an embodiment. In some embodiments, at least one selected from among the plurality of emission layers included in the light emitting device ED-BT may include the fused polycyclic compound of an embodiment.

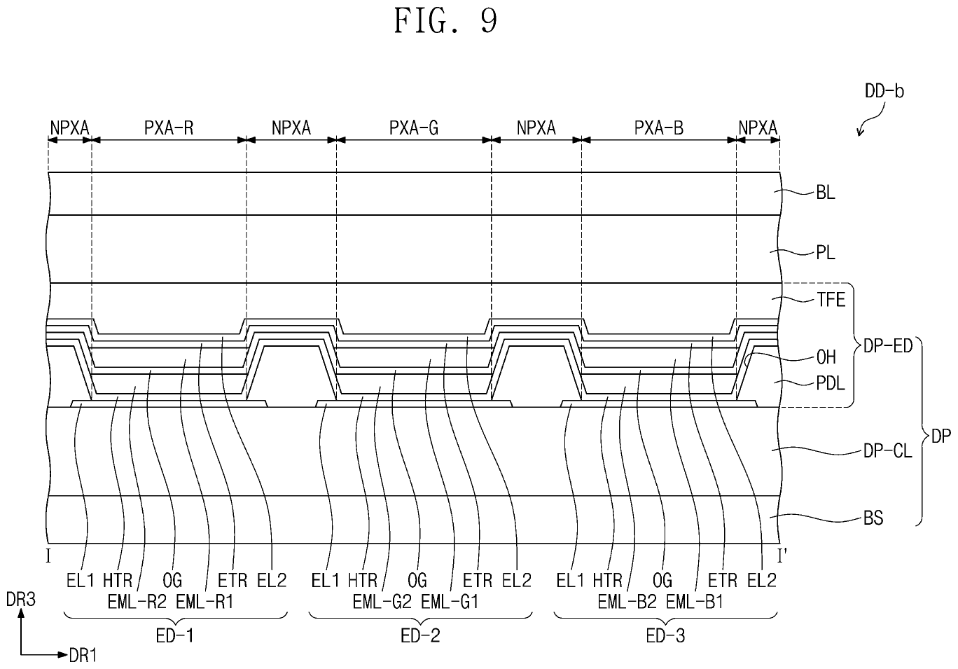

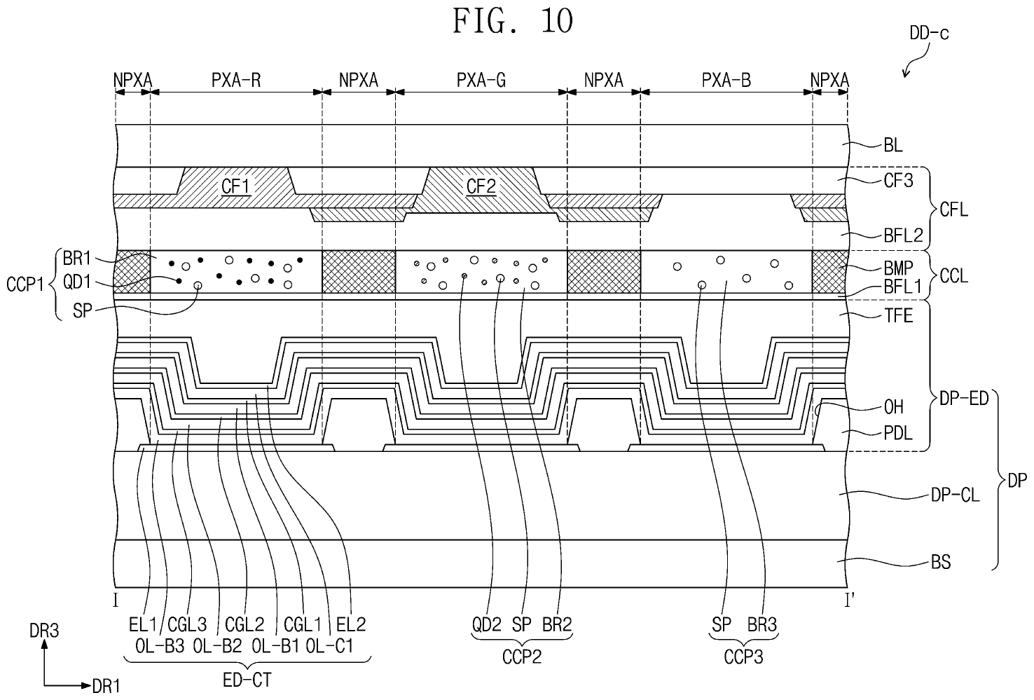

FIG. 9 is a cross-sectional view illustrating a display apparatus according to an embodiment of the present disclosure; FIG. 10 is a cross-sectional view illustrating a display apparatus according to an embodiment of the present disclosure.

Referring to FIG. 9, the display apparatus DD-b according to an embodiment may include light emitting devices ED-1, ED-2, and ED-3 in which two emission layers are stacked. Compared with the display apparatus DD of an embodiment illustrated in FIG. 2, an embodiment illustrated in FIG. 9 has a difference in that the first to third light emitting devices ED-1, ED-2, and ED-3 each include two emission layers stacked in the thickness direction. In each of the first to third light emitting devices ED-1, ED-2, and ED-3, the two emission layers may emit light in the same (e.g., substantially same) wavelength region.

The first light emitting device ED-1 may include a first red emission layer EML-R1 and a second red emission layer EML-R2. The second light emitting device ED-2 may include a first green emission layer EML-G1 and a second green emission layer EML-G2. In addition, the third light emitting device ED-3 may include a first blue emission layer EML-B1 and a second blue emission layer EML-B2. An emission auxiliary part OG may be between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may include a single layer or a multilayer. The emission auxiliary part OG may include a charge generation layer. For example, the emission auxiliary part OG may include an electron transport region, a charge generation layer, and a hole transport region that are sequentially stacked. The emission auxiliary part OG may be provided as a common layer in the whole of the first to third light emitting devices ED-1, ED-2, and ED-3. However, embodiments of the present disclosure are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may be between the electron transport region ETR and the emission auxiliary part OG. The second red emission layer EML-R2, the second green emission layer EML-G2, and the second blue emission layer EML-B2 may be between the emission auxiliary part OG and the hole transport region HTR.

In some embodiments, the first light emitting device ED-1 may include the first electrode EL1, the hole transport region HTR, the second red emission layer EML-R2, the emission auxiliary part OG, the first red emission layer EML-R1, the electron transport region ETR, and the second electrode EL2 that are sequentially stacked. The second light emitting device ED-2 may include the first electrode EL1, the hole transport region HTR, the second green emission layer EML-G2, the emission auxiliary part OG, the first green emission layer EML-G1, the electron transport region ETR, and the second electrode EL2 that are sequentially stacked. The third light emitting device ED-3 may include the first electrode EL1, the hole transport region HTR, the second blue emission layer EML-B2, the emission auxiliary part OG, the first blue emission layer EML-B1, the electron transport region ETR, and the second electrode EL2 that are sequentially stacked.

In some embodiments, an optical auxiliary layer PL may be on the display device layer DP-ED. The optical auxiliary layer PL may include a polarizing layer. The optical auxiliary layer PL may be on the display panel DP and control reflected light in the display panel DP due to external light. Unlike the configuration illustrated, the optical auxiliary layer PL in the display apparatus according to an embodiment may be omitted.

At least one emission layer included in the display apparatus DD-b of an embodiment illustrated in FIG. 9 may include the above-described fused polycyclic compound of an embodiment. For example, in an embodiment, at least one of the first blue emission layer EML-B1 or the second blue emission layer may include the fused polycyclic compound of an embodiment.

Unlike FIGS. 8 and 9, FIG. 10 illustrates that a display apparatus DD-c includes four light emitting structures OL-B1, OL-B2, OL-B3, and OL-C1. A light emitting device ED-CT may include a first electrode EL1 and a second electrode EL2 which face each other, and first to fourth light emitting structures OL-B1, OL-B2, OL-B3, and OL-C1 that are sequentially stacked in the thickness direction between the first electrode EL1 and the second electrode EL2. Charge generation layers CGL1, CGL2, and CGL3 may be between the first to fourth light emitting structures OL-B1, OL-B2, OL-B3, and OL-C1. Among the four light emitting structures, the first to third light emitting structures OL-B1, OL-B2, and OL-B3 may emit blue light, and the fourth light emitting structure OL-C1 may emit green light. However, embodiments of the present disclosure are not limited thereto, and the first to fourth light emitting structures OL-B1, OL-B2, OL-B3, and OL-C1 may emit light beams in different wavelength regions.

The charge generation layers CGL1, CGL2, and CGL3 between adjacent light emitting structures OL-B1, OL-B2, OL-B3, and OL-C1 may include a p-type charge generation layer and/or an n-type charge generation layer.

At least one selected from among the light emitting structures OL-B1, OL-B2, OL-B3, and OL-C1 included in the display apparatus DD-c of an embodiment may contain the above-described fused polycyclic compound of an embodiment. For example, in an embodiment, at least one selected from among the first to third light emitting structures OL-B1, OL-B2, and OL-B3 may include the described-above fused polycyclic compound of an embodiment.

Hereinafter, with reference to Examples and Comparative Examples, a condensed polycyclic according to an embodiment of the present disclosure and a luminescence device of an embodiment of the present disclosure will be described in more detail. In addition, Examples described below are only illustrations to assist the understanding of the subject matter of the present disclosure, and the scope of the present disclosure is not limited thereto.

### Examples

### 1. Synthesis of Fused Polycyclic Compound

First, a synthetic method of the fused polycyclic compound according to the present embodiment will be described by illustrating synthetic methods of Compounds 1, 33, 53, 64, 66, 81, 101, and 104. In addition, the synthetic methods of the fused polycyclic compounds as described below are only examples, and the synthetic method of the fused polycyclic compound according to an embodiment of the present disclosure is not limited to the following examples.

### (1) Synthesis of Compound 1

Fused Polycyclic Compound 1 according to an example may be synthesized, for example, by the reaction below.

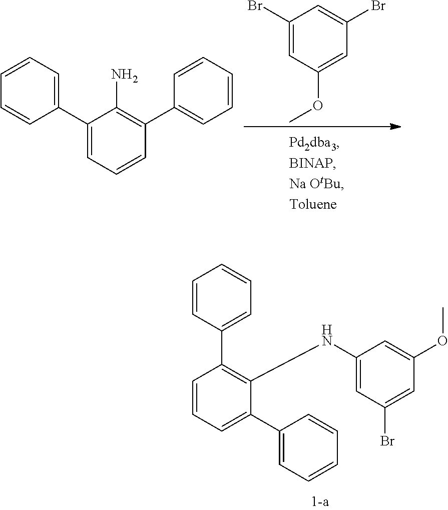

### (Synthesis of Intermediate 1-a)

In an argon atmosphere, to a 2 L-flask, [1,1′:3′,1″-terphenyl]-2′-amine (18 g, 74 mmol), 1,3-dibromo-5-methoxybenzene (23.6 g, 88.8 mmol), pd₂dba₃ (2.0 g, 2.22 mmol), BINAP (2.8 g, 4.44 mmol), and sodium tert-butoxide (14 g, 148 mmol) were added and dissolved in 1 L of toluene, and then the resultant reaction solution was stirred at about 100° C. for about 12 hours. After cooling, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography using CH₂Cl₂ and hexane as eluent to obtain Intermediate 1-a (22 g, 70%). The obtained compound was identified as Intermediate 1-a through ESI-LCMS.

ESI-LCMS: [M]+: C₂₅H₂₀BrNO. 429.0718.

### (Synthesis of Intermediate 1-b)

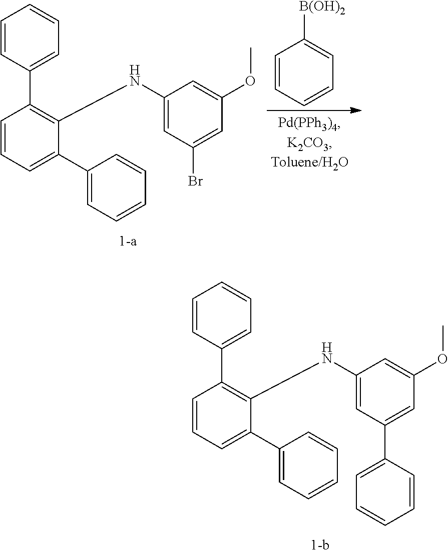

In an argon atmosphere, to a 1 L-flask, Intermediate 1-a (22 g, 51 mmol), phenyl boronic acid (12.4 g, 102 mmol), pd(PPh₃)₄ (3 g, 2.6 mmol), and potassium carbonate (11 g, 76.5 mmol) were added and dissolved in 300 mL of toluene and 100 mL of H₂O, and then the resultant reaction solution was stirred at about 100° C. for about 12 hours. After cooling, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography using CH₂Cl₂ and hexane as eluent to obtain Intermediate 1-b (15.2 g, 71%). The obtained compound was identified as Intermediate 1-b through ESI-LCMS.

ESI-LCMS: [M]+: C₃₁H₂₅NO. 427.1905.

### (Synthesis of Intermediate 1-c)

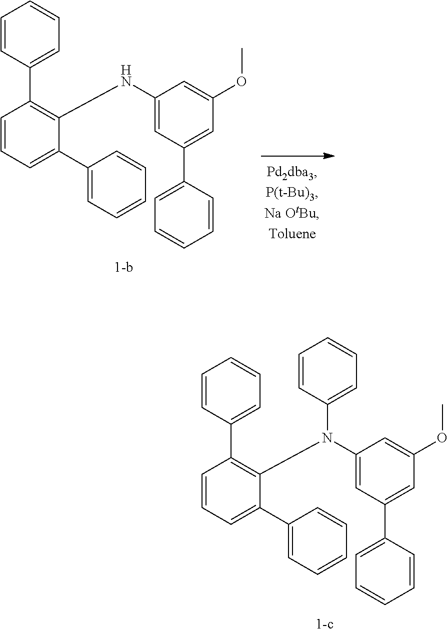 [SMILES: COc1cc(Nc2c(-c3ccccc3)cccc2-c2ccccc2)cc(-c2ccccc2)c1 ; COc1cc(-c2ccccc2)cc(N(c2ccccc2)c2c(-c3ccccc3)cccc2-c2ccccc2)c1]

In an argon atmosphere, to a 1 L-flask, Intermediate 1-b (15.2 g, 35.5 mmol), bromobenzene (2.5 g, 35.5 mmol), Pd₂dba₃ (1.0 g, 1.1 mmol), tris-tert-butyl phosphine (0.8 mL, 2.2 mmol), and sodium tert-butoxide (6.8 g, 71 mmol) were added and dissolved in 400 mL of o-xylene, and then the resultant reaction solution was stirred at about 140° C. for about 12 hours. After cooling, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography using CH₂Cl₂ and hexane as eluent to obtain Intermediate 1-c (13 g, 78%). The obtained compound was identified as Intermediate 1-c through ESI-LCMS.

ESI-LCMS: [M]+: C₃₇H₂₉NO. 503.2212.

### (Synthesis of Intermediate 1-d)

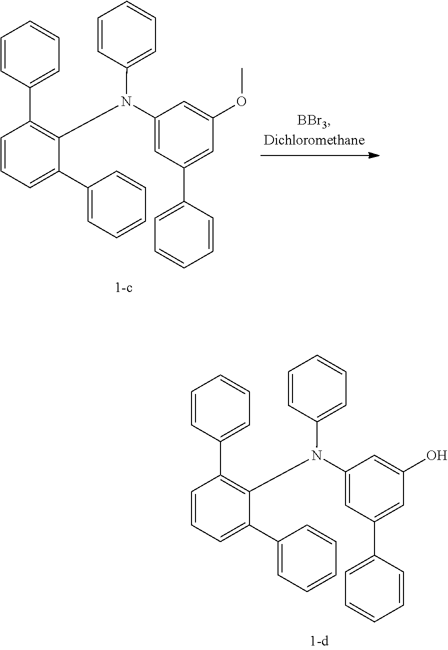 [SMILES: COc1cc(-c2ccccc2)cc(N(c2ccccc2)c2c(-c3ccccc3)cccc2-c2ccccc2)c1 ; Oc1cc(-c2ccccc2)cc(N(c2ccccc2)c2c(-c3ccccc3)cccc2-c2ccccc2)c1]

In an argon atmosphere, to a 1 L-flask, Compound 1-c (13 g) was added and dissolved in 500 mL of dichloromethane, and then cooled using water and ice, and BBr₃ (3 equiv.) was slowly added dropwise thereto, and the resultant reaction solution was stirred at room temperature for about 12 hours. The reaction solution was extracted with water/CH₂Cl₂ to collect organic layers, and the organic layers were dried over MgSO₄ and then filtered. In the filtrate, the solvent was removed under reduced pressure to obtain a solid. The solid thus obtained was purified and separated by silica gel column chromatography using CH₂Cl₂ and hexane as eluent to obtain Intermediate 1-d (7.2 g, 55%). The obtained compound was identified as Intermediate 1-d through ESI-LCMS.

ESI-LCMS: [M]+: C₃₆H₂₇NO. 489.2111.

### (Synthesis of Intermediate 1-e)

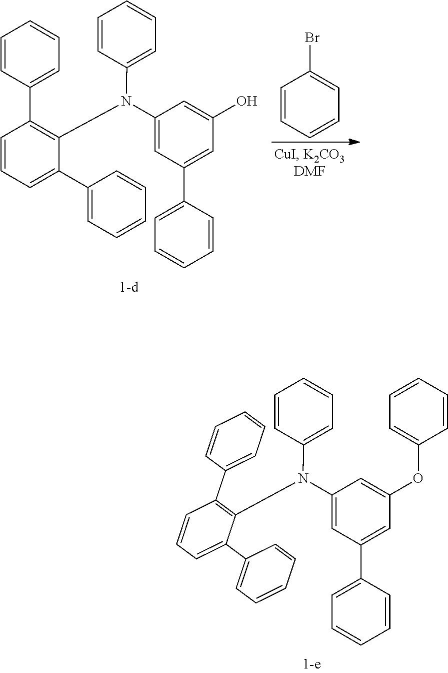

In an argon atmosphere, in a 1 L-flask, Intermediate 1-d (7.2 g, 14.7 mmol), bromobenzene (2.3 g, 14.7 mmol), copper iodide (2.8 g, 14.7 mmol), 1,10-phenanthroline (2.6 mL, 14.7 mmol), and potassium carbonate (4.1 g, 29.4 mmol) were added and dissolved in 200 mL of DMF, and the resultant reaction solution was then stirred at about 160° C. for about 12 hours. After cooling, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography using CH₂Cl₂ and hexane as eluent to obtain Intermediate 1-e (5.4 g, 65%). The obtained compound was identified as Intermediate 1-e through ESI-LCMS.

ESI-LCMS: [M]+: C₄₂H₃₁NO. 565.2412.

### (Synthesis of Compound 1)

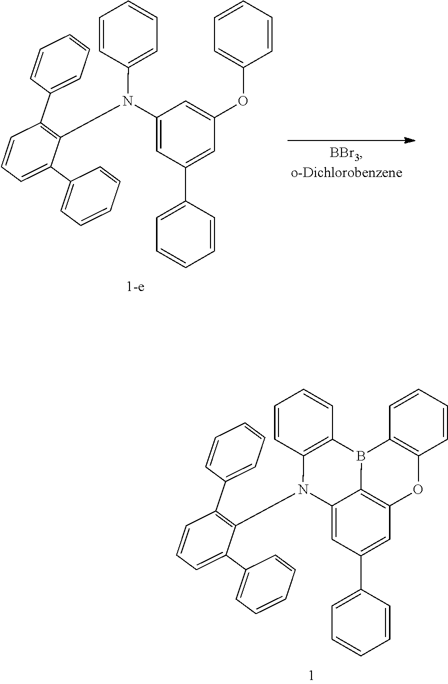 [SMILES: c1ccc(Oc2cc(-c3ccccc3)cc(N(c3ccccc3)c3c(-c4ccccc4)cccc3-c3ccccc3)c2)cc1 ; c1ccc(-c2cc3c4c(c2)N(c2c(-c5ccccc5)cccc2-c2ccccc2)c2ccccc2B4c2ccccc2O3)cc1]

In an argon atmosphere, to a 500 mL-flask, Intermediate 1-e (5.4 g, 9.5 mmol) was added and dissolved in 100 mL of o-dichlorobenzene, then cooled using water and ice, and BBr₃ (5 equiv.) was slowly added dropwise thereto, and the resultant reaction solution was stirred at about 180° C. for about 12 hours. After cooling, the reaction was terminated by adding triethylamine (5 equiv.), the resulting product was extracted with water/CH₂Cl₂ to collect organic layers, and the organic layers were dried over MgSO₄ and then filtered. In the filtrate, the solvent was removed under reduced pressure to obtain a solid. The solid thus obtained was purified and separated by silica gel column chromatography using CH₂Cl₂ and hexane as eluent to obtain Compound 1 (yellow solid, 0.6 g, yield: 11%). The obtained compound was identified as Compound 1 through ¹H-NMR and ESI-LCMS.

¹H-NMR (400 MHz, CDCl₃): d=9.10 (d, 2H), 8.36 (s, 2H), 7.86 (d, 2H), 7.75 (m, 4H), 7.62 (d, 2H), 7.55 (m, 8H), 7.41-7.24 (m, 4H), 7.11 (d, 2H), 6.95 (s, 2H), ESI-LCMS: [M]+: C₄₂H₂₈BNO. 573.2385.

### (2) Synthesis of Compound 33

Fused Polycyclic Compound 33 according to an example may be synthesized, for example, by the reaction below.

### (Synthesis of Intermediate 33-a)

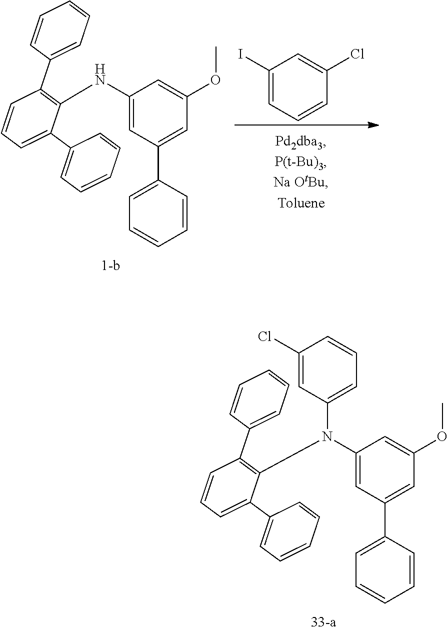

Intermediate 33-a was synthesized in substantially the same manner as the synthesis of Intermediate 1-c by using 1-chloro-3-iodobenzene instead of bromobenzene (yield: 68%). The obtained solid was identified as Intermediate 33-a through ESI-LCMS.

ESI-LCMS: [M]+: C₃₇H₂₈ClNO. 537.1987.

### (Synthesis of Intermediate 33-b)

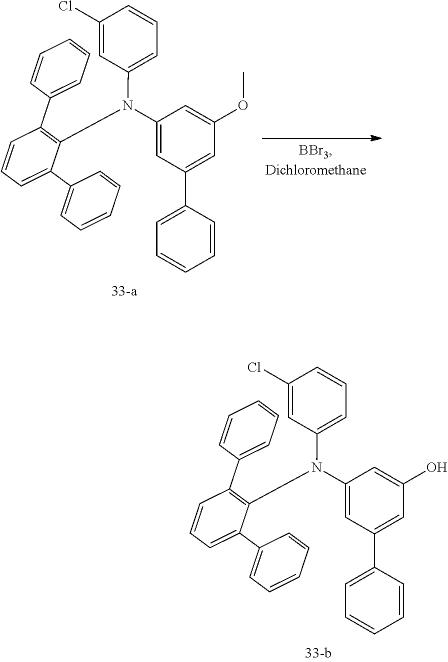 [SMILES: COc1cc(-c2ccccc2)cc(N(c2cccc(Cl)c2)c2c(-c3ccccc3)cccc2-c2ccccc2)c1 ; Oc1cc(-c2ccccc2)cc(N(c2cccc(Cl)c2)c2c(-c3ccccc3)cccc2-c2ccccc2)c1]

Intermediate 33-b was synthesized in substantially the same manner as the synthesis of Intermediate 1-d by using Intermediate 33-a instead of Intermediate 1-c (yield: 58%). The obtained solid was identified as Intermediate 33-b through ESI-LCMS.

ESI-LCMS: [M]+: C₃₆H₂₆ClNO. 523.1721.

### (Synthesis of Intermediate 33-c)

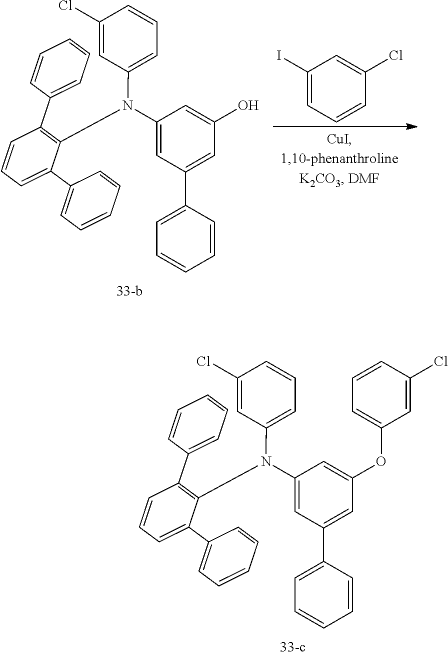 [SMILES: Oc1cc(-c2ccccc2)cc(N(c2cccc(Cl)c2)c2c(-c3ccccc3)cccc2-c2ccccc2)c1 ; Clc1cccc(I)c1 ; Clc1cccc(Oc2cc(-c3ccccc3)cc(N(c3cccc(Cl)c3)c3c(-c4ccccc4)cccc3-c3ccccc3)c2)c1]

Intermediate 33-c was synthesized in substantially the same manner as the synthesis of Intermediate 1-e by using Intermediate 33-b instead of Intermediate 1-d and using 1-chloro-3-iodobenzene instead of bromobenzene (yield: 71%). The obtained solid was identified as Intermediate 33-c through ESI-LCMS.

ESI-LCMS: [M]+: C42H29Cl₂NO. 633.1647.

### (Synthesis of Intermediate 33-d)

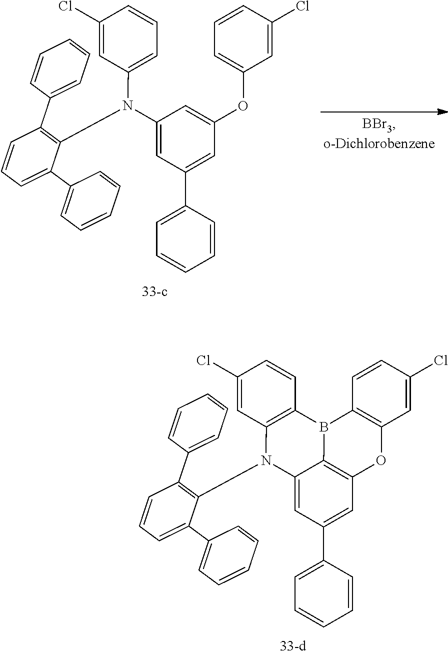 [SMILES: Clc1cccc(Oc2cc(-c3ccccc3)cc(N(c3cccc(Cl)c3)c3c(-c4ccccc4)cccc3-c3ccccc3)c2)c1 ; Clc1ccc2c(c1)Oc1cc(-c3ccccc3)cc3c1B2c1ccc(Cl)cc1N3c1c(-c2ccccc2)cccc1-c1ccccc1]

Intermediate 33-d was synthesized in substantially the same manner as the synthesis of Compound 1 by using Intermediate 33-c instead of Intermediate 1-e (yield: 12%). The obtained solid was identified as Intermediate 33-d through ESI-LCMS.

ESI-LCMS: [M]+: C42H26BCl₂NO. 641.1511.

### (Synthesis of Compound 33)

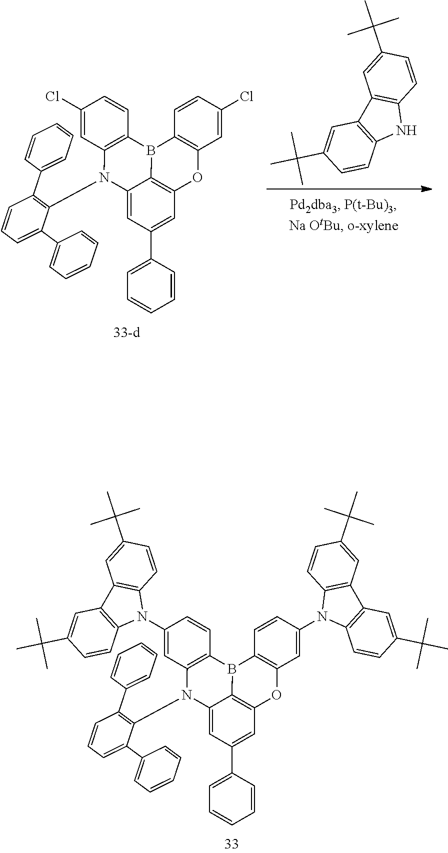 [SMILES: Clc1ccc2c(c1)Oc1cc(-c3ccccc3)cc3c1B2c1ccc(Cl)cc1N3c1c(-c2ccccc2)cccc1-c1ccccc1 ; CC(C)(C)c1ccc2[nH]c3ccc(C(C)(C)C)cc3c2c1 ; CC(C)(C)c1ccc2c(c1)c1cc(C(C)(C)C)ccc1n2-c1ccc2c(c1)Oc1cc(-c3ccccc3)cc3c1B2c1ccc(-n2c4ccc(C(C)(C)C)cc4c4cc(C(C)(C)C)ccc42)cc1N3c1c(-c2ccccc2)cccc1-c1ccccc1]

In an argon atmosphere, to a 100 mL-flask, Intermediate 33-d (1 g, 1.6 mmol), 3,6-di-tert-butyl-9H-carbazole (0.92 g, 3.3 mmol), Pd₂dba₃ (0.16 g, 0.17 mmol), tris-tert-butyl phosphine (0.08 mL, 0.34 mmol), and sodium tert-butoxide (0.5 g, 4.8 mmol) were added and dissolved in 10 mL of o-xylene, and then the resultant reaction solution was stirred at about 140° C. for about 12 hours. After cooling, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography using CH₂Cl₂ and hexane as eluent to obtain Compound 33 (yellow solid, 1.2 g, yield: 68%). The obtained yellow solid was identified as Compound 33 through ¹H-NMR and ESI-LCMS.

¹H-NMR (400 MHz, CDCl₃): d=9.24 (d, 2H), 8.55 (d, 4H), 8.33 (d, 2H), 8.20 (d, 4H), 8.13 (s, 2H), 7.94 (d, 2H), 7.77 (s, 2H), 7.50 (d, 2H), 7.43 (m, 8H), 7.19 (m, 4H), 7.08 (m, 4H), 6.89 (s, 2H), 1.38 (s, 36H).

ESI-LCMS: [M]+: C₈₂H₇₄BN₃O. 1127.5912.

### (3) Synthesis of Compound 53

Fused Polycyclic Compound 53 according to an example may be synthesized, for example, by the reaction below.

### (Synthesis of Intermediate 53-a)

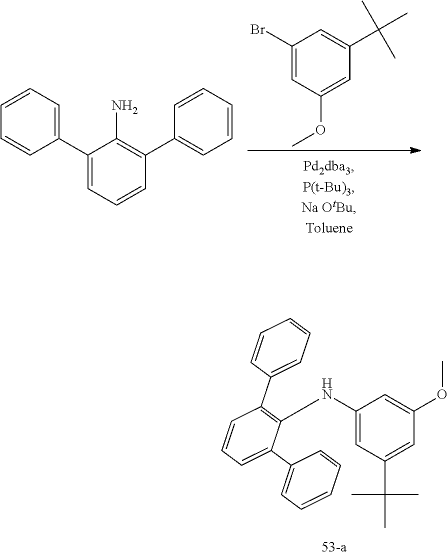 [SMILES: Nc1c(-c2ccccc2)cccc1-c1ccccc1 ; COc1cc(Br)cc(C(C)(C)C)c1 ; COc1cc(Nc2c(-c3ccccc3)cccc2-c2ccccc2)cc(C(C)(C)C)c1]

In an argon atmosphere, to a 2 L-flask, [1,1′:3′,1″-terphenyl]-2′-amine (18 g, 74 mmol), 1-bromo-3-(tert-butyl)-5-methoxybenzene (18 g, 74 mmol), pd₂dba₃ (2.0 g, 2.22 mmol), tris-tert-butyl phosphine (0.9 ml, 4.44 mmol), and sodium tert-butoxide (14 g, 148 mmol) were added and dissolved in 1 L of toluene, and then the resultant reaction solution was stirred at about 100° C. for about 12 hours. After cooling, the reaction solution was extracted by adding water (1 L) and ethyl acetate (300 mL) to collect organic layers, and the organic layers were dried over MgSO₄ and then filtered. In the filtrate, the solvent was removed under reduced pressure to obtain a solid. The solid thus obtained was purified and separated by silica gel column chromatography using CH₂Cl₂ and hexane as eluent to obtain Intermediate 53-a (24 g, 80%). The obtained compound was identified as Intermediate 53-a through ESI-LCMS.

ESI-LCMS: [M]+: C₂₉H₂₉NO. 407.2249.

### (Synthesis of Intermediate 53-b)

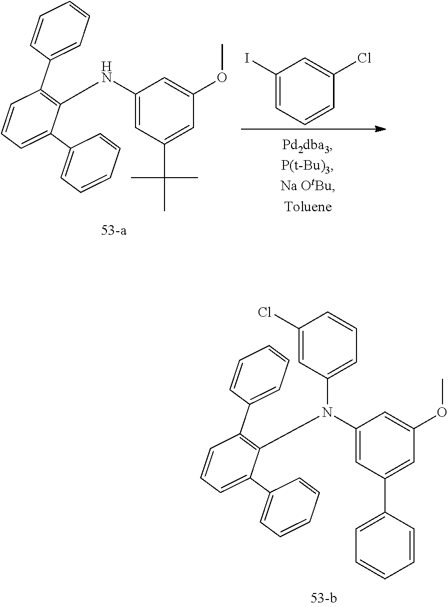

Intermediate 53-b was synthesized in substantially the same manner as the synthesis of Intermediate 1-c by using 1-chloro-3-iodobenzene instead of bromobenzene and using Intermediate 53-a instead of Intermediate 1-b (yield: 54%).

The obtained solid was identified as Intermediate 53-b through ESI-LCMS.

ESI-LCMS: [M]+: C₃₅H₃₂ClNO. 517.2171

### (Synthesis of Intermediate 53-c)

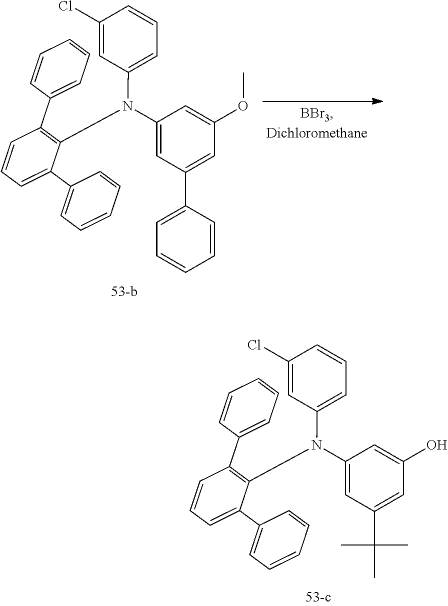 [SMILES: COc1cc(-c2ccccc2)cc(N(c2cccc(Cl)c2)c2c(-c3ccccc3)cccc2-c2ccccc2)c1 ; CC(C)(C)c1cc(O)cc(N(c2cccc(Cl)c2)c2c(-c3ccccc3)cccc2-c2ccccc2)c1]

Intermediate 53-c was synthesized in substantially the same manner as the synthesis of Intermediate 1-d by using Intermediate 53-b instead of Intermediate 1-c (yield: 67%). The obtained solid was identified as Intermediate 53-c through ESI-LCMS.

ESI-LCMS: [M]+: C₃₄H₃₀ClNO. 503.2016

### (Synthesis of Intermediate 53-d)

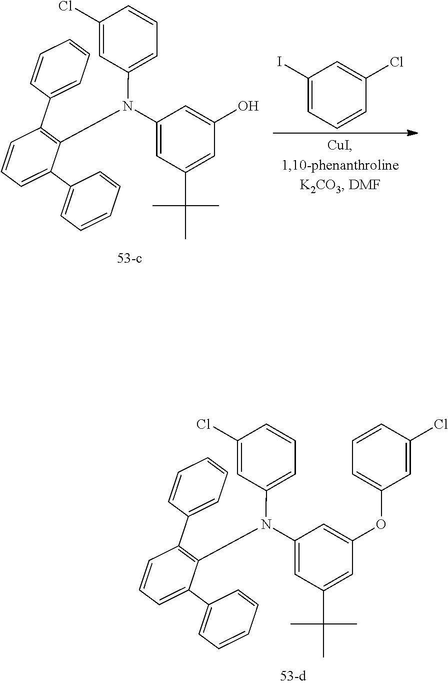 [SMILES: CC(C)(C)c1cc(O)cc(N(c2cccc(Cl)c2)c2c(-c3ccccc3)cccc2-c2ccccc2)c1 ; Clc1cccc(I)c1 ; CC(C)(C)c1cc(Oc2cccc(Cl)c2)cc(N(c2cccc(Cl)c2)c2c(-c3ccccc3)cccc2-c2ccccc2)c1]

Intermediate 53-d was synthesized in substantially the same manner as the synthesis of Intermediate 1-e by using Intermediate 53-c instead of Intermediate 1-d and using 1-chloro-3-iodobenzene instead of bromobenzene (yield: 62%). The obtained solid was identified as Intermediate 53-d through ESI-LCMS.

ESI-LCMS: [M]+: C₄₀H₃₃Cl₂NO. 613.1939

### (Synthesis of Intermediate 53-e)

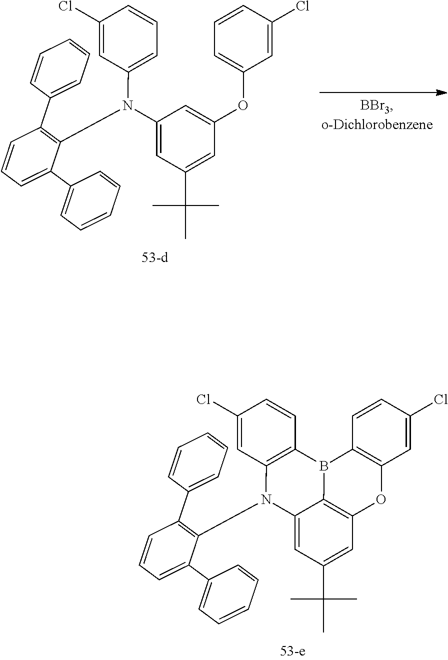 [SMILES: CC(C)(C)c1cc(Oc2cccc(Cl)c2)cc(N(c2cccc(Cl)c2)c2c(-c3ccccc3)cccc2-c2ccccc2)c1 ; CC(C)(C)c1cc2c3c(c1)N(c1c(-c4ccccc4)cccc1-c1ccccc1)c1cc(Cl)ccc1B3c1ccc(Cl)cc1O2]

Intermediate 53-e was synthesized in substantially the same manner as the synthesis of Compound 1 by using Intermediate 53-d instead of Intermediate 1-e (yield: 9%). The obtained solid was identified as Intermediate 53-e through ESI-LCMS.

ESI-LCMS: [M]+: C₄₀H₃₀BCl₂NO. 621.1798

### (Synthesis of Compound 53)

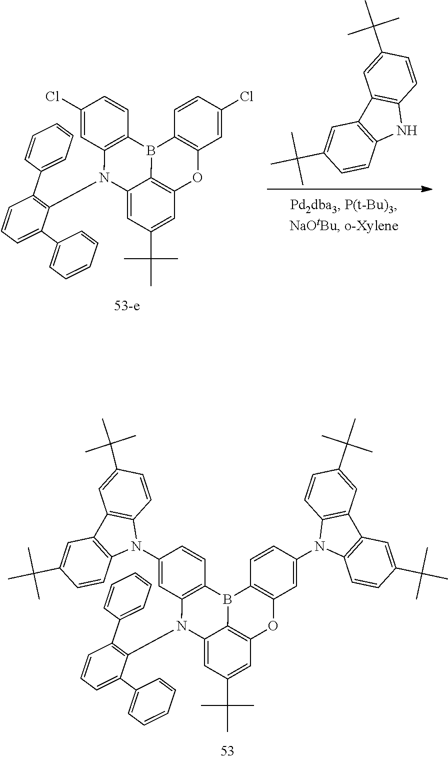 [SMILES: CC(C)(C)c1cc2c3c(c1)N(c1c(-c4ccccc4)cccc1-c1ccccc1)c1cc(Cl)ccc1B3c1ccc(Cl)cc1O2 ; CC(C)(C)c1ccc2[nH]c3ccc(C(C)(C)C)cc3c2c1 ; CC(C)(C)c1cc2c3c(c1)N(c1c(-c4ccccc4)cccc1-c1ccccc1)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1O2]

Compound 53 was synthesized in substantially the same manner as the synthesis of Compound 33 by using Intermediate 53-e instead of Intermediate 33-d (yield: 52%). The obtained yellow solid was identified as Compound 53 through ¹H-NMR and ESI-LCMS.

¹H-NMR (400 MHz, CDCl₃): d=9.24 (d, 2H), 8.55 (d, 4H), 8.33 (d, 2H), 8.20 (d, 4H), 8.13 (s, 2H), 7.94 (d, 2H), 7.77 (s, 2H), 7.50 (d, 2H), 7.43 (m, 8H), 7.19 (m, 4H), 7.08 (m, 4H), 6.89 (s, 2H), 1.38 (s, 36H).

ESI-LCMS: [M]+: C₈₀H₇₈BN₃O. 1107.6238

### (4) Synthesis of Compound 64

Fused polycyclic compound 64 according to an example may be synthesized by, for example, the reaction below.

### (Synthesis of Intermediate 64-a)

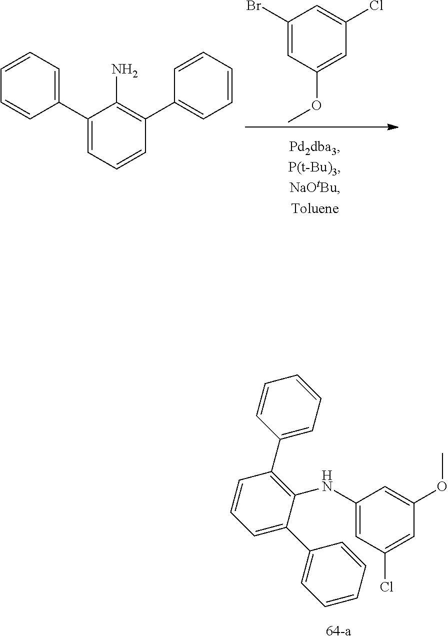

Intermediate 64-a was synthesized in substantially the same manner as the synthesis of Intermediate 53-a by using 1-bromo-3-chloro-5-methoxybenzene instead of 1-bromo-3-(tert-butyl)-5-methoxybenzene (yield: 72%). The obtained solid was identified as Intermediate 64-a through ESI-LCMS.

ESI-LCMS: [M]+: C₂₅H₂₀ClNO. 385.1233

### (Synthesis of Intermediate 64-b)

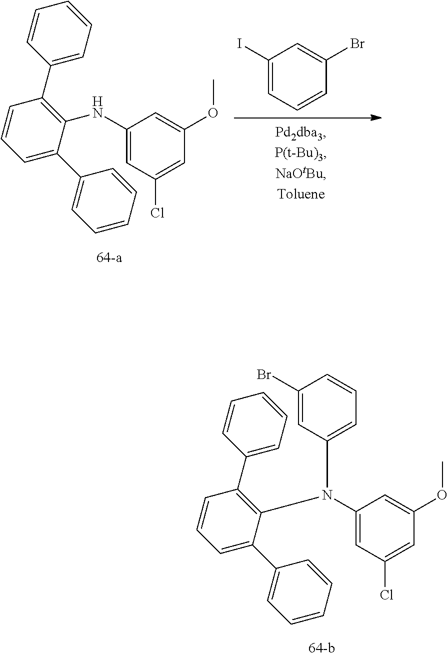

Intermediate 64-b was synthesized in substantially the same manner as the synthesis of Intermediate 1-c by using 1-bromo-3-iodobenzene instead of bromobenzene and using Intermediate 64-a instead of Intermediate 1-b (yield: 51%). The obtained solid was identified as Intermediate 64-b through ESI-LCMS.

ESI-LCMS: [M]+: C₃₁H₂₃BrClNO. 539.0652

### (Synthesis of Intermediate 64-c)

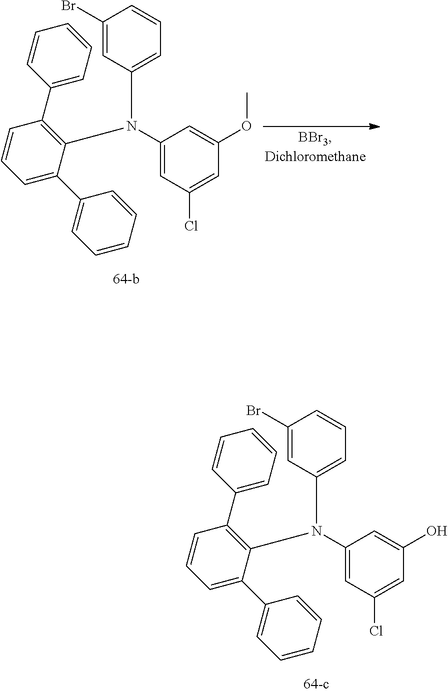 [SMILES: COc1cc(Cl)cc(N(c2cccc(Br)c2)c2c(-c3ccccc3)cccc2-c2ccccc2)c1 ; Oc1cc(Cl)cc(N(c2cccc(Br)c2)c2c(-c3ccccc3)cccc2-c2ccccc2)c1]

Intermediate 64-c was synthesized in substantially the same manner as the synthesis of Intermediate 1-d by using Intermediate 64-b instead of Intermediate 1-c (yield: 63%). The obtained solid was identified as Intermediate 64-c through ESI-LCMS.

ESI-LCMS: [M]+: C₃₀H₂₁ClNO. 525.0495

### (Synthesis of Intermediate 64-d)

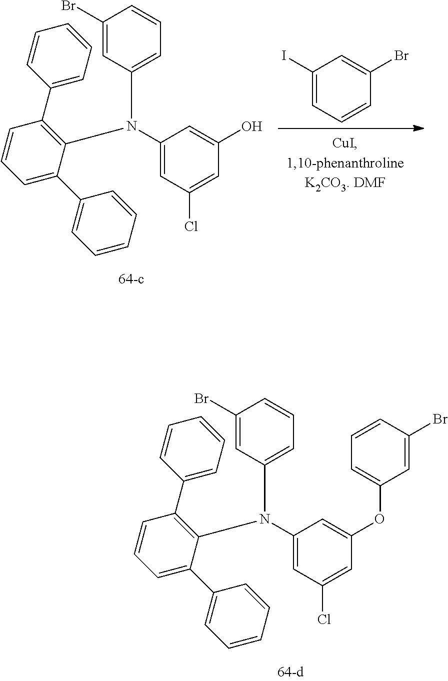 [SMILES: Oc1cc(Cl)cc(N(c2cccc(Br)c2)c2c(-c3ccccc3)cccc2-c2ccccc2)c1 ; Brc1cccc(I)c1 ; Clc1cc(Oc2cccc(Br)c2)cc(N(c2cccc(Br)c2)c2c(-c3ccccc3)cccc2-c2ccccc2)c1]

Intermediate 64-d was synthesized in substantially the same manner as the synthesis of Intermediate 1-e by using Intermediate 64-b instead of Intermediate 1-d and using 1-bromo-3-iodobenzene instead of bromobenzene (yield: 58%). The obtained solid was identified as Intermediate 64-d through ESI-LCMS.

ESI-LCMS: [M]+: C₃₆H₂₄Br₂ClNO. 678.9913

### (Synthesis of Intermediate 64-e)

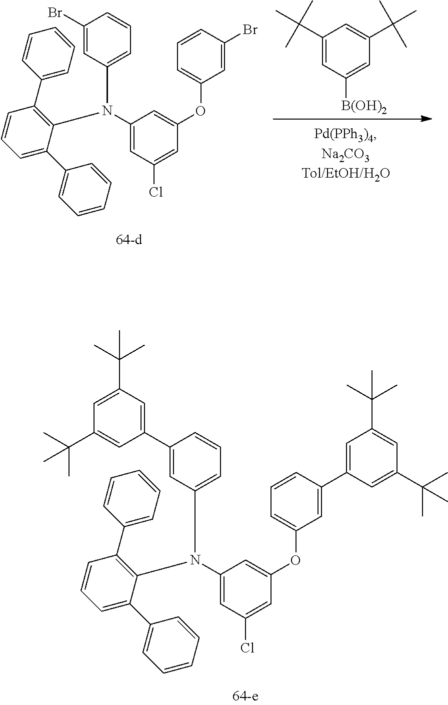

(3,5-di-tert-butylphenyl)boronic acid (1.5 equiv.), Intermediate 64-d (1 equiv.), tetrakis(triphenylphosphine)palladium(0) (0.05 equiv.), and sodium carbonate (3 equiv.) were dissolved in toluene, ethanol, and pure water (a ratio of 1:1:3), and then the resultant reaction solution was stirred in a nitrogen atom at about 100° C. for about 12 hours. After cooling, the resulting product was washed three times with ethyl acetate and water to obtain organic layers. The obtained organic layers were dried over MgSO₄, and then dried under reduced pressure. The residue thus obtained was purified and separated by column chromatography to obtain Intermediate 64-e (yield: 68%). The obtained solid was identified as Intermediate 64-e through ESI-LCMS.

ESI-LCMS: [M]+: C₆₄H₆₆ClNO. 899.4833

### (Synthesis of Intermediate 64-f)

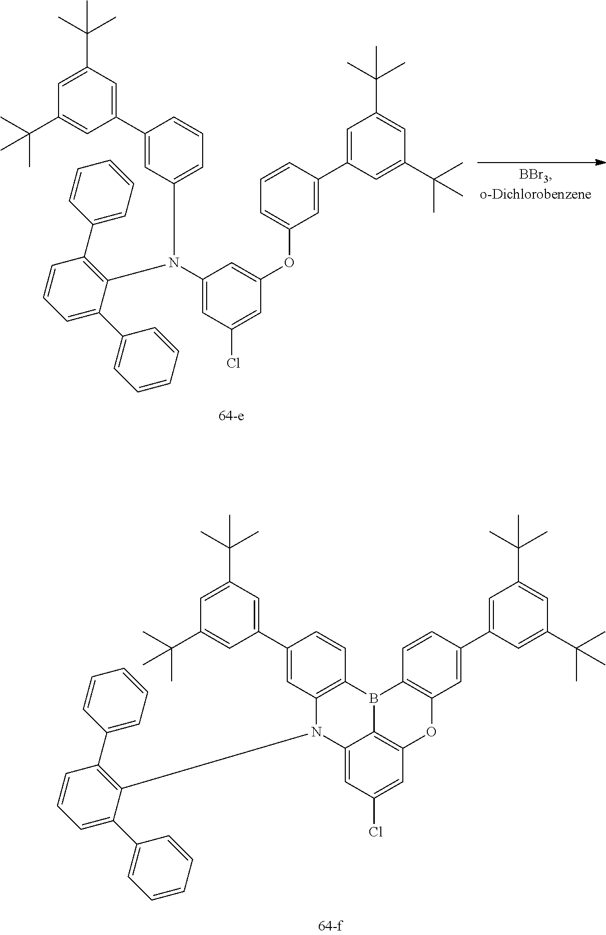 [SMILES: CC(C)(C)c1cc(-c2cccc(Oc3cc(Cl)cc(N(c4cccc(-c5cc(C(C)(C)C)cc(C(C)(C)C)c5)c4)c4c(-c5ccccc5)cccc4-c4ccccc4)c3)c2)cc(C(C)(C)C)c1 ; CC(C)(C)c1cc(-c2ccc3c(c2)Oc2cc(Cl)cc4c2B3c2ccc(-c3cc(C(C)(C)C)cc(C(C)(C)C)c3)cc2N4c2c(-c3ccccc3)cccc2-c2ccccc2)cc(C(C)(C)C)c1]

Intermediate 64-f was synthesized in substantially the same manner as the synthesis of Compound 1 by using Intermediate 64-e instead of Intermediate 1-e (yield: 23%). The obtained solid was identified as Intermediate 64-f through ESI-LCMS.

ESI-LCMS: [M]+: C₆₄H₆₃BClNO. 907.4691

### (Synthesis of Compound 64)

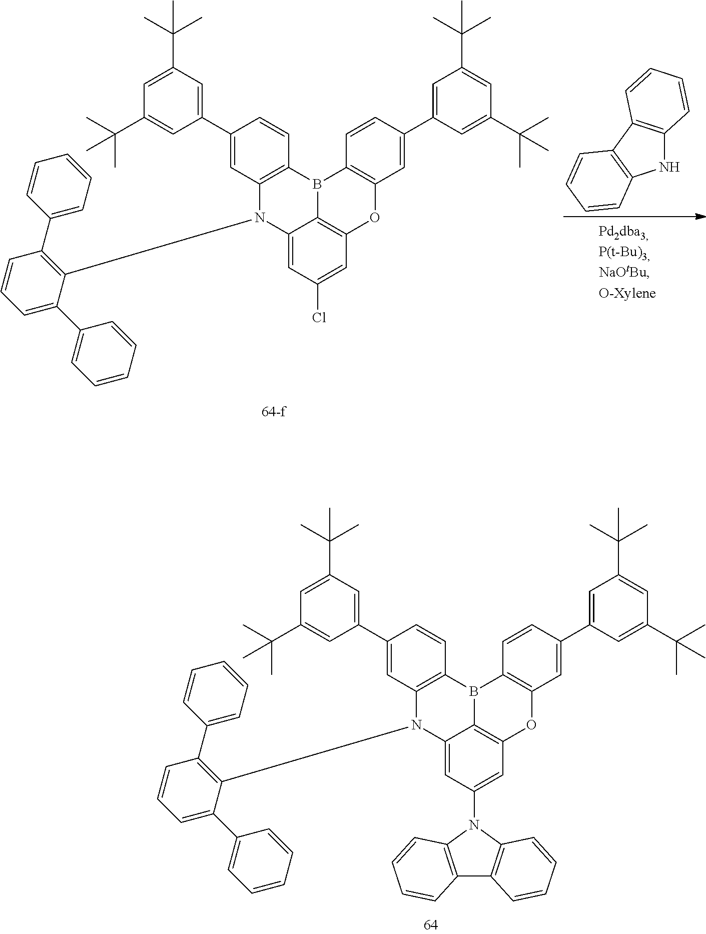

Compound 64 was synthesized in substantially the same manner as the synthesis of Compound 33 by using Intermediate 64-f instead of Intermediate 33-d and 9H-carbazole (1.1 equiv.) instead of 3,6-di-tert-butyl-9H-carbazole (yield: 63%). The obtained yellow solid was identified as Compound 64 through ¹H-NMR and ESI-LCMS.

¹H-NMR (400 MHz, CDCl₃): d=9.35 (d, 2H), 8.62 (d, 2H), 8.33 (m, 2H), 8.20 (d, 2H), 8.13 (m, 2H), 7.97 (m, 4H), 7.87 (m, 3H), 7.50 (s, 2H), 7.43 (m, 8H), 7.19 (s, 2H), 7.08 (s, 4H), 6.91 (s, 2H), 1.38 (d, 36H).

ESI-LCMS: [M]+: C₇₆H₇₁BN₂O. 1038.5659

### (5) Synthesis of Compound 66

Fused Polycyclic Compound 66 according to an example may be synthesized, for example, by the reaction below.

(Synthesis of Intermediate 66-a) o-Dichlorobenzene

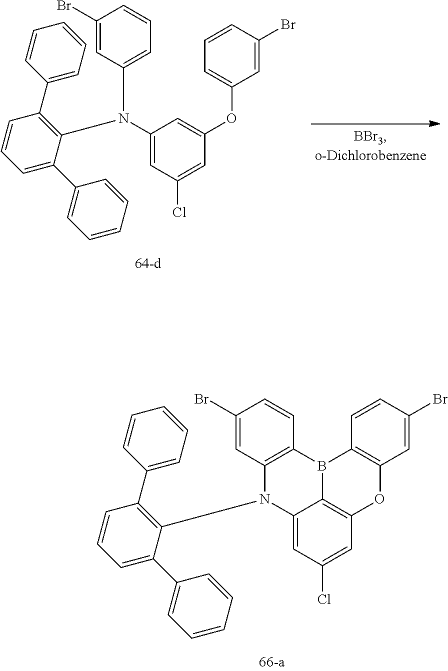 [SMILES: Clc1cc(Oc2cccc(Br)c2)cc(N(c2cccc(Br)c2)c2c(-c3ccccc3)cccc2-c2ccccc2)c1 ; Clc1cc2c3c(c1)N(c1c(-c4ccccc4)cccc1-c1ccccc1)c1cc(Br)ccc1B3c1ccc(Br)cc1O2]

Intermediate 66-a was synthesized in substantially the same manner as the synthesis of Compound 1 by using Intermediate 64-d instead of Intermediate 1-e (yield: 8%). The obtained solid was identified as Intermediate 66-a through ESI-LCMS.

ESI-LCMS: [M]+: C₃₆H₂₁BBr₂ClNO. 686.9771

### (Synthesis of Intermediate 66-b)

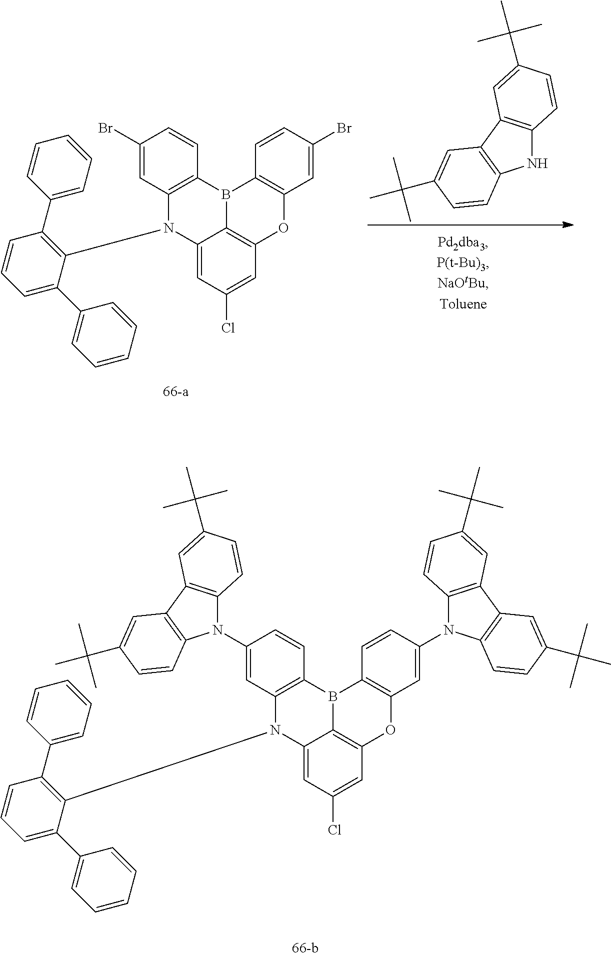 [SMILES: Clc1cc2c3c(c1)N(c1c(-c4ccccc4)cccc1-c1ccccc1)c1cc(Br)ccc1B3c1ccc(Br)cc1O2 ; CC(C)(C)c1ccc2[nH]c3ccc(C(C)(C)C)cc3c2c1 ; CC(C)(C)c1ccc2c(c1)c1cc(C(C)(C)C)ccc1n2-c1ccc2c(c1)Oc1cc(Cl)cc3c1B2c1ccc(-n2c4ccc(C(C)(C)C)cc4c4cc(C(C)(C)C)ccc42)cc1N3c1c(-c2ccccc2)cccc1-c1ccccc1]

Compound 66-b was synthesized in substantially the same manner as the synthesis of Compound 33 by using Intermediate 66-a instead of Intermediate 33-d and using toluene instead of o-xylene (yield: 72%). The obtained solid was identified as Intermediate 66-b through ESI-LCMS.

ESI-LCMS: [M]+: C₇₆H₆₉BClN₃O. 1085.5222

### (Synthesis of Compound 66)

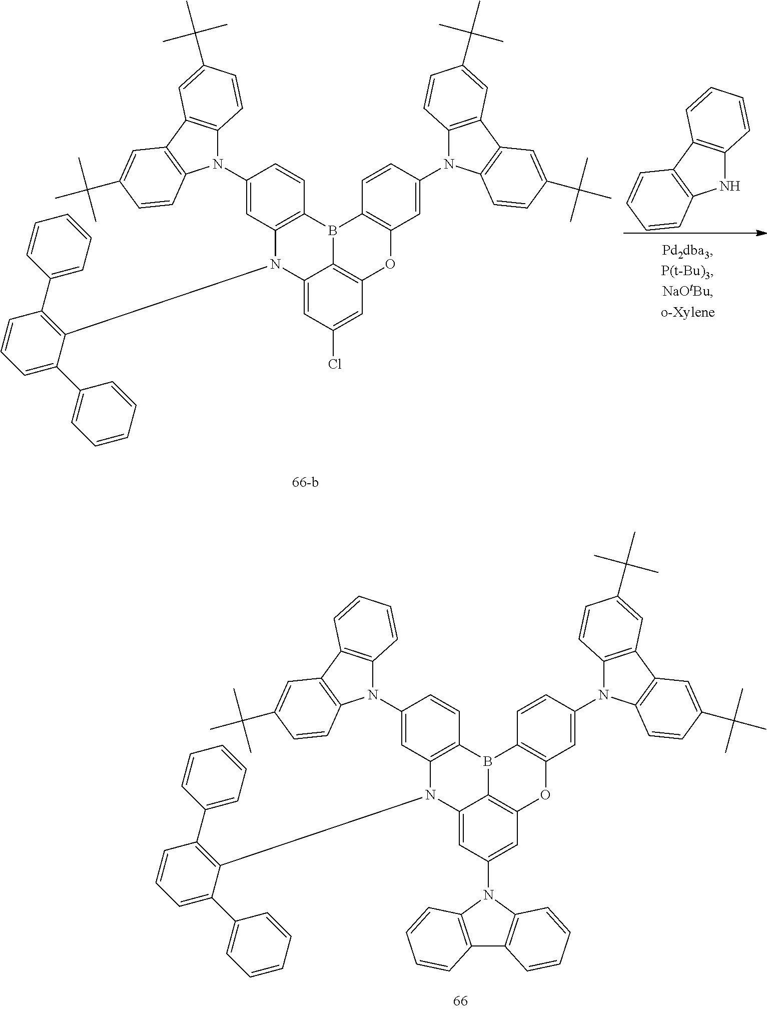

Compound 66 was synthesized in substantially the same manner as the synthesis of Compound 64 by using Intermediate 66-b instead of Intermediate 64-f (yield: 68%). The obtained yellow solid was identified as Compound 66 through ¹H-NMR and ESI-LCMS.

¹H-NMR (400 MHz, CDCl₃): d=9.35 (d, 2H), 8.78 (m, 4H), 8.52 (m, 4H), 8.31 (d, 6H), 8.25 (m, 6H), 7.91 (m, 2H), 7.87 (m, 3H), 7.77 (s, 2H), 7.68 (m, 4H), 7.19 (s, 2H), 7.08 (s, 4H), 6.91 (s, 2H), 1.38 (d, 36H).

ESI-LCMS: [M]+: C₈₈H₇₇BN₄O. 1216.6190

### (6) Synthesis of Compound 81

Fused Polycyclic Compound 81 according to an example may be synthesized, for example, by the reaction below.

### (Synthesis of Intermediate 81-a)

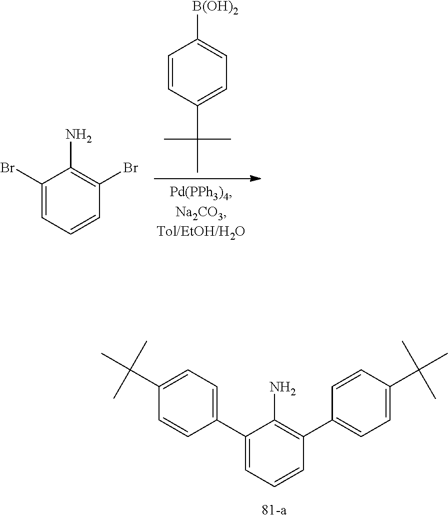

Intermediate 81-a was synthesized in substantially the same manner as the synthesis of Intermediate 64-e by using 2,6-dibromoaniline instead of Intermediate 64-d and using (4-(tert-butyl)phenyl)boronic acid (3 equiv.) instead of (3,5-di-tert-butylphenyl)boronic acid (yield: 75%). The obtained solid was identified as Intermediate 81-a through ESI-LCMS.

ESI-LCMS: [M]+: C₂₆H₃₁N. 357.2457

### (Synthesis of Intermediate 81-b)

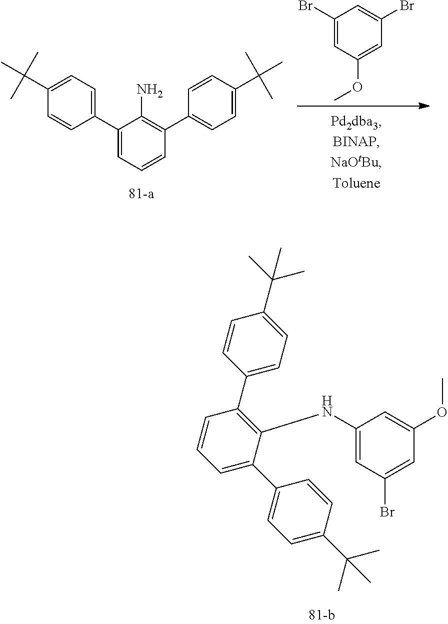

Intermediate 81-b was synthesized in substantially the same manner as the synthesis of Intermediate 1-a by using Intermediate 81-a instead of [1,1′:3′,1″-terphenyl]-2′-amine (yield: 67%). The obtained solid was identified as Intermediate 81-b through ESI-LCMS.

ESI-LCMS: [M]+: C₃₃H₃₆BrNO. 541.1980

### (Synthesis of Intermediate 81-c)

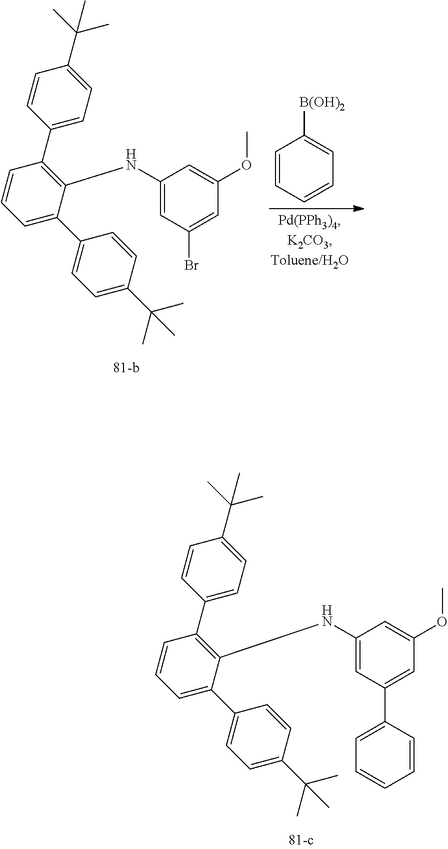

Intermediate 81-c was synthesized in substantially the same manner as the synthesis of Intermediate 1-b by using Intermediate 81-b instead of Intermediate 1-a (yield: 75%). The obtained solid was identified as Intermediate 81-c through ESI-LCMS.

ESI-LCMS: [M]+: C₃₉H₄₁NO. 539.3188

### (Synthesis of Intermediate 81-d)

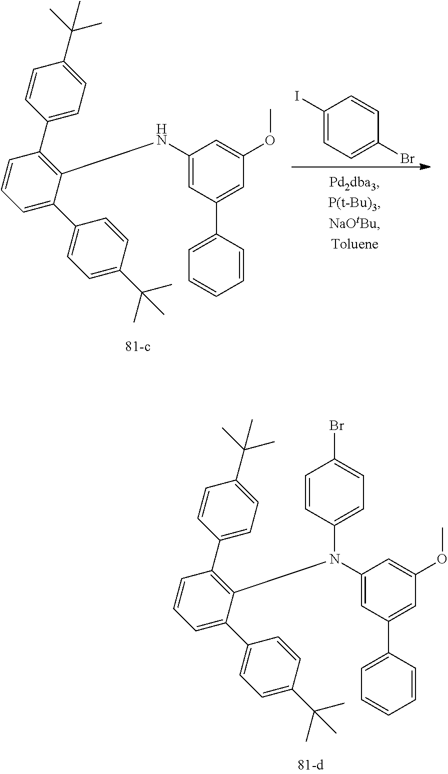

Intermediate 81-d was synthesized in substantially the same manner as the synthesis of Intermediate 1-c by using 1-bromo-4-iodobenzene instead of bromobenzene and using Intermediate 81-c instead of Intermediate 1-b (yield: 48%). The obtained solid was identified as Intermediate 81-d through ESI-LCMS.

ESI-LCMS: [M]+: C₄₅H₄₄BrNO. 693.2606

### (Synthesis of Intermediate 81-e)

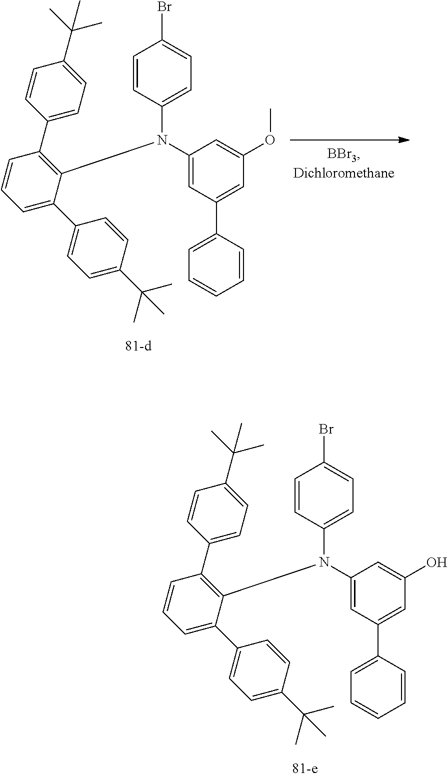 [SMILES: COc1cc(-c2ccccc2)cc(N(c2ccc(Br)cc2)c2c(-c3ccc(C(C)(C)C)cc3)cccc2-c2ccc(C(C)(C)C)cc2)c1 ; CC(C)(C)c1ccc(-c2cccc(-c3ccc(C(C)(C)C)cc3)c2N(c2ccc(Br)cc2)c2cc(O)cc(-c3ccccc3)c2)cc1]

Intermediate 81-e was synthesized in substantially the same manner as the synthesis of Intermediate 1-d by using Intermediate 81-d instead of Intermediate 1-c (yield: 65%). The obtained solid was identified as Intermediate 81-e through ESI-LCMS.

ESI-LCMS: [M]+: C₄₄H₄₂BrNO. 679.2450

### (Synthesis of Intermediate 81-f)

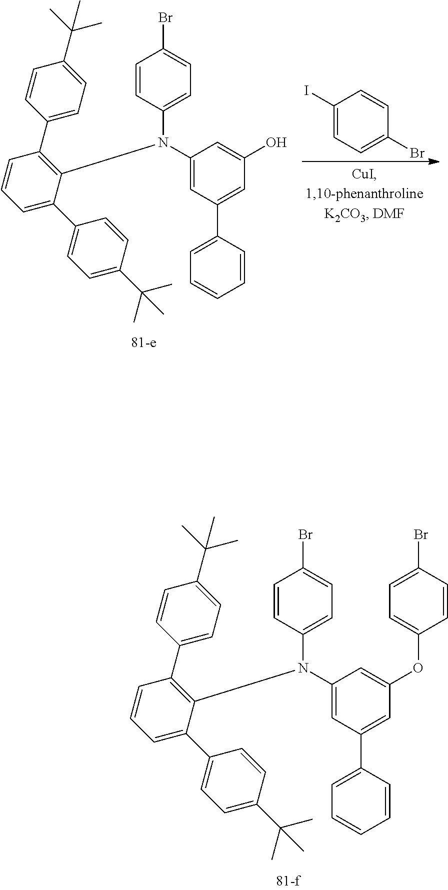 [SMILES: CC(C)(C)c1ccc(-c2cccc(-c3ccc(C(C)(C)C)cc3)c2N(c2ccc(Br)cc2)c2cc(O)cc(-c3ccccc3)c2)cc1 ; Brc1ccc(I)cc1 ; CC(C)(C)c1ccc(-c2cccc(-c3ccc(C(C)(C)C)cc3)c2N(c2ccc(Br)cc2)c2cc(Oc3ccc(Br)cc3)cc(-c3ccccc3)c2)cc1]

Intermediate 81-f was synthesized in substantially the same manner as the synthesis of Intermediate 1-e by using Intermediate 81-e instead of Intermediate 1-d and using 1-bromo-4-iodobenzene instead of bromobenzene (yield: 51%). The obtained solid was identified as Intermediate 81-f through ESI-LCMS.

ESI-LCMS: [M]+: C₅₀H₄₂Br₂NO. 833.1868

### (Synthesis of Intermediate 81-g)

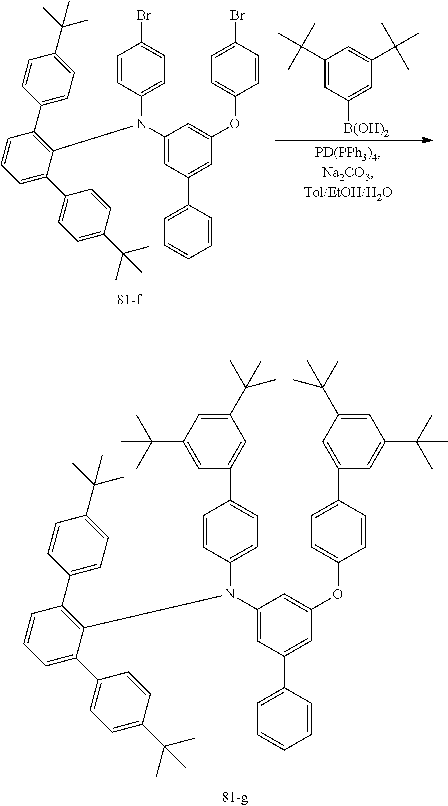

Intermediate 81-g was synthesized in substantially the same manner as the synthesis of Intermediate 64-e by using Intermediate 81-f instead of Intermediate 64-d (yield: 73%). The obtained solid was identified as Intermediate 81-g through ESI-LCMS.

ESI-LCMS: [M]+: C₇₈H₈₇NO. 1053.6788

### (Synthesis of Compound 81)

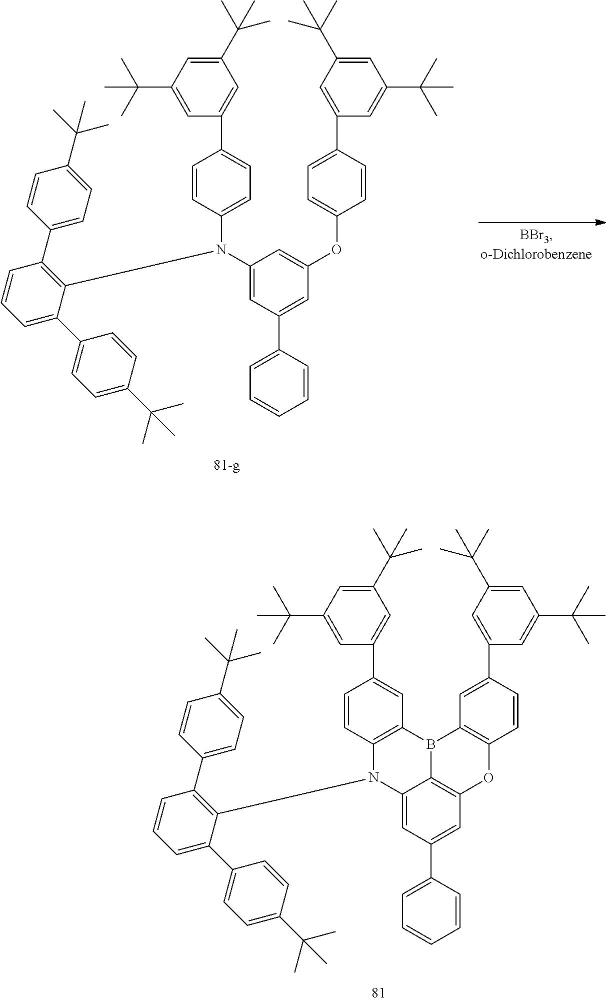 [SMILES: CC(C)(C)c1ccc(-c2cccc(-c3ccc(C(C)(C)C)cc3)c2N(c2ccc(-c3cc(C(C)(C)C)cc(C(C)(C)C)c3)cc2)c2cc(Oc3ccc(-c4cc(C(C)(C)C)cc(C(C)(C)C)c4)cc3)cc(-c3ccccc3)c2)cc1 ; CC(C)(C)c1ccc(-c2cccc(-c3ccc(C(C)(C)C)cc3)c2N2c3ccc(-c4cc(C(C)(C)C)cc(C(C)(C)C)c4)cc3B3c4cc(-c5cc(C(C)(C)C)cc(C(C)(C)C)c5)ccc4Oc4cc(-c5ccccc5)cc2c43)cc1]

Compound 81 was synthesized in substantially the same manner as the synthesis of Compound 1 by using Intermediate 81-g instead of Intermediate 1-e (yield: 8%). The obtained yellow solid was identified as Compound 81 through ¹H-NMR and ESI-LCMS.

¹H-NMR (400 MHz, CDCl₃): d=9.11 (d, 2H), 7.86 (d, 2H), 7.79 (m, 6H), 7.65 (m, 4H), 7.55 (m, 8H), 7.41-7.24 (m, 4H), 7.11 (d, 2H), 6.83 (s, 2H), 1.43 (s, 18H), 1.38 (d, 36H).

ESI-LCMS: [M]+: C₇₈H₈₄BNO. 1061.6646

### (7) Synthesis of Compound 101

Fused Polycyclic Compound 101 according to an example may be synthesized, for example, by the reaction below.

### (Synthesis of Intermediate 101-a)

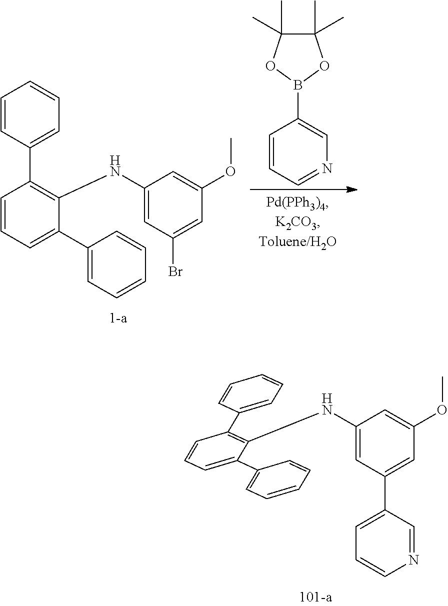

Intermediate 101-a was synthesized in substantially the same manner as the synthesis of Intermediate 1-b by using 3-(4,4,5,5-tetramethyl-1,3,2-dioxaborolan-2-yl)pyridine instead of phenyl boronic acid (yield: 51%). The obtained solid was identified as Intermediate 101-a through ESI-LCMS.

ESI-LCMS: [M]+: C₃₀H₂₄N₂O. 428.1889

### (Synthesis of Intermediate 101-b)

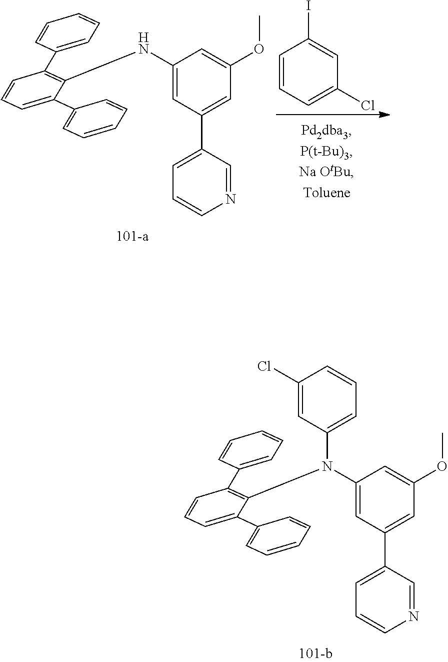

Intermediate 101-b was synthesized in substantially the same manner as the synthesis of Intermediate 1-c by using 1-chloro-3-iodobenzene instead of bromobenzene and using Intermediate 101-a instead of Intermediate 1-b (yield: 55%). The obtained solid was identified as Intermediate 101-b through ESI-LCMS.

ESI-LCMS: [M]+: C₃₆H₂₇ClN₂O. 538.1812

### (Synthesis of Intermediate 101-c)

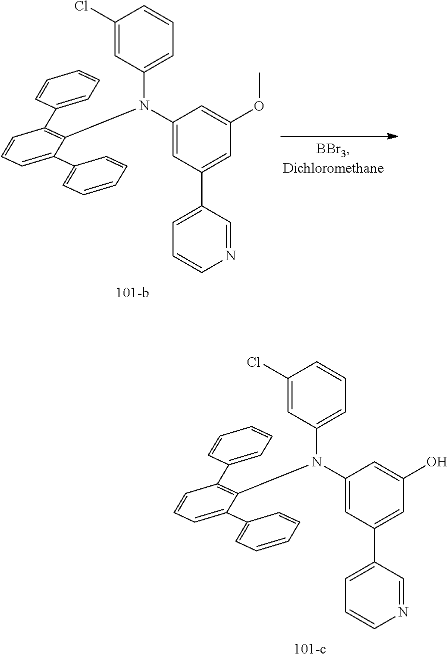 [SMILES: COc1cc(-c2cccnc2)cc(N(c2cccc(Cl)c2)c2c(-c3ccccc3)cccc2-c2ccccc2)c1 ; Oc1cc(-c2cccnc2)cc(N(c2cccc(Cl)c2)c2c(-c3ccccc3)cccc2-c2ccccc2)c1]

Intermediate 101-c was synthesized in substantially the same manner as the synthesis of Intermediate 1-d by using Intermediate 101-b instead of Intermediate 1-c (yield: 61%). The obtained solid was identified as Intermediate 101-c through ESI-LCMS.

ESI-LCMS: [M]+: C₃₅H₂₅ClN₂O. 524.1655

### (Synthesis of Intermediate 101-d)

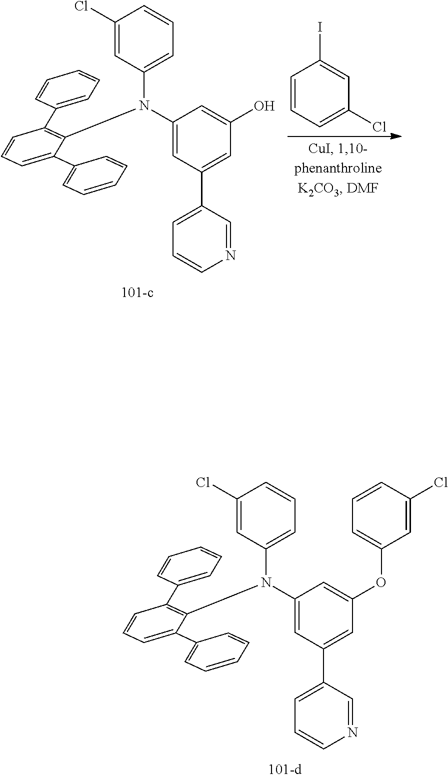

Intermediate 101-d was synthesized in substantially the same manner as the synthesis of Intermediate 1-e by using Intermediate 101-c instead of Intermediate 1-d and using 1-chloro-3-iodobenzene instead of bromobenzene (yield: 58%). The obtained solid was identified as Intermediate 101-d through ESI-LCMS.

ESI-LCMS: [M]+: C₄₁H₂₈Cl₂N₂O. 634.1579

### (Synthesis of Intermediate 101-e)

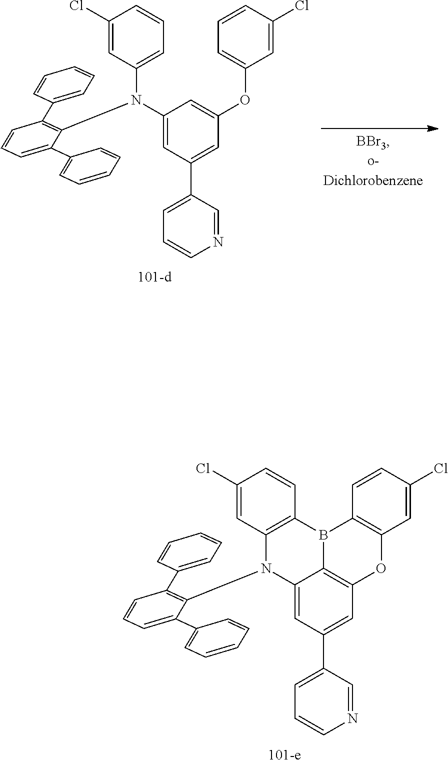 [SMILES: Clc1cccc(Oc2cc(-c3cccnc3)cc(N(c3cccc(Cl)c3)c3c(-c4ccccc4)cccc3-c3ccccc3)c2)c1 ; Clc1ccc2c(c1)Oc1cc(-c3cccnc3)cc3c1B2c1ccc(Cl)cc1N3c1c(-c2ccccc2)cccc1-c1ccccc1]

Intermediate 101-e was synthesized in substantially the same manner as the synthesis of Compound 1 by using Intermediate 101-d instead of Intermediate 1-e (yield: 6%). The obtained solid was identified as Intermediate 101-e through ESI-LCMS.

ESI-LCMS: [M]+: C₄₁H₂₅BCl₂N₂O. 642.1437

### (Synthesis of Compound 101)

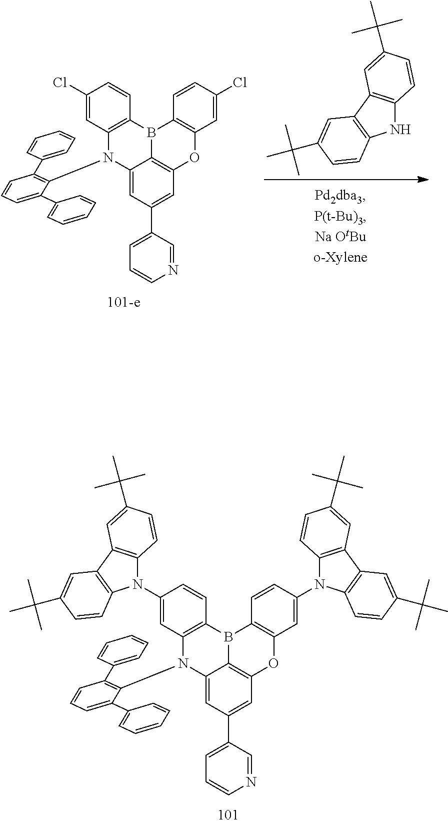 [SMILES: Clc1ccc2c(c1)Oc1cc(-c3cccnc3)cc3c1B2c1ccc(Cl)cc1N3c1c(-c2ccccc2)cccc1-c1ccccc1 ; CC(C)(C)c1ccc2[nH]c3ccc(C(C)(C)C)cc3c2c1 ; CC(C)(C)c1ccc2c(c1)c1cc(C(C)(C)C)ccc1n2-c1ccc2c(c1)Oc1cc(-c3cccnc3)cc3c1B2c1ccc(-n2c4ccc(C(C)(C)C)cc4c4cc(C(C)(C)C)ccc42)cc1N3c1c(-c2ccccc2)cccc1-c1ccccc1]

Compound 101 was synthesized in substantially the same manner as the synthesis of Compound 33 by using Intermediate 101-e instead of Intermediate 33-d (yield: 64%). The obtained yellow solid was identified as Compound 101 through ¹H-NMR and ESI-LCMS.

¹H-NMR (400 MHz, CDCl₃): d=9.35 (d, 2H), 8.70 (s, 1H), 8.56 (m, 4H), 8.33 (m, 5H), 8.13 (m, 3H), 7.95 (d, 2H), 7.87 (m, 5H), 7.50 (d, 2H), 7.41 (m, 4H), 7.21 (m, 3H), 7.11 (m, 4H), 6.78 (s, 2H), 1.43 (s, 36H).

ESI-LCMS: [M]+: C₈₁H₇₃BN₄O. 1128.5877

### (8) Synthesis of Compound 104

Fused polycyclic compound 104 according to an example may be synthesized by, for example, the reaction below.

### (Synthesis of Intermediate 104-a)

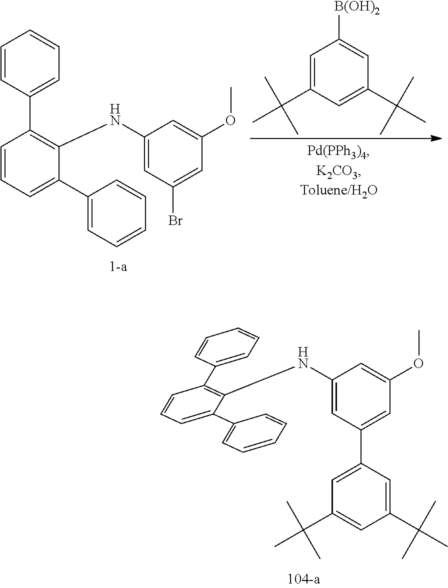

Intermediate 104-a was synthesized in substantially the same manner as the synthesis of Intermediate 1-b by using (3,5-di-tert-butylphenyl)boronic acid instead of phenyl boronic acid (yield: 72%). The obtained solid was identified as Intermediate 104-a through ESI-LCMS.

ESI-LCMS: [M]+: C₃₉H₄₁NO. 539.3188

### (Synthesis of Intermediate 104-b)

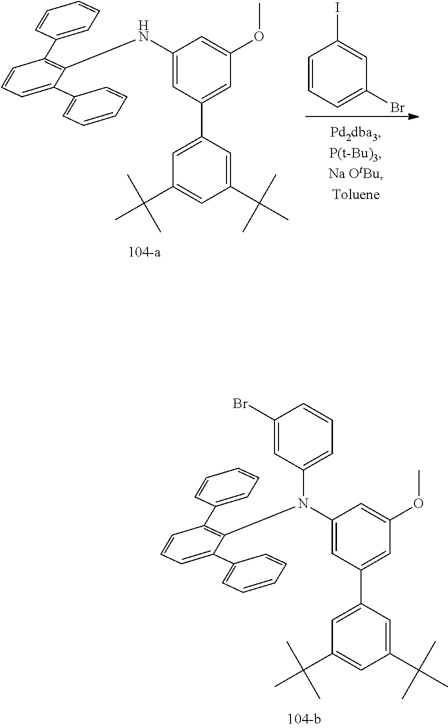 [SMILES: COc1cc(Nc2c(-c3ccccc3)cccc2-c2ccccc2)cc(-c2cc(C(C)(C)C)cc(C(C)(C)C)c2)c1 ; Brc1cccc(I)c1 ; COc1cc(-c2cc(C(C)(C)C)cc(C(C)(C)C)c2)cc(N(c2cccc(Br)c2)c2c(-c3ccccc3)cccc2-c2ccccc2)c1]

Intermediate 104-b was synthesized in substantially the same manner as the synthesis of Intermediate 1-c by using 1-bromo-3-iodobenzene instead of bromobenzene and using Intermediate 104-a instead of Intermediate 1-b (yield: 53%). The obtained solid was identified as Intermediate 104-b through ESI-LCMS.

ESI-LCMS: [M]+: C₄₅H₄₄BrNO. 693.2606

### (Synthesis of Intermediate 104-c)

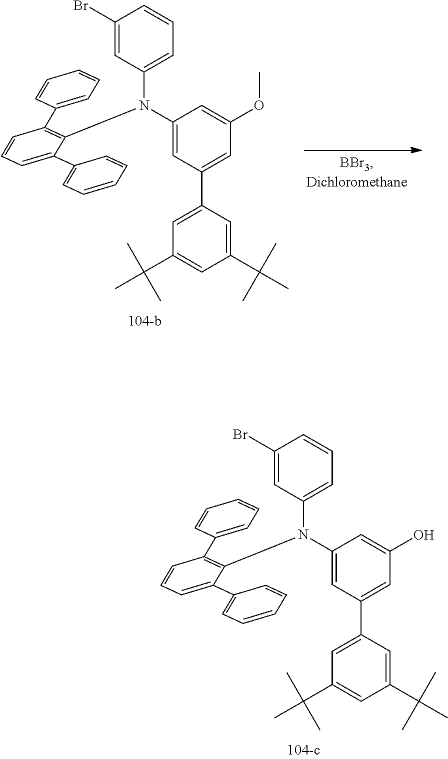 [SMILES: COc1cc(-c2cc(C(C)(C)C)cc(C(C)(C)C)c2)cc(N(c2cccc(Br)c2)c2c(-c3ccccc3)cccc2-c2ccccc2)c1 ; CC(C)(C)c1cc(-c2cc(O)cc(N(c3cccc(Br)c3)c3c(-c4ccccc4)cccc3-c3ccccc3)c2)cc(C(C)(C)C)c1]

Intermediate 104-c was synthesized in substantially the same manner as the synthesis of Intermediate 1-d by using Intermediate 104-b instead of Intermediate 1-c (yield: 58%). The obtained solid was identified as Intermediate 104-c through ESI-LCMS.

ESI-LCMS: [M]+: C₄₄H₄₂BrNO. 679.2450

### (Synthesis of Intermediate 104-d)

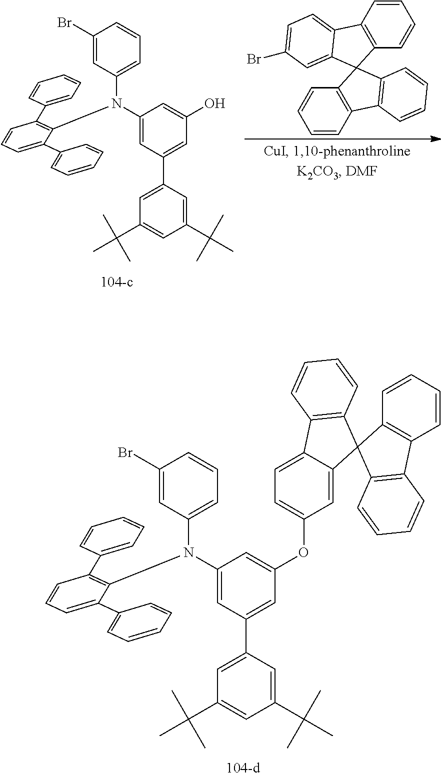 [SMILES: CC(C)(C)c1cc(-c2cc(O)cc(N(c3cccc(Br)c3)c3c(-c4ccccc4)cccc3-c3ccccc3)c2)cc(C(C)(C)C)c1 ; Brc1ccc2c(c1)C1(c3ccccc3-c3ccccc31)c1ccccc1-2 ; CC(C)(C)c1cc(-c2cc(Oc3ccc4c(c3)C3(c5ccccc5-c5ccccc53)c3ccccc3-4)cc(N(c3cccc(Br)c3)c3c(-c4ccccc4)cccc3-c3ccccc3)c2)cc(C(C)(C)C)c1]

Intermediate 104-d was synthesized in substantially the same manner as the synthesis of Intermediate 1-e by using Intermediate 104-c instead of Intermediate 1-d and using 2-bromo-9,9′-spirobi[fluorene] instead of bromobenzene (yield: 45%). The obtained solid was identified as Intermediate 104-d through ESI-LCMS.

ESI-LCMS: [M]+: C₆₉H₅₆BrNO. 993.3545

### (Synthesis of Intermediate 104-e)

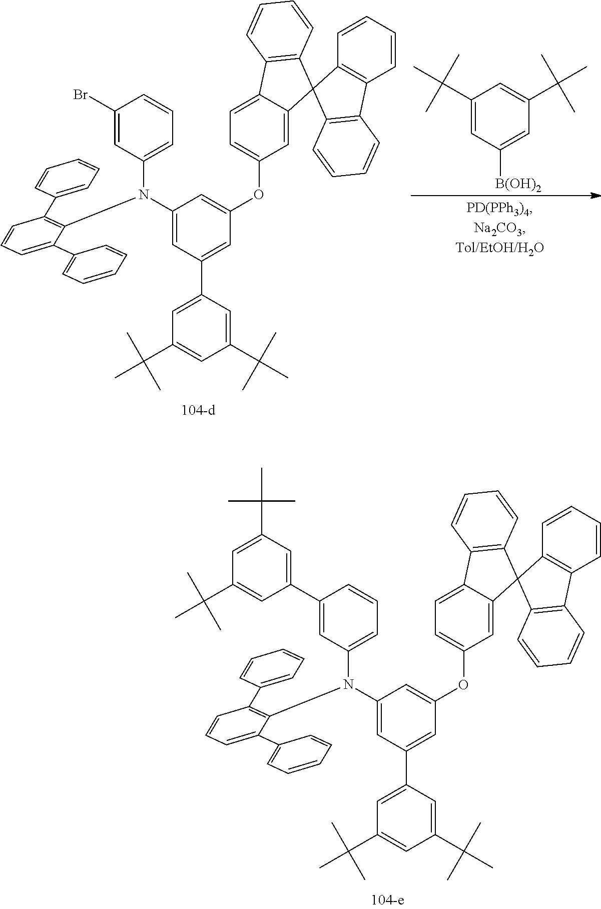

Intermediate 104-e was synthesized in substantially the same manner as the synthesis of Intermediate 64-e by using Intermediate 104-d instead of Intermediate 64-d (yield: 65%). The obtained solid was identified as Intermediate 104-e through ESI-LCMS.

ESI-LCMS: [M]+: C₈₃H₇₇NO. 1103.6005

### (Synthesis of Compound 104)

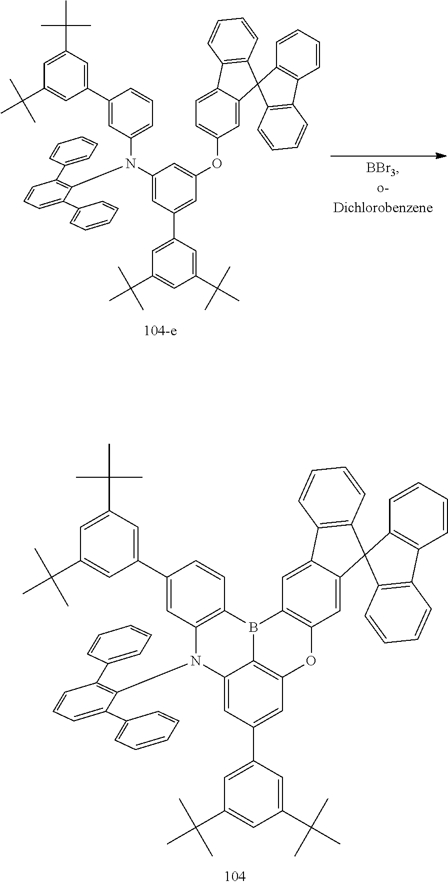 [SMILES: CC(C)(C)c1cc(-c2cccc(N(c3cc(Oc4ccc5c(c4)C4(c6ccccc6-c6ccccc64)c4ccccc4-5)cc(-c4cc(C(C)(C)C)cc(C(C)(C)C)c4)c3)c3c(-c4ccccc4)cccc3-c3ccccc3)c2)cc(C(C)(C)C)c1 ; CC(C)(C)c1cc(-c2ccc3c(c2)N(c2c(-c4ccccc4)cccc2-c2ccccc2)c2cc(-c4cc(C(C)(C)C)cc(C(C)(C)C)c4)cc4c2B3c2cc3c(cc2O4)C2(c4ccccc4-c4ccccc42)c2ccccc2-3)cc(C(C)(C)C)c1]

Compound 104 was synthesized in substantially the same manner as the synthesis of Compound 1 by using Intermediate 104-e instead of Intermediate 1-e (yield: 5%). The obtained yellow solid was identified as Compound 104 through ¹H-NMR and ESI-LCMS.

¹H-NMR (400 MHz, CDCl₃): d=9.13 (d, 2H), 7.87 (d, 2H), 7.80 (m, 6H), 7.63 (m, 6H), 7.58 (m, 8H), 7.41-7.24 (m, 6H), 7.18 (m, 6H), 6.83 (s, 2H), 1.38 (s, 18H), 1.32 (d, 18H).

ESI-LCMS: [M]+: C₈₇H₇₄BNO. 1111.5863

### 2. Manufacture and Evaluation of Light Emitting Device Including Fused Polycyclic Compound

The light emitting device of an example including the fused polycyclic compound of an example in an emission layer was manufactured as follows. Fused polycyclic compounds of Compounds 1, 33, 53, 64, 66, 81, 101, and 104, which are Example Compounds as described above were used as dopant materials for the emission layers to manufacture the light emitting devices of Examples 1 to 8, respectively. Comparative Examples 1 to 3 correspond to the light emitting devices manufactured by using Comparative Example Compounds C1 to C3 as emission layer dopant materials, respectively.

### [Example Compounds]

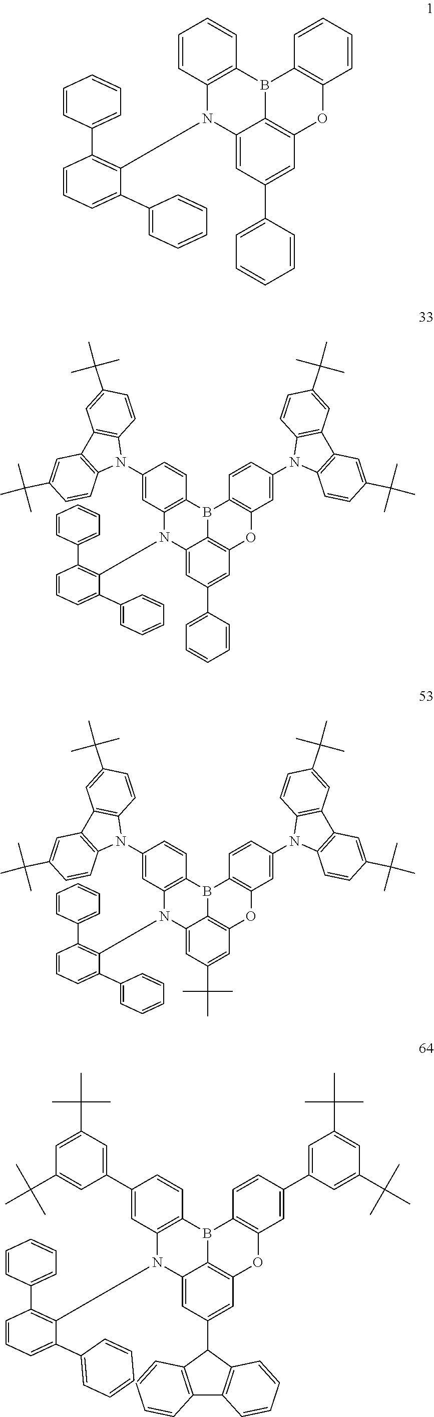

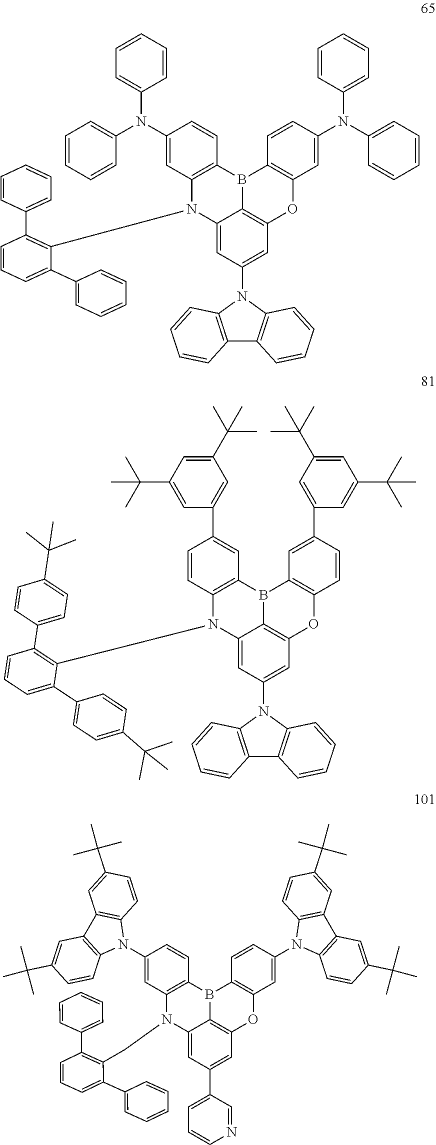

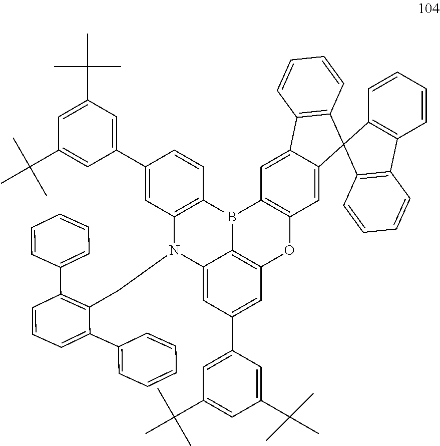 [SMILES: CC(C)(C)c1cc(-c2ccc3c(c2)N(Cc2c(-c4ccccc4)cccc2-c2ccccc2)c2cc(-c4cc(C(C)(C)C)cc(C(C)(C)C)c4)cc4c2B3c2cc3c(cc2O4)C2(c4ccccc4-c4ccccc42)c2ccccc2-3)cc(C(C)(C)C)c1]

### [Comparative Example Compounds]

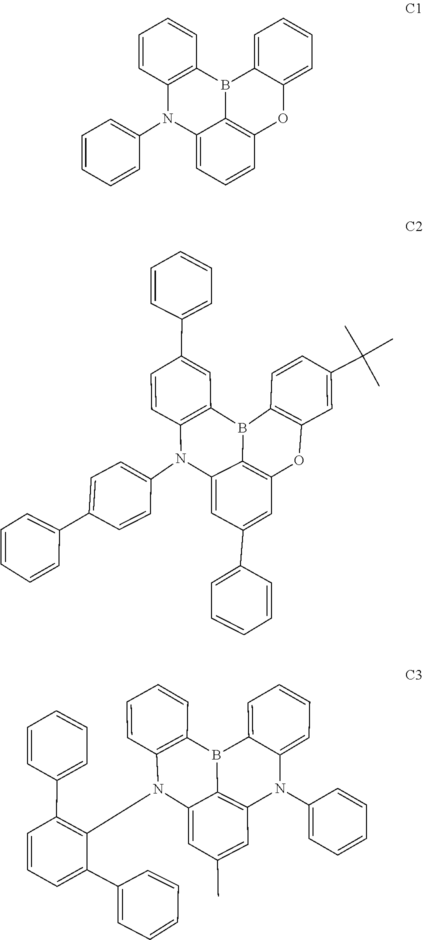 [SMILES: c1ccc(N2c3ccccc3B3c4ccccc4Oc4cccc2c43)cc1 ; CC(C)(C)c1ccc2c(c1)Oc1cc(-c3ccccc3)cc3c1B2c1cc(-c2ccccc2)ccc1N3c1ccc(-c2ccccc2)cc1 ; Cc1cc2c3c(c1)N(c1c(-c4ccccc4)cccc1-c1ccccc1)c1ccccc1B3c1ccccc1N2c1ccccc1]

### (Manufacture of Light Emitting Device)

With respect to the light emitting devices of Examples and Comparative Examples, an ITO glass substrate was cut to a size of about 50 mm×50 mm×0.7 mm, washed by ultrasonic waves using isopropyl alcohol and distilled water for about 5 minutes, respectively, and then irradiated with ultraviolet rays for about 30 minutes and cleansed by exposing to ozone, and then installed on a vacuum deposition apparatus. Then, NPD was used to form a hole injection layer having a thickness of about 300 Å, HT-1-19 was used to form a hole transport layer having a thickness of about 200 Å, and then CzSi was used to form an emission auxiliary layer having about 100 Å. Then, a host compound in which the first host and the second host according to an embodiment were mixed together in an amount of about 1:1, the second dopant, and Example Compound or Comparative Example Compound were co-deposited in a weight ratio of about 85:14:1 to form a 200 Å-thick emission layer EML, and TSPO1 was used to form a 200 Å-thick electron transport layer ETL. Next, TPBi, a buffer electron transporting compound, was used to form a 300 Å-thick buffer layer, and LiF was used to form 10 Å-thick electron injection layer EIL. Al was then used to form a 3,000 Å-thick second electrode EL2 to form a LiF/Al electrode. Then, on the upper portion of the second electrode, P4 was used to form a 700 Å-thick capping layer. Each layer was formed by a vacuum deposition method. HTH29 among the compounds in Compound Group 2 as described above was used as the first host, ETH66 among the compounds in Compound Group 3 as described above was used as the second host, and AD-37 among the compounds in Compound Group 4 as described above was used as the second dopant (sensitizer).

Compounds used for manufacturing the light emitting devices of Examples and Comparative Examples are disclosed below. The materials below were used to manufacture the elements by subjecting commercial products to sublimation purification.

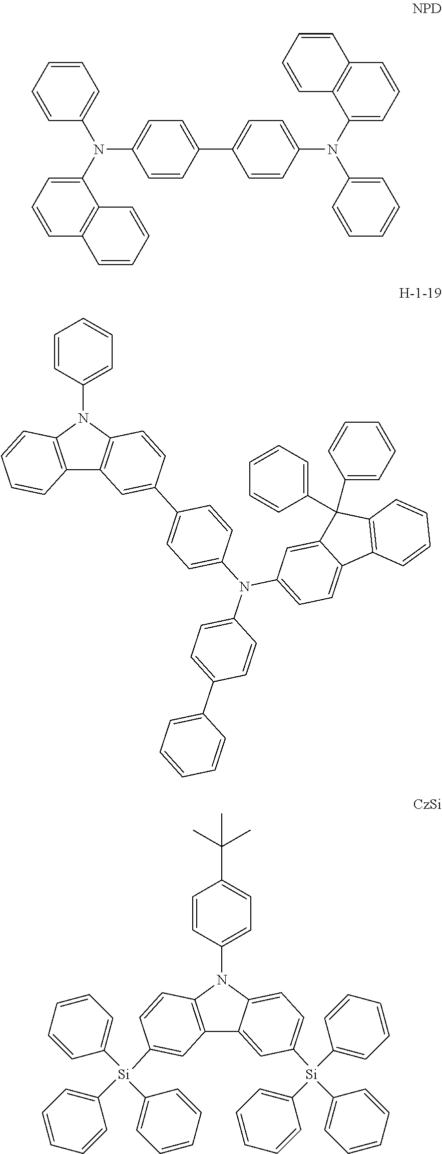

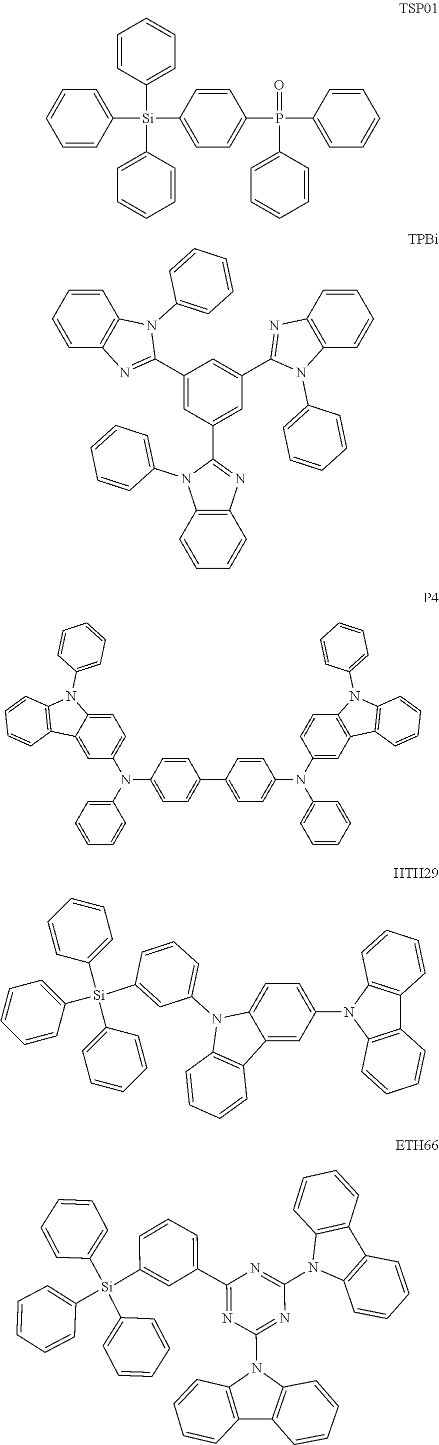 [SMILES: O=P(c1ccccc1)(c1ccccc1)c1ccc([Si](c2ccccc2)(c2ccccc2)c2ccccc2)cc1 ; c1ccc(-n2c(-c3cc(-c4nc5ccccc5n4-c4ccccc4)cc(-c4nc5ccccc5n4-c4ccccc4)c3)nc3ccccc32)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; c1ccc([Si](c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1]

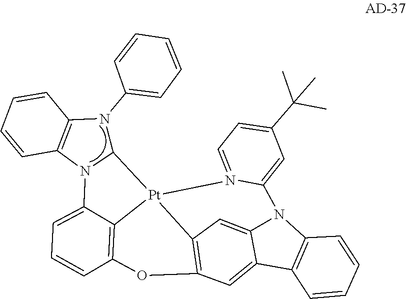

### (Evaluation of Physical Properties of Example and Comparative Example Compounds)

Physical properties of Compounds 1, 33, 53, 64, 66, 81, 101, and 104, which are Example Compounds, and Comparative Example Compounds C1 to C3, which are Comparative Example Compounds are evaluated and the results are listed in Table 1 below.

The lowest unoccupied molecular orbital (LUMO) energy level, highest occupied molecular orbital (HOMO) energy level, lowest singlet exciton energy level (S1), lowest triplet exciton energy level (Ti), difference (S1−T1, hereinafter ΔE_{ST}) between the lowest singlet exciton energy level (S1) and lowest triplet exciton energy level (T1), delayed fluorescence service life (T), luminous efficiency (photoluminescence quantum yield, PLQY), absorption wavelength in a solution phase (λ_{Abs}), luminescence wavelength in a solution phase (λₑₘᵢ), luminescence wavelength on a deposited film (λ_{film}), Stokes-shift, and full width at quarter maximum (FWQM) were measured in the Example Compounds and the Comparative Example Compounds, and the results are listed in Table 1 below:

TABLE 1

| | | HOMO | LUMO | S1 | T1 | ΔE_{ST} | τ | PLQY | λ_{Abs} | λₑₘᵢ | λ_{film} | Stokes- | FWQM |
|---|---|---|---|---|---|---|---|---|---|---|---|---|---|
| | Dopant | (eV) | (eV) | (eV) | (eV) | (eV) | (μs) | (%) | (nm) | (nm) | (nm) | shift | (nm) |
| Example 1 | Compound | −5.21 | −2.05 | 2.83 | 2.60 | 0.23 | 176 | 84 | 431 | 443 | 446 | 12 | 42 |
| | 1 | | | | | | | | | | | | |
| Example 2 | Compound | −5.43 | −2.45 | 2.73 | 2.54 | 0.19 | 130 | 93 | 437 | 450 | 453 | 13 | 43 |
| | 33 | | | | | | | | | | | | |
| Example 3 | Compound | −5.34 | −2.05 | 2.80 | 2.63 | 0.17 | 116 | 90 | 434 | 448 | 451 | 14 | 45 |
| | 53 | | | | | | | | | | | | |
| Example 4 | Compound | −5.30 | −2.11 | 2.81 | 2.62 | 0.19 | 88 | 87 | 435 | 445 | 448 | 10 | 42 |
| | 64 | | | | | | | | | | | | |
| Example 5 | Compound | −5.42 | −2.09 | 2.83 | 2.62 | 0.21 | 83 | 188 | 430 | 442 | 445 | 12 | 41 |
| | 66 | | | | | | | | | | | | |
| Example 6 | Compound | −5.26 | −2.20 | 2.75 | 2.52 | 0.23 | 153 | 92 | 437 | 450 | 452 | 13 | 42 |
| | 81 | | | | | | | | | | | | |
| Example 7 | Compound | −5.34 | −2.21 | 2.71 | 2.55 | 10.16 | 122 | 90 | 442 | 455 | 458 | 12 | 42 |
| | 101 | | | | | | | | | | | | |
| Example 8 | Compound | −5.28 | −2.32 | 2.73 | 2.52 | 0.21 | 152 | 86 | 446 | 457 | 459 | 11 | 43 |
| | 104 | | | | | | | | | | | | |
| Comparative | Compound | −5.12 | −1.84 | 2.82 | 2.54 | 0.28 | 242 | 80 | 418 | 430 | 440 | 12 | 46 |
| Example 1 | C1 | | | | | | | | | | | | |
| Comparative | Compound | −5.22 | −2.01 | 2.77 | 12.50 | 0.25 | 190 | 83 | 422 | 437 | 447 | 15 | 45 |
| Example 2 | C2 | | | | | | | | | | | | |
| Comparative | Compound | −5.13 | −2.12 | 2.72 | 2.47 | 0.25 | 170 | 88 | 435 | 447 | 456 | 12 | 43 |
| Example 3 | C3 | | | | | | | | | | | | |

Referring to Table 1, it can be seen that compounds of Examples 1 to 8 have lower ΔE_{ST} values than compounds of Comparative Examples 1 to 3, the delayed fluorescence characteristics may be increased, thereby improving the luminous efficiency.

In addition, the Example Compounds included in Examples 1 to 8 have shorter delayed fluorescence service lives (τ), higher luminous efficiencies (PLQY), and smaller FWQM than compounds included in Comparative Examples 1 and 2. For FWQM, it may be seen that the FWQM of Example Compounds included in Examples 1 to 8 are smaller than those of Comparative Example Compounds C1 and C2 included in Comparative Examples 1 and 2. In addition, it may be seen that Example Compounds exhibit high color purity because the differences between the luminescence wavelengths (λₑₘᵢ) measured in a solution state and luminescence wavelengths (λ_{film}) measured in a deposited film state of Example Compounds is smaller than those of Comparative Example Compounds included in Comparative Examples 1 to 3. Therefore, the light emitting devices of Examples 1 to 8 may exhibit higher luminous efficiencies, improved device service lives, and higher color purities as compared with the light emitting devices of Comparative Examples 1 to 3.

### (Evaluation of Light Emitting Device Characteristics)

Driving voltages, luminous efficiencies, luminescence wavelengths, FWQMs, service life ratios, color diagrams (CIE), and quantum efficiencies of the light emitting devices manufactured with Example Compounds 1, 33, 53, 64, 66, 81, 101, and 104, and Comparative Example Compounds C1 to C3 as described above were evaluated. Evaluation results of the light emitting devices of Examples 1 to 8 and Comparative Examples 1 to 3 are listed in Table 2. In the characteristic evaluation results of Examples and Comparative Examples listed in Table 2, driving voltages and current densities were measured by using a V7000 OLED IVL Test System (Polaronix). To evaluate the characteristics of the light emitting devices manufactured in Examples 1 to 8 and Comparative Examples 1 to 3, driving voltages and efficiencies (cd/A) at a current density of 10 mA/cm² were measured, and the relative device service life was set as a numerical value in which the deterioration time from an initial value to 50% brightness when the device was continuously operated at a current density of 10 mA/cm² was compared to Comparative Example 1, and then the evaluation was carried out.

TABLE 2

| | Second | | | Driving | | Luminescence | Half-width | Service | | |
|---|---|---|---|---|---|---|---|---|---|---|
| | compound/Third | Fourth | First | voltage | Efficiency | wavelength | FWQM | life ratio | CIE | Q.E |
| | compound | compound | compound | (V) | (cd/A) | (nm) | (nm) | (T95) | (x, y) | (%) |
| Example 1 | HTH29/ETH66 | AD-37 | Compound | 4.4 | 4.8 | 446 | 46 | 3.3 | 0.141, | 8.0 |
| | | | 1 | | | | | | 0.103 | |
| Example 2 | HTH29/ETH66 | AD-37 | Compound | 4.5 | 8.6 | 453 | 48 | 6.8 | 0.140, | 11.0 |
| | | | 33 | | | | | | 0.111 | |
| Example 3 | HTH29/ETH66 | AD-37 | Compound | 4.3 | 7.8 | 451 | 47 | 7.1 | 0.141, | 10.3 |
| | | | 53 | | | | | | 0.113 | |
| Example 4 | HTH29/ETH66 | AD-37 | Compound | 4.4 | 8.1 | 448 | 48 | 5.9 | 0.139, | 10.5 |
| | | | 64 | | | | | | 0.116 | |
| Example 5 | HTH29/ETH66 | AD-37 | Compound | 4.2 | 7.3 | 445 | 46 | 5.5 | 0.135, | 10.1 |
| | | | 66 | | | | | | 0.108 | |
| Example 6 | HTH29/ETH66 | AD-37 | Compound | 4.3 | 5.3 | 452 | 47 | 5.1 | 0.140, | 8.1 |
| | | | 81 | | | | | | 0.103 | |
| Example 7 | HTH29/ETH66 | AD-37 | Compound | 4.1 | 9.6 | 458 | 46 | 8.4 | 0.138. | 13.6 |
| | | | 101 | | | | | | 0.113 | |
| Example 8 | HTH29/ETH66 | AD-37 | Compound | 4.4 | 9.4 | 459 | 48 | 9.1 | 0.139, | 11.3 |
| | | | 104 | | | | | | 0.109 | |
| Comparative | HTH29/ETH66 | AD-37 | Compound | 5.5 | 2.4 | 440 | 48 | 1.0 | 0.133, | 5.0 |
| Example 1 | | | C1 | | | | | | 0.135 | |
| Comparative | HTH29/ETH66 | AD-37 | Compound | 4.9 | 4.3 | 447 | 50 | 1.4 | 0.134, | 7.5 |
| Example 2 | | | C2 | | | | | | 0.098 | |
| Comparative | HTH29/ETH66 | AD-37 | Compound | 4.7 | 6.1 | 456 | 48 | 1.1 | 0.148, | 7.8 |
| Example 3 | | | C3 | | | | | | 0.051 | |

Referring to the results of Table 2, it may be seen that Examples of the light emitting devices in which the fused polycyclic compounds according to examples of the present disclosure are used as a luminescent material exhibit lower driving voltages, higher luminous efficiencies, improved device service life characteristics, and higher quantum efficiencies as compared with the Comparative Examples. In addition, it may be seen that the Examples cause a blue shift of the luminescence wavelengths, and thus, exhibit color purities closer to neutral blue.

The Example Compounds have a structure in which a plurality of aromatic rings are fused around at least one boron atom, at least one nitrogen atom, and at least one oxygen atom, thereby increasing multiple resonance effects and having a low ΔE_{ST}. Accordingly, because reverse intersystem crossing (RISC) from the triplet excited state to the singlet excited state easily occurs, delayed fluorescence characteristics may be enhanced, thereby improving the luminous efficiency.

In addition, the Example Compounds include the first substituent, which is a steric hindrance substituent, at the nitrogen atom constituting the fused ring, and thus, may effectively protect the boron atom, thereby achieving high efficiency and long service life. The Example Compounds may have an increase in the luminous efficiency and may suppress or reduce the red shift of luminescence wavelength because the intermolecular interaction may be suppressed or reduced by the introduction of the first substituent, thereby controlling the formation of an excimer or exciplex. In addition, the Example Compounds have an increase in the distance between adjacent molecules due to the large steric hindrance structure to thereby suppress or reduce the Dexter energy transfer, and thus, may suppress or reduce the deterioration of service life due to the increase of triplet concentration.

In addition, the Example Compounds may easily control the electron distribution of the orbital in the light emitting core by the introduction of an oxygen atom as an atom constituting the fused ring. Accordingly, the Example Compounds may cause a blue shift of the luminescence wavelength by the introduction of an oxygen atom, and a change in kinds of substituents linked to the fused ring makes it possible to finely control a desired luminescence wavelength within a wavelength range of about 440 nm to about 460 nm while the optical and physical properties are not greatly or substantially changed.

When Examples 1 to 8 and Comparative Examples 1 and 2 are compared, it may be seen that Comparative Example Compounds C1 and C2 included in Comparative Examples 1 and 2 include the fused ring structure having one boron atom, one nitrogen atom, and one oxygen atom at the center, but do not include the first substituent of embodiments of the present disclosure, which is a steric hindrance substituent, in the fused ring, and thus, have increased driving voltages, and decreased luminous efficiency and service life characteristics.

When Example 1 and Comparative Example 3 are compared, it may be seen that Comparative Example 3 has a higher driving voltage and a lower device service life than Example 1. While the present disclosure is not limited by any particular mechanism or theory, it is thought that Comparative Example Compound C3 included in Comparative Example 3 includes a structure in which a steric hindrance substituent is substituted at the fused ring core in which three aromatic rings are fused around the boron atom, but does not include an oxygen atom as an atom constituting the fused ring, and thus, when applied to the light emitting device, Comparative Example Compound C3 causes a red shift, and has reduced service life characteristics as compared with Example 1. As the fused polycyclic compound of an example of an embodiment of the present disclosure, the essential inclusion of the first substituent, which is a steric hindrance substituent, at the fused ring core and the introduction of an oxygen atom as an atom constituting the fused ring core may achieve high luminous efficiency and long service life in a blue light wavelength region.

The light emitting device of an embodiment may exhibit improved device characteristics having high efficiency and a long service life.

The fused polycyclic compound of an embodiment may be included in the emission layer of the light emitting device to contribute to high efficiency and a long service life of the light emitting device.

Although the subject matter of the present disclosure has been described with reference to example embodiments of the present disclosure, it will be understood that the present disclosure should not be limited to these example embodiments but various changes and modifications can be made by those skilled in the art without departing from the spirit and scope of the present disclosure.

Accordingly, the technical scope of the present disclosure is not intended to be limited to the contents set forth in the detailed description of the present specification, but is intended to be defined by the appended claims, and equivalents thereof.

What is claimed is:

1. A light emitting device comprising:
a first electrode;
a second electrode facing the first electrode; and
an emission layer between the first electrode and the second electrode,
wherein the emission layer comprises a first compound represented by Formula 1 below: 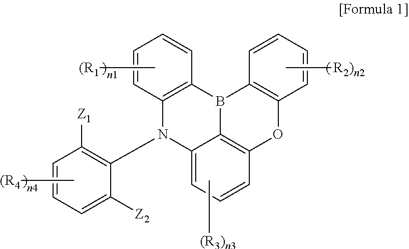
wherein, in Formula 1 above,
R₁ to R₄ are each independently a hydrogen atom, a deuterium atom, a halogen atom, a cyano group, a nitro group, a substituted or unsubstituted oxy group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
Z₁ and Z₂ are each independently a substituted or unsubstituted aryl group having 6 to 30 ring-forming carbon atoms, or a substituted or unsubstituted heteroaryl group having 2 to 30 ring-forming carbon atoms,
n1 and n2 are each independently an integer of 0 to 4, and
n3 and n4 are each independently an integer of 0 to 3.

2. The light emitting device of claim 1, wherein the first compound represented by Formula 1 above is represented by Formula 2 below: 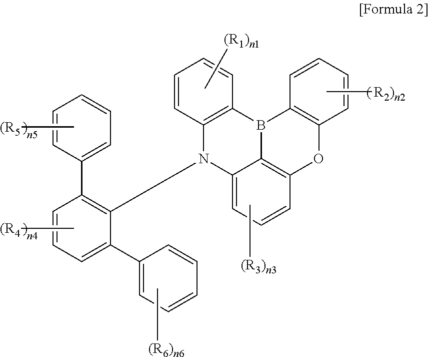
wherein, in Formula 2 above,
R₅ and R₆ are each independently a hydrogen atom, a deuterium atom, a halogen atom, a cyano group, a nitro group, a substituted or unsubstituted oxy group, a substituted or unsubstituted thio group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
n5 and n6 are each independently an integer of 0 to 5, and
R₁ to R₄, and n1 to n4 are the same as defined with respect to Formula 1 above.

3. The light emitting device of claim 1, wherein the first compound represented by Formula 1 above is represented by any one selected from among Formula 3-1 to Formula 3-3 below: 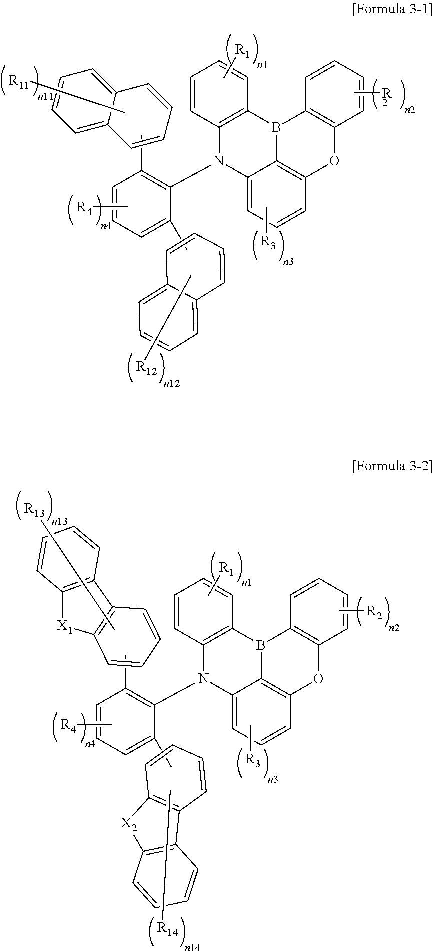 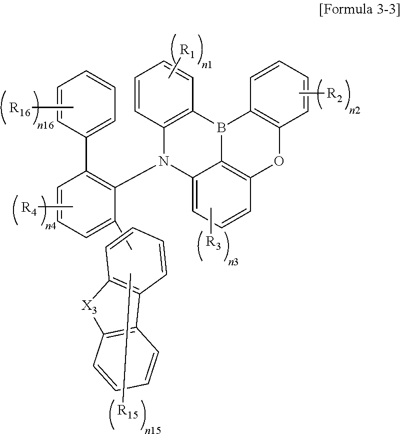
wherein, in Formula 3-1 to Formula 3-3 above,
X₁ to X₃ are each independently NR₁₇, O or S,
R₁₁ to R₁₇ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n11 to n15 are each independently an integer of 0 to 7, and
n16 is an integer of 0 to 5,
R₁ to R₄, and n1 to n4 are the same as defined with respect to Formula 1 above.

4. The light emitting device of claim 1, wherein the first compound represented by Formula 1 above is represented by Formula 4 below: 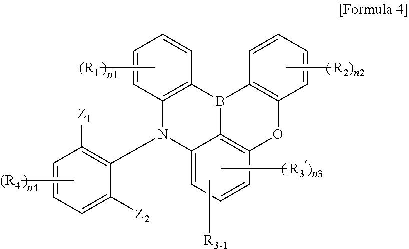
wherein, in Formula 4 above,
R₃₋₁ is a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R₃′ is a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n3′ is an integer of 0 to 2, and
R₁, R₂, R₄, n1, n2, n4, Z₁, and Z₂ are the same as defined with respect to Formula 1 above.

5. The light emitting device of claim 4, wherein R₃₋₁ above is a deuterium atom or a substituted or unsubstituted alkyl group having 1 to 10 carbon atoms, or is represented by any one selected from among Formula 5-1 to Formula 5-4 below: 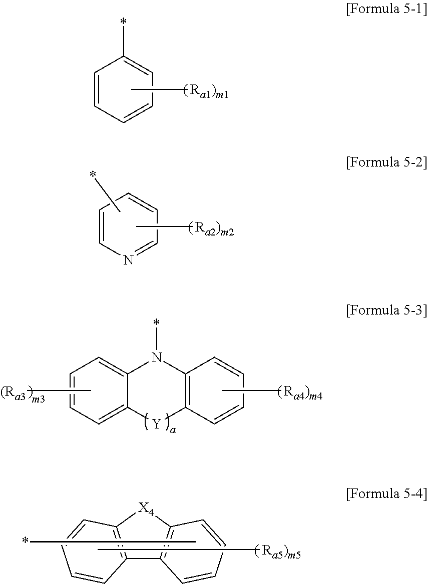
wherein, in Formula 5-1 to Formula 5-4 above,
X₄ is NRₐ₆, O, S, or Se,
Rₐ₁ to Rₐ₆ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
a is 0 or 1,
when a is 1, Y is a direct linkage,
m1, m3 and m4 are each independently an integer of 0 to 5,
m2 is an integer of 0 to 4,
m5 is an integer of 0 to 7,
the sum of a and m3 is 5 or less, and
the sum of a and m4 is 5 or less.

6. The light emitting device of claim 1, wherein the first compound represented by Formula 1 above is represented by any one selected from among Formula 6-1 to Formula 6-4 below: 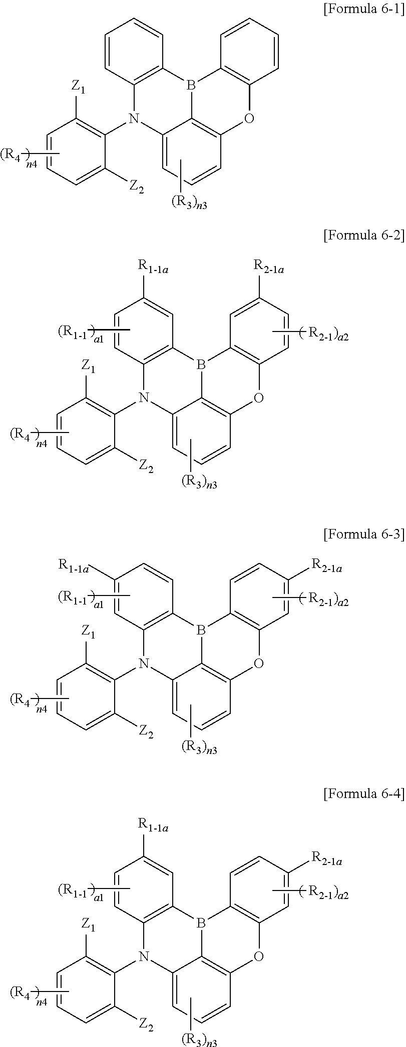
wherein, in Formula 6-1 to Formula 6-4 above,
R₁₋₁ and R₂₋₁ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R₁₋₁ₐ and R₂₋₁ₐ are each independently a substituted or unsubstituted amine group, a substituted or unsubstituted phenyl group, a substituted or unsubstituted dibenzofuran group, or a substituted or unsubstituted carbazole group,
a1 and a2 are each independently an integer of 0 to 3, and
R₃, R₄, n3, n4, Z₁, and Z₂ are the same as defined with respect to Formula 1 above.

7. The light emitting device of claim 1, wherein the first compound represented by Formula 1 above is represented by any one selected from among Formula 7-1 to Formula 7-5 below: 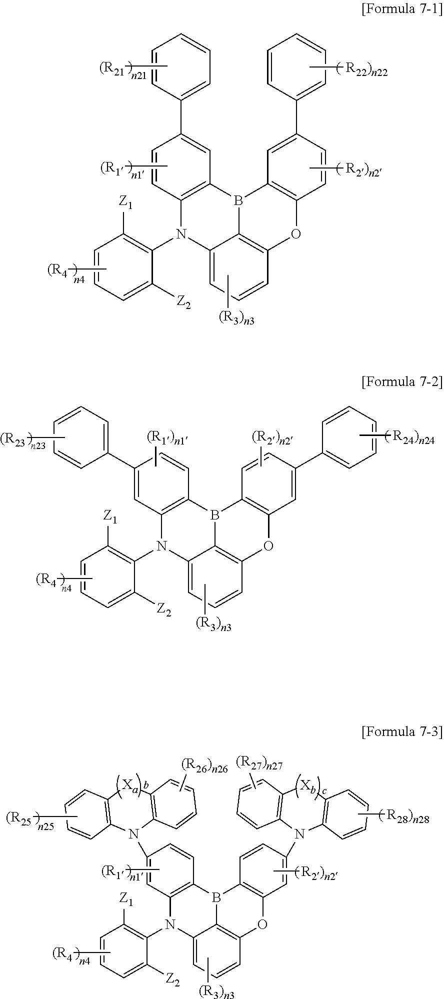 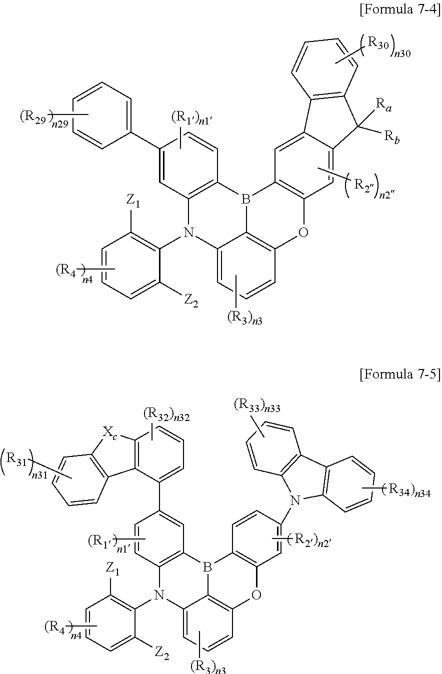
wherein, in Formula 7-1 to Formula 7-5 above,
Xₐ to X_{c} are each independently a direct linkage, O, NR₃₅, CR₃₆R₃₇, S, or Se,
R₂₁ to R₃₇ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
Rₐ and R_{b} are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
R₁′, R₂′, and R₂″ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n1′, n2′, and n32 are each independently an integer of 0 to 3,
n2″ is an integer of 0 to 2,
b and c are each independently 0 or 1,
n21 to n29 are each independently an integer of 0 to 5,
n30, n31, n33, and n34 are each independently an integer of 0 to 4,
the sum of b and n25 is 5 or less,
the sum of b and n26 is 5 or less,
the sum of c and n27 is 5 or less,
the sum of c and n28 is 5 or less, and
R₃, R₄, n3, n4, Z₁, and Z₂ are the same as defined with respect to Formula 1 above.

8. The light emitting device of claim 1, wherein Z₁ and Z₂ above are each independently represented by any one selected from among Formula 8-1 to Formula 8-4 below: 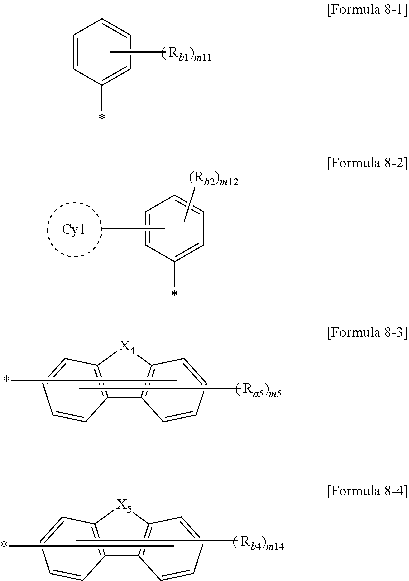
wherein, in Formula 8-1 to Formula 8-4 above,
Cy1 is a substituted or unsubstituted cycloalkyl group having 3 to 10 carbon atoms,
X₅ is NR_{b5}, O, or S,
R_{b1} to R_{b5} are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
m11 is an integer of 0 to 5,
m12 is an integer of 0 to 4, and
m13 and m14 are each independently an integer of 0 to 7.

9. The light emitting device of claim 1, wherein the first compound represented by Formula 1 above comprises at least one from among compounds in Compound Group 1 below:

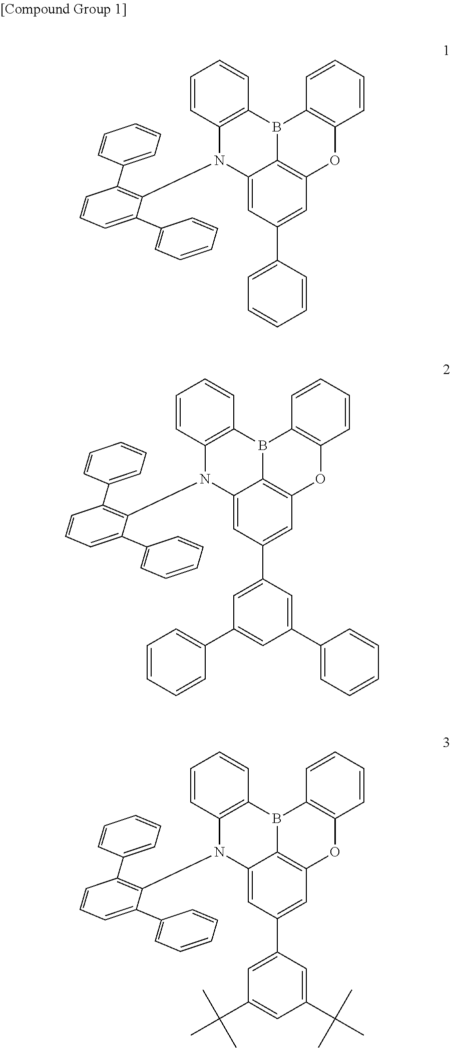 [SMILES: c1ccc(-c2cc3c4c(c2)N(c2c(-c5ccccc5)cccc2-c2ccccc2)c2ccccc2B4c2ccccc2O3)cc1 ; c1ccc(-c2cc(-c3ccccc3)cc(-c3cc4c5c(c3)N(c3c(-c6ccccc6)cccc3-c3ccccc3)c3ccccc3B5c3ccccc3O4)c2)cc1 ; CC(C)(C)c1cc(-c2cc3c4c(c2)N(c2c(-c5ccccc5)cccc2-c2ccccc2)c2ccccc2B4c2ccccc2O3)cc(C(C)(C)C)c1]

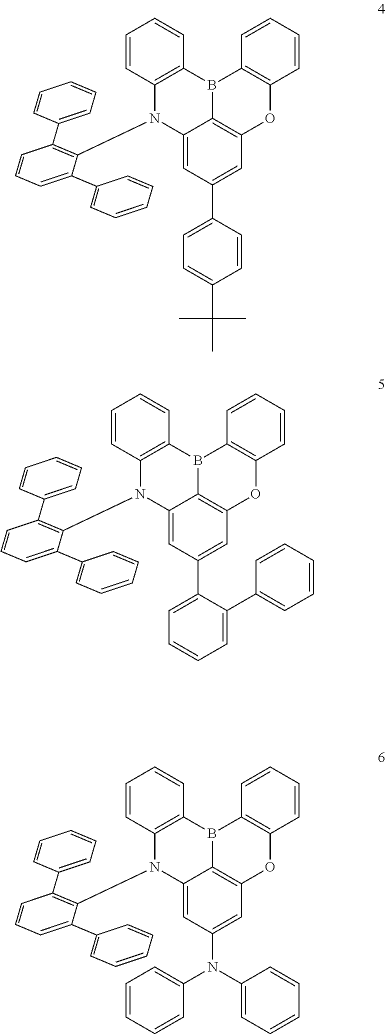 [SMILES: CC(C)(C)c1ccc(-c2cc3c4c(c2)N(c2c(-c5ccccc5)cccc2-c2ccccc2)c2ccccc2B4c2ccccc2O3)cc1 ; c1ccc(-c2ccccc2-c2cc3c4c(c2)N(c2c(-c5ccccc5)cccc2-c2ccccc2)c2ccccc2B4c2ccccc2O3)cc1 ; c1ccc(-c2cccc(-c3ccccc3)c2N2c3ccccc3B3c4ccccc4Oc4cc(N(c5ccccc5)c5ccccc5)cc2c43)cc1]

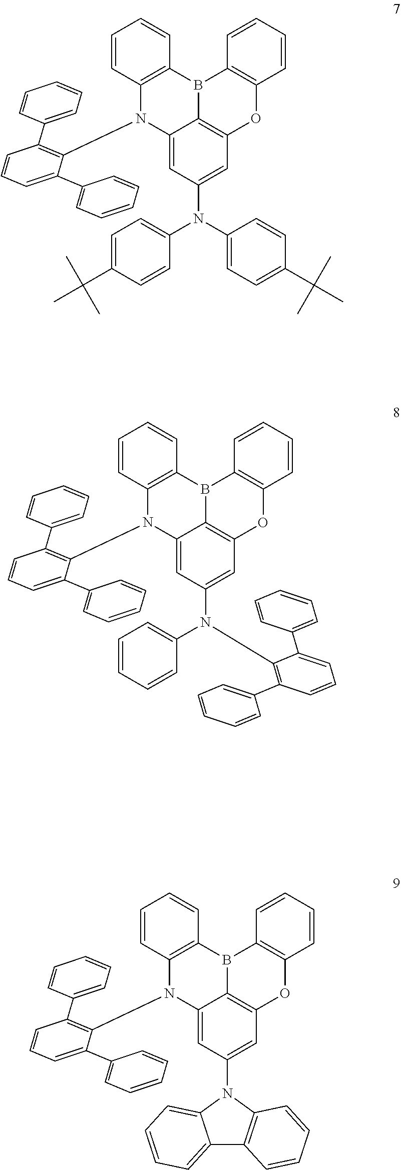 [SMILES: CC(C)(C)c1ccc(N(c2ccc(C(C)(C)C)cc2)c2cc3c4c(c2)N(c2c(-c5ccccc5)cccc2-c2ccccc2)c2ccccc2B4c2ccccc2O3)cc1 ; c1ccc(-c2cccc(-c3ccccc3)c2N(c2ccccc2)c2cc3c4c(c2)N(c2c(-c5ccccc5)cccc2-c2ccccc2)c2ccccc2B4c2ccccc2O3)cc1 ; c1ccc(-c2cccc(-c3ccccc3)c2N2c3ccccc3B3c4ccccc4Oc4cc(-n5c6ccccc6c6ccccc65)cc2c43)cc1]

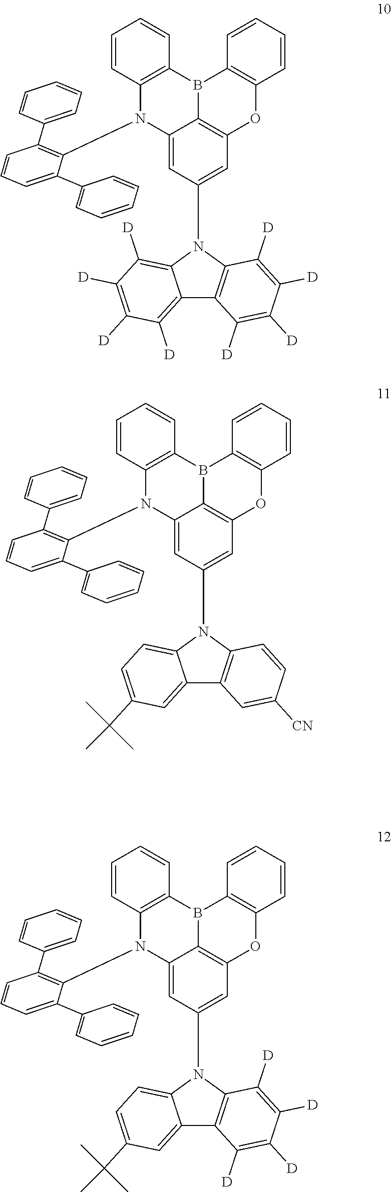 [SMILES: [2H]c1c([2H])c([2H])c2c(c1[2H])c1c([2H])c([2H])c([2H])c([2H])c1n2-c1cc2c3c(c1)N(c1c(-c4ccccc4)cccc1-c1ccccc1)c1ccccc1B3c1ccccc1O2 ; CC(C)(C)c1ccc2c(c1)c1cc(C#N)ccc1n2-c1cc2c3c(c1)N(c1c(-c4ccccc4)cccc1-c1ccccc1)c1ccccc1B3c1ccccc1O2 ; [2H]c1c([2H])c([2H])c2c(c1[2H])c1cc(C(C)(C)C)ccc1n2-c1cc2c3c(c1)N(c1c(-c4ccccc4)cccc1-c1ccccc1)c1ccccc1B3c1ccccc1O2]

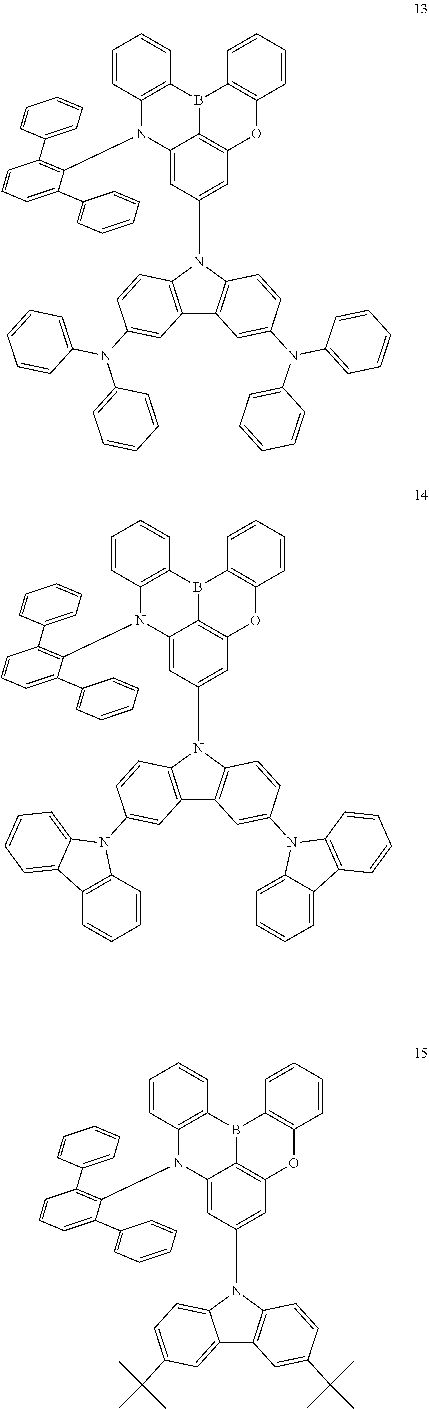 [SMILES: c1ccc(-c2cccc(-c3ccccc3)c2N2c3ccccc3B3c4ccccc4Oc4cc(-n5c6ccc(N(c7ccccc7)c7ccccc7)cc6c6cc(N(c7ccccc7)c7ccccc7)ccc65)cc2c43)cc1 ; c1ccc(-c2cccc(-c3ccccc3)c2N2c3ccccc3B3c4ccccc4Oc4cc(-n5c6ccc(-n7c8ccccc8c8ccccc87)cc6c6cc(-n7c8ccccc8c8ccccc87)ccc65)cc2c43)cc1 ; CC(C)(C)c1ccc2c(c1)c1cc(C(C)(C)C)ccc1n2-c1cc2c3c(c1)N(c1c(-c4ccccc4)cccc1-c1ccccc1)c1ccccc1B3c1ccccc1O2]

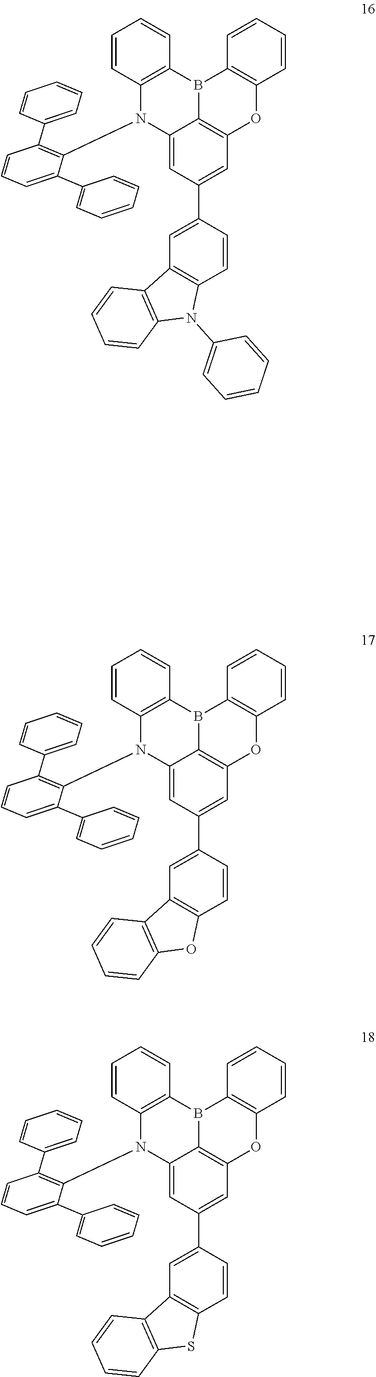 [SMILES: c1ccc(-c2cccc(-c3ccccc3)c2N2c3ccccc3B3c4ccccc4Oc4cc(-c5ccc6c(c5)c5ccccc5n6-c5ccccc5)cc2c43)cc1 ; c1ccc(-c2cccc(-c3ccccc3)c2N2c3ccccc3B3c4ccccc4Oc4cc(-c5ccc6oc7ccccc7c6c5)cc2c43)cc1 ; c1ccc(-c2cccc(-c3ccccc3)c2N2c3ccccc3B3c4ccccc4Oc4cc(-c5ccc6sc7ccccc7c6c5)cc2c43)cc1]

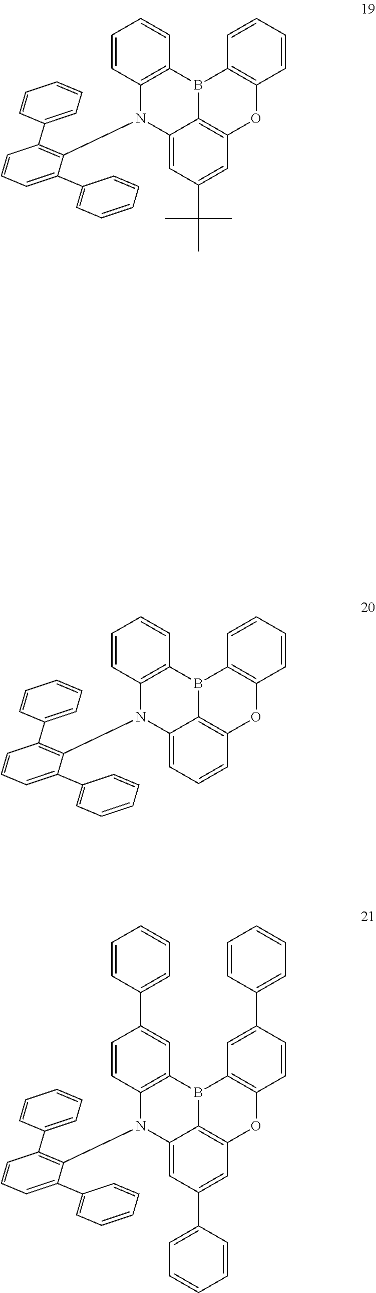 [SMILES: CC(C)(C)c1cc2c3c(c1)N(c1c(-c4ccccc4)cccc1-c1ccccc1)c1ccccc1B3c1ccccc1O2 ; c1ccc(-c2cccc(-c3ccccc3)c2N2c3ccccc3B3c4ccccc4Oc4cccc2c43)cc1 ; c1ccc(-c2ccc3c(c2)B2c4cc(-c5ccccc5)ccc4N(c4c(-c5ccccc5)cccc4-c4ccccc4)c4cc(-c5ccccc5)cc(c42)O3)cc1]

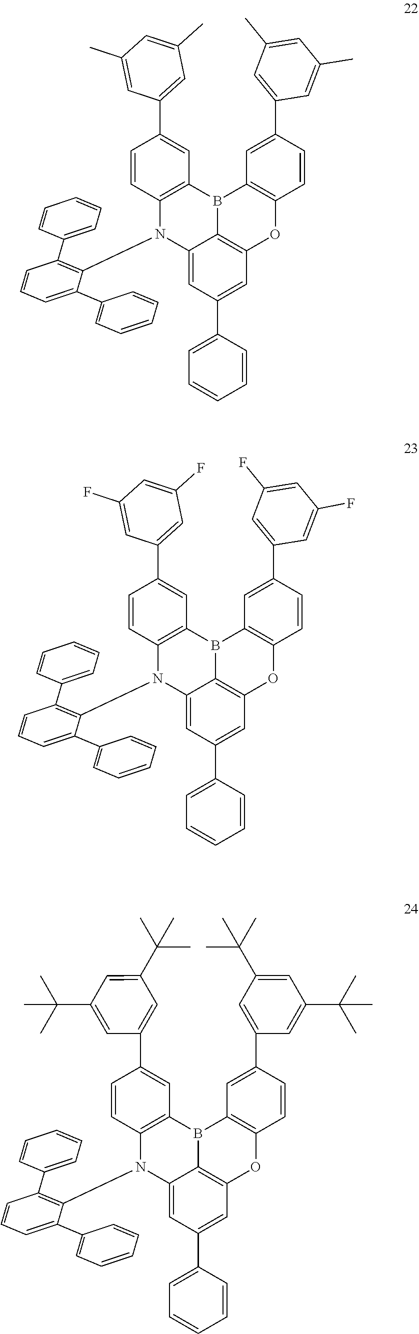 [SMILES: Cc1cc(C)cc(-c2ccc3c(c2)B2c4cc(-c5cc(C)cc(C)c5)ccc4N(c4c(-c5ccccc5)cccc4-c4ccccc4)c4cc(-c5ccccc5)cc(c42)O3)c1 ; Fc1cc(F)cc(-c2ccc3c(c2)B2c4cc(-c5cc(F)cc(F)c5)ccc4N(c4c(-c5ccccc5)cccc4-c4ccccc4)c4cc(-c5ccccc5)cc(c42)O3)c1 ; CC(C)(C)c1cc(-c2ccc3c(c2)B2c4cc(-c5cc(C(C)(C)C)cc(C(C)(C)C)c5)ccc4N(c4c(-c5ccccc5)cccc4-c4ccccc4)c4cc(-c5ccccc5)cc(c42)O3)cc(C(C)(C)C)c1]

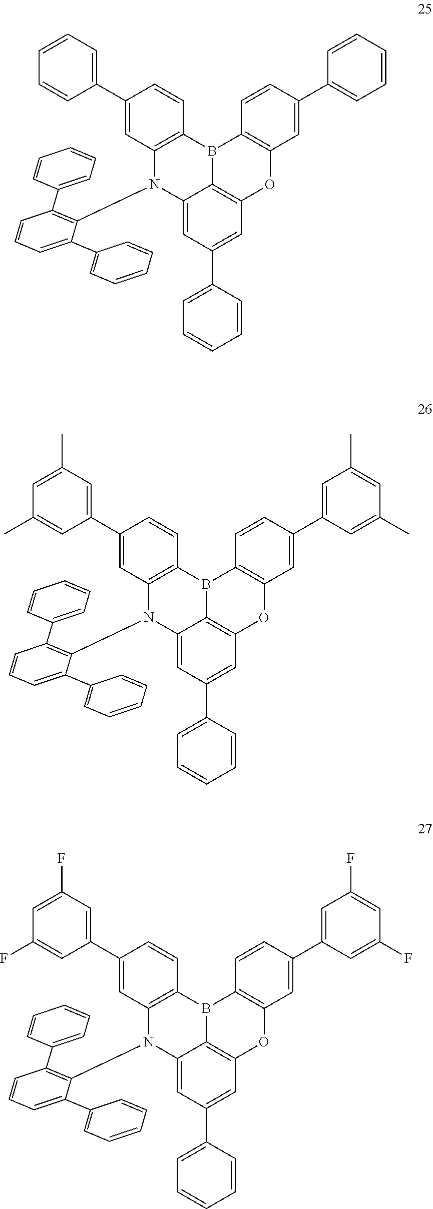

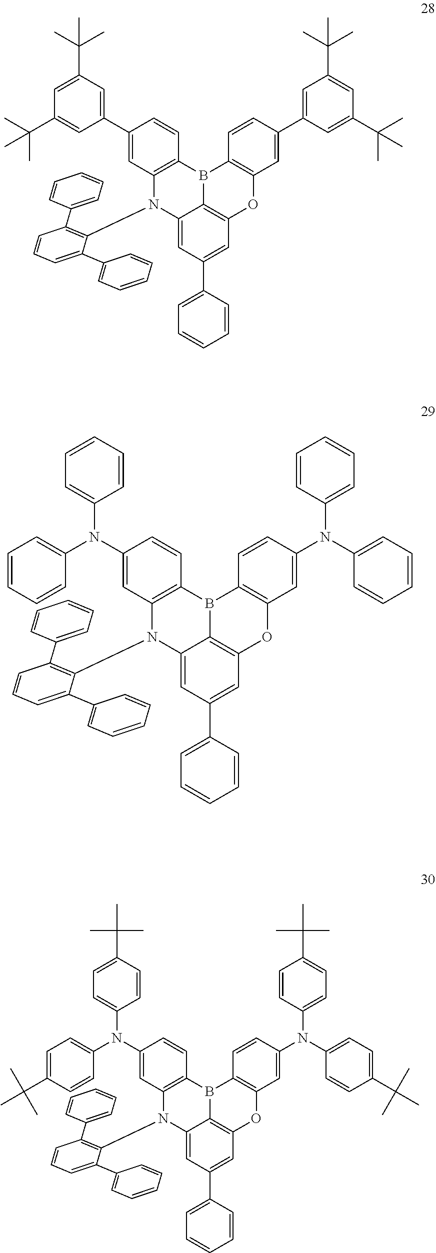

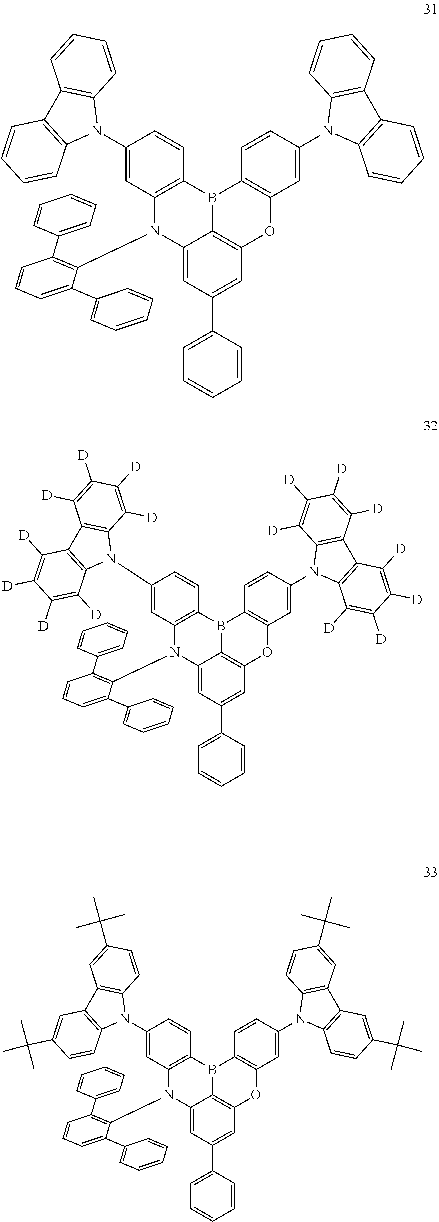 [SMILES: c1ccc(-c2cc3c4c(c2)N(c2c(-c5ccccc5)cccc2-c2ccccc2)c2cc(-n5c6ccccc6c6ccccc65)ccc2B4c2ccc(-n4c5ccccc5c5ccccc54)cc2O3)cc1 ; [2H]c1c([2H])c([2H])c2c(c1[2H])c1c([2H])c([2H])c([2H])c([2H])c1n2-c1ccc2c(c1)Oc1cc(-c3ccccc3)cc3c1B2c1ccc(-n2c4c([2H])c([2H])c([2H])c([2H])c4c4c([2H])c([2H])c([2H])c([2H])c42)cc1N3c1c(-c2ccccc2)cccc1-c1ccccc1 ; CC(C)(C)c1ccc2c(c1)c1cc(C(C)(C)C)ccc1n2-c1ccc2c(c1)Oc1cc(-c3ccccc3)cc3c1B2c1ccc(-n2c4ccc(C(C)(C)C)cc4c4cc(C(C)(C)C)ccc42)cc1N3c1c(-c2ccccc2)cccc1-c1ccccc1]

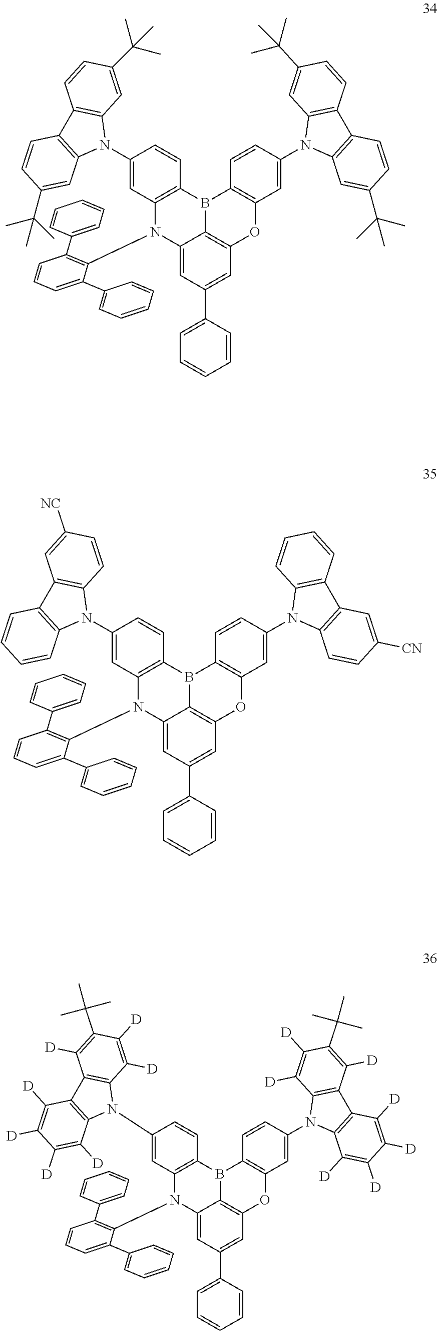 [SMILES: CC(C)(C)c1ccc2c3ccc(C(C)(C)C)cc3n(-c3ccc4c(c3)Oc3cc(-c5ccccc5)cc5c3B4c3ccc(-n4c6cc(C(C)(C)C)ccc6c6ccc(C(C)(C)C)cc64)cc3N5c3c(-c4ccccc4)cccc3-c3ccccc3)c2c1 ; N#Cc1ccc2c(c1)c1ccccc1n2-c1ccc2c(c1)Oc1cc(-c3ccccc3)cc3c1B2c1ccc(-n2c4ccccc4c4cc(C#N)ccc42)cc1N3c1c(-c2ccccc2)cccc1-c1ccccc1 ; [2H]c1c([2H])c([2H])c2c(c1[2H])c1c([2H])c(C(C)(C)C)c([2H])c([2H])c1n2-c1ccc2c(c1)Oc1cc(-c3ccccc3)cc3c1B2c1ccc(-n2c4c([2H])c([2H])c([2H])c([2H])c4c4c([2H])c(C(C)(C)C)c([2H])c([2H])c42)cc1N3c1c(-c2ccccc2)cccc1-c1ccccc1]

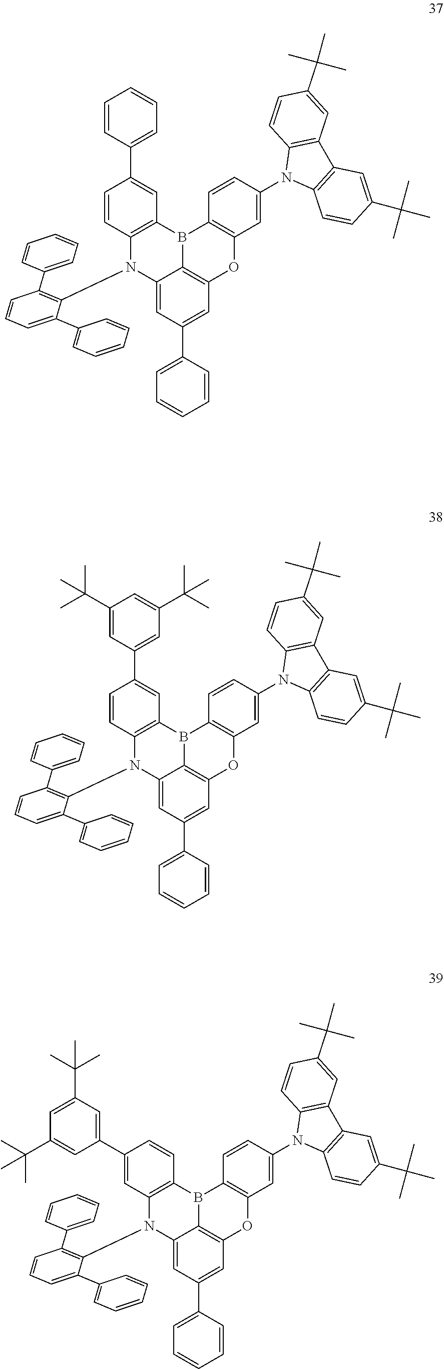

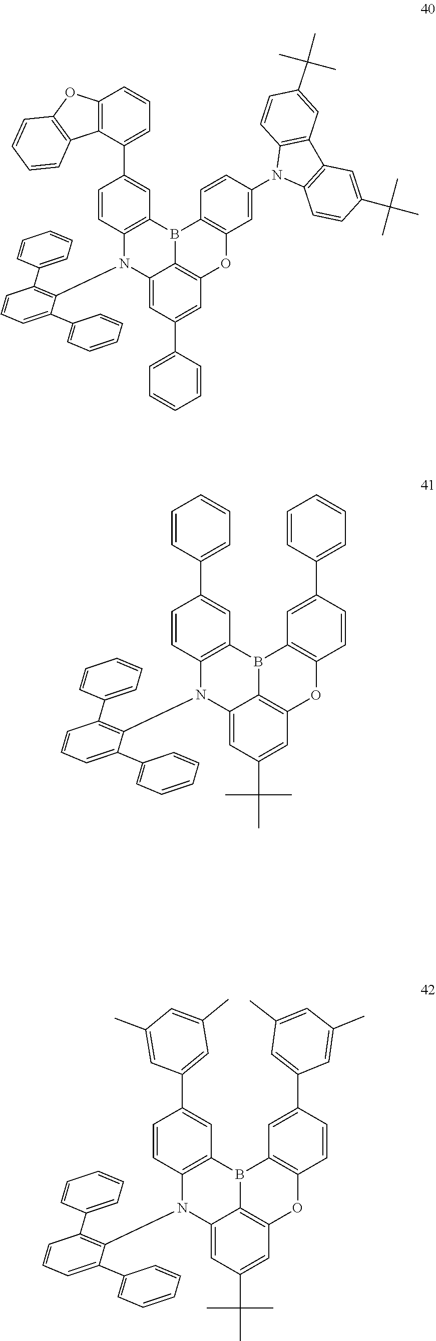 [SMILES: CC(C)(C)c1ccc2c(c1)c1cc(C(C)(C)C)ccc1n2-c1ccc2c(c1)Oc1cc(-c3ccccc3)cc3c1B2c1cc(-c2cccc4oc5ccccc5c24)ccc1N3c1c(-c2ccccc2)cccc1-c1ccccc1 ; CC(C)(C)c1cc2c3c(c1)N(c1c(-c4ccccc4)cccc1-c1ccccc1)c1ccc(-c4ccccc4)cc1B3c1cc(-c3ccccc3)ccc1O2 ; Cc1cc(C)cc(-c2ccc3c(c2)B2c4cc(-c5cc(C)cc(C)c5)ccc4N(c4c(-c5ccccc5)cccc4-c4ccccc4)c4cc(C(C)(C)C)cc(c42)O3)c1]

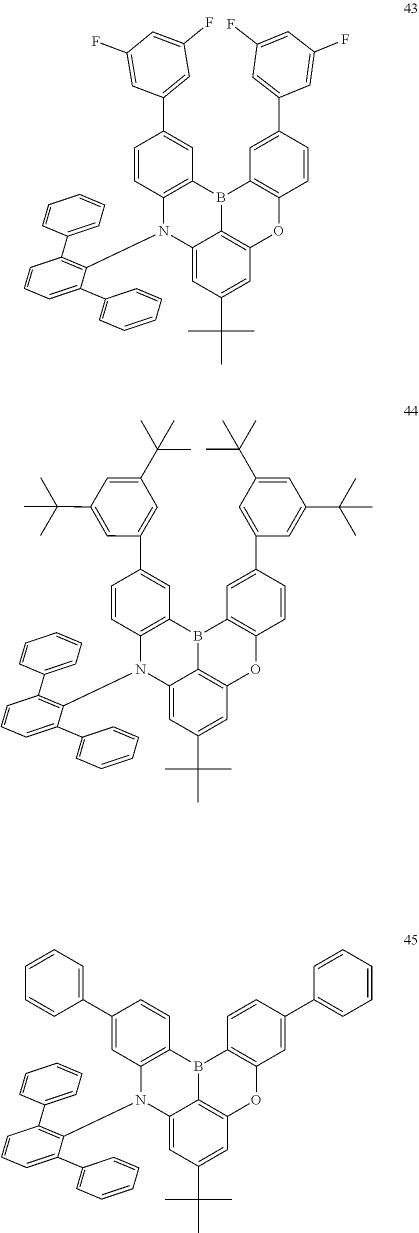 [SMILES: CC(C)(C)c1cc2c3c(c1)N(c1c(-c4ccccc4)cccc1-c1ccccc1)c1ccc(-c4cc(F)cc(F)c4)cc1B3c1cc(-c3cc(F)cc(F)c3)ccc1O2 ; CC(C)(C)c1cc(-c2ccc3c(c2)B2c4cc(-c5cc(C(C)(C)C)cc(C(C)(C)C)c5)ccc4N(c4c(-c5ccccc5)cccc4-c4ccccc4)c4cc(C(C)(C)C)cc(c42)O3)cc(C(C)(C)C)c1 ; CC(C)(C)c1cc2c3c(c1)N(c1c(-c4ccccc4)cccc1-c1ccccc1)c1cc(-c4ccccc4)ccc1B3c1ccc(-c3ccccc3)cc1O2]

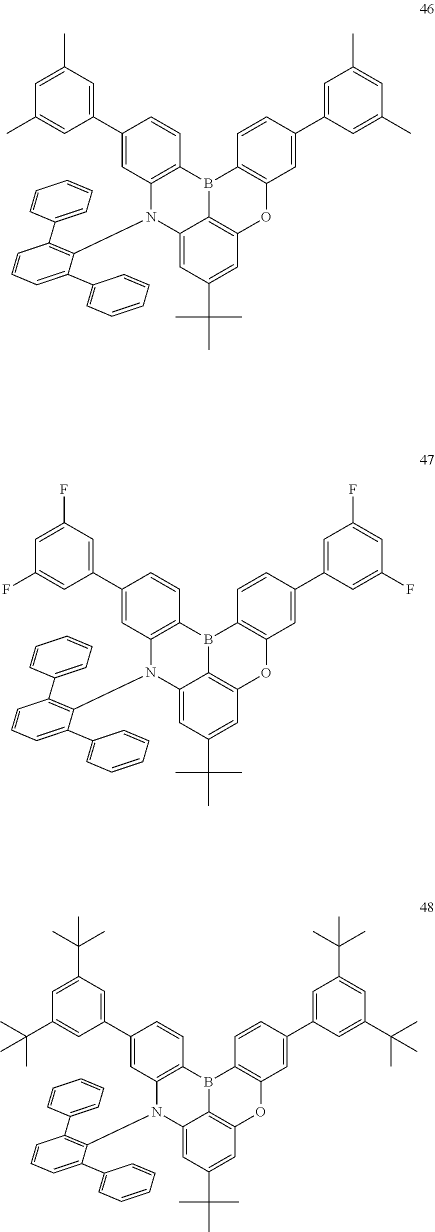

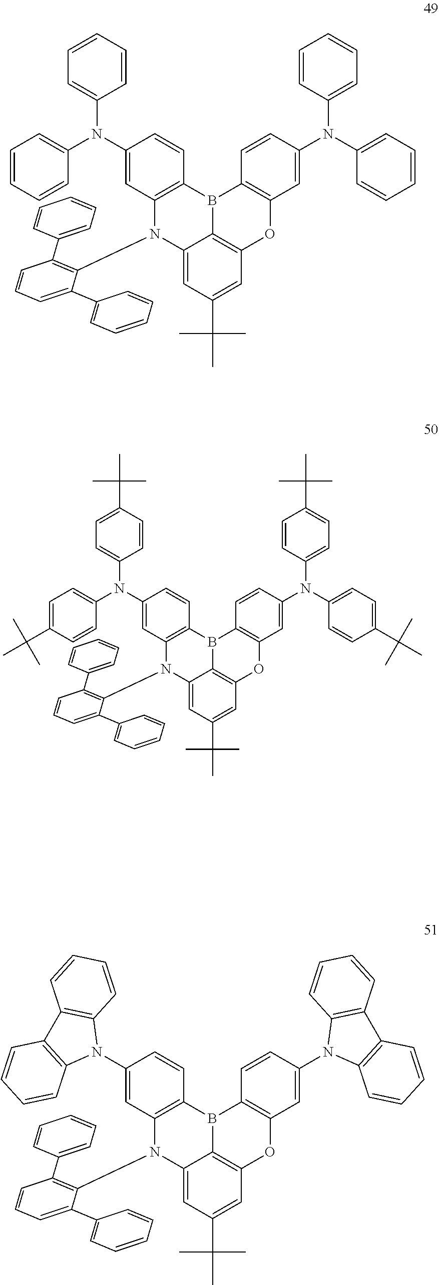 [SMILES: CC(C)(C)c1cc2c3c(c1)N(c1c(-c4ccccc4)cccc1-c1ccccc1)c1cc(N(c4ccccc4)c4ccccc4)ccc1B3c1ccc(N(c3ccccc3)c3ccccc3)cc1O2 ; CC(C)(C)c1ccc(N(c2ccc(C(C)(C)C)cc2)c2ccc3c(c2)Oc2cc(C(C)(C)C)cc4c2B3c2ccc(N(c3ccc(C(C)(C)C)cc3)c3ccc(C(C)(C)C)cc3)cc2N4c2c(-c3ccccc3)cccc2-c2ccccc2)cc1 ; CC(C)(C)c1cc2c3c(c1)N(c1c(-c4ccccc4)cccc1-c1ccccc1)c1cc(-n4c5ccccc5c5ccccc54)ccc1B3c1ccc(-n3c4ccccc4c4ccccc43)cc1O2]

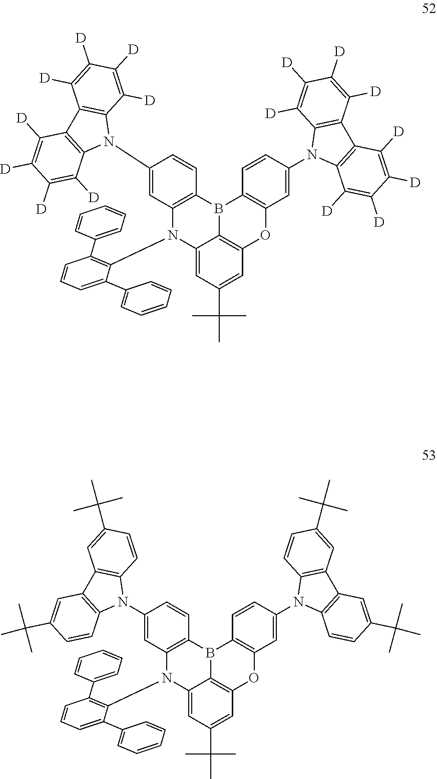 [SMILES: [2H]c1c([2H])c([2H])c2c(c1[2H])c1c([2H])c([2H])c([2H])c([2H])c1n2-c1ccc2c(c1)Oc1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2ccccc2)cccc1-c1ccccc1 ; CC(C)(C)c1cc2c3c(c1)N(c1c(-c4ccccc4)cccc1-c1ccccc1)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1O2]

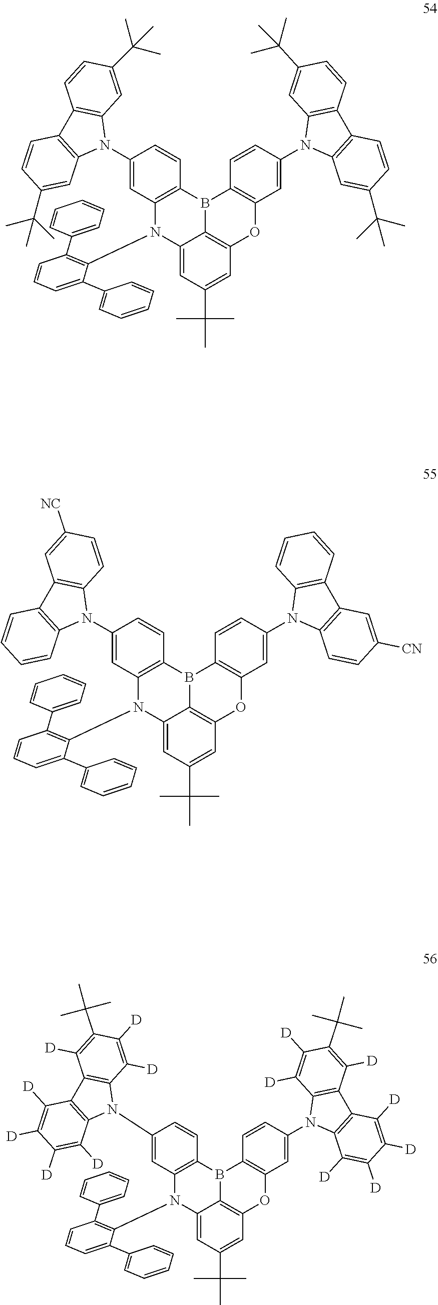

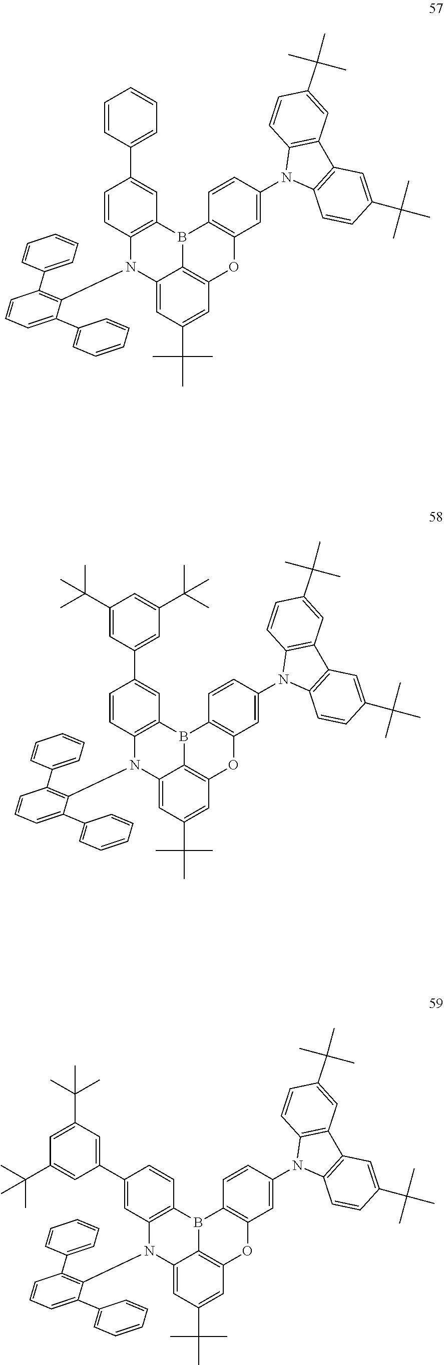

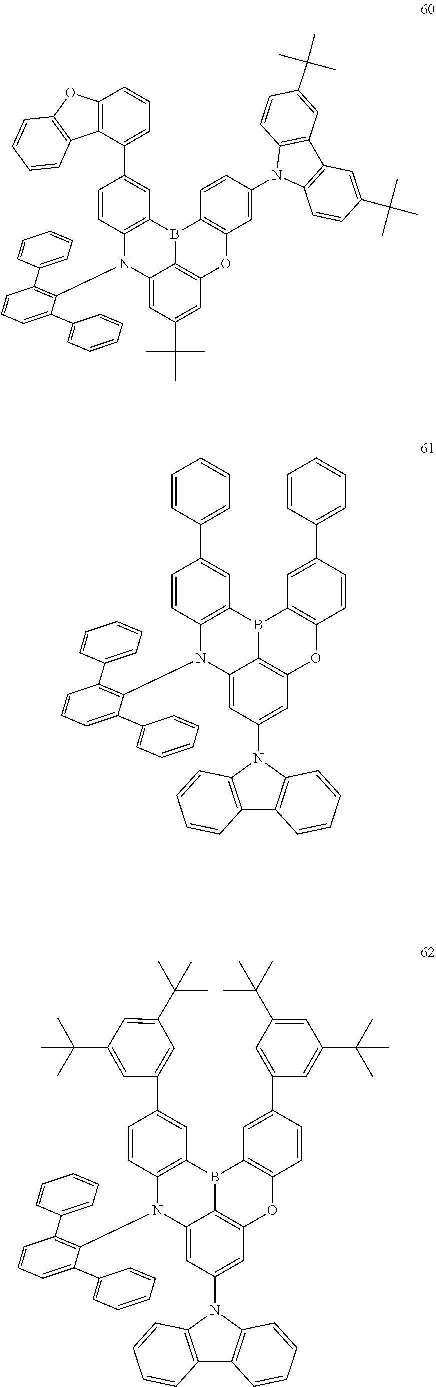 [SMILES: CC(C)(C)c1cc2c3c(c1)N(c1c(-c4ccccc4)cccc1-c1ccccc1)c1ccc(-c4cccc5oc6ccccc6c45)cc1B3c1ccc(-n3c4ccc(C(C)(C)C)cc4c4cc(C(C)(C)C)ccc43)cc1O2 ; c1ccc(-c2ccc3c(c2)B2c4cc(-c5ccccc5)ccc4N(c4c(-c5ccccc5)cccc4-c4ccccc4)c4cc(-n5c6ccccc6c6ccccc65)cc(c42)O3)cc1 ; CC(C)(C)c1cc(-c2ccc3c(c2)B2c4cc(-c5cc(C(C)(C)C)cc(C(C)(C)C)c5)ccc4N(c4c(-c5ccccc5)cccc4-c4ccccc4)c4cc(-n5c6ccccc6c6ccccc65)cc(c42)O3)cc(C(C)(C)C)c1]

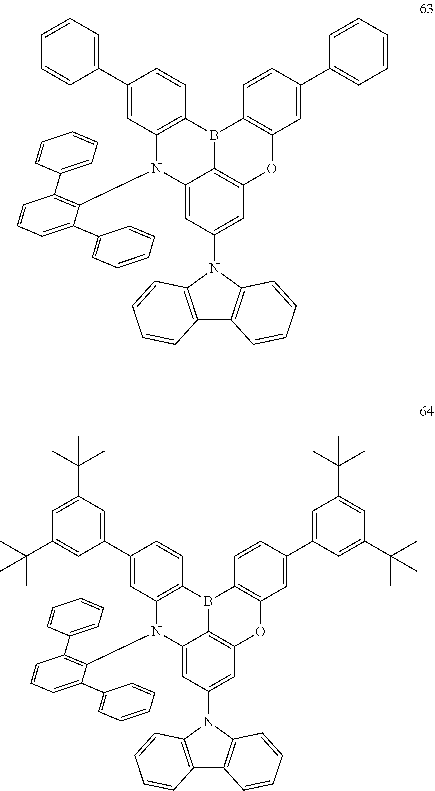 [SMILES: c1ccc(-c2ccc3c(c2)Oc2cc(-n4c5ccccc5c5ccccc54)cc4c2B3c2ccc(-c3ccccc3)cc2N4c2c(-c3ccccc3)cccc2-c2ccccc2)cc1 ; CC(C)(C)c1cc(-c2ccc3c(c2)Oc2cc(-n4c5ccccc5c5ccccc54)cc4c2B3c2ccc(-c3cc(C(C)(C)C)cc(C(C)(C)C)c3)cc2N4c2c(-c3ccccc3)cccc2-c2ccccc2)cc(C(C)(C)C)c1]

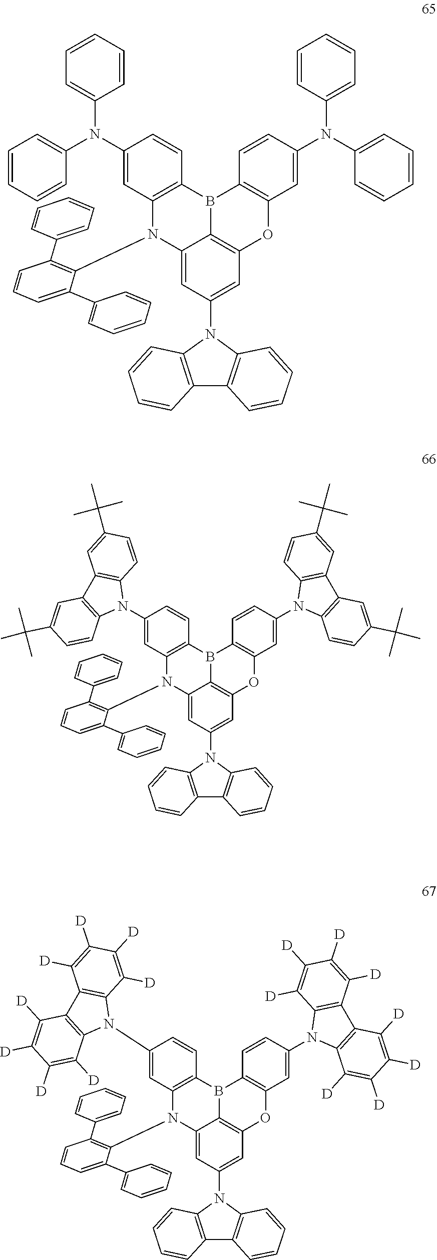

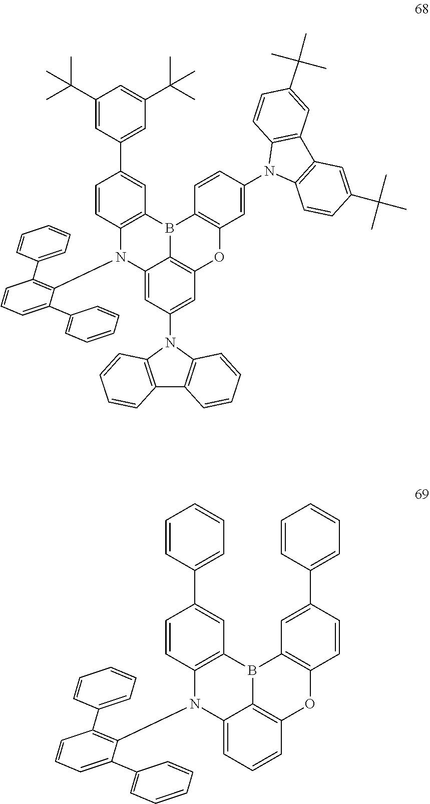 [SMILES: CC(C)(C)c1cc(-c2ccc3c(c2)B2c4ccc(-n5c6ccc(C(C)(C)C)cc6c6cc(C(C)(C)C)ccc65)cc4Oc4cc(-n5c6ccccc6c6ccccc65)cc(c42)N3c2c(-c3ccccc3)cccc2-c2ccccc2)cc(C(C)(C)C)c1 ; c1ccc(-c2ccc3c(c2)B2c4cc(-c5ccccc5)ccc4N(c4c(-c5ccccc5)cccc4-c4ccccc4)c4cccc(c42)O3)cc1]

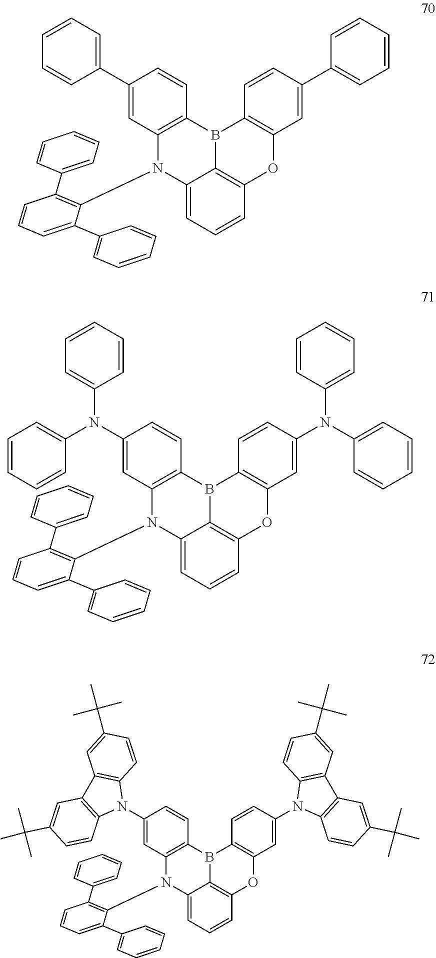 [SMILES: c1ccc(-c2ccc3c(c2)Oc2cccc4c2B3c2ccc(-c3ccccc3)cc2N4c2c(-c3ccccc3)cccc2-c2ccccc2)cc1 ; c1ccc(-c2cccc(-c3ccccc3)c2N2c3cc(N(c4ccccc4)c4ccccc4)ccc3B3c4ccc(N(c5ccccc5)c5ccccc5)cc4Oc4cccc2c43)cc1 ; CC(C)(C)c1ccc2c(c1)c1cc(C(C)(C)C)ccc1n2-c1ccc2c(c1)Oc1cccc3c1B2c1ccc(-n2c4ccc(C(C)(C)C)cc4c4cc(C(C)(C)C)ccc42)cc1N3c1c(-c2ccccc2)cccc1-c1ccccc1]

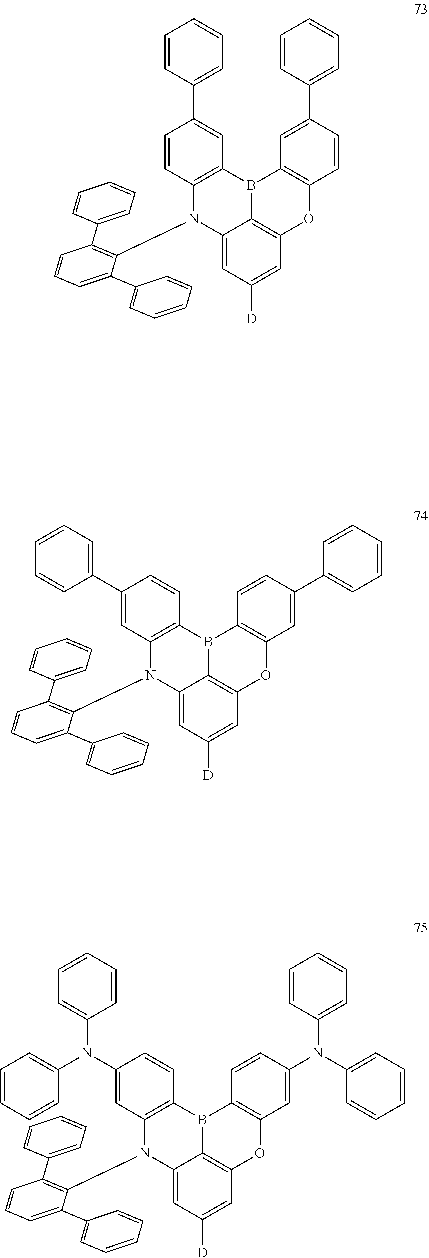 [SMILES: [2H]c1cc2c3c(c1)N(c1c(-c4ccccc4)cccc1-c1ccccc1)c1ccc(-c4ccccc4)cc1B3c1cc(-c3ccccc3)ccc1O2 ; [2H]c1cc2c3c(c1)N(c1c(-c4ccccc4)cccc1-c1ccccc1)c1cc(-c4ccccc4)ccc1B3c1ccc(-c3ccccc3)cc1O2 ; [2H]c1cc2c3c(c1)N(c1c(-c4ccccc4)cccc1-c1ccccc1)c1cc(N(c4ccccc4)c4ccccc4)ccc1B3c1ccc(N(c3ccccc3)c3ccccc3)cc1O2]

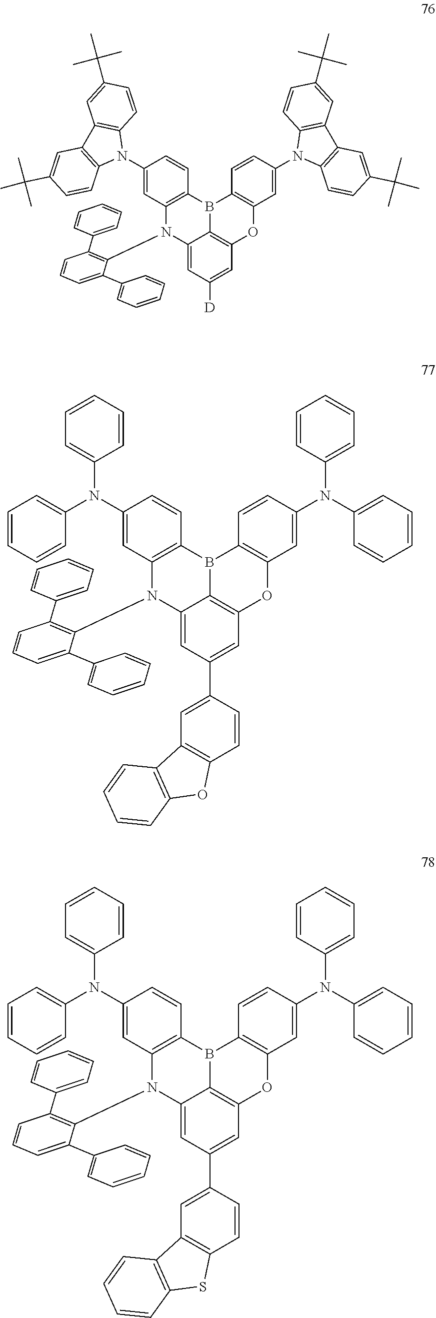 [SMILES: [2H]c1cc2c3c(c1)N(c1c(-c4ccccc4)cccc1-c1ccccc1)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1O2 ; c1ccc(-c2cccc(-c3ccccc3)c2N2c3cc(N(c4ccccc4)c4ccccc4)ccc3B3c4ccc(N(c5ccccc5)c5ccccc5)cc4Oc4cc(-c5ccc6oc7ccccc7c6c5)cc2c43)cc1 ; c1ccc(-c2cccc(-c3ccccc3)c2N2c3cc(N(c4ccccc4)c4ccccc4)ccc3B3c4ccc(N(c5ccccc5)c5ccccc5)cc4Oc4cc(-c5ccc6sc7ccccc7c6c5)cc2c43)cc1]

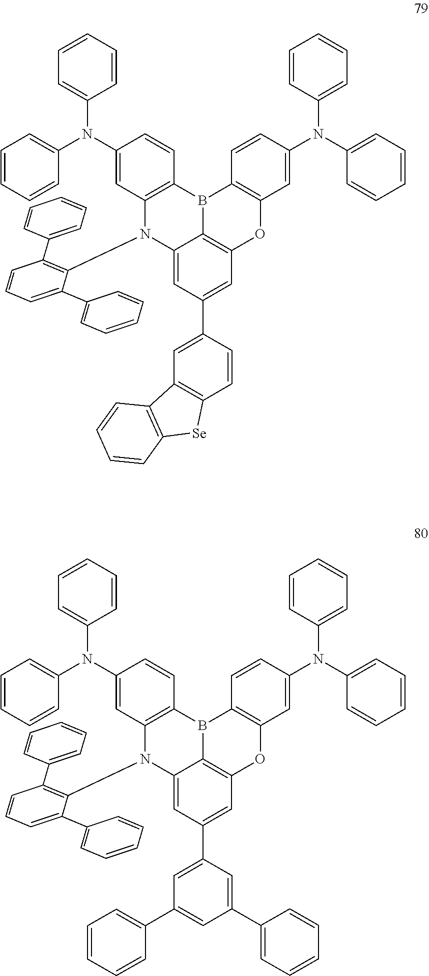 [SMILES: c1ccc(-c2cccc(-c3ccccc3)c2N2c3cc(N(c4ccccc4)c4ccccc4)ccc3B3c4ccc(N(c5ccccc5)c5ccccc5)cc4Oc4cc(-c5ccc6[se]c7ccccc7c6c5)cc2c43)cc1 ; c1ccc(-c2cc(-c3ccccc3)cc(-c3cc4c5c(c3)N(c3c(-c6ccccc6)cccc3-c3ccccc3)c3cc(N(c6ccccc6)c6ccccc6)ccc3B5c3ccc(N(c5ccccc5)c5ccccc5)cc3O4)c2)cc1]

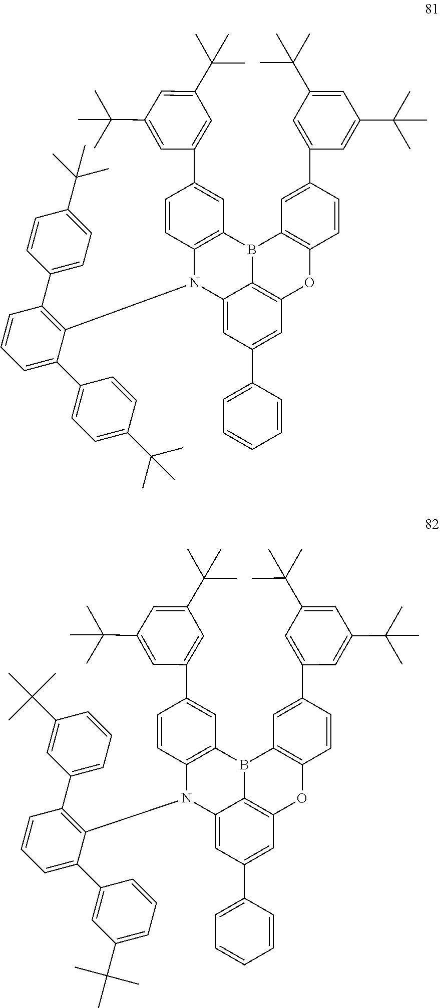

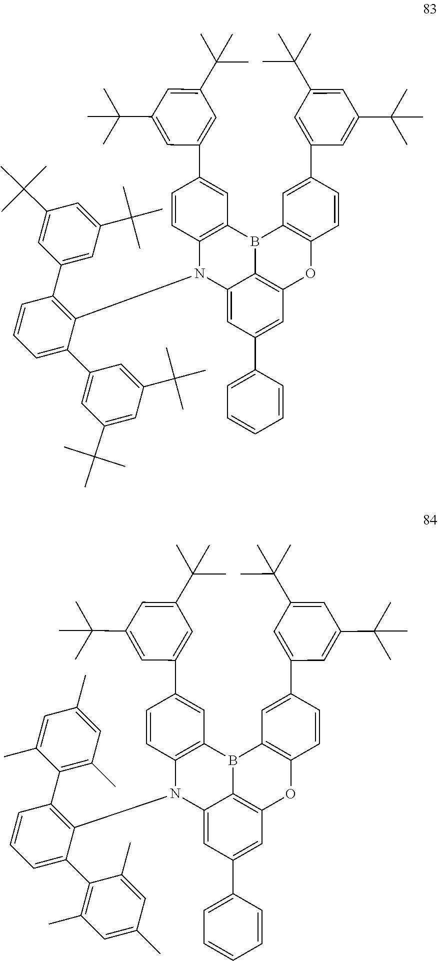

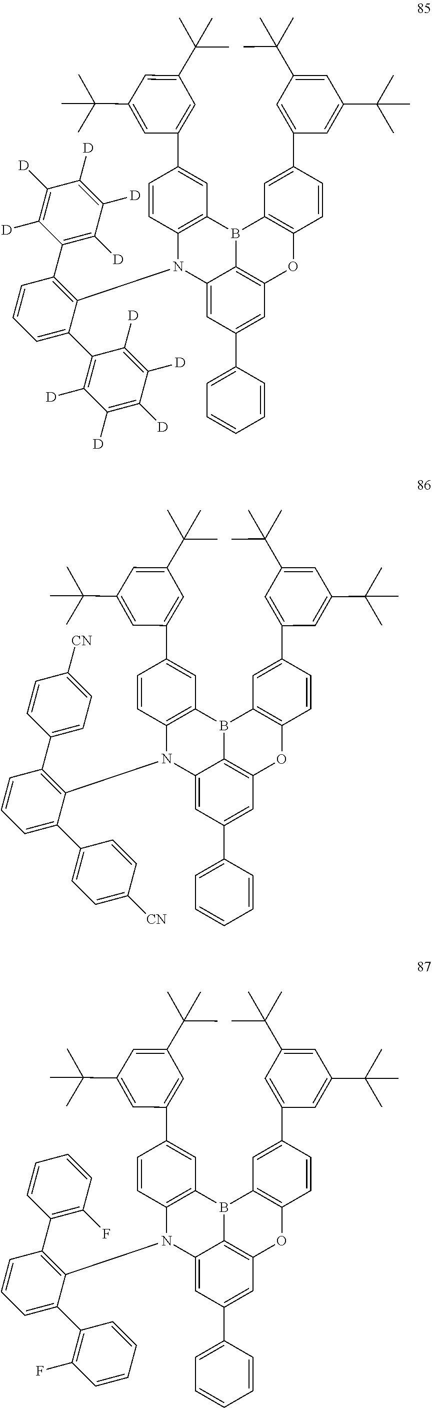 [SMILES: [2H]c1c([2H])c([2H])c(-c2cccc(-c3c([2H])c([2H])c([2H])c([2H])c3[2H])c2N2c3ccc(-c4cc(C(C)(C)C)cc(C(C)(C)C)c4)cc3B3c4cc(-c5cc(C(C)(C)C)cc(C(C)(C)C)c5)ccc4Oc4cc(-c5ccccc5)cc2c43)c([2H])c1[2H] ; CC(C)(C)c1cc(-c2ccc3c(c2)B2c4cc(-c5cc(C(C)(C)C)cc(C(C)(C)C)c5)ccc4N(c4c(-c5ccc(C#N)cc5)cccc4-c4ccc(C#N)cc4)c4cc(-c5ccccc5)cc(c42)O3)cc(C(C)(C)C)c1 ; CC(C)(C)c1cc(-c2ccc3c(c2)B2c4cc(-c5cc(C(C)(C)C)cc(C(C)(C)C)c5)ccc4N(c4c(-c5ccccc5F)cccc4-c4ccccc4F)c4cc(-c5ccccc5)cc(c42)O3)cc(C(C)(C)C)c1]

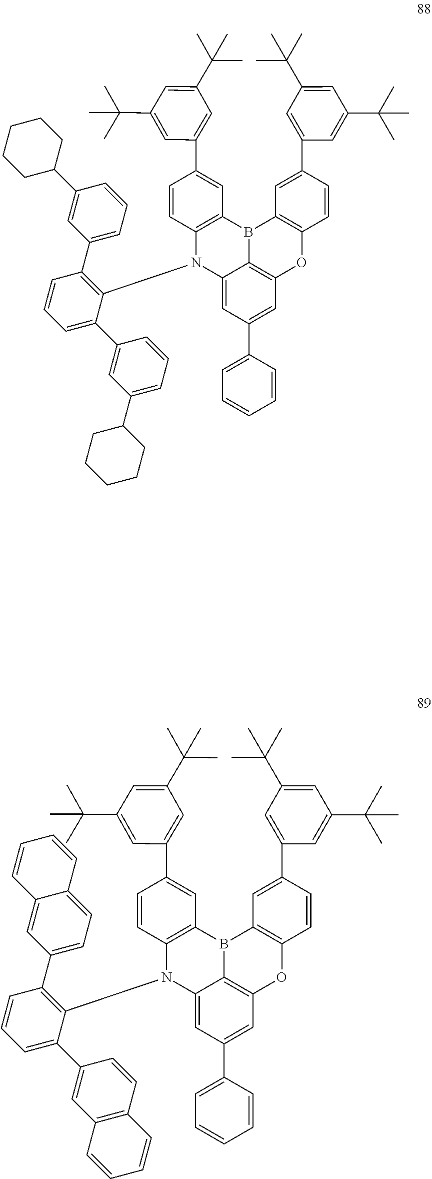 [SMILES: CC(C)(C)c1cc(-c2ccc3c(c2)B2c4cc(-c5cc(C(C)(C)C)cc(C(C)(C)C)c5)ccc4N(c4c(-c5cccc(C6CCCCC6)c5)cccc4-c4cccc(C5CCCCC5)c4)c4cc(-c5ccccc5)cc(c42)O3)cc(C(C)(C)C)c1 ; CC(C)(C)c1cc(-c2ccc3c(c2)B2c4cc(-c5cc(C(C)(C)C)cc(C(C)(C)C)c5)ccc4N(c4c(-c5ccc6ccccc6c5)cccc4-c4ccc5ccccc5c4)c4cc(-c5ccccc5)cc(c42)O3)cc(C(C)(C)C)c1]

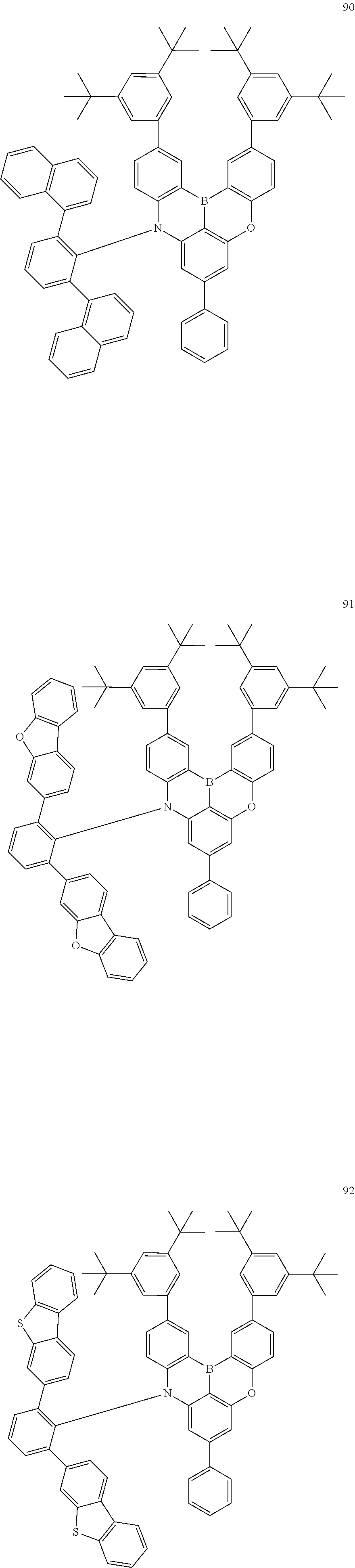 [SMILES: CC(C)(C)c1cc(-c2ccc3c(c2)B2c4cc(-c5cc(C(C)(C)C)cc(C(C)(C)C)c5)ccc4N(c4c(-c5cccc6ccccc56)cccc4-c4cccc5ccccc45)c4cc(-c5ccccc5)cc(c42)O3)cc(C(C)(C)C)c1 ; CC(C)(C)c1cc(-c2ccc3c(c2)B2c4cc(-c5cc(C(C)(C)C)cc(C(C)(C)C)c5)ccc4N(c4c(-c5ccc6c(c5)oc5ccccc56)cccc4-c4ccc5c(c4)oc4ccccc45)c4cc(-c5ccccc5)cc(c42)O3)cc(C(C)(C)C)c1 ; CC(C)(C)c1cc(-c2ccc3c(c2)B2c4cc(-c5cc(C(C)(C)C)cc(C(C)(C)C)c5)ccc4N(c4c(-c5ccc6c(c5)sc5ccccc56)cccc4-c4ccc5c(c4)sc4ccccc45)c4cc(-c5ccccc5)cc(c42)O3)cc(C(C)(C)C)c1]

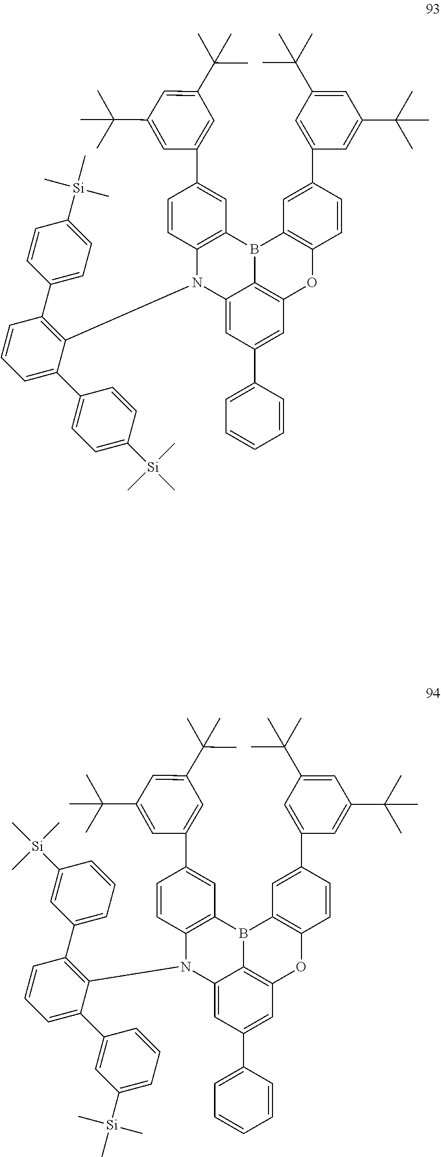

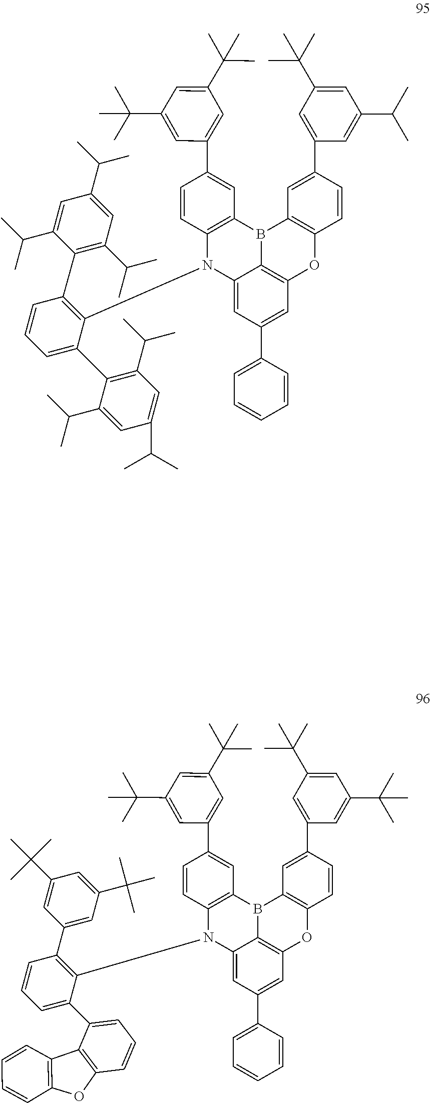 [SMILES: CC(C)c1cc(-c2ccc3c(c2)B2c4cc(-c5cc(C(C)(C)C)cc(C(C)(C)C)c5)ccc4N(c4c(-c5c(C(C)C)cc(C(C)C)cc5C(C)C)cccc4-c4c(C(C)C)cc(C(C)C)cc4C(C)C)c4cc(-c5ccccc5)cc(c42)O3)cc(C(C)(C)C)c1 ; CC(C)(C)c1cc(-c2ccc3c(c2)B2c4cc(-c5cc(C(C)(C)C)cc(C(C)(C)C)c5)ccc4N(c4c(-c5cc(C(C)(C)C)cc(C(C)(C)C)c5)cccc4-c4cccc5oc6ccccc6c45)c4cc(-c5ccccc5)cc(c42)O3)cc(C(C)(C)C)c1]

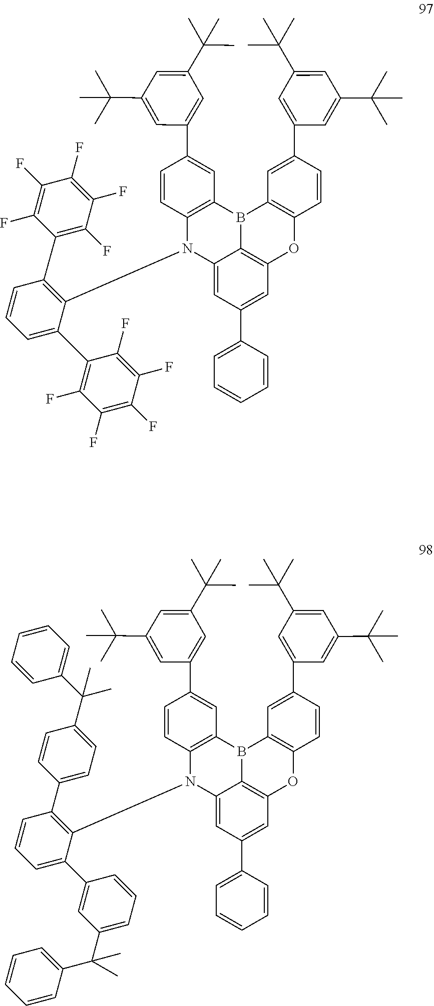 [SMILES: CC(C)(C)c1cc(-c2ccc3c(c2)B2c4cc(-c5cc(C(C)(C)C)cc(C(C)(C)C)c5)ccc4N(c4c(-c5c(F)c(F)c(F)c(F)c5F)cccc4-c4c(F)c(F)c(F)c(F)c4F)c4cc(-c5ccccc5)cc(c42)O3)cc(C(C)(C)C)c1 ; CC(C)(C)c1cc(-c2ccc3c(c2)B2c4cc(-c5cc(C(C)(C)C)cc(C(C)(C)C)c5)ccc4N(c4c(-c5ccc(C(C)(C)c6ccccc6)cc5)cccc4-c4cccc(C(C)(C)c5ccccc5)c4)c4cc(-c5ccccc5)cc(c42)O3)cc(C(C)(C)C)c1]

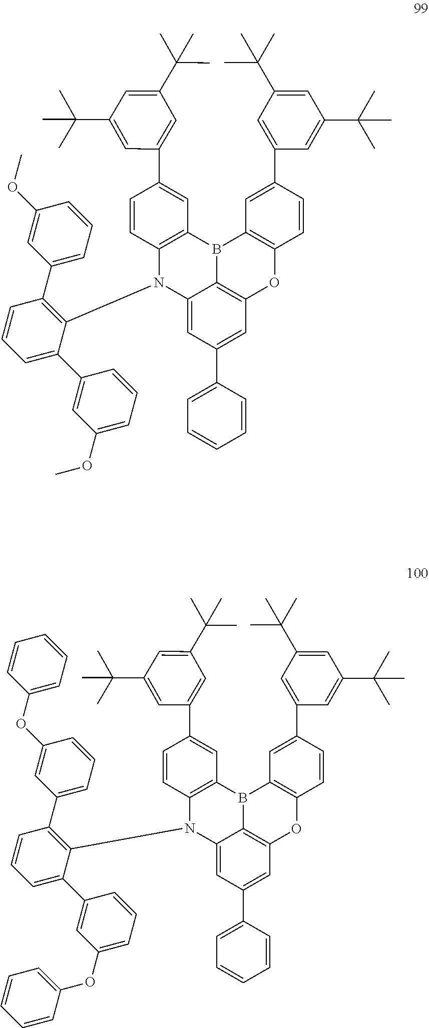 [SMILES: COc1cccc(-c2cccc(-c3cccc(OC)c3)c2N2c3ccc(-c4cc(C(C)(C)C)cc(C(C)(C)C)c4)cc3B3c4cc(-c5cc(C(C)(C)C)cc(C(C)(C)C)c5)ccc4Oc4cc(-c5ccccc5)cc2c43)c1 ; CC(C)(C)c1cc(-c2ccc3c(c2)B2c4cc(-c5cc(C(C)(C)C)cc(C(C)(C)C)c5)ccc4N(c4c(-c5cccc(Oc6ccccc6)c5)cccc4-c4cccc(Oc5ccccc5)c4)c4cc(-c5ccccc5)cc(c42)O3)cc(C(C)(C)C)c1]

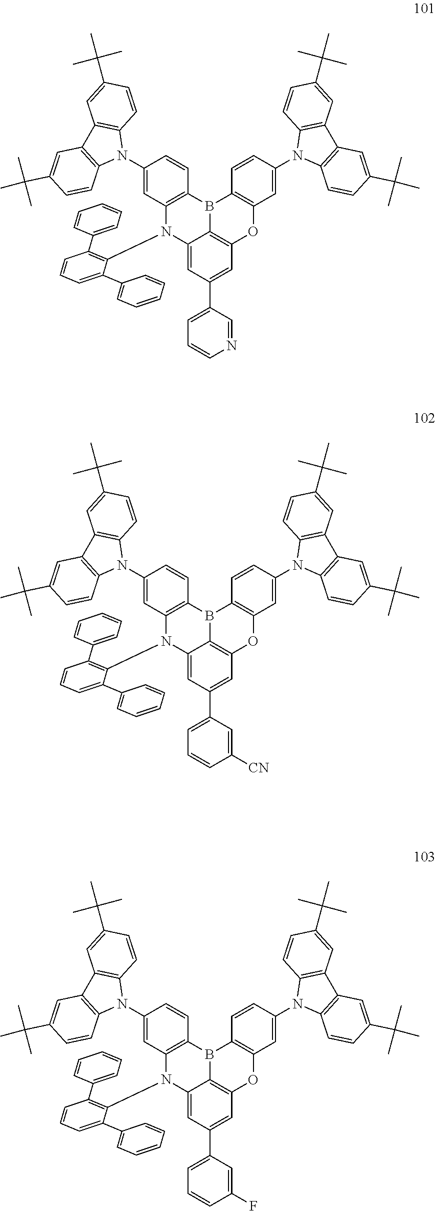

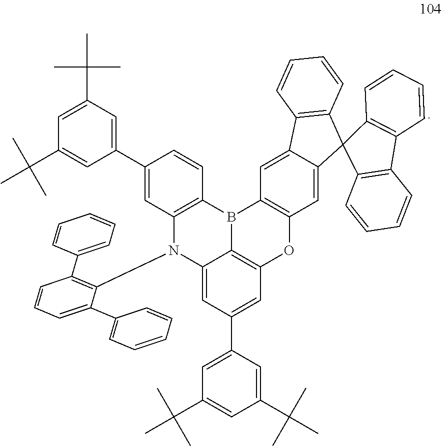 [SMILES: CC(C)(C)c1cc(-c2ccc3c(c2)N(c2c(-c4ccccc4)cccc2-c2ccccc2)c2cc(-c4cc(C(C)(C)C)cc(C(C)(C)C)c4)cc4c2B3c2cc3c(cc2O4)C2(c4ccccc4-c4ccccc42)c2ccccc2-3)cc(C(C)(C)C)c1]

10. The light emitting device of claim 1, wherein the emission layer further comprises a second compound represented by Formula H-1 below: 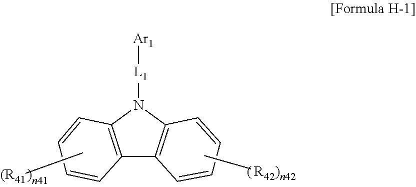
wherein, in Formula H-1 above,
L₁ is a direct linkage, a substituted or unsubstituted arylene group having 6 to 30 ring-forming carbon atoms, or a substituted or unsubstituted heteroarylene group having 2 to 30 ring-forming carbon atoms,
Ar₁ is a substituted or unsubstituted aryl group having 6 to 30 ring-forming carbon atoms, or a substituted or unsubstituted heteroaryl group having 2 to 30 ring-forming carbon atoms,
R₄₁ and R₄₂ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring, and
n41 and n42 are each independently an integer of 0 to 4.

11. The light emitting device of claim 1, wherein the emission layer further comprises a third compound represented by Formula H-2 below: 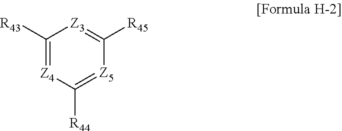
wherein, in Formula H-2 above,
Z₃ to Z₅ are each independently N or CR₄₆,
at least one selected from among Z₃ to Z₅ is N, and
R₄₃ to R₄₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring.

12. The light emitting device of claim 1, wherein the emission layer further comprises a fourth compound represented by Formula D-1 below: 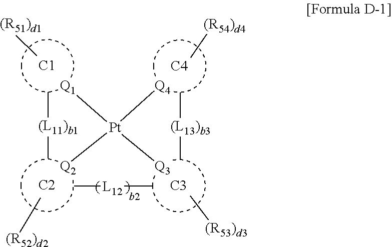
wherein, in Formula D-1 above,
Q₁ to Q₄ are each independently C or N,
C1 to C4 are each independently a substituted or unsubstituted hydrocarbon ring having 5 to 30 ring-forming carbon atoms, or a substituted or unsubstituted heterocycle having 2 to 30 ring-forming carbon atoms,
L₁₁ to L₁₃ are each independently a direct linkage, 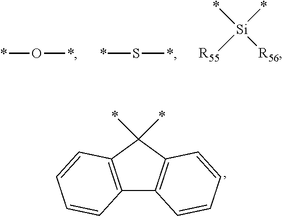
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b1 to b3 are each independently 0 or 1,
R₅₁ to R₅₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or are bonded to an adjacent group to form a ring, and
d1 to d4 are each independently an integer of 0 to 4.

13. A fused polycyclic compound represented by Formula 1 below: 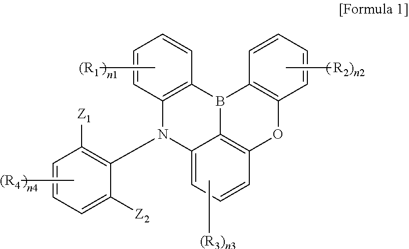
wherein, in Formula 1 above,
R₁ to R₆ are each independently a hydrogen atom, a deuterium atom, a halogen atom, a cyano group, a nitro group, a substituted or unsubstituted oxy group, a substituted or unsubstituted silyl group, a substituted or unsubstituted amine group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
Z₁ and Z₂ are each independently a substituted or unsubstituted aryl group having 6 to 30 ring-forming carbon atoms, or a substituted or unsubstituted heteroaryl group having 2 to 30 ring-forming carbon atoms,
n1 and n2 are each independently an integer of 0 to 4, and
n3 and n4 are each independently an integer of 0 to 3.

14. The fused polycyclic compound of claim 13, wherein the fused polycyclic compound represented by Formula 1 above is represented by Formula 2 below: 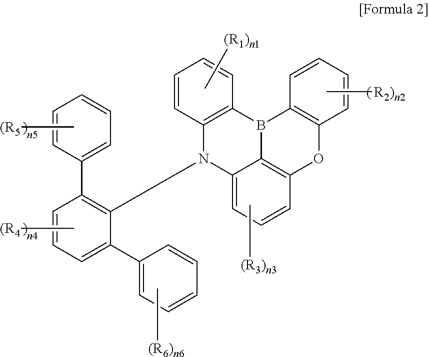
wherein, in Formula 2 above,
R₅ and R₆ are each independently a hydrogen atom, a deuterium atom, a halogen atom, a cyano group, a nitro group, a substituted or unsubstituted oxy group, a substituted or unsubstituted thio group, a substituted or unsubstituted silyl group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
n5 and n6 are each independently an integer of 0 to 5, and
R₁ to R₄, and n1 to n4 are the same as defined with respect to Formula 1 above.

15. The fused polycyclic compound of claim 13, wherein the fused polycyclic compound represented by Formula 1 above is represented by any one selected from among Formula 3-1 to Formula 3-3 below: 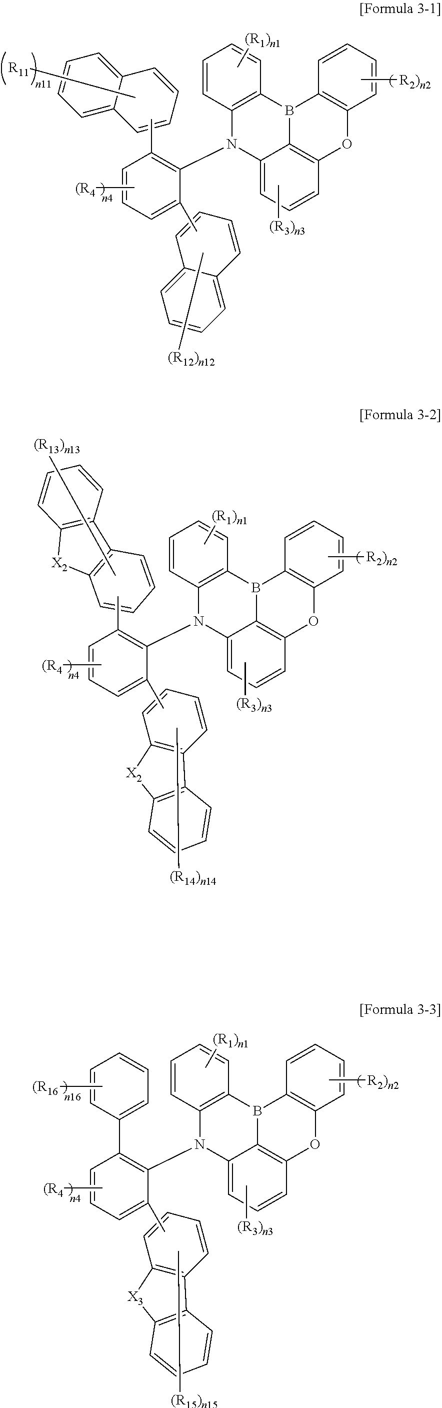
wherein, in Formula 3-1 to Formula 3-3 above,
X₁ to X₃ are each independently NR₁₇, O or S,
R₁₁ to R₁₇ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n11 to n15 are each independently an integer of 0 to 7,
n16 is an integer of 0 to 5, and
R₁ to R₄, and n1 to n4 are the same as defined with respect to Formula 1 above.

16. The fused polycyclic compound of claim 13, wherein the fused polycyclic compound represented by Formula 1 above is represented by Formula 4 below: 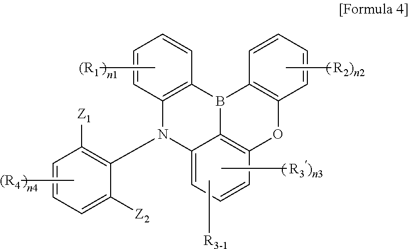
wherein, in Formula 4 above,
R₃₋₁ is a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R₃′ is a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n3′ is an integer of 0 to 2, and
R₁, R₂, R₄, n1, n2, n4, Z₁, and Z₂ are the same as defined with respect to Formula 1 above.

17. The fused polycyclic compound of claim 13, wherein the fused polycyclic compound represented by Formula 1 above is represented by any one selected from among Formula 6-1 to Formula 6-4 below: 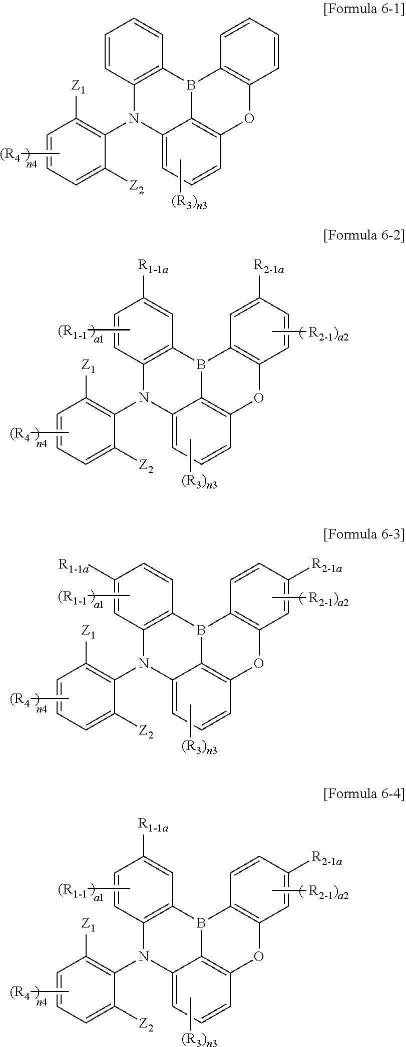
wherein, in Formula 6-1 to Formula 6-4 above,
R₁₋₁ and R₂₋₁ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R₁₋₁ₐ and R₂₋₁ₐ are each independently a substituted or unsubstituted amine group, a substituted or unsubstituted phenyl group, a substituted or unsubstituted dibenzofuran group, or a substituted or unsubstituted carbazole group,
a1 and a2 are each independently an integer of 0 to 3, and
R₃, R₄, n3, n4, Z₁, and Z₂ are the same as defined with respect to Formula 1 above.

18. The fused polycyclic compound of claim 13, wherein the fused polycyclic compound represented by Formula 1 above is represented by any one selected from among Formula 7-1 to Formula 7-5 below: 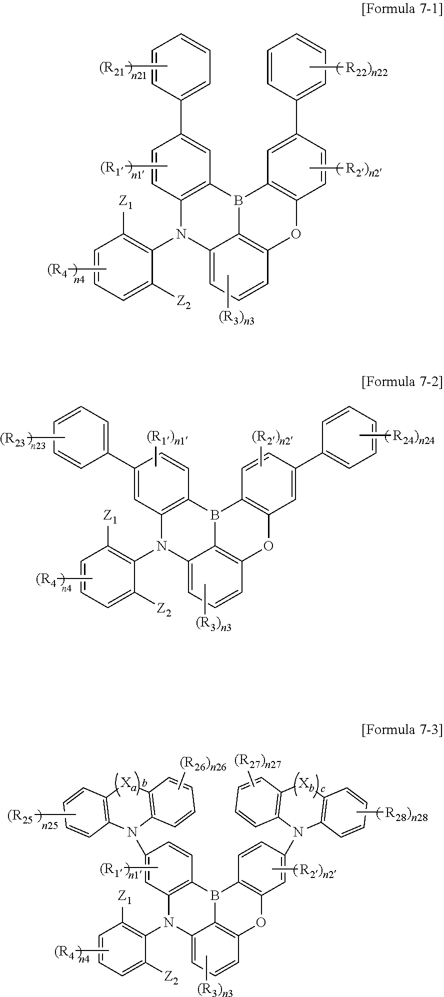 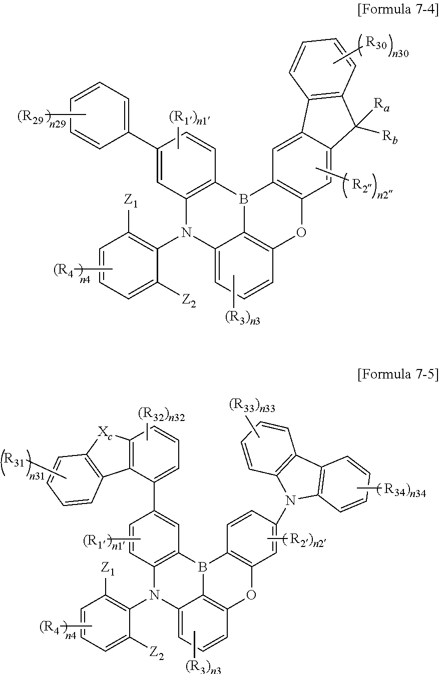
wherein, in Formula 7-1 to Formula 7-5 above,
Xₐ to X_{c} are each independently a direct linkage, O, NR₃₅, CR₃₆R₃₇, S, or Se,
R₂₁ to R₃₇ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
Rₐ and R_{b} are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring,
R₁′, R₂′, and R₂″ are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
n1′, n2′, and n32 are each independently an integer of 0 to 3,
n2″ is an integer of 0 to 2,
b and c are each independently 0 or 1,
n21 to n29 are each independently an integer of 0 to 5,
n30, n31, n33, and n34 are each independently an integer of 0 to 4,
the sum of b and n25 is 5 or less,
the sum of b and n26 is 5 or less,
the sum of c and n27 is 5 or less,
the sum of c and n28 is 5 or less, and
R₃, R₄, n3, n4, Z₁, and Z₂ are the same as defined with respect to Formula 1 above.

19. The fused polycyclic compound of claim 13, wherein Z₁ and Z₂ above are each independently represented by any one selected from among Formula 8-1 to Formula 8-4 below: 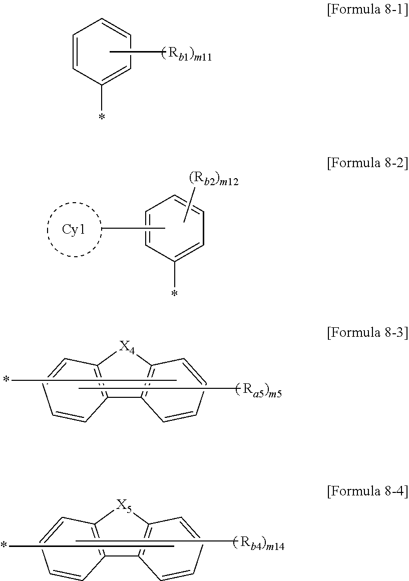
wherein, in Formula 8-1 to Formula 8-4 above,
Cy1 is a substituted or unsubstituted cycloalkyl group having 3 to 10 carbon atoms,
X₅ is NR_{b5}, O, or S,
R_{b1} to R_{b5} are each independently a hydrogen atom, a deuterium atom, a halogen atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
m11 is an integer of 0 to 5,
m12 is an integer of 0 to 4, and
m13 and m14 are each independently an integer of 0 to 7.

20. The fused polycyclic compound of claim 13, wherein the fused polycyclic compound represented by Formula 1 above comprises at least one selected from among compounds represented by Compound Group 1 below: 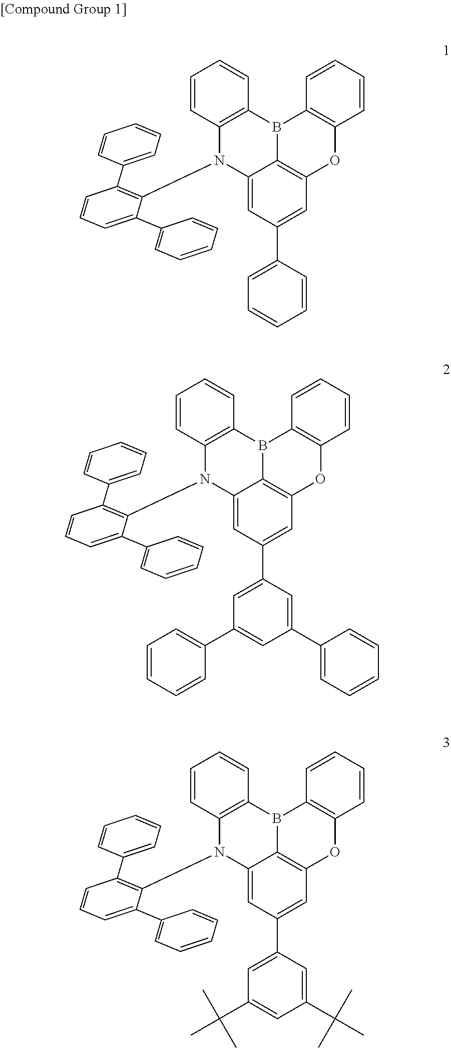 [SMILES: c1ccc(-c2cc3c4c(c2)N(c2c(-c5ccccc5)cccc2-c2ccccc2)c2ccccc2B4c2ccccc2O3)cc1 ; c1ccc(-c2cc(-c3ccccc3)cc(-c3cc4c5c(c3)N(c3c(-c6ccccc6)cccc3-c3ccccc3)c3ccccc3B5c3ccccc3O4)c2)cc1 ; CC(C)(C)c1cc(-c2cc3c4c(c2)N(c2c(-c5ccccc5)cccc2-c2ccccc2)c2ccccc2B4c2ccccc2O3)cc(C(C)(C)C)c1] 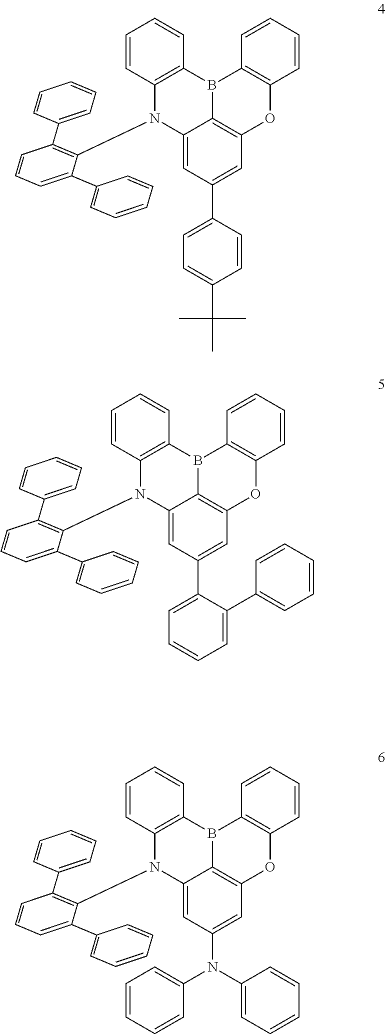 [SMILES: CC(C)(C)c1ccc(-c2cc3c4c(c2)N(c2c(-c5ccccc5)cccc2-c2ccccc2)c2ccccc2B4c2ccccc2O3)cc1 ; c1ccc(-c2ccccc2-c2cc3c4c(c2)N(c2c(-c5ccccc5)cccc2-c2ccccc2)c2ccccc2B4c2ccccc2O3)cc1 ; c1ccc(-c2cccc(-c3ccccc3)c2N2c3ccccc3B3c4ccccc4Oc4cc(N(c5ccccc5)c5ccccc5)cc2c43)cc1] 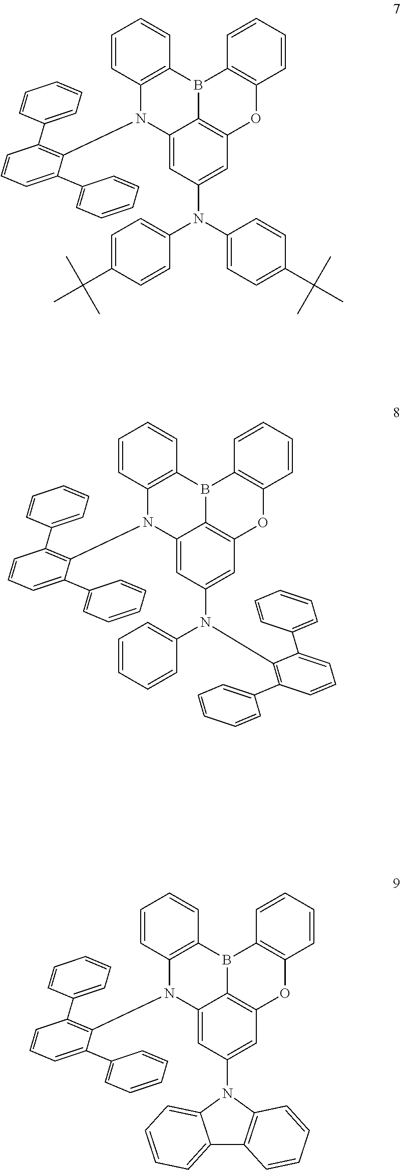 [SMILES: CC(C)(C)c1ccc(N(c2ccc(C(C)(C)C)cc2)c2cc3c4c(c2)N(c2c(-c5ccccc5)cccc2-c2ccccc2)c2ccccc2B4c2ccccc2O3)cc1 ; c1ccc(-c2cccc(-c3ccccc3)c2N(c2ccccc2)c2cc3c4c(c2)N(c2c(-c5ccccc5)cccc2-c2ccccc2)c2ccccc2B4c2ccccc2O3)cc1 ; c1ccc(-c2cccc(-c3ccccc3)c2N2c3ccccc3B3c4ccccc4Oc4cc(-n5c6ccccc6c6ccccc65)cc2c43)cc1] 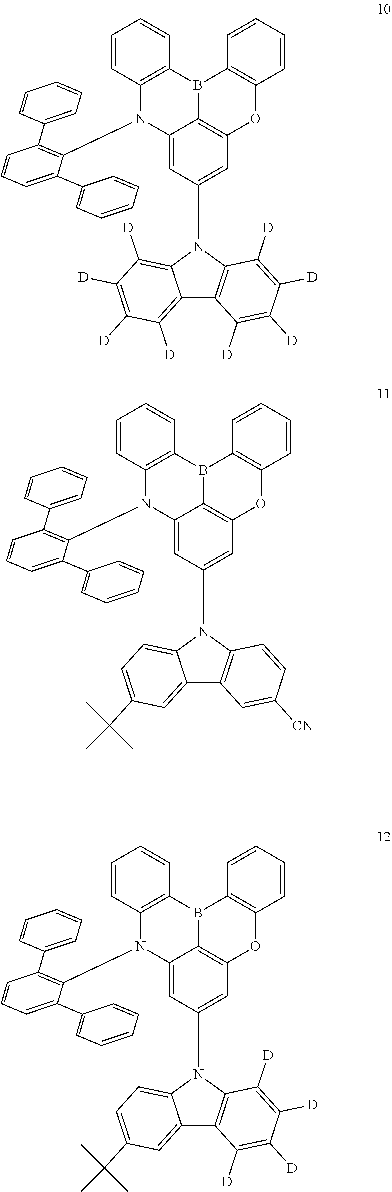 [SMILES: [2H]c1c([2H])c([2H])c2c(c1[2H])c1c([2H])c([2H])c([2H])c([2H])c1n2-c1cc2c3c(c1)N(c1c(-c4ccccc4)cccc1-c1ccccc1)c1ccccc1B3c1ccccc1O2 ; CC(C)(C)c1ccc2c(c1)c1cc(C#N)ccc1n2-c1cc2c3c(c1)N(c1c(-c4ccccc4)cccc1-c1ccccc1)c1ccccc1B3c1ccccc1O2 ; [2H]c1c([2H])c([2H])c2c(c1[2H])c1cc(C(C)(C)C)ccc1n2-c1cc2c3c(c1)N(c1c(-c4ccccc4)cccc1-c1ccccc1)c1ccccc1B3c1ccccc1O2] 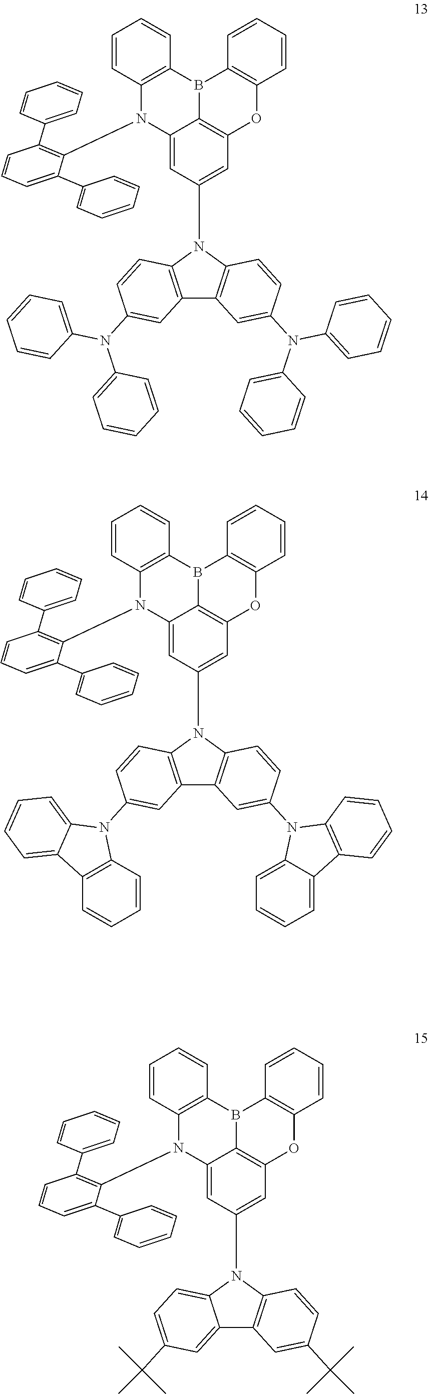 [SMILES: c1ccc(-c2cccc(-c3ccccc3)c2N2c3ccccc3B3c4ccccc4Oc4cc(-n5c6ccc(N(c7ccccc7)c7ccccc7)cc6c6cc(N(c7ccccc7)c7ccccc7)ccc65)cc2c43)cc1 ; c1ccc(-c2cccc(-c3ccccc3)c2N2c3ccccc3B3c4ccccc4Oc4cc(-n5c6ccc(-n7c8ccccc8c8ccccc87)cc6c6cc(-n7c8ccccc8c8ccccc87)ccc65)cc2c43)cc1 ; CC(C)(C)c1ccc2c(c1)c1cc(C(C)(C)C)ccc1n2-c1cc2c3c(c1)N(c1c(-c4ccccc4)cccc1-c1ccccc1)c1ccccc1B3c1ccccc1O2] 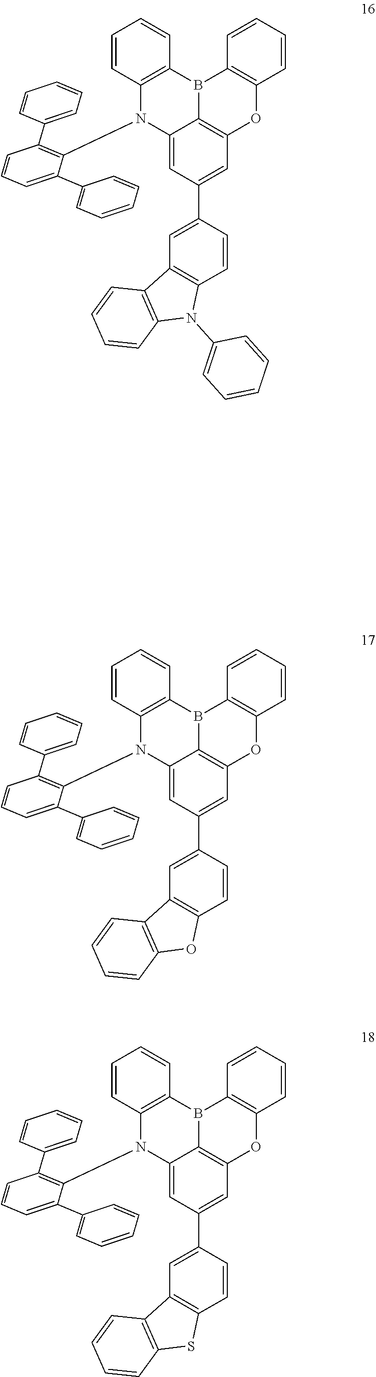 [SMILES: c1ccc(-c2cccc(-c3ccccc3)c2N2c3ccccc3B3c4ccccc4Oc4cc(-c5ccc6c(c5)c5ccccc5n6-c5ccccc5)cc2c43)cc1 ; c1ccc(-c2cccc(-c3ccccc3)c2N2c3ccccc3B3c4ccccc4Oc4cc(-c5ccc6oc7ccccc7c6c5)cc2c43)cc1 ; c1ccc(-c2cccc(-c3ccccc3)c2N2c3ccccc3B3c4ccccc4Oc4cc(-c5ccc6sc7ccccc7c6c5)cc2c43)cc1] 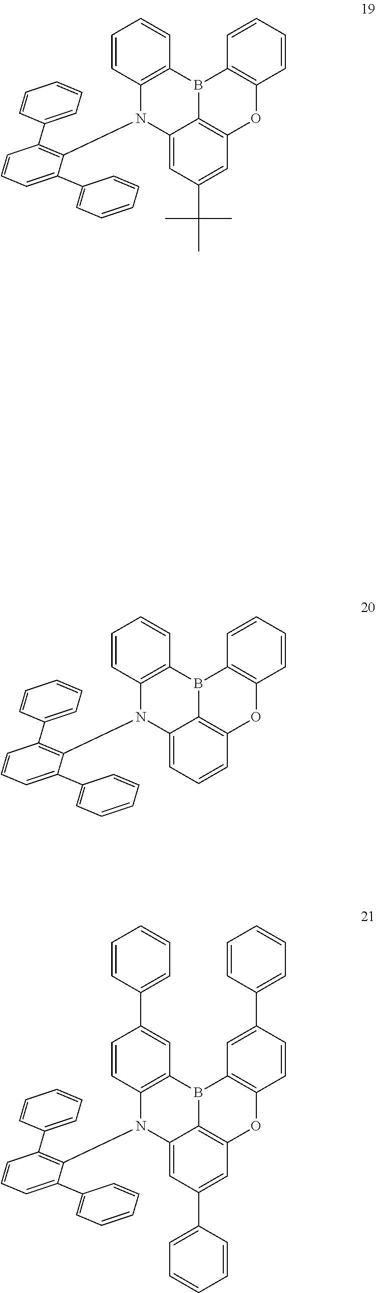 [SMILES: CC(C)(C)c1cc2c3c(c1)N(c1c(-c4ccccc4)cccc1-c1ccccc1)c1ccccc1B3c1ccccc1O2 ; c1ccc(-c2cccc(-c3ccccc3)c2N2c3ccccc3B3c4ccccc4Oc4cccc2c43)cc1 ; c1ccc(-c2ccc3c(c2)B2c4cc(-c5ccccc5)ccc4N(c4c(-c5ccccc5)cccc4-c4ccccc4)c4cc(-c5ccccc5)cc(c42)O3)cc1] 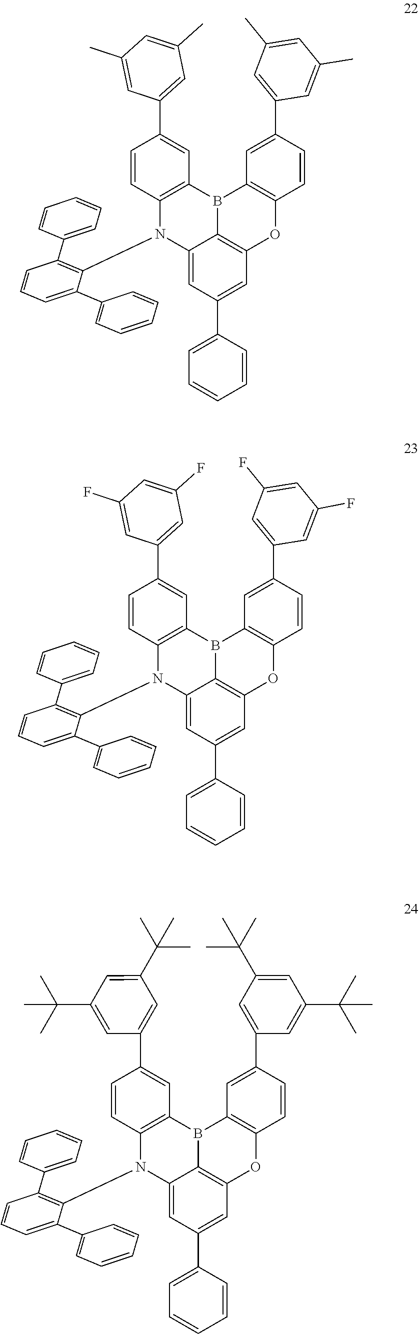 [SMILES: Cc1cc(C)cc(-c2ccc3c(c2)B2c4cc(-c5cc(C)cc(C)c5)ccc4N(c4c(-c5ccccc5)cccc4-c4ccccc4)c4cc(-c5ccccc5)cc(c42)O3)c1 ; Fc1cc(F)cc(-c2ccc3c(c2)B2c4cc(-c5cc(F)cc(F)c5)ccc4N(c4c(-c5ccccc5)cccc4-c4ccccc4)c4cc(-c5ccccc5)cc(c42)O3)c1 ; CC(C)(C)c1cc(-c2ccc3c(c2)B2c4cc(-c5cc(C(C)(C)C)cc(C(C)(C)C)c5)ccc4N(c4c(-c5ccccc5)cccc4-c4ccccc4)c4cc(-c5ccccc5)cc(c42)O3)cc(C(C)(C)C)c1] 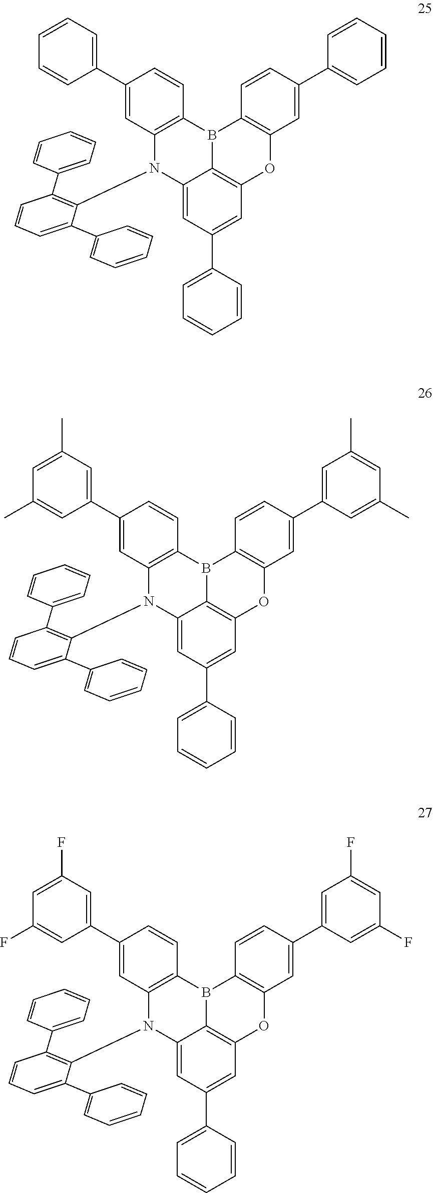 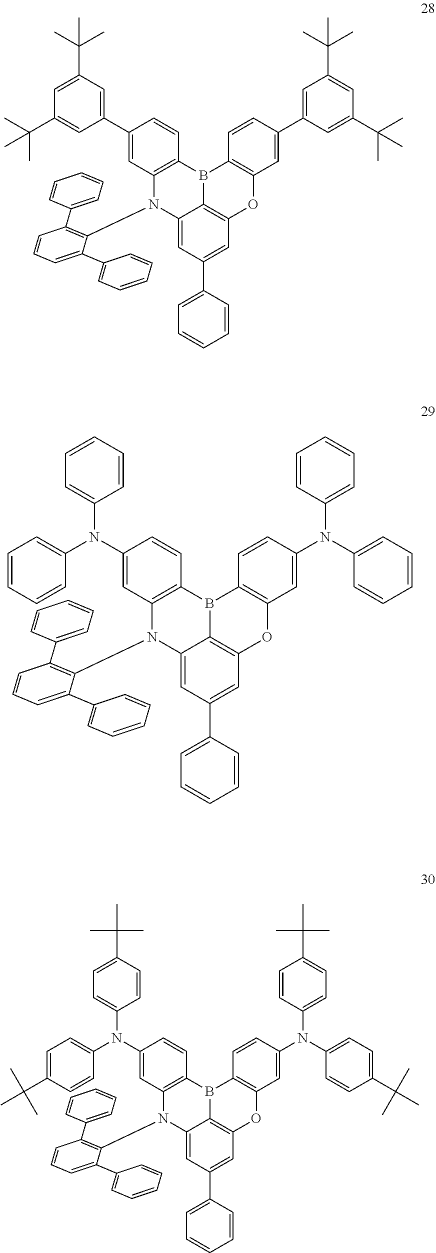 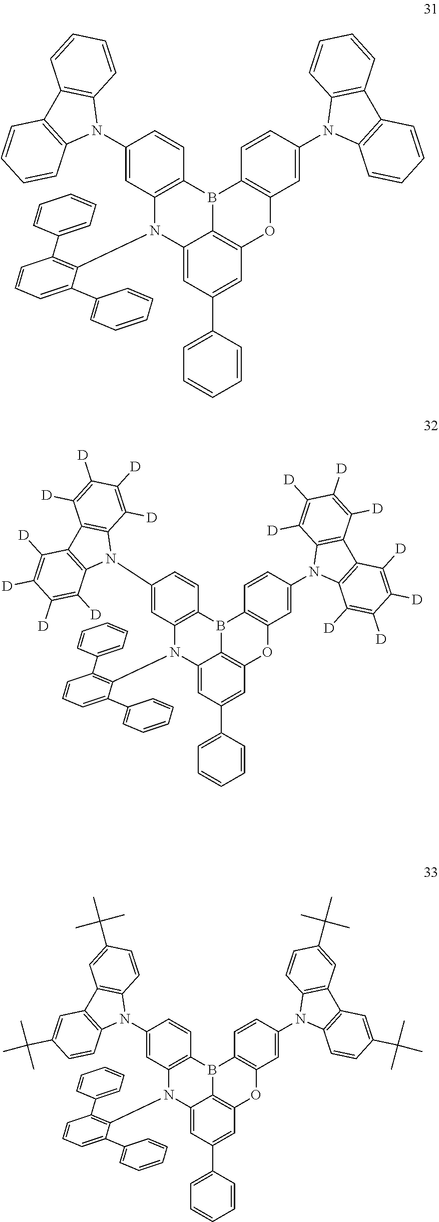 [SMILES: c1ccc(-c2cc3c4c(c2)N(c2c(-c5ccccc5)cccc2-c2ccccc2)c2cc(-n5c6ccccc6c6ccccc65)ccc2B4c2ccc(-n4c5ccccc5c5ccccc54)cc2O3)cc1 ; [2H]c1c([2H])c([2H])c2c(c1[2H])c1c([2H])c([2H])c([2H])c([2H])c1n2-c1ccc2c(c1)Oc1cc(-c3ccccc3)cc3c1B2c1ccc(-n2c4c([2H])c([2H])c([2H])c([2H])c4c4c([2H])c([2H])c([2H])c([2H])c42)cc1N3c1c(-c2ccccc2)cccc1-c1ccccc1 ; CC(C)(C)c1ccc2c(c1)c1cc(C(C)(C)C)ccc1n2-c1ccc2c(c1)Oc1cc(-c3ccccc3)cc3c1B2c1ccc(-n2c4ccc(C(C)(C)C)cc4c4cc(C(C)(C)C)ccc42)cc1N3c1c(-c2ccccc2)cccc1-c1ccccc1] 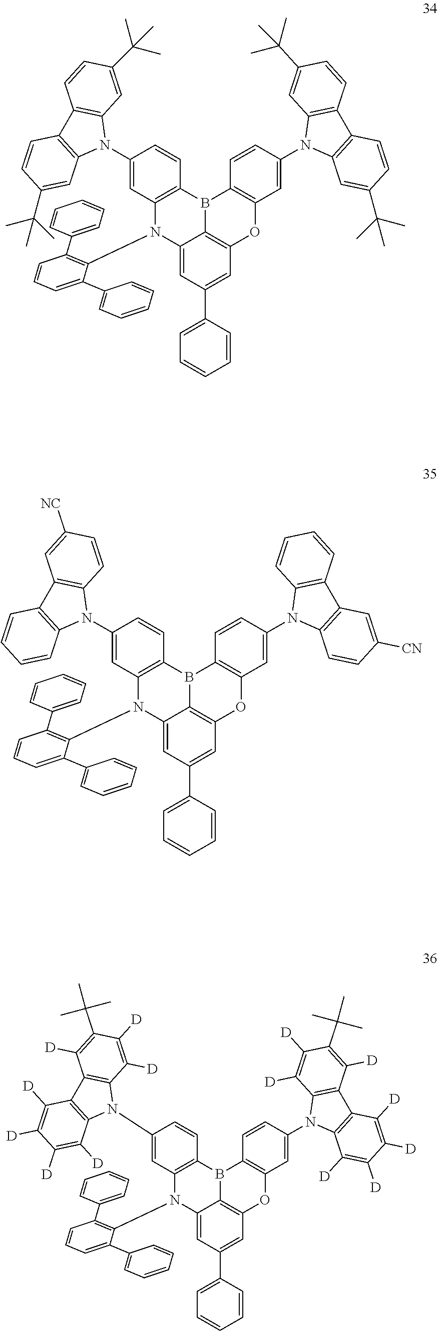 [SMILES: CC(C)(C)c1ccc2c3ccc(C(C)(C)C)cc3n(-c3ccc4c(c3)Oc3cc(-c5ccccc5)cc5c3B4c3ccc(-n4c6cc(C(C)(C)C)ccc6c6ccc(C(C)(C)C)cc64)cc3N5c3c(-c4ccccc4)cccc3-c3ccccc3)c2c1 ; N#Cc1ccc2c(c1)c1ccccc1n2-c1ccc2c(c1)Oc1cc(-c3ccccc3)cc3c1B2c1ccc(-n2c4ccccc4c4cc(C#N)ccc42)cc1N3c1c(-c2ccccc2)cccc1-c1ccccc1 ; [2H]c1c([2H])c([2H])c2c(c1[2H])c1c([2H])c(C(C)(C)C)c([2H])c([2H])c1n2-c1ccc2c(c1)Oc1cc(-c3ccccc3)cc3c1B2c1ccc(-n2c4c([2H])c([2H])c([2H])c([2H])c4c4c([2H])c(C(C)(C)C)c([2H])c([2H])c42)cc1N3c1c(-c2ccccc2)cccc1-c1ccccc1] 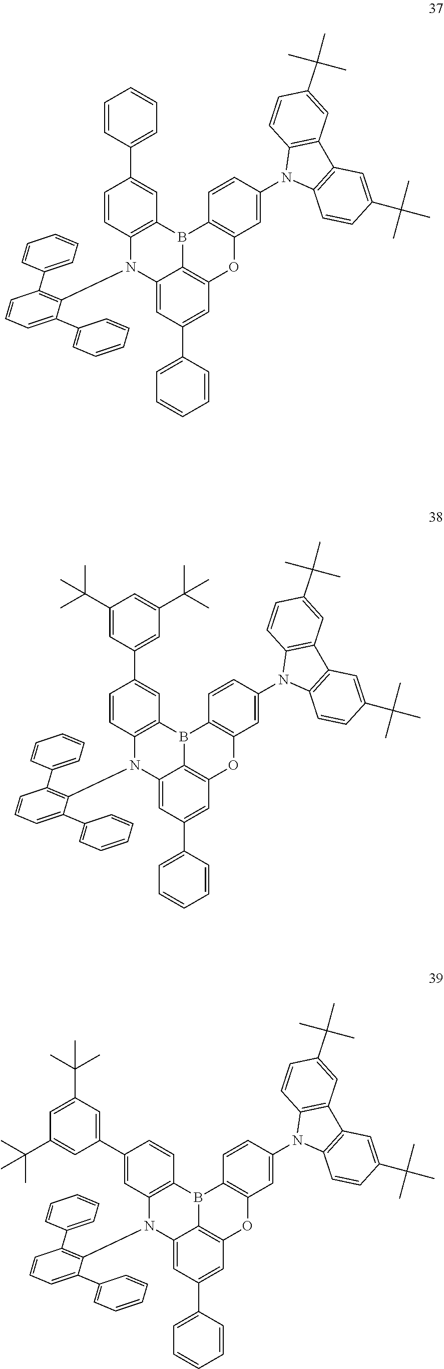 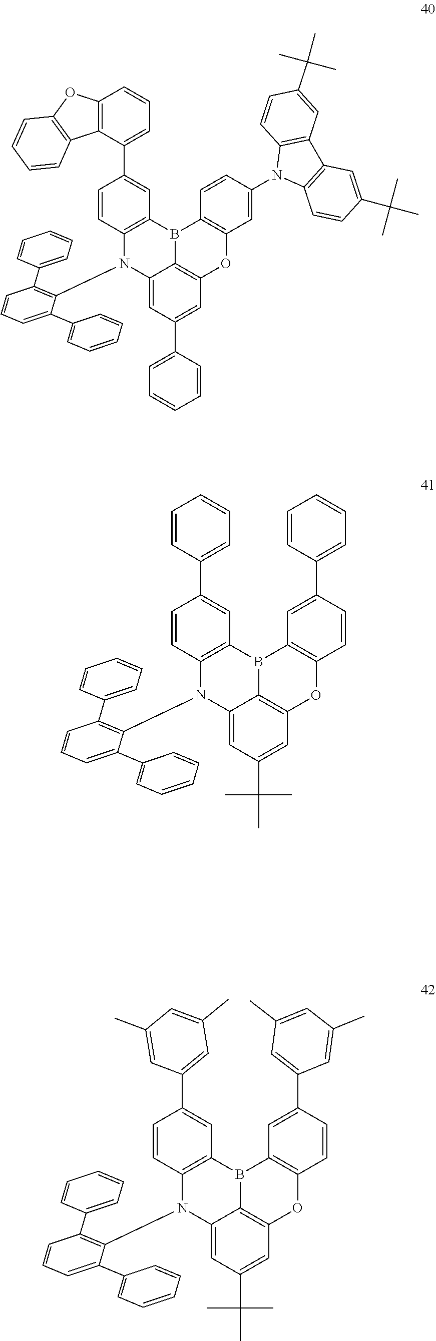 [SMILES: CC(C)(C)c1ccc2c(c1)c1cc(C(C)(C)C)ccc1n2-c1ccc2c(c1)Oc1cc(-c3ccccc3)cc3c1B2c1cc(-c2cccc4oc5ccccc5c24)ccc1N3c1c(-c2ccccc2)cccc1-c1ccccc1 ; CC(C)(C)c1cc2c3c(c1)N(c1c(-c4ccccc4)cccc1-c1ccccc1)c1ccc(-c4ccccc4)cc1B3c1cc(-c3ccccc3)ccc1O2 ; Cc1cc(C)cc(-c2ccc3c(c2)B2c4cc(-c5cc(C)cc(C)c5)ccc4N(c4c(-c5ccccc5)cccc4-c4ccccc4)c4cc(C(C)(C)C)cc(c42)O3)c1] 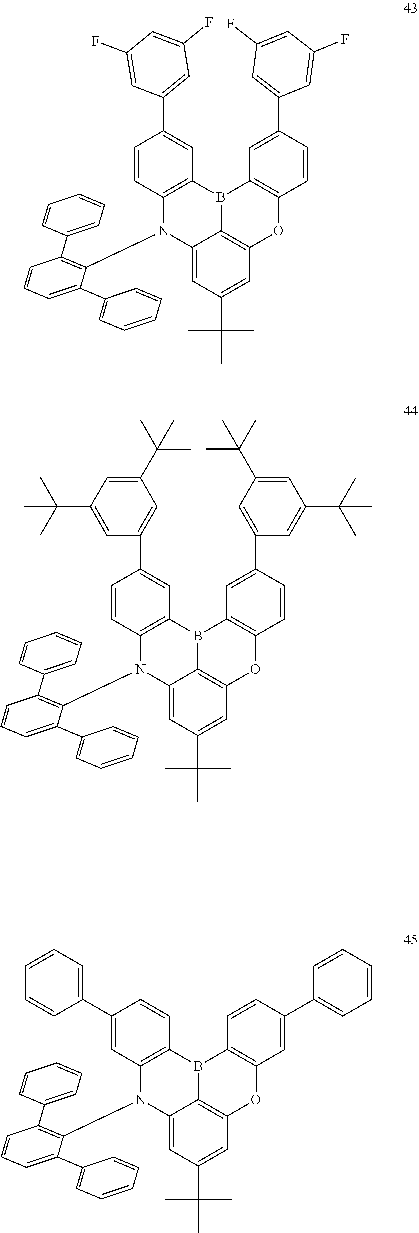 [SMILES: CC(C)(C)c1cc2c3c(c1)N(c1c(-c4ccccc4)cccc1-c1ccccc1)c1ccc(-c4cc(F)cc(F)c4)cc1B3c1cc(-c3cc(F)cc(F)c3)ccc1O2 ; CC(C)(C)c1cc(-c2ccc3c(c2)B2c4cc(-c5cc(C(C)(C)C)cc(C(C)(C)C)c5)ccc4N(c4c(-c5ccccc5)cccc4-c4ccccc4)c4cc(C(C)(C)C)cc(c42)O3)cc(C(C)(C)C)c1 ; CC(C)(C)c1cc2c3c(c1)N(c1c(-c4ccccc4)cccc1-c1ccccc1)c1cc(-c4ccccc4)ccc1B3c1ccc(-c3ccccc3)cc1O2] 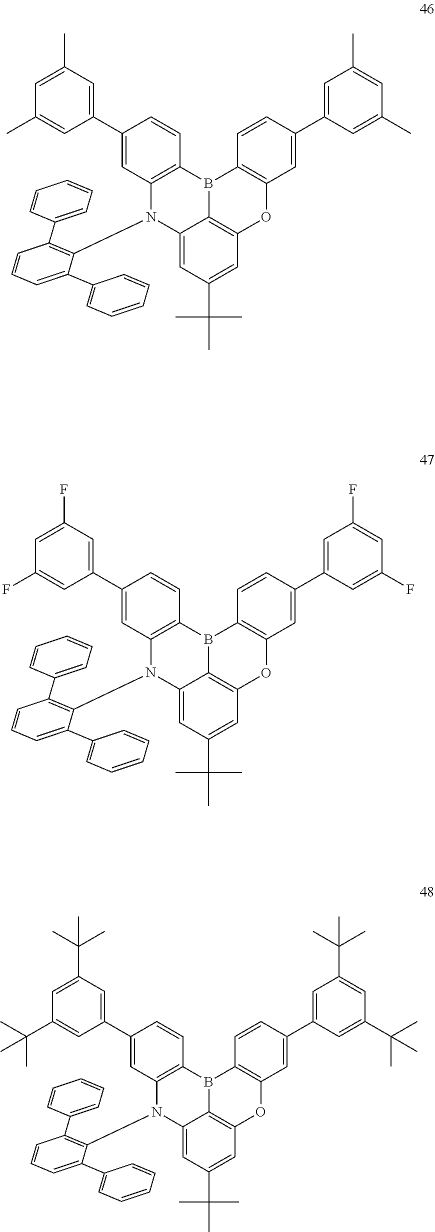 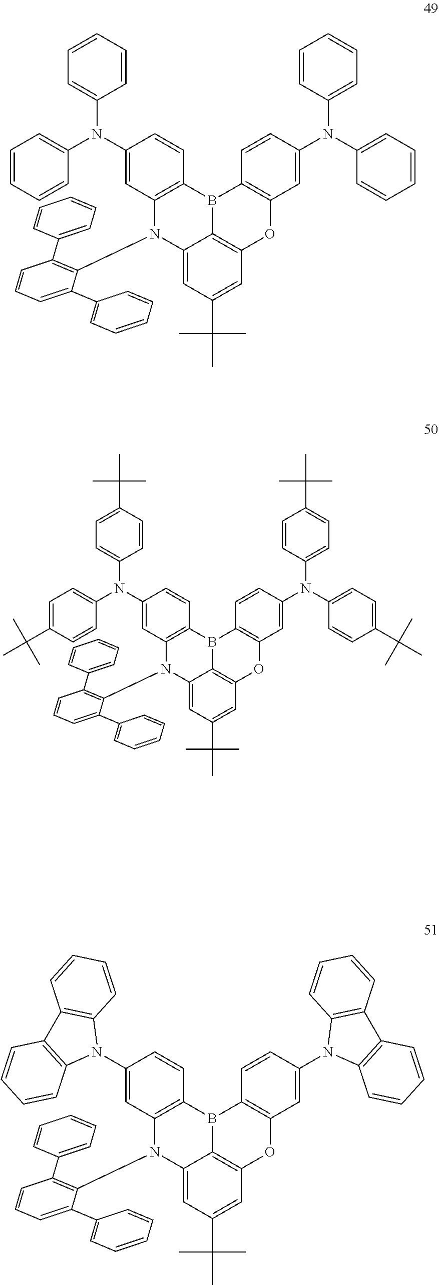 [SMILES: CC(C)(C)c1cc2c3c(c1)N(c1c(-c4ccccc4)cccc1-c1ccccc1)c1cc(N(c4ccccc4)c4ccccc4)ccc1B3c1ccc(N(c3ccccc3)c3ccccc3)cc1O2 ; CC(C)(C)c1ccc(N(c2ccc(C(C)(C)C)cc2)c2ccc3c(c2)Oc2cc(C(C)(C)C)cc4c2B3c2ccc(N(c3ccc(C(C)(C)C)cc3)c3ccc(C(C)(C)C)cc3)cc2N4c2c(-c3ccccc3)cccc2-c2ccccc2)cc1 ; CC(C)(C)c1cc2c3c(c1)N(c1c(-c4ccccc4)cccc1-c1ccccc1)c1cc(-n4c5ccccc5c5ccccc54)ccc1B3c1ccc(-n3c4ccccc4c4ccccc43)cc1O2] 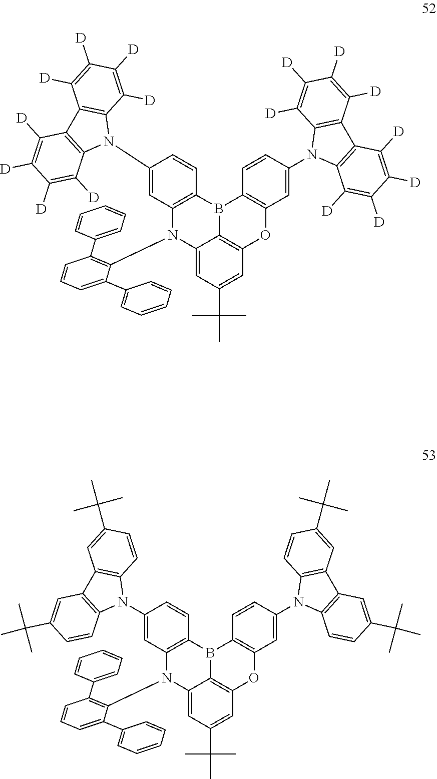 [SMILES: [2H]c1c([2H])c([2H])c2c(c1[2H])c1c([2H])c([2H])c([2H])c([2H])c1n2-c1ccc2c(c1)Oc1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2ccccc2)cccc1-c1ccccc1 ; CC(C)(C)c1cc2c3c(c1)N(c1c(-c4ccccc4)cccc1-c1ccccc1)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1O2] 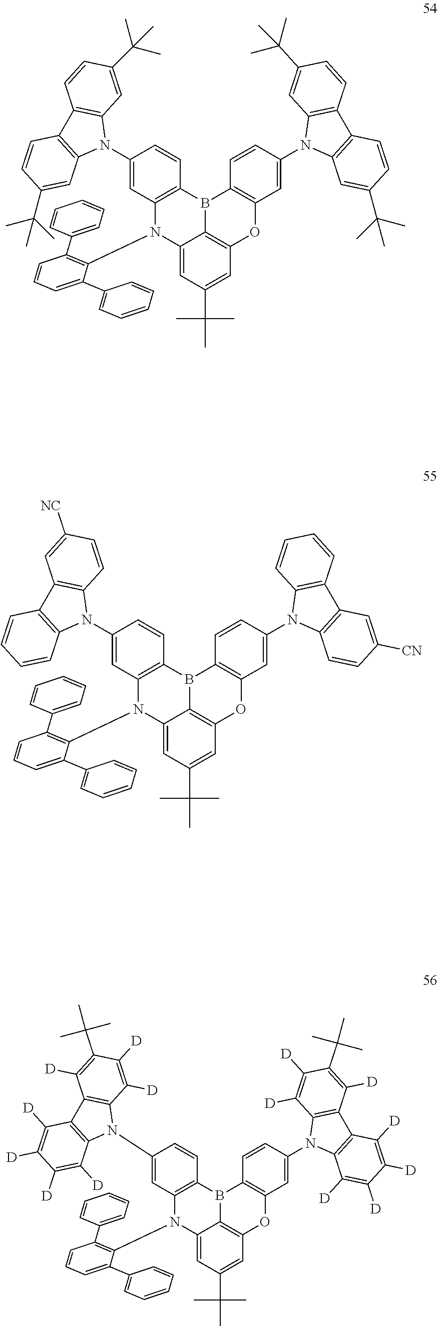 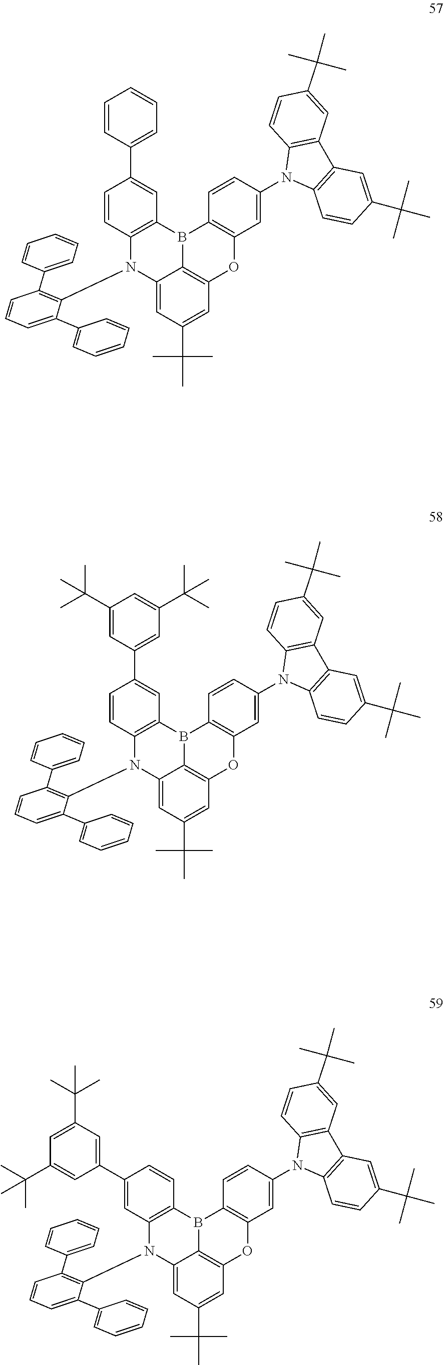 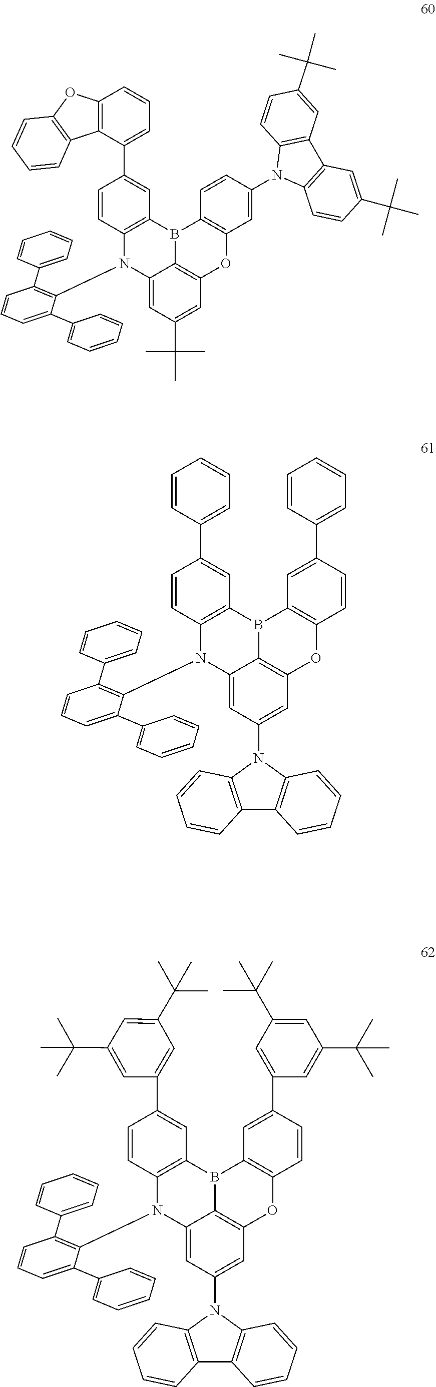 [SMILES: CC(C)(C)c1cc2c3c(c1)N(c1c(-c4ccccc4)cccc1-c1ccccc1)c1ccc(-c4cccc5oc6ccccc6c45)cc1B3c1ccc(-n3c4ccc(C(C)(C)C)cc4c4cc(C(C)(C)C)ccc43)cc1O2 ; c1ccc(-c2ccc3c(c2)B2c4cc(-c5ccccc5)ccc4N(c4c(-c5ccccc5)cccc4-c4ccccc4)c4cc(-n5c6ccccc6c6ccccc65)cc(c42)O3)cc1 ; CC(C)(C)c1cc(-c2ccc3c(c2)B2c4cc(-c5cc(C(C)(C)C)cc(C(C)(C)C)c5)ccc4N(c4c(-c5ccccc5)cccc4-c4ccccc4)c4cc(-n5c6ccccc6c6ccccc65)cc(c42)O3)cc(C(C)(C)C)c1] 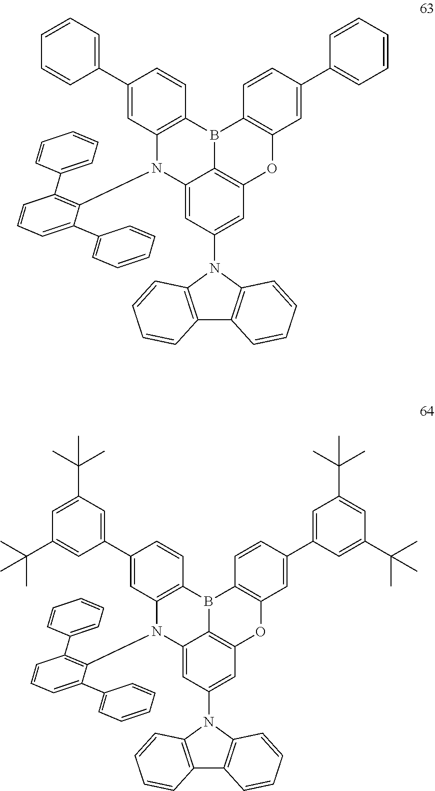 [SMILES: c1ccc(-c2ccc3c(c2)Oc2cc(-n4c5ccccc5c5ccccc54)cc4c2B3c2ccc(-c3ccccc3)cc2N4c2c(-c3ccccc3)cccc2-c2ccccc2)cc1 ; CC(C)(C)c1cc(-c2ccc3c(c2)Oc2cc(-n4c5ccccc5c5ccccc54)cc4c2B3c2ccc(-c3cc(C(C)(C)C)cc(C(C)(C)C)c3)cc2N4c2c(-c3ccccc3)cccc2-c2ccccc2)cc(C(C)(C)C)c1] 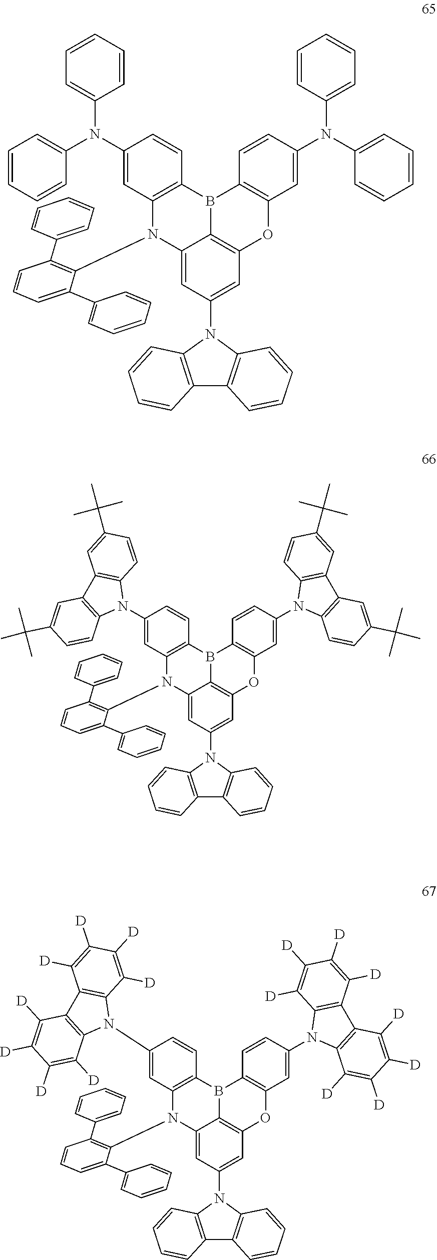 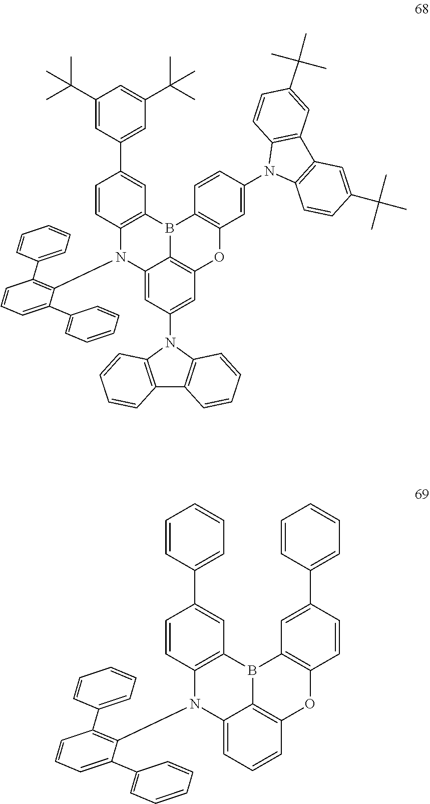 [SMILES: CC(C)(C)c1cc(-c2ccc3c(c2)B2c4ccc(-n5c6ccc(C(C)(C)C)cc6c6cc(C(C)(C)C)ccc65)cc4Oc4cc(-n5c6ccccc6c6ccccc65)cc(c42)N3c2c(-c3ccccc3)cccc2-c2ccccc2)cc(C(C)(C)C)c1 ; c1ccc(-c2ccc3c(c2)B2c4cc(-c5ccccc5)ccc4N(c4c(-c5ccccc5)cccc4-c4ccccc4)c4cccc(c42)O3)cc1] 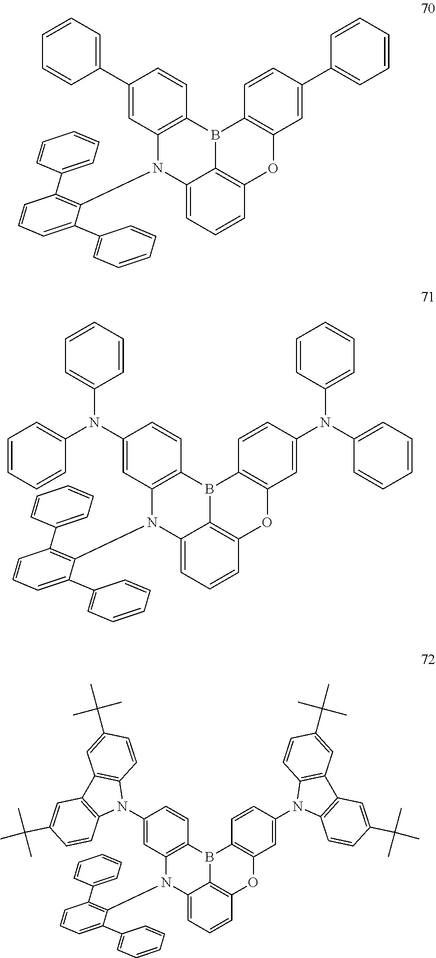 [SMILES: c1ccc(-c2ccc3c(c2)Oc2cccc4c2B3c2ccc(-c3ccccc3)cc2N4c2c(-c3ccccc3)cccc2-c2ccccc2)cc1 ; c1ccc(-c2cccc(-c3ccccc3)c2N2c3cc(N(c4ccccc4)c4ccccc4)ccc3B3c4ccc(N(c5ccccc5)c5ccccc5)cc4Oc4cccc2c43)cc1 ; CC(C)(C)c1ccc2c(c1)c1cc(C(C)(C)C)ccc1n2-c1ccc2c(c1)Oc1cccc3c1B2c1ccc(-n2c4ccc(C(C)(C)C)cc4c4cc(C(C)(C)C)ccc42)cc1N3c1c(-c2ccccc2)cccc1-c1ccccc1] 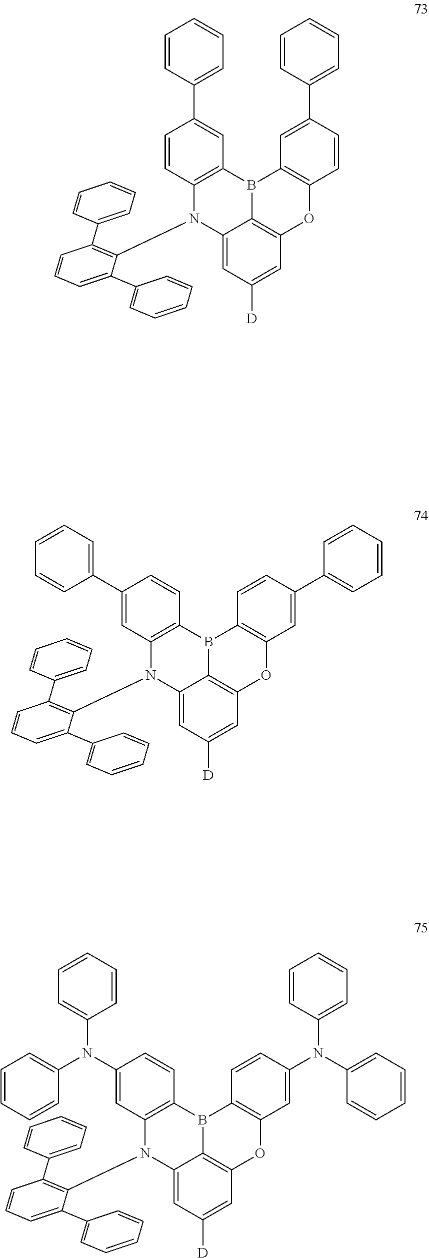 [SMILES: [2H]c1cc2c3c(c1)N(c1c(-c4ccccc4)cccc1-c1ccccc1)c1ccc(-c4ccccc4)cc1B3c1cc(-c3ccccc3)ccc1O2 ; [2H]c1cc2c3c(c1)N(c1c(-c4ccccc4)cccc1-c1ccccc1)c1cc(-c4ccccc4)ccc1B3c1ccc(-c3ccccc3)cc1O2 ; [2H]c1cc2c3c(c1)N(c1c(-c4ccccc4)cccc1-c1ccccc1)c1cc(N(c4ccccc4)c4ccccc4)ccc1B3c1ccc(N(c3ccccc3)c3ccccc3)cc1O2] 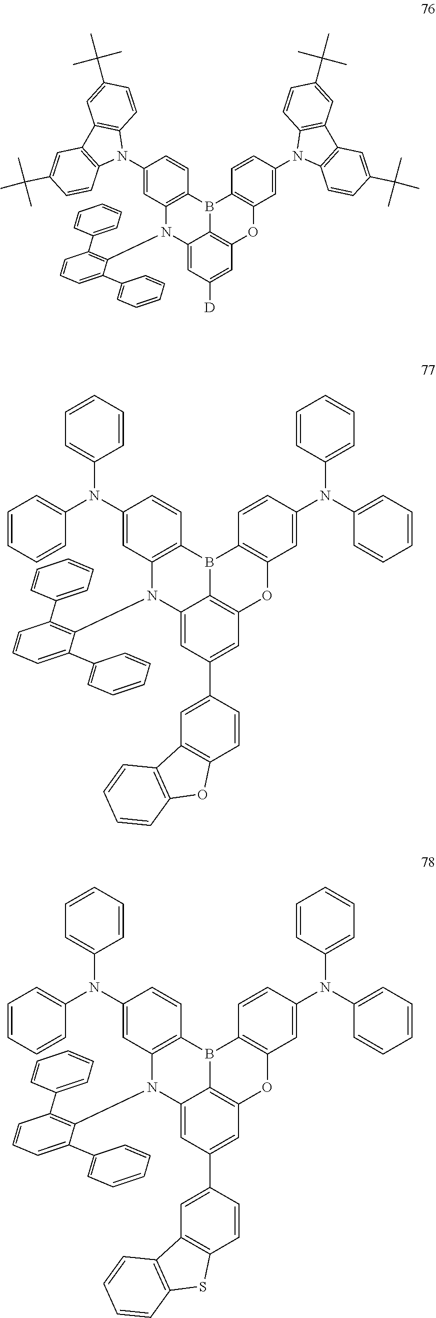 [SMILES: [2H]c1cc2c3c(c1)N(c1c(-c4ccccc4)cccc1-c1ccccc1)c1cc(-n4c5ccc(C(C)(C)C)cc5c5cc(C(C)(C)C)ccc54)ccc1B3c1ccc(-n3c4ccc(C(C)(C)C)cc4c4cc(C(C)(C)C)ccc43)cc1O2 ; c1ccc(-c2cccc(-c3ccccc3)c2N2c3cc(N(c4ccccc4)c4ccccc4)ccc3B3c4ccc(N(c5ccccc5)c5ccccc5)cc4Oc4cc(-c5ccc6oc7ccccc7c6c5)cc2c43)cc1 ; c1ccc(-c2cccc(-c3ccccc3)c2N2c3cc(N(c4ccccc4)c4ccccc4)ccc3B3c4ccc(N(c5ccccc5)c5ccccc5)cc4Oc4cc(-c5ccc6sc7ccccc7c6c5)cc2c43)cc1] 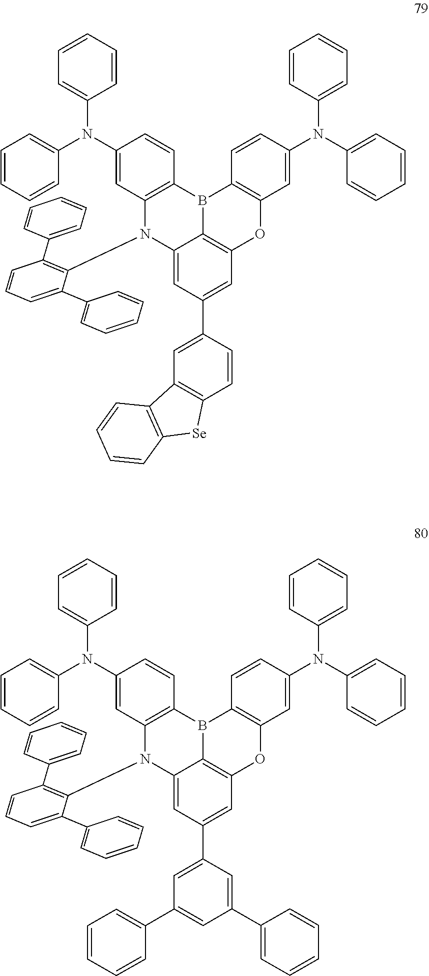 [SMILES: c1ccc(-c2cccc(-c3ccccc3)c2N2c3cc(N(c4ccccc4)c4ccccc4)ccc3B3c4ccc(N(c5ccccc5)c5ccccc5)cc4Oc4cc(-c5ccc6[se]c7ccccc7c6c5)cc2c43)cc1 ; c1ccc(-c2cc(-c3ccccc3)cc(-c3cc4c5c(c3)N(c3c(-c6ccccc6)cccc3-c3ccccc3)c3cc(N(c6ccccc6)c6ccccc6)ccc3B5c3ccc(N(c5ccccc5)c5ccccc5)cc3O4)c2)cc1] 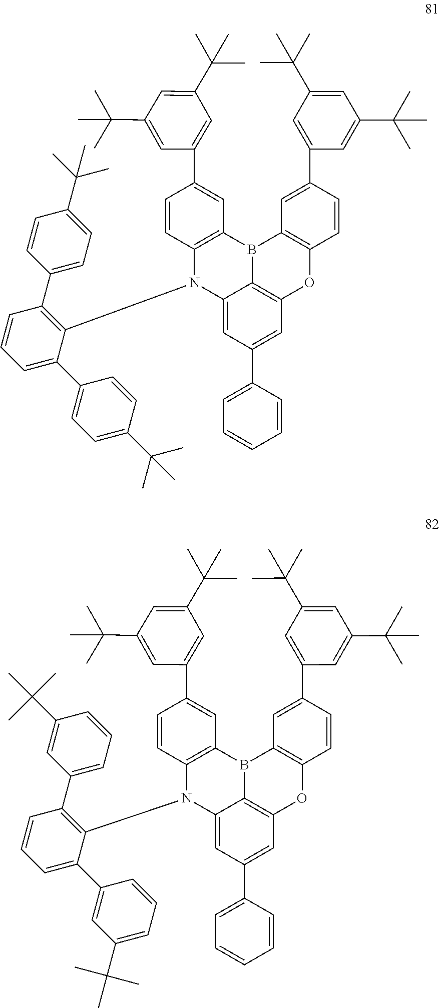 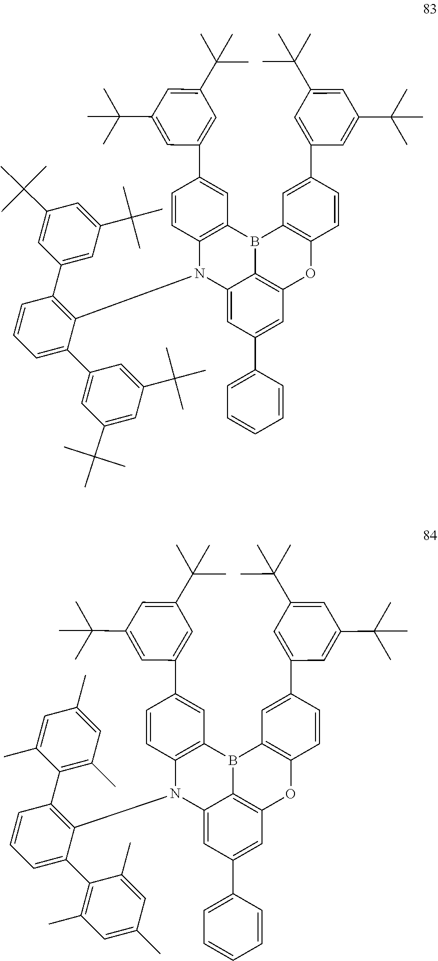 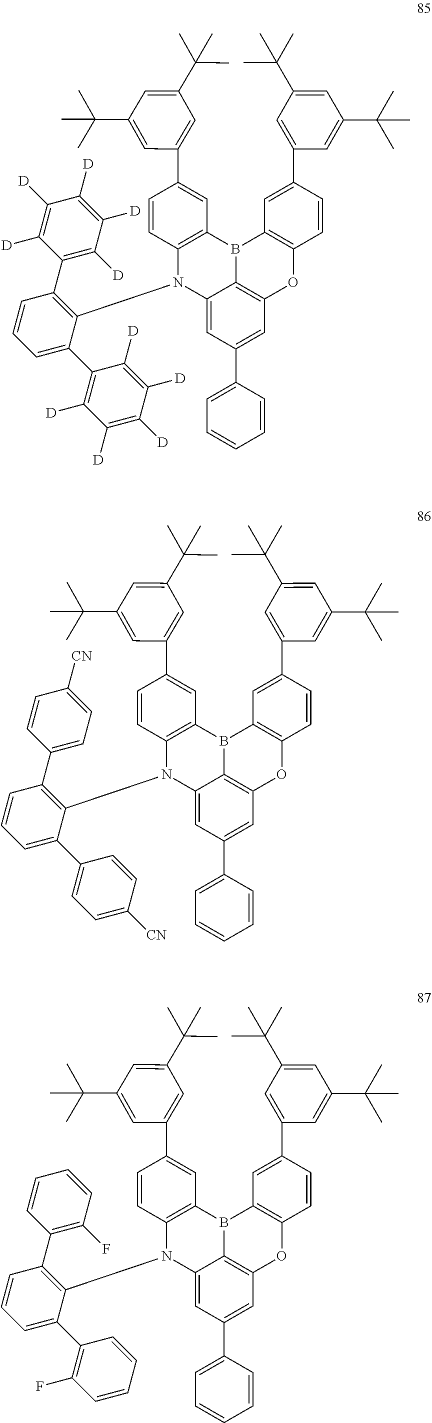 [SMILES: [2H]c1c([2H])c([2H])c(-c2cccc(-c3c([2H])c([2H])c([2H])c([2H])c3[2H])c2N2c3ccc(-c4cc(C(C)(C)C)cc(C(C)(C)C)c4)cc3B3c4cc(-c5cc(C(C)(C)C)cc(C(C)(C)C)c5)ccc4Oc4cc(-c5ccccc5)cc2c43)c([2H])c1[2H] ; CC(C)(C)c1cc(-c2ccc3c(c2)B2c4cc(-c5cc(C(C)(C)C)cc(C(C)(C)C)c5)ccc4N(c4c(-c5ccc(C#N)cc5)cccc4-c4ccc(C#N)cc4)c4cc(-c5ccccc5)cc(c42)O3)cc(C(C)(C)C)c1 ; CC(C)(C)c1cc(-c2ccc3c(c2)B2c4cc(-c5cc(C(C)(C)C)cc(C(C)(C)C)c5)ccc4N(c4c(-c5ccccc5F)cccc4-c4ccccc4F)c4cc(-c5ccccc5)cc(c42)O3)cc(C(C)(C)C)c1] 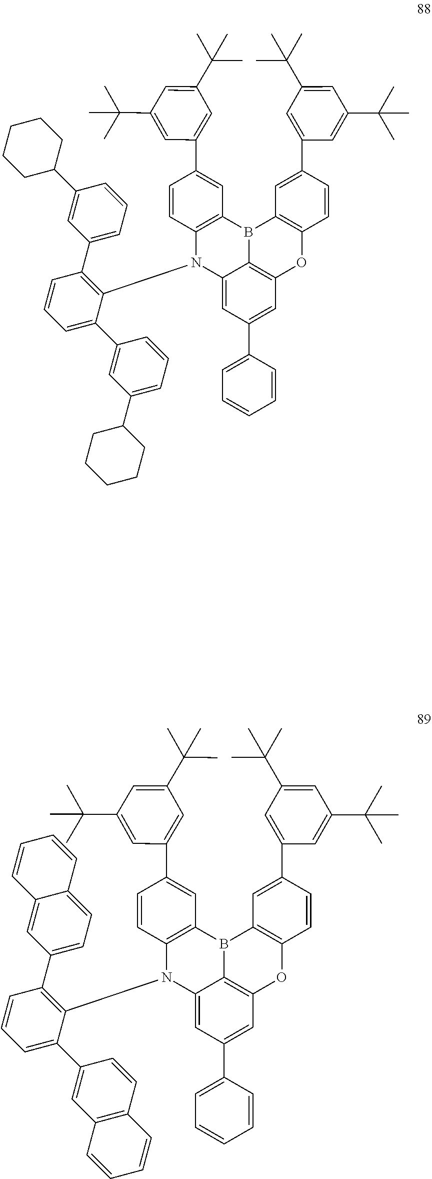 [SMILES: CC(C)(C)c1cc(-c2ccc3c(c2)B2c4cc(-c5cc(C(C)(C)C)cc(C(C)(C)C)c5)ccc4N(c4c(-c5cccc(C6CCCCC6)c5)cccc4-c4cccc(C5CCCCC5)c4)c4cc(-c5ccccc5)cc(c42)O3)cc(C(C)(C)C)c1 ; CC(C)(C)c1cc(-c2ccc3c(c2)B2c4cc(-c5cc(C(C)(C)C)cc(C(C)(C)C)c5)ccc4N(c4c(-c5ccc6ccccc6c5)cccc4-c4ccc5ccccc5c4)c4cc(-c5ccccc5)cc(c42)O3)cc(C(C)(C)C)c1] 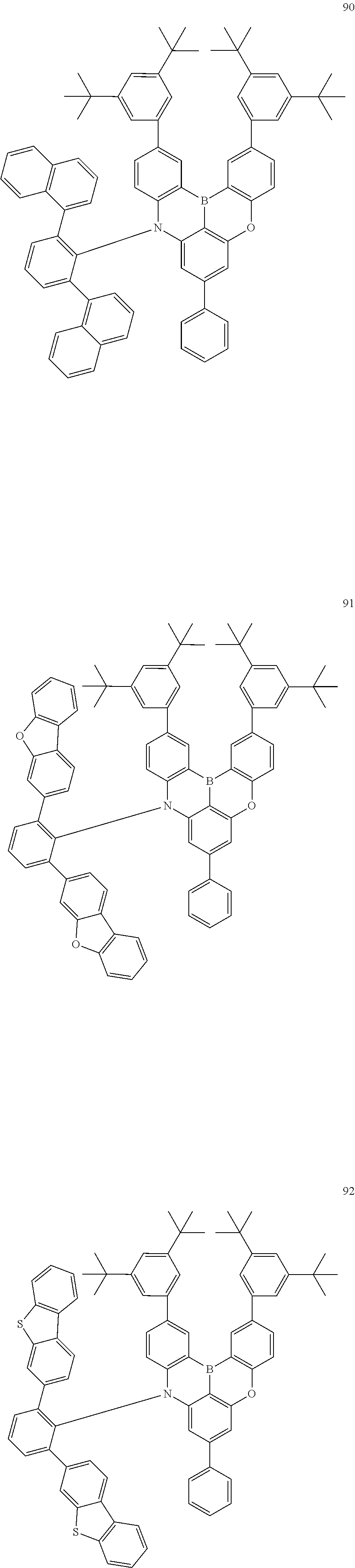 [SMILES: CC(C)(C)c1cc(-c2ccc3c(c2)B2c4cc(-c5cc(C(C)(C)C)cc(C(C)(C)C)c5)ccc4N(c4c(-c5cccc6ccccc56)cccc4-c4cccc5ccccc45)c4cc(-c5ccccc5)cc(c42)O3)cc(C(C)(C)C)c1 ; CC(C)(C)c1cc(-c2ccc3c(c2)B2c4cc(-c5cc(C(C)(C)C)cc(C(C)(C)C)c5)ccc4N(c4c(-c5ccc6c(c5)oc5ccccc56)cccc4-c4ccc5c(c4)oc4ccccc45)c4cc(-c5ccccc5)cc(c42)O3)cc(C(C)(C)C)c1 ; CC(C)(C)c1cc(-c2ccc3c(c2)B2c4cc(-c5cc(C(C)(C)C)cc(C(C)(C)C)c5)ccc4N(c4c(-c5ccc6c(c5)sc5ccccc56)cccc4-c4ccc5c(c4)sc4ccccc45)c4cc(-c5ccccc5)cc(c42)O3)cc(C(C)(C)C)c1] 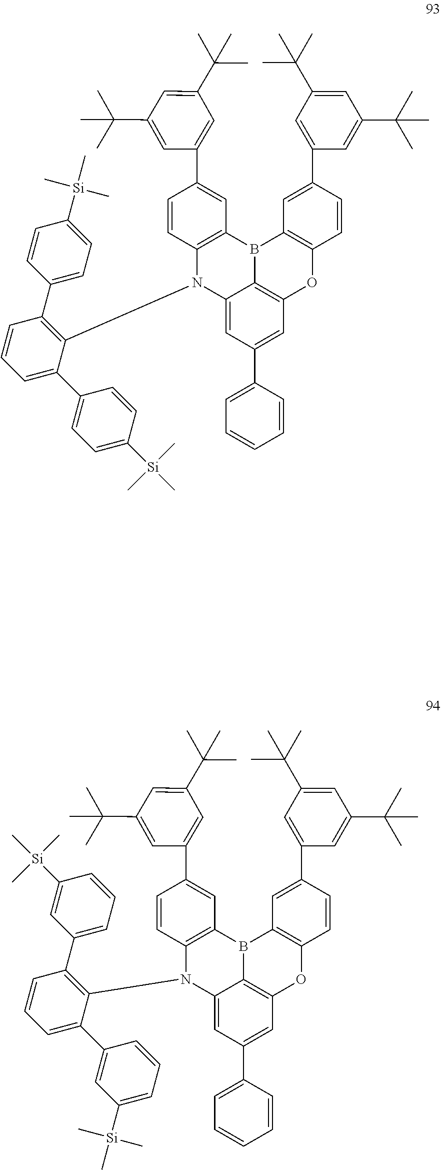 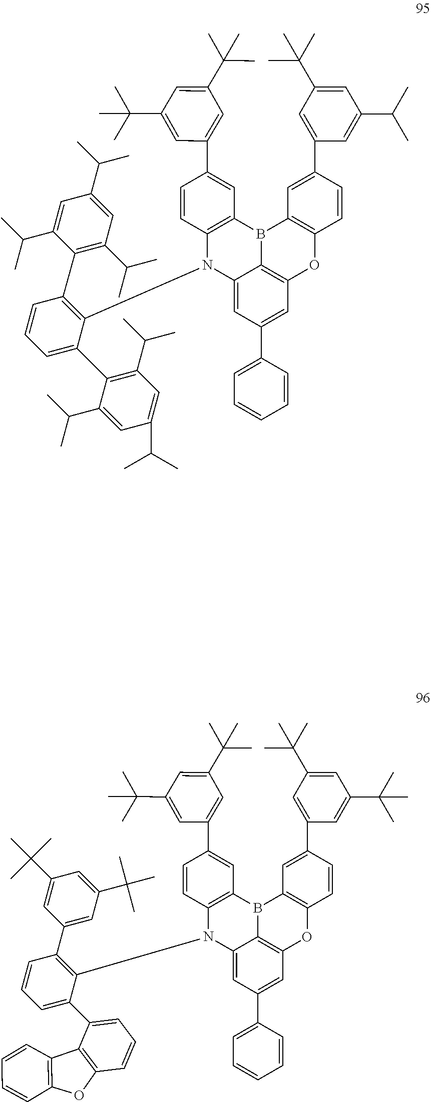 [SMILES: CC(C)c1cc(-c2ccc3c(c2)B2c4cc(-c5cc(C(C)(C)C)cc(C(C)(C)C)c5)ccc4N(c4c(-c5c(C(C)C)cc(C(C)C)cc5C(C)C)cccc4-c4c(C(C)C)cc(C(C)C)cc4C(C)C)c4cc(-c5ccccc5)cc(c42)O3)cc(C(C)(C)C)c1 ; CC(C)(C)c1cc(-c2ccc3c(c2)B2c4cc(-c5cc(C(C)(C)C)cc(C(C)(C)C)c5)ccc4N(c4c(-c5cc(C(C)(C)C)cc(C(C)(C)C)c5)cccc4-c4cccc5oc6ccccc6c45)c4cc(-c5ccccc5)cc(c42)O3)cc(C(C)(C)C)c1] 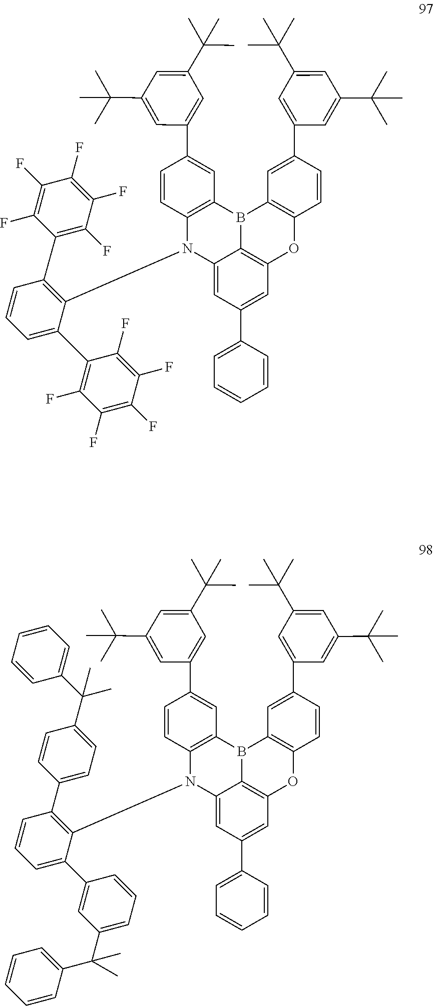 [SMILES: CC(C)(C)c1cc(-c2ccc3c(c2)B2c4cc(-c5cc(C(C)(C)C)cc(C(C)(C)C)c5)ccc4N(c4c(-c5c(F)c(F)c(F)c(F)c5F)cccc4-c4c(F)c(F)c(F)c(F)c4F)c4cc(-c5ccccc5)cc(c42)O3)cc(C(C)(C)C)c1 ; CC(C)(C)c1cc(-c2ccc3c(c2)B2c4cc(-c5cc(C(C)(C)C)cc(C(C)(C)C)c5)ccc4N(c4c(-c5ccc(C(C)(C)c6ccccc6)cc5)cccc4-c4cccc(C(C)(C)c5ccccc5)c4)c4cc(-c5ccccc5)cc(c42)O3)cc(C(C)(C)C)c1] 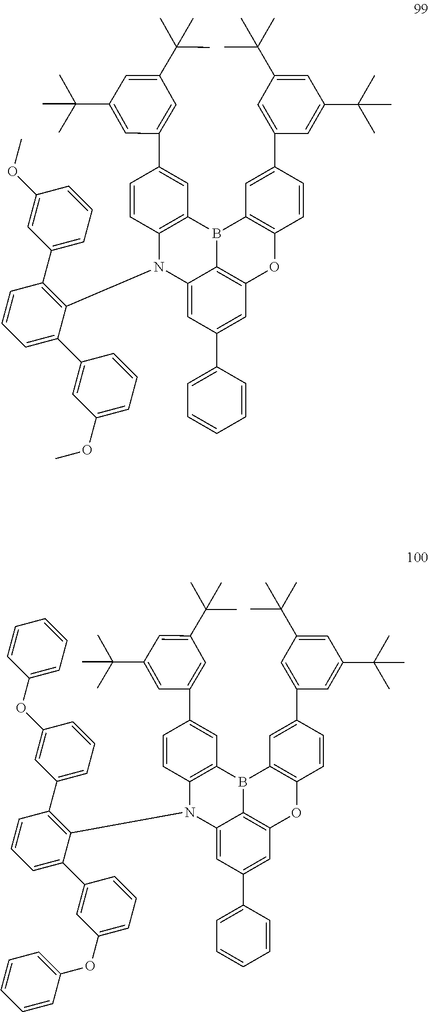 [SMILES: COc1cccc(-c2cccc(-c3cccc(OC)c3)c2N2c3ccc(-c4cc(C(C)(C)C)cc(C(C)(C)C)c4)cc3B3c4cc(-c5cc(C(C)(C)C)cc(C(C)(C)C)c5)ccc4Oc4cc(-c5ccccc5)cc2c43)c1 ; CC(C)(C)c1cc(-c2ccc3c(c2)B2c4cc(-c5cc(C(C)(C)C)cc(C(C)(C)C)c5)ccc4N(c4c(-c5cccc(Oc6ccccc6)c5)cccc4-c4cccc(Oc5ccccc5)c4)c4cc(-c5ccccc5)cc(c42)O3)cc(C(C)(C)C)c1] 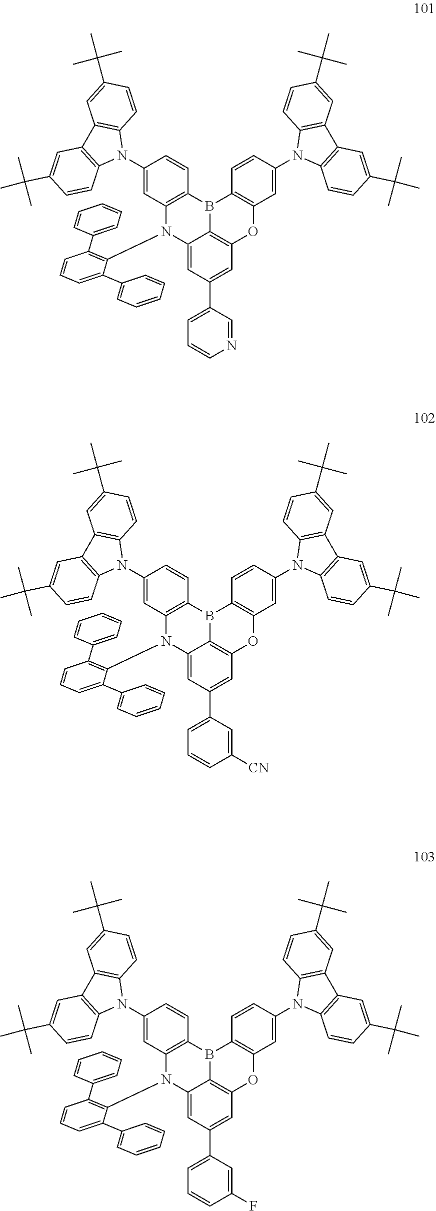 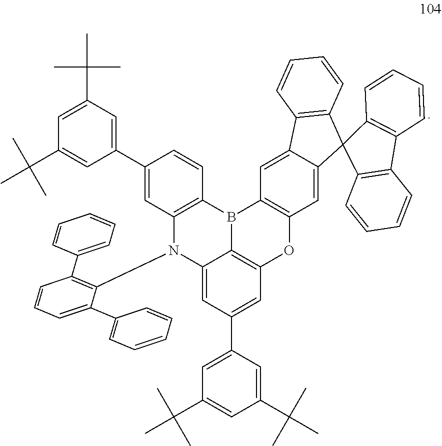 [SMILES: CC(C)(C)c1cc(-c2ccc3c(c2)N(c2c(-c4ccccc4)cccc2-c2ccccc2)c2cc(-c4cc(C(C)(C)C)cc(C(C)(C)C)c4)cc4c2B3c2cc3c(cc2O4)C2(c4ccccc4-c4ccccc42)c2ccccc2-3)cc(C(C)(C)C)c1]
